(19) United States
(12) Patent Application Publication
(10) Pub. No.: US 2026/0353704 A1
(43) Pub. Date: Nov. 5, 2026

(54) SEMICONDUCTOR DEVICE

(71) Applicant: ROHM CO., LTD., Kyoto-shi (JP)

(72) Inventor: Ryoichi MAKINO, Kyoto-shi (JP)

(73) Assignee: ROHM CO., LTD., Kyoto-shi (JP)

(21) Appl. No.: 19/467,792

(22) Filed: Feb. 3, 2026

Related U.S. Application Data
(63) Continuation of application No. PCT/JP2024/027558, filed on Aug. 1, 2024.

(30) Foreign Application Priority Data
Aug. 3, 2023 (JP) 2023-126932

(51) Int. Cl. H10D 30/66; H10D 62/10; H10D 62/60; H10D 62/832; H10D 64/23; H10D 64/27

(52) U.S. Cl. CPC H10D 30/665; H10D 30/668; H10D 62/107; H10D 62/124; H10D 62/60; H10D 62/8325; H10D 64/256; H10D 64/518; H10D 64/516

(57) ABSTRACT

A semiconductor device includes a chip having a main surface, a semiconductor region of a first conductivity type formed in a surface layer portion of the main surface, and a terminal region of a second conductivity type formed in a surface layer portion of the semiconductor region at an interval in a thickness direction of the chip from the main surface in a peripheral edge portion of the main surface.

### CROSS-REFERENCE TO RELATED APPLICATIONS

This application is a bypass continuation of International Patent Application No. PCT/JP2024/027558 filed on Aug. 1, 2024, which claims the benefit of priority to Japanese Patent Application No. 2023-126932 filed on Aug. 3, 2023 in the Japan Patent Office, and the entire contents of these applications are hereby incorporated herein by reference.

### BACKGROUND

### 1. Field of the Disclosure

The present disclosure relates to a semiconductor device.

### 2. Description of the Related Art

US2008/0277669A1 discloses a semiconductor device having a terminal structure in an outer peripheral region of a drift layer.

### BRIEF DESCRIPTION OF DRAWINGS

FIG. 1 is a plan view illustrating a semiconductor device according to a first embodiment.

FIG. 2 is a cross-sectional view taken along line II-II illustrated in FIG. 1

FIG. 3 is a plan view illustrating a layout example of a first main surface.

FIG. 4 is an enlarged plan view illustrating one main portion of the first main surface illustrated in FIG. 3.

FIG. 5 is an enlarged plan view illustrating one main portion of the first main surface illustrated in FIG. 3.

FIG. 6 is a cross-sectional view taken along line VI-VI illustrated in FIG. 4.

FIG. 7 is a cross-sectional view taken along line VII-VII illustrated in FIG. 4.

FIG. 8 is an enlarged cross-sectional view of one region illustrated in FIG. 6.

FIG. 9 is a cross-sectional view taken along line IX-IX illustrated in FIG. 5.

FIG. 10A is a cross-sectional view illustrating a cross-sectional structure of an outer peripheral region along line X-X illustrated in FIG. 1 together with an outer peripheral structure according to a first configuration example.

FIG. 10B is a cross-sectional view illustrating a cross-sectional structure of an outer peripheral region along line X-X illustrated in FIG. 1 together with the outer peripheral structure according to a second configuration example.

FIG. 10C is a cross-sectional view illustrating a cross-sectional structure of an outer peripheral region taken along line X-X illustrated in FIG. 1 together with the outer peripheral structure according to a third configuration example.

FIG. 10D is a cross-sectional view illustrating a cross-sectional structure of an outer peripheral region along line X-X illustrated in FIG. 1 together with the outer peripheral structure according to a fourth configuration example.

FIG. 10E is a cross-sectional view illustrating a cross-sectional structure of an outer peripheral region taken along line X-X illustrated in FIG. 1 together with the outer peripheral structure according to a fifth configuration example.

FIG. 11A is a cross-sectional view illustrating a first outer peripheral structure according to a first modification example.

FIG. 11B is a cross-sectional view illustrating the first outer peripheral structure according to a second modification example.

FIG. 11C is a cross-sectional view illustrating the first outer peripheral structure according to a third modification example.

FIG. 11D is a cross-sectional view illustrating the first outer peripheral structure according to a fourth modification example.

FIG. 11E is a cross-sectional view illustrating the first outer peripheral structure according to a fifth modification example.

FIG. 11F is a cross-sectional view illustrating the first outer peripheral structure according to a sixth modification example.

FIG. 11G is a cross-sectional view illustrating the first outer peripheral structure according to a seventh modification example.

FIG. 11H is a cross-sectional view illustrating the first outer peripheral structure according to an eighth modification example.

FIG. 11I is a cross-sectional view illustrating the first outer peripheral structure according to a ninth modification example.

FIG. 11J is a cross-sectional view illustrating the first outer peripheral structure according to a tenth modification example.

FIG. 12A is a cross-sectional view illustrating a second outer peripheral structure according to a first modification example.

FIG. 12B is a cross-sectional view illustrating the second outer peripheral structure according to a second modification example.

FIG. 12C is a cross-sectional view illustrating the second outer peripheral structure according to a third modification example.

FIG. 12D is a cross-sectional view illustrating the second outer peripheral structure according to a fourth modification example.

FIG. 12E is a cross-sectional view illustrating the second outer peripheral structure according to a fifth modification example.

FIG. 12F is a cross-sectional view illustrating the second outer peripheral structure according to a sixth modification example.

FIG. 12G is a cross-sectional view illustrating the second outer peripheral structure according to a seventh modification example.

FIG. 12H is a cross-sectional view illustrating the second outer peripheral structure according to an eighth modification example.

FIG. 12I is a cross-sectional view illustrating the second outer peripheral structure according to a ninth modification example.

FIG. 12J is a cross-sectional view illustrating the second outer peripheral structure according to a tenth modification example.

FIG. 13 is a cross-sectional view illustrating one main portion of an active region of a semiconductor device according to a second embodiment.

FIG. 14 is a cross-sectional view illustrating one main portion of the active region of the semiconductor device illustrated in FIG. 13.

FIG. 15 is a cross-sectional view illustrating an outer peripheral region of the semiconductor device illustrated in FIG. 13 together with the outer peripheral structure according to the first configuration example.

FIG. 16 is an enlarged plan view illustrating one main portion of an active region of a semiconductor device according to a third embodiment.

FIG. 17 is a cross-sectional view taken along line XVII-XVII illustrated in FIG. 16.

FIG. 18 is a cross-sectional view taken along line XVIII-XVIII illustrated in FIG. 16.

FIG. 19 is a cross-sectional view illustrating one main portion of the active region of the semiconductor device illustrated in FIG. 16.

FIG. 20 is a plan view illustrating a semiconductor device according to a fourth embodiment.

FIG. 21 is a cross-sectional view taken along line XXI-XXI illustrated in FIG. 20.

FIG. 22 is a perspective view illustrating a shape of a chip.

FIG. 23 is a plan view illustrating a layout example of a first main surface.

FIG. 24 is an enlarged plan view illustrating one main portion of the first main surface illustrated in FIG. 23.

FIG. 25 is an enlarged plan view illustrating one main portion of the first main surface illustrated in FIG. 23.

FIG. 26 is a cross-sectional view taken along line XXVI-XXVI illustrated in FIG. 25.

FIG. 27 is a cross-sectional view illustrating a cross-sectional structure of an outer peripheral region taken along line XXVII-XXVII illustrated in FIG. 20 together with the outer peripheral structure according to the first configuration example.

FIG. 28 is a cross-sectional view illustrating one main portion of an active region of a semiconductor device according to a fifth embodiment.

FIG. 29 is a cross-sectional view illustrating one main portion of an active region of the semiconductor device illustrated in FIG. 28.

FIG. 30 is a cross-sectional view illustrating an outer peripheral region of the semiconductor device illustrated in FIG. 28 together with the outer peripheral structure according to the first configuration example.

FIG. 31 is an enlarged plan view illustrating an active region of a semiconductor device according to a sixth embodiment.

FIG. 32 is a cross-sectional view taken along line XXXII-XXXII illustrated in FIG. 31.

FIG. 33 is a cross-sectional view taken along line XXXIII-XXXIII illustrated in FIG. 31.

FIG. 34 is a cross-sectional view illustrating one main portion of an active region of the semiconductor device illustrated in FIG. 31.

FIG. 35 is a plan view illustrating a semiconductor device according to a seventh embodiment.

FIG. 36 is a cross-sectional view taken along line XXXVI-XXXVI illustrated in FIG. 35.

FIG. 37 is a plan view illustrating a layout example of the first main surface.

FIG. 38 is an enlarged plan view illustrating one main portion of the first main surface illustrated in FIG. 37.

FIG. 39 is a cross-sectional view taken along line XXXIX-XXXIX illustrated in FIG. 38.

FIG. 40 is an enlarged cross-sectional view of one region illustrated in FIG. 39.

FIG. 41 is a cross-sectional view illustrating a cross-sectional structure taken along line XLI-XLI illustrated in FIG. 35 together with the outer peripheral structure according to the first configuration example.

### DETAILED DESCRIPTION OF THE PREFERRED EMBODIMENTS

Hereinafter, specific embodiments will be described in detail with reference to attached drawings. The attached drawings are all schematic views and are not strictly illustrated, and relative positional relationships, scales, proportions, angles and the like thereof do not always match. Identical reference signs are given to corresponding structures among the attached drawings, and duplicate descriptions thereof shall be omitted or simplified. For the structures whose description has been omitted or simplified, the description given before the omission or simplification shall apply.

When the wording “substantially” is used in this Description, the wording includes a numerical value (shape) equal to a numerical value (shape) of a comparison target and also includes numerical errors (shape errors) in a range of ±10% with the numerical value (shape) of the comparison target as a reference. Although the wordings “first,” “second,” “third,” etc., are used in the following description, these are indicators added to names of respective structures in order to clarify the order of description and are not added with an intention of restricting the names of the respective structures.

In the following description, a “p-type” or an “n-type” is used to indicate a conductivity type of a semiconductor (impurity). However, the “p-type” may be referred to as a “first conductivity type,” and the “n-type” may be referred to as a “second conductivity type.” As a matter of course, the “n-type” may be referred to as a “first conductivity type,” and the “p-type” may be referred to as a “second conductivity type.”

The “p-type” is a conductivity type caused by a trivalent element, and the “n-type” is a conductivity type caused by a pentavalent element. The trivalent element is at least one of boron, aluminum, gallium, and indium. The pentavalent element is at least one of nitrogen, phosphorus, arsenic, antimony, and bismuth.

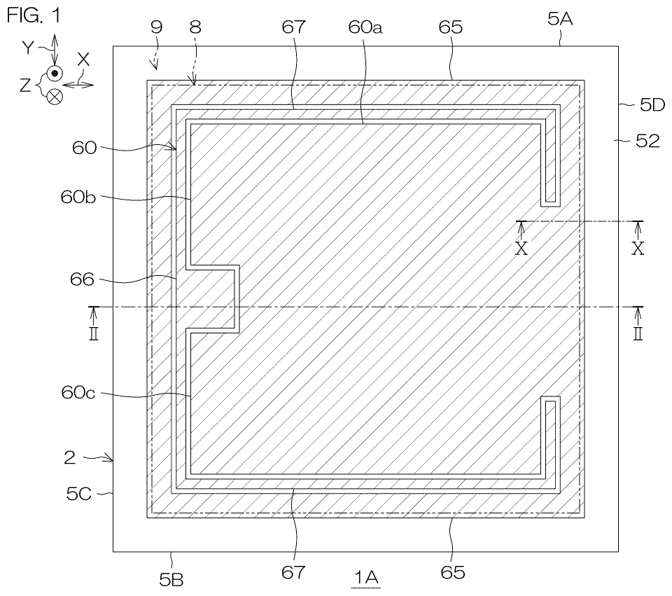

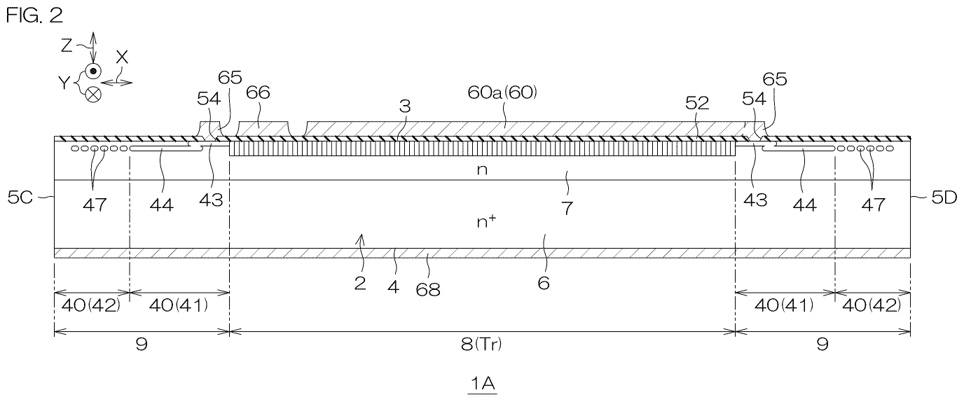

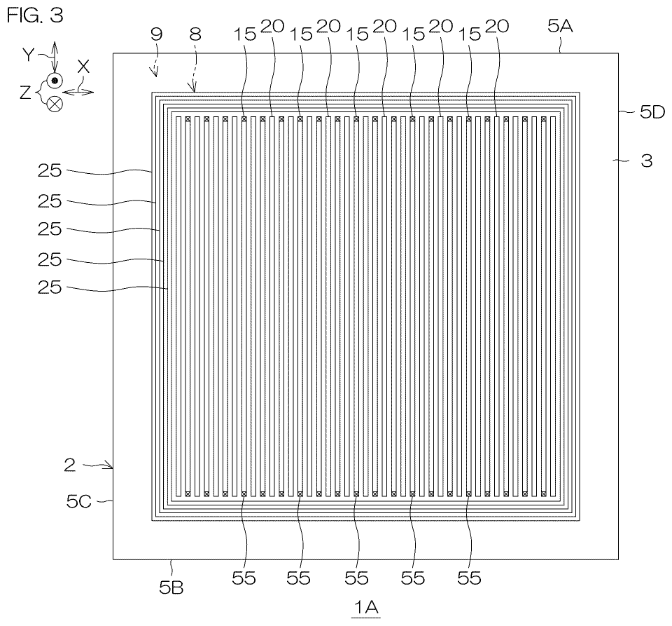

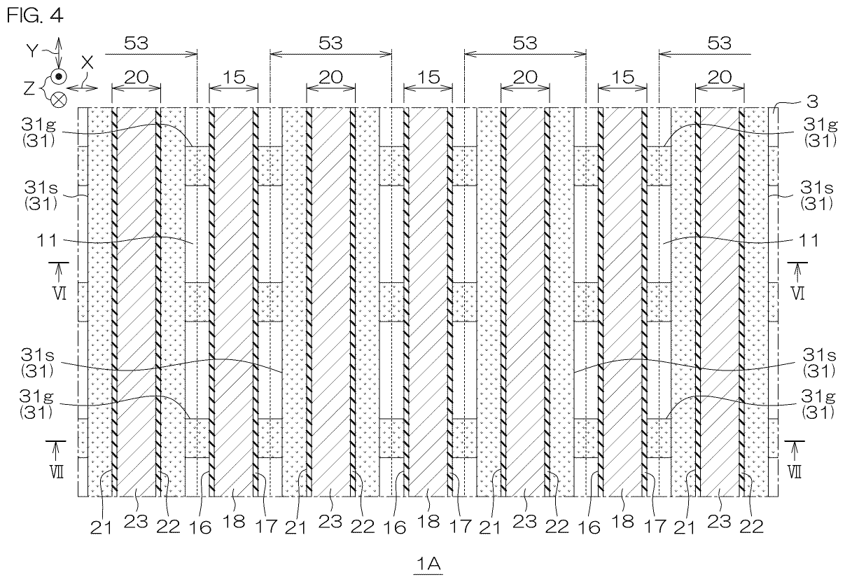

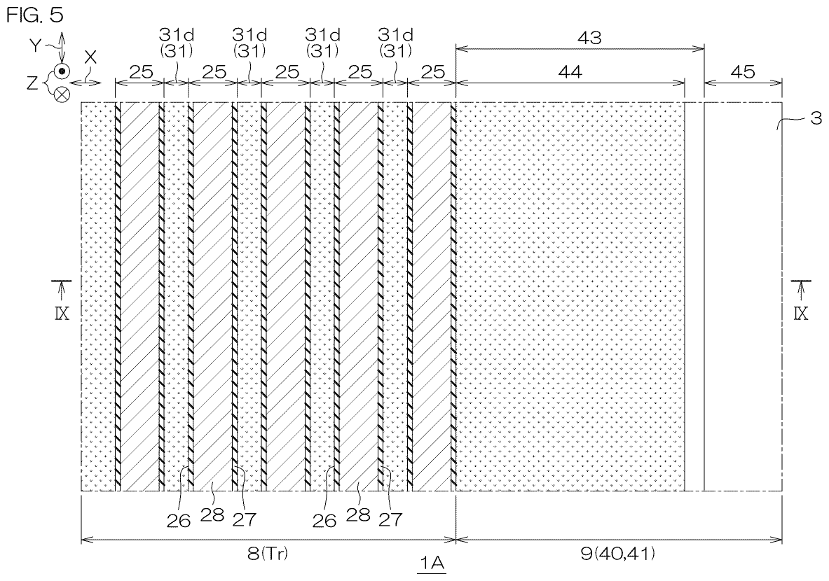

FIG. 1 is a plan view illustrating a semiconductor device 1A according to a first embodiment. FIG. 2 is a cross-sectional view taken along line II-II illustrated in FIG. 1 FIG. 3 is a plan view illustrating a layout example of a first main surface 3. FIG. 4 is an enlarged plan view illustrating one main portion of the first main surface 3 illustrated in FIG. 3 FIG. 5 is an enlarged plan view illustrating one main portion of the first main surface 3 illustrated in FIG. 3

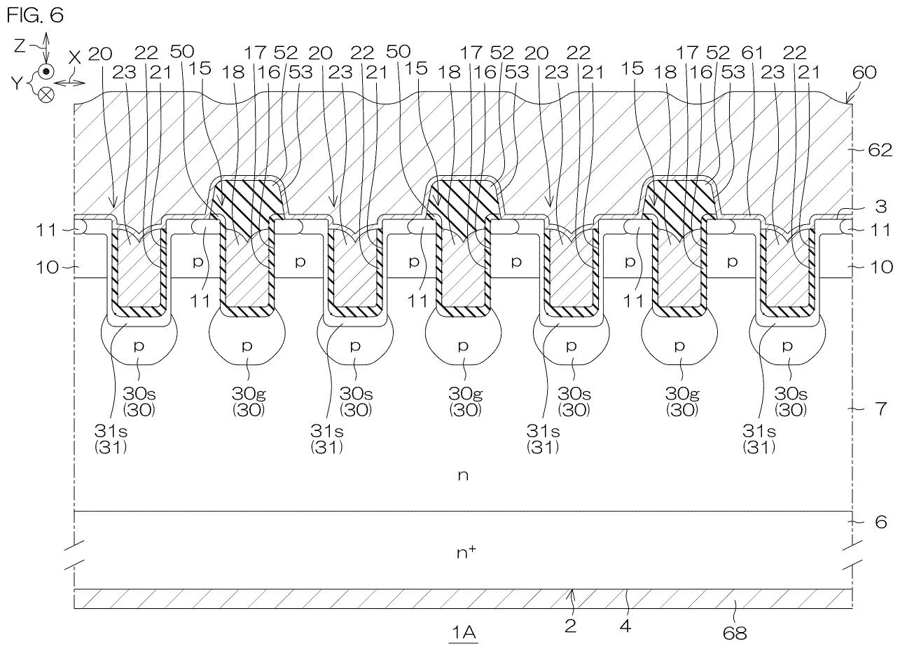

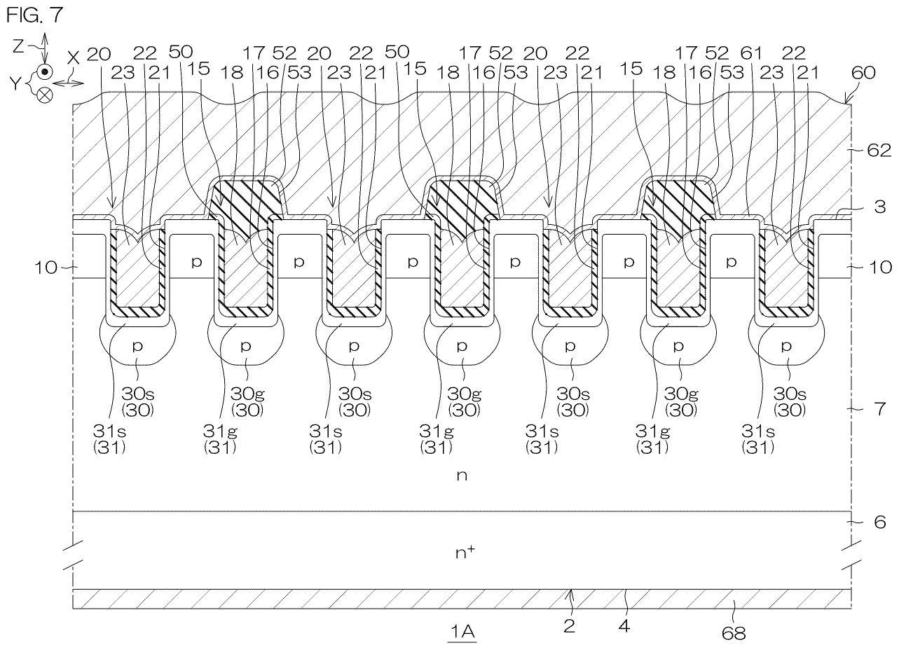

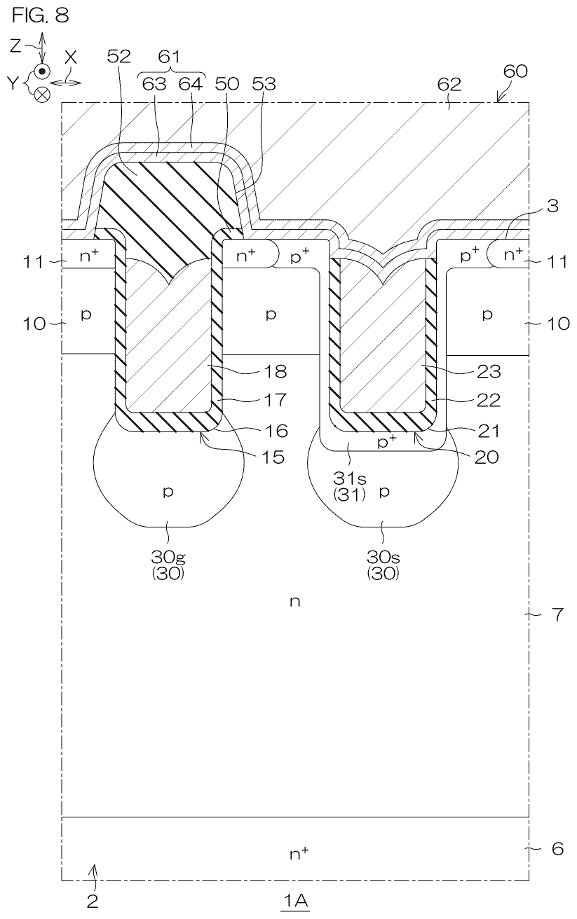

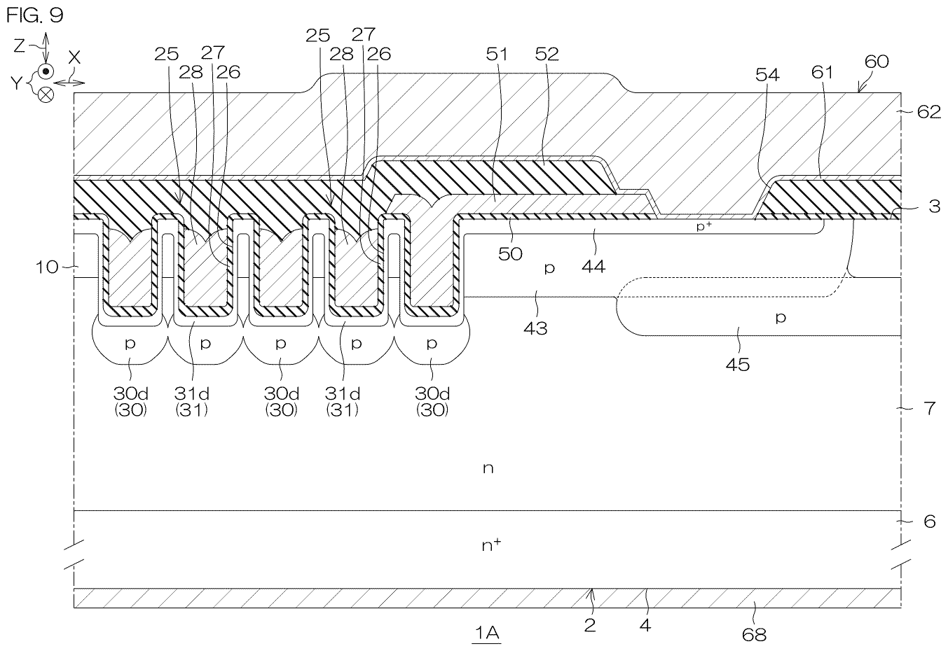

FIG. 6 is a cross-sectional view taken along line VI-VI illustrated in FIG. 4. FIG. 7 is a cross-sectional view taken along line VII-VII illustrated in FIG. 4. FIG. 8 is an enlarged cross-sectional view of one region illustrated in FIG. 6. FIG. 9 is a cross-sectional view taken along line IX-IX illustrated in FIG. 5.

Referring to FIG. 1 to FIG. 9, the semiconductor device 1A is a semiconductor switching device having a transistor structure Tr of an insulated gate type as an example of a device structure. The transistor structure Tr has a trench gate type vertical structure.

The semiconductor device 1A includes a chip 2 formed in a hexahedral shape (specifically, a rectangular parallelepiped shape). In this embodiment, the chip 2 includes a monocrystal of a wide bandgap semiconductor. That is, the semiconductor device 1A is a “wide bandgap semiconductor device.” The chip 2 may also be referred to as a “semiconductor chip” or a “wide bandgap semiconductor chip,” etc.

The wide bandgap semiconductor is a semiconductor that has a bandgap exceeding a bandgap of Si (silicon). GaN (gallium nitride), SiC (silicon carbide), C (diamond), etc., can be given as examples of the wide bandgap semiconductor. In this embodiment, the chip 2 is an “SiC chip” that includes, as an example of the wide bandgap semiconductor, an SiC monocrystal that is a hexagonal crystal. That is, the semiconductor device 1A is a “SiC semiconductor device.”

The SiC monocrystal that is a hexagonal crystal has multiple polytypes including a 2H (hexagonal)-SiC monocrystal, a 4H-SiC monocrystal, a 6H-SiC monocrystal, etc. In this embodiment, an example in which the chip 2 includes the 4H-SiC monocrystal is given, but the chip 2 may include another polytype instead.

The chip 2 has the first main surface 3 on one side, a second main surface 4 on the other side, and first to fourth side surfaces 5A to 5D connected to the first main surface 3 and the second main surface 4. In plan view when viewed from a vertical direction Z (hereinafter, referred to simply as “plan view”), the first main surface 3 and the second main surface 4 are formed in quadrilateral shapes. The vertical direction Z is also a thickness direction of the chip 2.

Preferably, the first main surface 3 and the second main surface 4 are formed by c-planes of the SiC monocrystal. In this case, preferably, the first main surface 3 is formed by a silicon plane (a (0001) plane) of the SiC monocrystal, and the second main surface 4 is formed by a carbon plane (a (000-1) plane) of the SiC monocrystal.

The first side surface 5A and the second side surface 5B extend in a first direction X along the first main surface 3, and oppose each other in a second direction Y intersecting the first direction X along the first main surface 3. Specifically, the second direction Y is orthogonal to the first direction X. The third side surface 5C and the fourth side surface 5D extend in the second direction Y, and oppose each other in the first direction X.

In this embodiment, the first direction X is an m-axis direction (a [1-100] direction) of the SiC monocrystal, and the second direction Y is an a-axis direction (a [11-20] direction) of the SiC monocrystal. As a matter of course, the first direction X may be the a-axis direction of the SiC monocrystal, and the second direction Y may be the m-axis direction of the SiC monocrystal.

In the following, directions extending along the first main surface 3 are expressed at times as “horizontal directions.” The horizontal directions are also an XY plane (a horizontal plane) formed by the first direction X and the second direction Y and are orthogonal to the vertical direction Z.

The chip 2 (the first main surface 3 and the second main surface 4) has an off angle by being inclined at a predetermined angle in a predetermined off direction with respect to the c-plane of the SiC monocrystal. That is, a c-axis (a (0001) axis) of the SiC monocrystal is inclined by the off angle from the vertical line along the vertical direction Z toward the off direction. Also, the c-plane of the SiC monocrystal is inclined by the off angle with respect to the horizontal plane.

The off direction is preferably the a-axis direction (in this embodiment, the second direction Y) of the SiC monocrystal. The off angle may exceed 0° but be not more than 10°. The off angle may have a value belonging to at least one range among exceeding 0° and being not more than 1°, being not less than 1° and not more than 2.5°, being not less than 2.5° and not more than 5°, being not less than 5° and not more than 7.5°, and being not less than 7.5° and not more than 10°.

Preferably, the off angle is not more than 5°. It is particularly preferable that the off angle is not less than 2° and not more than 4.5°. The off angle is typically set in a range of 4°±0.1°. This Description does not exclude an embodiment in which the off angle is 0° (that is, an embodiment in which the first main surface 3 is a just surface with respect to the c-plane).

The semiconductor device 1A includes a first semiconductor region 6 of the n-type formed in a surface layer portion of the second main surface 4. A drain potential is to be applied as a first potential (a high potential) to the first semiconductor region 6. The first semiconductor region 6 may be referred to as a “base region (layer),” a “semiconductor region (layer),” a “drain region (layer),” etc.

The first semiconductor region 6 extends in a layer shape along the second main surface 4 and is exposed from the second main surface 4 and the first to fourth side surfaces 5A to 5D. In this embodiment, the first semiconductor region 6 is constituted of a semiconductor layer of the n-type. Specifically, the first semiconductor region 6 is constituted of a substrate (an SiC substrate) including an SiC monocrystal (a semiconductor monocrystal), and forms the second main surface 4 and the first to fourth side surfaces 5A to 5D. The first semiconductor region 6 (the substrate) has the off direction and the off angle described above.

The first semiconductor region 6 may have a thickness of not less than 10 μm and not more than 500 μm. The thickness of the first semiconductor region 6 may have a value belonging to at least one range among not less than 10 μm and not more than 50 μm, not less than 50 μm and not more than 100 μm, not less than 100 μm and not more than 150 μm, not less than 150 μm and not more than 200 μm, not less than 200 μm and not more than 300 μm, not less than 300 μm and not more than 400 μm, and not less than 400 μm and not more than 500 μm.

The semiconductor device 1A includes a second semiconductor region 7 of the n-type formed in the surface layer portion of the first main surface 3. The second semiconductor region 7 may be referred to as a “semiconductor region (layer),” a “drift region (layer),” etc. The second semiconductor region 7 has an n-type impurity concentration that is less than an n-type impurity concentration of the first semiconductor region 6. The second semiconductor region 7 is formed in a region on the first main surface 3 side with respect to the first semiconductor region 6 in cross-sectional view, and is electrically connected to the first semiconductor region 6.

The second semiconductor region 7 extends in a layer shape along the first main surface 3 and is exposed from the first main surface 3 and the first to fourth side surfaces 5A to 5D. In this embodiment, the second semiconductor region 7 is constituted of a semiconductor layer of the n-type. Specifically, the second semiconductor region 7 is constituted of an epitaxial layer (an SiC epitaxial layer) including an SiC monocrystal (a semiconductor monocrystal) and forms the first main surface 3 and the first to fourth side surfaces 5A to 5D.

The second semiconductor region 7 (the epitaxial layer) has the off direction and the off angle described above. The second semiconductor region 7 preferably has a thickness less than the thickness of the first semiconductor region 6. As a matter of course, the thickness of the second semiconductor region 7 may instead be greater than the thickness of the first semiconductor region 6.

The thickness of the second semiconductor region 7 may be not less than 5 μm and not more than 15 μm. The thickness of the second semiconductor region 7 may have a value belonging to at least one range among not less than 5 μm and not more than 7.5 μm, not less than 7.5 μm and not more than 10 μm, not less than 10 μm and not more than 12.5 μm, and not less than 12.5 μm and not more than 15 μm.

The semiconductor device 1A includes an active region 8 that is set in the chip 2. The active region 8 is a region that has a device structure (the transistor structure Tr) and in which an output current (a drain current) is generated. The active region 8 is set in the inner portion of the chip 2 at an interval from the peripheral edge (the first to fourth side surfaces 5A to 5D) of the first main surface 3.

The active region 8 is set in a polygonal shape (in this embodiment, quadrilateral shape) having four sides parallel to the peripheral edge of the chip 2 in plan view. A ratio (area ratio) of the planar area of the active region 8 to the planar area of the first main surface 3 may be not less than 0.5 and not more than 0.95. The area ratio may be not less than 0.5 and not more than 0.6, not less than 0.6 and not more than 0.7, not less than 0.7 and not more than 0.8, not less than 0.8 and not more than 0.9, or not less than 0.9 and not more than 0.95.

The semiconductor device 1A includes an outer peripheral region 9 set outside the active region 8 in the chip 2. The outer peripheral region 9 is a region in which the device structure (the transistor structure Tr) is not included. The outer peripheral region 9 is set in a peripheral edge portion of the chip 2.

That is, the outer peripheral region 9 is provided in a region between the peripheral edge of the chip 2 and the active region 8 in plan view. The outer peripheral region 9 extends in a band shape along the active region 8 in plan view, and is set in a polygonal annular shape (in this embodiment, a quadrilateral annular shape) that surrounds the active region 8.

The semiconductor device 1A includes a body region 10 of the p-type formed in the surface layer portion of the first main surface 3 in an inner portion of the first main surface 3. The body region 10 may be referred to as an “impurity region,” a “channel region,” etc.

The body region 10 has a p-type impurity concentration higher than the n-type impurity concentration of the second semiconductor region 7. A source potential may be applied to the body region 10. The source potential may be a reference potential serving as a reference of circuit operation. The reference potential may be the ground potential.

The body region 10 is formed in a surface layer portion of the second semiconductor region 7. The body region 10 is formed in the inner portion of the first main surface 3 at an interval from the peripheral edge (the first to fourth side surfaces 5A to 5D) of the first main surface 3. The body region 10 is formed in the active region 8 and is not formed in the outer peripheral region 9. In this embodiment, the body region 10 is formed over the entire active region 8.

The body region 10 is formed at an interval toward the first main surface 3 side from a bottom portion of the second semiconductor region 7 (the first semiconductor region 6), and faces the first semiconductor region 6 with a portion of the second semiconductor region 7 interposed therebetween. That is, the body region 10 is formed in a region on the first main surface 3 side with respect to the second semiconductor region 7 in cross-sectional view, and is electrically connected to the second semiconductor region 7.

In other words, the body region 10 is formed in a thickness range between the first main surface 3 and the second semiconductor region 7 in cross-sectional view, and forms a pn junction portion with the second semiconductor region 7. The bottom portion of the body region 10 is positioned at the first main surface 3 side with respect to a depth position of the intermediate portion of the second semiconductor region 7.

The semiconductor device 1A includes a source region 11 of the n-type formed in the surface layer portion of the first main surface 3 in the inner portion of the first main surface 3. The source potential is to be applied to the source region 11. The source region 11 has an n-type impurity concentration higher than the n-type impurity concentration of the second semiconductor region 7. The n-type impurity concentration of the source region 11 is higher than the p-type impurity concentration of the body region 10.

The source region 11 is formed in the inner portion of the first main surface 3 at an interval from the peripheral edge (the first to fourth side surfaces 5A to 5D) of the first main surface 3. The source region 11 is formed in the active region 8 and is not formed in the outer peripheral region 9.

The source region 11 is formed in the surface layer portion of the body region 10 at an interval toward the first main surface 3 side from the bottom portion of the body region 10, and faces the second semiconductor region 7 with a portion of the body region 10 interposed therebetween. In other words, the source region 11 is formed in a thickness range between the first main surface 3 and the body region 10 in cross-sectional view.

That is, source region 11 is formed in a region on the first main surface 3 side with respect to body region 10 in cross-sectional view, and is electrically connected to body region 10. The source region 11 may be formed at an interval inward from the peripheral edge of the body region 10 in plan view. The source region 11 extends in a layer shape along the first main surface 3.

The semiconductor device 1A includes a plurality of gate structures 15 of a trench type (a trench electrode type) formed in the inner portion of the first main surface 3. The gate structure 15 may be referred to as a “trench structure,” a “trench gate structure,” etc. A gate potential (a gate signal) as a control potential is to be applied to the plurality of gate structures 15. The plurality of gate structures 15 control inversion and non-inversion of channels in the body region 10 in response to the gate potential.

The plurality of gate structures 15 are formed in the inner portion of the first main surface 3 at an interval from the peripheral edge (the first to fourth side surfaces 5A to 5D) of the first main surface 3. The plurality of gate structures 15 are formed in the active region 8 and are not formed in the outer peripheral region 9.

The plurality of gate structures 15 are aligned at intervals in the first direction X (=the m-axis direction) in plan view, and each extend in a band shape in the second direction Y (=the a-axis direction). That is, the plurality of gate structures 15 are aligned in a stripe shape extending in the second direction Y in plan view. The extension direction of the plurality of gate structures 15 coincides with the off direction of the SiC monocrystal.

As a matter of course, the plurality of gate structures 15 may be aligned at intervals in the second direction Y in plan view, and may each extend in a band shape in the first direction X. With respect to the second direction Y, both end portions of the plurality of gate structures 15 may be positioned in a region between a peripheral edge portion of the body region 10 and a peripheral edge portion of the source region 11.

When a distance in the horizontal direction (the first direction X) between central portions of the plurality of gate structures 15 is defined as a gate pitch, the gate pitch may be not less than 1 μm and not more than 5 μm. The gate pitch may have a value belonging to at least one range among not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The plurality of gate structures 15 penetrate the body region 10 and the source region 11 so as to reach the second semiconductor region 7. The plurality of gate structures 15 are formed at intervals toward the first main surface 3 side from a depth position of the bottom portion of the second semiconductor region 7, and face the first semiconductor region 6 with a portion of the second semiconductor region 7 interposed therebetween.

In this embodiment, the plurality of gate structures 15 are formed substantially perpendicular to the first main surface 3. As a matter of course, the plurality of gate structures 15 may be formed in a tapered shape toward the bottom portion of the second semiconductor region 7.

Side walls (long sides) of the plurality of gate structures 15 are each formed by an m-plane (a (1-100) plane) of SiC monocrystal. As a matter of course, the side walls (the long sides) of the plurality of gate structures 15 may each be formed by an a-plane (a (11-20) plane) of the SiC monocrystal in accordance with the extension direction of the gate structure 15. The side walls of the plurality of gate structures 15 are formed substantially perpendicular to the first main surface 3.

Bottom walls of the plurality of gate structures 15 are formed by the c-plane (the Si plane) of SiC monocrystal. The bottom walls of the plurality of gate structures 15 preferably extend substantially flat along the horizontal directions. As a matter of course, the bottom walls of the plurality of gate structures 15 may be curved in an arc shape toward the second main surface 4 side.

An inclination angle (absolute value) of each side wall (long side) of the gate structures 15 on a basis of a vertical line may be not less than 85° and not more than 95°. The inclination angle may have a value belonging to at least one range among not less than 85° and not more than 87.5°, not less than 87.5° and not more than 90°, not less than 90° and not more than 92.5°, and not less than 92.5° and not more than 95°. The inclination angle is preferably not less than 87° and not more than 93°.

The gate structure 15 may have a width of not less than 0.1 μm and not more than 2 μm. The width of the gate structure 15 may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

A depth of the gate structure 15 may be not less than 0.1 μm and not more than 3 μm. The depth of the gate structure 15 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The depth of the gate structure 15 is preferably not less than 0.5 μm and not more than 1.5 μm.

The gate structure 15 may have an aspect ratio of not less than 1 and not more than 3. The aspect ratio of the gate structure 15 is a ratio of the depth of the gate structure 15 to the width of the gate structure 15. The aspect ratio may have a value belonging to at least one range among not less than 1 and not more than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, and not less than 2.75 and not more than 3. The aspect ratio is preferably not less than 1.5 and not more than 2.5.

Each of the plurality of gate structures 15 includes a first trench 16, a first insulating film 17, and a first embedded electrode 18. The first trench 16 is formed in the first main surface 3 and demarcates wall surfaces (the side wall and the bottom wall) of the gate structure 15.

The first insulating film 17 covers a wall surface of the first trench 16. The first insulating film 17 may include at least one among a silicon oxide film, a silicon nitride film, and a silicon oxynitride film. In this embodiment, the first insulating film 17 has a single layer structure constituted of a silicon oxide film. The first insulating film 17 particularly preferably includes a silicon oxide film made of an oxide of the chip 2.

The first insulating film 17 includes a first film portion and a second film portion. The first film portion covers side walls of the first trench 16 in a film shape. The second film portion covers a bottom wall of the first trench 16 in a film shape and is continuous to the first film portion. The second film portion has a thickness greater than a thickness of the first film portion. The thickness of the second film portion may instead be substantially equal to the thickness of the first film portion.

The first insulating film 17 may have a thickness of not less than 10 nm and not more than 150 nm. The thickness of the first insulating film 17 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, and not less than 125 nm and not more than 150 nm.

The first embedded electrode 18 is embedded in the first trench 16 with the first insulating film 17 interposed therebetween. The first embedded electrode 18 may contain either or both of a conductive polysilicon of the p-type and a conductive polysilicon of the n-type. The first embedded electrode 18 faces the second semiconductor region 7, the body region 10, and the source region 11 with the first insulating film 17 interposed therebetween.

The first embedded electrode 18 has an electrode surface exposed from the first trench 16. The electrode surface of the first embedded electrode 18 is positioned at the bottom wall side of the first trench 16 with respect to a height position of the first main surface 3. The electrode surface of the first embedded electrode 18 is positioned at the first main surface 3 side with respect to a depth position of the bottom portion of the source region 11. The electrode surface of the first embedded electrode 18 has a recess that is recessed in a tapered shape toward the bottom wall side of the first trench 16 in the inner portion.

The semiconductor device 1A includes a plurality of source structures 20 of the trench type (the trench electrode type) formed in the inner portion of the first main surface 3. The source structure 20 may be referred to as a “first source structure,” a “first trench source structure,” a “second trench structure,” etc. The source potential is to be applied to the plurality of source structures 20.

The plurality of source structures 20 are formed in the inner portion of the first main surface 3 at an interval from the peripheral edge (the first to fourth side surfaces 5A to 5D) of the first main surface 3. The source structure 20 is formed in the active region 8 and is not formed in the outer peripheral region 9.

The plurality of source structures 20 penetrate the body region 10 and the source region 11 so as to reach the second semiconductor region 7. The plurality of source structures 20 are formed at intervals toward the first main surface 3 side from the bottom portion of the second semiconductor region 7, and face the first semiconductor region 6 with a portion of the second semiconductor region 7 interposed therebetween.

In this embodiment, the plurality of source structures 20 are formed substantially perpendicular to the first main surface 3. As a matter of course, the plurality of source structures 20 may be formed in a tapered shape toward the bottom portion of the second semiconductor region 7.

The plurality of source structures 20 are respectively arranged in regions between the plurality of gate structures 15 at intervals in the first direction X from the plurality of gate structures 15, and face the plurality of gate structures 15 in the first direction X.

That is, the plurality of source structures 20 are alternately aligned with the plurality of gate structures 15 in the first direction X in plan view, and each extend in a band shape in the second direction Y. That is, the plurality of source structures 20 is aligned in a stripe shape extending in the second direction Y. The extension direction of the plurality of source structures 20 coincides with the off direction of the SiC monocrystal.

As a matter of course, the plurality of source structures 20 may be aligned at intervals in the second direction Y in accordance with the extension direction of the plurality of gate structures 15, and may each extend in a band shape in the first direction X. With respect to the second direction Y, both end portions of the plurality of source structures 20 may be positioned in a region between the peripheral edge portion of the body region 10 and the peripheral edge portion of the source region 11.

When a distance in the horizontal direction (the first direction X) between central portions of the plurality of source structures 20 is defined as a source pitch, the source pitch is preferably substantially equal to the gate pitch of the plurality of gate structures 15. As a matter of course, the source pitch may be greater than the gate pitch or may be less than the gate pitch.

The source pitch may be not less than 1 μm and not more than 5 μm. The source pitch may have a value belonging to at least one range among not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

When a distance in the horizontal direction between the central portion of the gate structure 15 and the central portion of the source structure 20 is defined as a trench pitch, the trench pitch may be not less than 0.25 μm and not more than 2.5 μm.

The trench pitch may have a value belonging to at least one range among not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.25 μm, and not less than 2.25 μm and not more than 2.5 μm.

Side walls of the plurality of source structures 20 are each formed by the m-plane (the (1-100) plane) of the SiC monocrystal. As a matter of course, side walls of the plurality of source structures 20 may each be formed by the a-plane (the (11-20) plane) of the SiC monocrystal in accordance with the extension direction of the source structure 20. The side walls of the plurality of source structures 20 are formed substantially perpendicular to the first main surface 3.

Bottom walls of the plurality of source structures 20 are formed by the c-plane (the Si plane) of SiC monocrystal. The bottom walls of the plurality of source structures 20 preferably extend substantially flat along the horizontal directions. As a matter of course, the bottom walls of the plurality of source structures 20 may be curved in an arc shape toward the second main surface 4 side.

An inclination angle (absolute value) of each side wall of the source structure 20 on a basis of a vertical line may be not less than 85° and not more than 95°. The inclination angle may have a value belonging to at least one range among not less than 85° and not more than 87.5°, not less than 87.5° and not more than 90°, not less than 90° and not more than 92.5°, and not less than 92.5° and not more than 95°. The inclination angle is preferably not less than 87° and not more than 93°.

The source structure 20 has a width that is substantially equal to the width of the gate structure 15. As a matter of course, the width of the source structure 20 may be greater than the width of the gate structure 15 or may be less than the width of the gate structure 15.

The width of the source structure 20 may be not less than 0.1 μm and not more than 2 μm. The width of the source structure 20 may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

A depth of the source structure 20 is substantially equal to the depth of the gate structure 15. As a matter of course, the depth of the source structure 20 may be greater than the depth of the gate structure 15 or may be less than the depth of the gate structure 15.

A ratio (depth ratio) of the depth of the source structure 20 to the depth of the gate structure 15 is preferably not less than 0.8 and not more than 1.2. The depth ratio may have a value belonging to at least one range among not less than 0.8 and not more than 0.85, not less than 0.85 and not more than 0.9, not less than 0.9 and not more than 0.95, not less than 0.95 and not more than 1, not less than 1 and not more than 1.05, not less than 1.05 and not more than 1.1, not less than 1.1 and not more than 1.15, and not less than 1.15 and not more than 1.2. The depth ratio is preferably not less than 0.95 and not more than 1.05.

The depth of the source structure 20 may be not less than 0.1 μm and not more than 3 μm. The depth of the source structure 20 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The depth of the source structure 20 is preferably not less than 0.5 μm and not more than 1.5 μm.

The source structure 20 may have an aspect ratio of not less than 1 and not more than 3. The aspect ratio of source structure 20 is a ratio of the depth of source structure 20 to the width of source structure 20. The aspect ratio may have a value belonging to at least one range among not less than 1 and not more than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, and not less than 2.75 and not more than 3. The aspect ratio is preferably not less than 1.5 and not more than 2.5.

Each of the plurality of source structures 20 includes a second trench 21, a second insulating film 22, and a second embedded electrode 23. The second trench 21 is formed in the first main surface 3 and demarcates wall surfaces (the side wall and the bottom wall) of the source structure 20.

The second insulating film 22 covers a wall surface of the second trench 21. The second insulating film 22 may include at least one among a silicon oxide film, a silicon nitride film, and a silicon oxynitride film. The second insulating film 22 preferably includes the same type of insulating material as the insulating material of the first insulating film 17. In this embodiment, the second insulating film 22 has a single layer structure constituted of a silicon oxide film. The second insulating film 22 particularly preferably includes a silicon oxide film made of the oxide of the chip 2.

The second insulating film 22 includes a first film portion and a second film portion. The first film portion covers side walls of the second trench 21 in a film shape. The second film portion covers a bottom wall of the second trench 21 in a film shape and is continuous to the first film portion. The second film portion has a thickness greater than a thickness of the first film portion. The thickness of the second film portion may instead be substantially equal to the thickness of the first film portion.

A thickness of the first film portion of the second insulating film 22 may be substantially equal to the thickness of the first film portion of the first insulating film 17. A thickness of the second film portion of the second insulating film 22 may be substantially equal to the thickness of the second film portion of the first insulating film 17.

The second insulating film 22 may have a thickness of not less than 10 nm and not more than 150 nm. The thickness of the second insulating film 22 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, and not less than 125 nm and not more than 150 nm.

The second embedded electrode 23 is embedded in the second trench 21 with the second insulating film 22 interposed therebetween. The second embedded electrode 23 may contain either or both of a conductive polysilicon of the p-type and a conductive polysilicon of the n-type. The second embedded electrode 23 preferably includes the same type of conductive material as the conductive material of the first embedded electrode 18. The second embedded electrode 23 faces the second semiconductor region 7, the body region 10, and the source region 11 with the second insulating film 22 interposed therebetween.

The second embedded electrode 23 has an electrode surface exposed from the second trench 21. The electrode surface of the second embedded electrode 23 is positioned at the bottom wall side of the second trench 21 with respect to the height position of the first main surface 3. The electrode surface of the second embedded electrode 23 is positioned at the first main surface 3 side with respect to the depth position of the bottom portion of the source region 11.

The electrode surface of the second embedded electrode 23 has a recess that is recessed in a tapered shape toward the bottom wall of the second trench 21 in the inner portion. As a matter of course, the second embedded electrode 23 may be embedded on the bottom wall side of the second trench 21 with respect to the depth position of the bottom portion of the source region 11 such that the second embedded electrode 23 does not face the source region 11 with the second insulating film 22 interposed therebetween.

The semiconductor device 1A includes one or a plurality of dummy structures 25 of a trench type (a trench electrode type) formed in the inner portion of the first main surface 3. The dummy structure 25 may be referred to as a “second source structure,” a “second trench source structure,” a “third trench structure,” a “dummy trench structure,” a “peripheral edge structure,” etc. The number of the dummy structures 25 is arbitrary.

The number of the dummy structures 25 may be not less than 1 and not more than 15. The number of the dummy structures 25 may be 1, 2, 3, 4, 5, 6, 7, 8, 9, 10, 11, 12, 13, 14, or 15. The number of the dummy structures 25 is typically not less than 1 and not more than 10. In this embodiment, the semiconductor device 1A includes the five dummy structures 25 as an example.

The one or plurality of dummy structures 25 may be formed in an electrically floating state. The source potential may be applied to the one or plurality of dummy structures 25. The plurality of dummy structures 25 may be electrically formed in a floating state or may be fixed to the source potential. As a matter of course, the plurality of dummy structures 25 may include the one or plurality of dummy structures 25 formed in an electrically floating state and the one or plurality of dummy structures 25 to which the source potential is to be applied.

The plurality of dummy structures 25 are formed in the inner portion of the first main surface 3 at an interval from the peripheral edge (the first to fourth side surfaces 5A to 5D) of the first main surface 3. The dummy structure 25 is formed in the active region 8 and is not formed in the outer peripheral region 9.

The plurality of dummy structures 25 are arranged at the peripheral edge portion of the active region 8 at intervals from a structure group including the plurality of gate structures 15 and the plurality of source structures 20. The plurality of dummy structures 25 are aligned at intervals from each other in the peripheral edge portion of the active region 8, and are adjacent to each other in the horizontal direction.

The plurality of dummy structures 25 are each formed in a band shape extending along the peripheral edge of the active region 8 in plan view. The plurality of dummy structures 25 extend in the extension direction (the second direction Y) of the plurality of gate structures 15 (the plurality of source structures 20).

The plurality of dummy structures 25 extend in a direction (the first direction X) intersecting (specifically, orthogonal to) the extension direction of the plurality of gate structures 15 (the plurality of source structures 20). The plurality of dummy structures 25 may be formed in a polygonal annular shape (a quadrilateral annular shape) entirely surrounding a structure group including the plurality of gate structures 15 and the plurality of source structures 20 in plan view.

In this embodiment, the plurality of dummy structures 25 are formed in a region outside the source region 11 and penetrate only the body region 10. As a matter of course, in this embodiment, the plurality of dummy structures 25 penetrate the body region 10 and the source region 11 so as to reach the second semiconductor region 7.

The plurality of dummy structures 25 are formed at intervals toward the first main surface 3 side from the bottom portion of the second semiconductor region 7, and face the first semiconductor region 6 with a portion of the second semiconductor region 7 interposed therebetween. In this embodiment, the plurality of dummy structures 25 are formed substantially perpendicular to the first main surface 3. As a matter of course, the plurality of dummy structures 25 may be formed in a tapered shape toward the bottom portion of the second semiconductor region 7.

When a distance in the horizontal direction (the first direction X) between central portions of the plurality of dummy structures 25 is defined as a dummy pitch, the dummy pitch is preferably less than the trench pitch of the gate structure 15 and the source structure 20. As a matter of course, the dummy pitch may be substantially equal to the trench pitch or may be greater than the trench pitch.

The dummy pitch may be not less than 0.25 μm and not more than 2.5 μm. The dummy pitch may have a value belonging to at least one range among not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.25 μm, and not less than 2.25 μm and not more than 2.5 μm.

Side walls of the plurality of dummy structures 25 are each formed by the m-plane (the (1-100) plane) of the SiC monocrystal and the a-plane (the (11-20) plane) of the SiC monocrystal. The side walls of the plurality of dummy structures 25 are formed substantially perpendicular to the first main surface 3.

Bottom walls of the plurality of dummy structures 25 are formed by the c-plane (the Si plane) of SiC monocrystal. The bottom walls of the plurality of dummy structures 25 preferably extend substantially flat along the horizontal directions. As a matter of course, the bottom walls of the plurality of dummy structures 25 may be curved in an arc shape toward the second main surface 4 side.

An inclination angle (absolute value) of each side wall of the dummy structure 25 on a basis of a vertical line may be not less than 85° and not more than 95°. The inclination angle may have a value belonging to at least one range among not less than 85° and not more than 87.5°, not less than 87.5° and not more than 90°, not less than 90° and not more than 92.5°, and not less than 92.5° and not more than 95°. The inclination angle is preferably not less than 87° and not more than 93°.

The dummy structure 25 may have a width that is substantially equal to the width of the gate structure 15. The width of the dummy structure 25 may be greater than the width of the gate structure 15 or may be less than the width of the gate structure 15. The width of the dummy structure 25 may be substantially equal to the width of the source structure 20. The width of the dummy structure 25 may be greater than the width of the source structure 20 or may be less than the width of the source structure 20.

The width of the dummy structure 25 may be not less than 0.1 μm and not more than 2 μm. The width of the dummy structure 25 may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

The dummy structure 25 preferably has a depth substantially equal to one or both of the depth of the gate structure 15 and the depth of the source structure 20. The depth of the dummy structure 25 may be greater than the depth of the gate structure 15 or may be less than the depth of the gate structure 15. The depth of the dummy structure 25 may be greater than the depth of the source structure 20 or may be less than the depth of the source structure 20. In this embodiment, the depth of the dummy structure 25 is substantially equal to both the depth of the gate structure 15 and the depth of the source structure 20.

A ratio (depth ratio) of the depth of the dummy structure 25 to the depth of the gate structure 15 (the source structure 20) is preferably not less than 0.8 and not more than 1.2. The depth ratio may have a value belonging to at least one range among not less than 0.8 and not more than 0.85, not less than 0.85 and not more than 0.9, not less than 0.9 and not more than 0.95, not less than 0.95 and not more than 1, not less than 1 and not more than 1.05, not less than 1.05 and not more than 1.1, not less than 1.1 and not more than 1.15, and not less than 1.15 and not more than 1.2. The depth ratio is preferably not less than 0.95 and not more than 1.05.

The depth of the dummy structure 25 may be not less than 0.1 μm and not more than 3 μm. The depth of the dummy structure 25 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. The depth of the dummy structure 25 is preferably not less than 0.5 μm and not more than 1.5 μm.

The dummy structure 25 may have an aspect ratio of not less than 1 and not more than 3. The aspect ratio of the dummy structure 25 is a ratio of the depth of the dummy structure 25 to the width of the dummy structure 25. The aspect ratio may have a value belonging to at least one range among not less than 1 and not more than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, and not less than 2.75 and not more than 3. The aspect ratio is preferably not less than 1.5 and not more than 2.5.

Each of the plurality of dummy structures 25 includes a third trench 26, a third insulating film 27, and a third embedded electrode 28. The third trench 26 is formed in the first main surface 3 and demarcates wall surfaces (the side wall and the bottom wall) of the dummy structure 25.

The third insulating film 27 covers a wall surface of the third trench 26. The third insulating film 27 may include at least one among a silicon oxide film, a silicon nitride film, and a silicon oxynitride film.

The third insulating film 27 preferably includes the same type of insulating material as the insulating material of the first insulating film 17. In this embodiment, the third insulating film 27 has a single layer structure constituted of a silicon oxide film. The third insulating film 27 particularly preferably includes a silicon oxide film made of the oxide of the chip 2.

The third insulating film 27 includes a first film portion and a second film portion. The first film portion covers side walls of the third trench 26 in a film shape. The second film portion covers a bottom wall of the third trench 26 in a film shape and is continuous to the first film portion. The second film portion has a thickness greater than a thickness of the first film portion. The thickness of the second film portion may instead be substantially equal to the thickness of the first film portion.

A thickness of the first film portion of the third insulating film 27 may be substantially equal to the thickness of the first film portion of the first insulating film 17. A thickness of the second film portion of the third insulating film 27 may be substantially equal to the thickness of the second film portion of the first insulating film 17.

The third insulating film 27 may have a thickness of not less than 10 nm and not more than 150 nm. The thickness of the third insulating film 27 may have a value belonging to at least one range among not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, and not less than 125 nm and not more than 150 nm.

The third embedded electrode 28 is embedded in the third trench 26 with the third insulating film 27 interposed therebetween. The third embedded electrode 28 may contain either or both of a conductive polysilicon of the p-type and a conductive polysilicon of the n-type. The third embedded electrode 28 preferably includes the same type of conductive material as the conductive material of the first embedded electrode 18.

The third embedded electrode 28 faces the second semiconductor region 7 and the body region 10 with the third insulating film 27 interposed therebetween. As a matter of course, the third embedded electrode 28 may have a portion that faces the source region 11.

The third embedded electrode 28 has an electrode surface exposed from the third trench 26. The electrode surface of the third embedded electrode 28 is positioned at the bottom wall side of the third trench 26 with respect to the height position of the first main surface 3. The electrode surface of the third embedded electrode 28 is positioned at the first main surface 3 side with respect to the depth position of the bottom portion of the source region 11.

The electrode surface of the third embedded electrode 28 has a recess that is recessed in a tapered shape toward the bottom wall of the third trench 26 in the inner portion. As a matter of course, the third embedded electrode 28 may be embedded on the bottom wall side of the third trench 26 with respect to the depth position of the bottom portion of the source region 11.

The semiconductor device 1A includes a plurality of well regions 30 formed in the chip 2 (the second semiconductor region 7) in the active region 8. The plurality of well regions 30 may be referred to as “trench well regions.”

The plurality of well regions 30 have a p-type impurity concentration higher than the n-type impurity concentration of the second semiconductor region 7. The p-type impurity concentration of the plurality of well regions 30 may be higher than the p-type impurity concentration of the body region 10 or may be less than the p-type impurity concentration of the body region 10.

The plurality of well regions 30 include a plurality of gate well regions 30g, a plurality of source well regions 30s, and one or a plurality (in this embodiment, a plurality) of dummy well regions 30d. The gate well region 30g may be referred to as a “first well region,” etc., the source well region 30s may be referred to as a “second well region,” etc., and the dummy well region 30d may be referred to as a “third well region,” etc.

The plurality of gate well regions 30g are respectively formed in regions directly below the plurality of gate structures 15 at intervals from each other in the horizontal direction (the first direction X). The plurality of gate well regions 30g are each formed in a thickness range between the bottom portion of the second semiconductor region 7 and the bottom walls of the plurality of gate structures 15, and overlap the plurality of gate structures 15 in a one-to-one correspondence in the thickness direction.

Each of the plurality of gate well regions 30g extends in a band shape in the second direction Y in conformance to the extension direction of the corresponding gate structure 15 in plan view. That is, the plurality of gate well regions 30g are aligned in a stripe shape extending in the second direction Y in plan view. The extension direction of the plurality of gate well regions 30g coincides with the off direction of the SiC monocrystal.

As a matter of course, the plurality of gate well regions 30g may extend in the first direction X in accordance with the extension direction of the plurality of gate structures 15. In this case, the plurality of gate well regions 30g intersect (specifically, are orthogonal to) the off direction.

The plurality of gate well regions 30g are formed at intervals inward from the peripheral edge (the plurality of dummy structures 25) of the active region 8. In the second direction Y, both end portions of the plurality of gate well regions 30g may be positioned at the inner side of the plurality of gate structures 15 with respect to the both end portions of the plurality of gate structures 15, or may be positioned at the peripheral edge side of the active region 8 with respect to both end portions of the plurality of gate structures 15.

When a distance in the horizontal direction (the first direction X) between the central portions of the plurality of gate well regions 30g is defined as a gate well pitch, the gate well pitch is substantially equal to the gate pitch of the plurality of gate structures 15. As a matter of course, the gate well pitch may be greater than the gate pitch or may be less than the gate pitch.

The gate well region 30g may be substantially equal to the width of the gate structure 15. A width of the gate well region 30g may be greater than the width of the gate structure 15 or may be less than the width of the gate structure 15.

The width of the gate well region 30 g may be not less than 0.1 μm and not more than 2 μm. The width of the gate well region 30g may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

The plurality of gate well regions 30g are formed at intervals toward the bottom wall side of the plurality of gate structures 15 from the bottom portion of the second semiconductor region 7, and face the first semiconductor region 6 with a portion of the second semiconductor region 7 interposed therebetween. In this embodiment, the plurality of gate well regions 30g have a depth less than depths of the plurality of gate structures 15 in cross-sectional view, and are formed at intervals toward the bottom wall side of the plurality of gate structures 15 from the depth position of the intermediate portion of the second semiconductor region 7.

As a matter of course, the plurality of gate well regions 30g may have a depth greater than the depths of the plurality of gate structures 15 and may be formed in a column shape extending in the thickness direction of the chip 2. In this case, the plurality of gate well regions 30g may cross the depth position of the intermediate portion of the second semiconductor region 7. That is, the plurality of gate well regions 30g may have bottom portions positioned at the bottom portion side of the second semiconductor region 7 (the second main surface 4 side) with respect to the intermediate portion of the second semiconductor region 7.

A depth of the gate well region 30g is preferably more than 0 μm and not more than 5 μm. The depth of the gate well region 30g may have a value belonging to at least one range among more than 0 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The gate well region 30g may have an aspect ratio of more than 0 and not more than 10. The aspect ratio of the gate well region 30g is a ratio of the depth of the gate well region 30g to the width of the gate well region 30g. The aspect ratio may have a value belonging to at least one range among more than 0 and not more than 1, not less than 1 and not more than 2, not less than 2 and not more than 3, not less than 3 and not more than 4, not less than 4 and not more than 5, not less than 5 and not more than 6, not less than 6 and not more than 7, not less than 7 and not more than 8, not less than 8 and not more than 9, and not less than 9 and not more than 10.

Each of the plurality of gate well regions 30g has an upper end portion positioned at the bottom wall side of the corresponding gate structure 15. The upper end portions of the plurality of gate well regions 30g may be connected to the bottom walls of the corresponding gate structures 15.

The upper end portions of the plurality of gate well regions 30g may extend along the side walls of the corresponding gate structures 15 and be connected to the body region 10. As a matter of course, the upper end portion of each of the plurality of gate well region 30g may be formed at an interval toward the bottom portion side of the second semiconductor region 7 from the bottom wall of the corresponding gate structure 15.

The plurality of source well regions 30s are respectively formed in regions directly below the plurality of source structures 20 at intervals in the first direction X from the plurality of gate well regions 30g in the chip 2 (the second semiconductor region 7). The plurality of source well regions 30s are each formed in a thickness range between the bottom portion of the second semiconductor region 7 and the bottom walls of the plurality of source structures 20, and overlap the plurality of source structures 20 in a one-to-one correspondence in the thickness direction.

Each of the plurality of source well regions 30s extend in a band shape in the second direction Y in conformance to the extension direction of the corresponding source structure 20 in plan view. That is, the plurality of source well regions 30s are aligned in a stripe shape extending in the second direction Y in plan view. The extension direction of the plurality of source well regions 30s coincides with the off direction of the SiC monocrystal.

As a matter of course, the plurality of source well regions 30s may extend in the first direction X in accordance with the extension direction of the plurality of source structures 20. In this case, the plurality of source well regions 30s intersect (specifically, are orthogonal to) the off direction.

The plurality of source well regions 30s are formed at intervals inward from the peripheral edge (the plurality of dummy structures 25) of the active region 8. In the second direction Y, both end portions of the plurality of source well regions 30s may be positioned at the inner side of the plurality of source structures 20 with respect to both end portions of the plurality of source structures 20, or may be positioned at the peripheral edge side of the active region 8 with respect to both end portions of the plurality of source structures 20.

When a distance in the horizontal direction (the first direction X) between central portions of the plurality of source well regions 30s are defined as a source well pitch, the source well pitch is substantially equal to the source pitch of the plurality of source structures 20. As a matter of course, the source well pitch may be greater than the source pitch or may be less than the source pitch.

The source well pitch is preferably substantially equal to the gate well pitch. As a matter of course, the source well pitch may be greater than the gate well pitch or may be less than the gate well pitch.

When a distance in the horizontal direction (the first direction X) between the central portion of the gate well region 30g and the central portion of the source well region 30s is defined as a well pitch, the well pitch is preferably substantially equal to the trench pitch between the gate structure 15 and the source structure 20. As a matter of course, the well pitch may be greater than the trench pitch or may be less than the trench pitch.

The source well region 30s may have a width substantially equal to the width of the source structure 20. The source well region 30s may be greater than the width of the source structure 20 or may be less than the width of the source structure 20. The width of the source well region 30s may be substantially equal to the width of the gate well region 30g. The width of the source well region 30s may be greater than the width of the gate well region 30g or may be less than the width of the gate well region 30g.

The width of the source well region 30s may be not less than 0.1 μm and not more than 2 μm. The width of the source well region 30s may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

The plurality of source well regions 30s are formed at intervals toward the bottom wall side of the plurality of source structures 20 from the bottom portion of the second semiconductor region 7, and face the first semiconductor region 6 with a portion of the second semiconductor region 7 interposed therebetween. In this embodiment, the plurality of source well regions 30s have a depth less than depths of the plurality of source structures 20 in cross-sectional view, and are formed at intervals toward the bottom wall side of the plurality of source structures 20 from the depth position of the intermediate portion of the second semiconductor region 7.

As a matter of course, the plurality of source well regions 30s may have a depth greater than the depths of the plurality of source structures 20 and may be formed in a column shape extending in the thickness direction of the chip 2. In this case, the plurality of source well regions 30s may cross the depth position of the intermediate portion of the second semiconductor region 7. That is, the plurality of source well regions 30s may have a bottom portion positioned at the bottom portion side of the second semiconductor region 7 with respect to the intermediate portion of the second semiconductor region 7.

The plurality of source well regions 30s may form a super junction structure with the plurality of gate well regions 30g. In the super junction structure, when a reverse bias voltage is applied, a depletion layer spreading with the plurality of gate well regions 30g as starting points and a depletion layer spreading with the plurality of source well regions 30s as starting points are connected in a region (the second semiconductor region 7) between the plurality of gate well regions 30g and the plurality of source well regions 30s.

The depth of the plurality of source well regions 30s may be substantially equal to the depth of the plurality of gate well regions 30g. The depth of the plurality of source well regions 30s may be greater than the depth of the plurality of gate well regions 30g, or may be less than the depth of the plurality of gate well regions 30g.

The depth of the source well region 30 s is preferably more than 0 μm and not more than 5 μm. The depth of the source well region 30 s may have a value belonging to at least one range among more than 0 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The source well region 30s may have an aspect ratio of more than 0 and not more than 10. The aspect ratio of the source well region 30s is a ratio of the depth of the source well region 30s to the width of the source well region 30s. The aspect ratio may have a value belonging to at least one range among more than 0 and not more than 1, not less than 1 and not more than 2, not less than 2 and not more than 3, not less than 3 and not more than 4, not less than 4 and not more than 5, not less than 5 and not more than 6, not less than 6 and not more than 7, not less than 7 and not more than 8, not less than 8 and not more than 9, and not less than 9 and not more than 10.

Each of the plurality of source well regions 30s has an upper end portion positioned at the bottom wall side of the corresponding source structure 20. The upper end portions of the plurality of source well regions 30s may be connected to the bottom walls of the corresponding source structures 20.

The upper end portions of the plurality of source well regions 30s may extend along the side walls of the corresponding source structures 20 and be connected to the body region 10. As a matter of course, the upper end portion of each of the plurality of source well region 30s may be formed at an interval toward the bottom portion side of the second semiconductor region 7 from the bottom wall of the corresponding source structure 20.

The plurality of dummy well regions 30d are respectively formed in regions directly below the plurality of dummy structures 25 at intervals in the horizontal direction from the plurality of gate well regions 30g and the plurality of source well regions 30s in the chip 2 (the second semiconductor region 7).

The plurality of dummy well regions 30d are each formed in a thickness range between the bottom portion of the second semiconductor region 7 and the bottom walls of the plurality of dummy structures 25, and overlap the plurality of dummy structures 25 in a one-to-one correspondence in the thickness direction.

Each of the plurality of dummy well regions 30d extends in a band shape along the corresponding dummy structure 25 in plan view. In this embodiment, each of the plurality of dummy well regions 30d is formed in a polygonal annular shape (in this embodiment, a quadrilateral annular shape) extending along the corresponding dummy structure 25 in plan view. The plurality of dummy well regions 30d may be connected to each other in the horizontal direction. As a matter of course, the plurality of dummy well regions 30d may be formed at intervals from each other.

When a distance in the horizontal direction between central portions of the plurality of dummy well regions 30d is defined as a dummy well pitch, the dummy well pitch is substantially equal to the dummy pitch of the plurality of dummy structures 25. As a matter of course, the dummy well pitch may be greater than the dummy pitch or may be less than the dummy pitch.

In this embodiment, the dummy well pitch is less than the well pitch between the gate well region 30g and the source well region 30s. As a matter of course, the dummy well pitch may be substantially equal to the well pitch or may be greater than the well pitch.

The dummy well pitch may be substantially equal to the gate well pitch. The dummy well pitch may be greater than the gate well pitch or may be less than the gate well pitch. The dummy well pitch may be substantially equal to the source well pitch. The dummy well pitch may be greater than the source well pitch or may be less than the source well pitch.

The dummy well region 30d may have a width substantially equal to the width of the dummy structure 25. The width of the dummy well region 30d may be greater than the width of the dummy structure 25 or may be less than the width of the dummy structure 25.

The width of the dummy well region 30d may be substantially equal to the width of the gate well region 30g. The width of the dummy well region 30d may be greater than the width of the gate well region 30g or may be less than the width of the gate well region 30g.

The width of the dummy well region 30d may be substantially equal to the width of the source well region 30s. The width of the dummy well region 30d may be greater than the width of the source well region 30s or may be less than the width of the source well region 30s.

The width of the dummy well region 30d may be not less than 0.1 μm and not more than 2 μm. The width of the dummy well region 30d may have a value belonging to at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm.

The plurality of dummy well regions 30d are formed at intervals toward the bottom wall side of the plurality of dummy structures 25 from the bottom portion of the second semiconductor region 7, and face the first semiconductor region 6 with a portion of the second semiconductor region 7 interposed therebetween. In this embodiment, the plurality of dummy well regions 30d have a depth less than depths of the plurality of dummy structures 25 in cross-sectional view, and are formed at intervals toward the bottom wall side of the plurality of dummy structures 25 from the depth position of the intermediate portion of the second semiconductor region 7.

As a matter of course, the plurality of dummy well regions 30d may have a depth greater than the depths of the plurality of dummy structures 25 and may be formed in a column shape extending in the thickness direction of the chip 2. In this case, the plurality of dummy well regions 30d may cross the depth position of the intermediate portion of the second semiconductor region 7. That is, the plurality of dummy well regions 30d may have bottom portions positioned at the bottom portion side of the second semiconductor region 7 with respect to the intermediate portion of the second semiconductor region 7.

The depth of the plurality of dummy well regions 30d may be substantially equal to the depth of the plurality of gate well regions 30g. The depth of the plurality of dummy well regions 30d may be greater than the depth of the plurality of gate well regions 30g or may be less than the depth of the plurality of gate well regions 30g.

The depth of the plurality of dummy well regions 30d may be substantially equal to the depth of the plurality of source well regions 30s. The depth of the plurality of dummy well regions 30d may be greater than the depth of the plurality of source well regions 30s or may be less than the depth of the plurality of source well regions 30s.

The depth of the dummy well region 30d is preferably more than 0 μm and not more than 5 μm. The depth of the dummy well region 30d may have a value belonging to at least one range among more than 0 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The dummy well region 30d may have an aspect ratio of more than 0 and not more than 10. The aspect ratio of the dummy well region 30d is a ratio of the depth of the dummy well region 30d to the width of the dummy well region 30d. The aspect ratio may have a value belonging to at least one range among more than 0 and not more than 1, not less than 1 and not more than 2, not less than 2 and not more than 3, not less than 3 and not more than 4, not less than 4 and not more than 5, not less than 5 and not more than 6, not less than 6 and not more than 7, not less than 7 and not more than 8, not less than 8 and not more than 9, and not less than 9 and not more than 10.

Each of the plurality of dummy well regions 30d has an upper end portion positioned at the bottom wall side of the corresponding dummy structure 25. The upper end portions of the plurality of dummy well regions 30d may be connected to the bottom walls of the corresponding dummy structures 25.

The upper end portions of the plurality of dummy well regions 30d may extend along the side walls of the corresponding dummy structures 25 and be connected to the body region 10. As a matter of course, the upper end portion of each of the plurality of dummy well regions 30d may be formed at an interval toward the bottom portion side of the second semiconductor region 7 from the bottom wall of the corresponding dummy structure 25.

The semiconductor device 1A includes a plurality of contact regions 31 formed in the chip 2 (the second semiconductor region 7). The plurality of contact regions 31 has a p-type impurity concentration higher than the p-type impurity concentration of the body region 10. The p-type impurity concentration of the plurality of contact regions 31 is higher than the p-type impurity concentration of the well region 30.

The plurality of contact regions 31 include a plurality of gate contact regions 31g, a plurality of source contact regions 31s, and one or a plurality (in this embodiment, a plurality) of dummy contact regions 31d. The gate contact region 31g may be referred to as a “first contact region,” etc., the source contact region 31s may be referred to as a “second contact region,” etc., and the dummy contact region 31d may be referred to as a “third contact region,” etc.

The plurality of gate contact regions 31g are respectively formed in regions along the plurality of gate structures 15 at intervals from the plurality of source structures 20. The plurality of gate contact regions 31g are formed in a multiple-to-one correspondence with the plurality of gate structures 15. The plurality of gate contact regions 31g are respectively interposed in regions between the bottom walls of the plurality of gate structures 15 and the bottom portions of the plurality of gate well regions 30g, and are formed at intervals in the second direction Y.

With respect to the one gate structure 15 and the other gate structure 15, the plurality of gate contact regions 31g along the one gate structure 15 face the plurality of gate contact regions 31g along the other gate structure 15 in the first direction X in plan view. That is, the plurality of gate contact regions 31g are aligned in a matrix at intervals in the first direction X and the second direction Y as a whole in plan view.

As a matter of course, the plurality of gate contact regions 31g along the one gate structure 15 may face a region between the plurality of gate contact regions 31g along the other gate structure 15 in the first direction X in plan view. That is, the plurality of gate contact regions 31g may be aligned in a staggered manner at intervals in the first direction X and the second direction Y as a whole in plan view.

In this embodiment, the plurality of gate contact regions 31g extend in a band shape along the plurality of gate structures 15 in plan view. The lengths of the plurality of gate contact regions 31g in the second direction Y may be equal to each other or may be different from each other. The lengths of the plurality of gate contact regions 31g in the second direction Y are adjusted in accordance with the channel area to be formed.

The channel area is a total area of the portion of the source region 11 exposed from the region between the plurality of gate structures 15 and the plurality of source structures 20. That is, the channel area decreases and increases in accordance with the increase or decrease in the ratio of the total planar area of the plurality of gate contact regions 31g. The total planar area of the plurality of gate contact regions 31g is preferably less than the channel area.

That is, in the region between one gate structure 15 and one source structure 20 adjacent to each other, the total planar area of the plurality of gate contact regions 31g is preferably less than the planar area of the source region 11. According to such an arrangement, an increase in the resistance value (on resistance) caused by the short channel is suppressed.

The length of the plurality of gate contact regions 31g may be greater than the width of the gate structure 15 or may be smaller than the width of the gate structure 15. The length of the plurality of gate contact regions 31g may be greater than the gate pitch of the plurality of gate structures 15 or may be smaller than the gate pitch.

The interval between the plurality of gate contact regions 31g in the second direction Y is preferably greater than the width of the gate structure 15. As a matter of course, the interval between the plurality of gate contact regions 31g in the second direction Y may be smaller than the width of the gate structure 15. The interval between the plurality of gate contact regions 31g may be greater than the gate pitch or may be smaller than the gate pitch.

The plurality of gate contact regions 31g are connected to the bottom walls of the corresponding gate structures 15 and the corresponding gate well regions 30g. The gate contact region 31g has an extension portion protruding from the region directly below the gate structure 15 to both sides of the gate structure 15 and extending in the vertical direction Z along the side wall of the gate structure 15.

A thickness in the horizontal direction (the first direction X) of the portion (the extension portion) of the gate contact region 31g along the side wall of the gate structure 15 is preferably less than the thickness in the vertical direction Z of the portion of the gate contact region 31g along the bottom wall of the gate structure 15.

The extension portion of the gate contact region 31g is electrically connected to the body region 10 in the surface layer portion of the first main surface 3 and electrically connects the corresponding gate well region 30g to the body region 10. The gate well region 30g is thereby suppressed from being in an electrically floating state, and electrical response characteristics of the gate well region 30g are improved.

The gate contact region 31g has an upper end portion exposed from the first main surface 3. In this embodiment, the upper end portion of the gate contact region 31g is exposed from the side wall of the first trench 16 at an opening end of the first trench 16. The upper end portion of the gate contact region 31g may extend in the horizontal direction in the surface layer portion of the body region 10.

The plurality of source contact regions 31s are respectively formed in regions along the plurality of source structures 20 at intervals from the plurality of gate structures 15. The plurality of source contact regions 31s have a planar layout different from the planar layout of the plurality of gate contact regions 31g. In this embodiment, the plurality of source contact regions 31s are formed in a one-to-one correspondence with the plurality of source structures 20.

The plurality of source contact regions 31s are respectively interposed in regions between the bottom walls of the corresponding source structures 20 and the bottom portions of the corresponding source well regions 30s, and extend in a band shape in the second direction Y. That is, the plurality of source contact regions 31s are formed in a stripe shape extending along the plurality of source structures 20 in plan view.

That is, the plurality of source contact regions 31s have a length greater than the length of the plurality of gate contact regions 31g in the second direction Y, and cross the plurality of gate structures 15 in the second direction Y. In the second direction Y, the plurality of source contact regions 31s may have a length greater than the length of the plurality of source structures 20, or may have a length less than the length of the plurality of source structures 20.

The plurality of source contact regions 31s preferably have a total planar area greater than the total planar area of the plurality of gate contact regions 31g. The total planar area of the plurality of source contact regions 31s may be greater than the channel area or may be less than the channel area.

As a matter of course, as with the plurality of gate contact regions 31g, the plurality of source contact regions 31s may be formed in a multiple-to-one correspondence with the plurality of source structures 20. In this case, with respect to the one source structure 20 and the other source structure 20, the plurality of gate contact regions 31g along the one source structure 20 may face the plurality of source contact regions 31s along the other source structure 20 in the first direction X in plan view.

That is, the plurality of source contact regions 31s may be aligned in a matrix at intervals in the first direction X and the second direction Y as a whole in plan view. As a matter of course, the plurality of source contact regions 31s along the one source structure 20 may face a region between the plurality of source contact regions 31s along the other source structure 20 in the first direction X in plan view. That is, the plurality of source contact regions 31s may be aligned in a staggered manner at intervals in the first direction X and the second direction Y as a whole in plan view.

The plurality of source contact regions 31s are respectively connected to the bottom walls of the corresponding source structures 20 and the corresponding source well regions 30s. Each of the plurality of source contact regions 31s has an extension portion protruding from the region directly below the source structure 20 to both sides of the source structure 20 and extending along the side walls of the source structure 20.

The thickness in the horizontal direction (the first direction X) of the portion (the extension portion) of the source contact region 31s along the side wall of the source structure 20 is preferably less than the thickness in the vertical direction Z of the portion of the source contact region 31s along the bottom wall of the source structure 20.

The extension portion of the source contact region 31s is electrically connected to the body region 10 in the surface layer portion of the first main surface 3 and electrically connects the corresponding source well region 30s to the body region 10. The source well region 30s is thereby suppressed from being in an electrically floating state, and electrical response characteristics of the source well region 30s are improved.

The source contact region 31s has an upper end portion exposed from the first main surface 3. In this embodiment, the upper end portion of the source contact region 31s is exposed from the side wall of the second trench 21 at an opening end of the second trench 21. The upper end portion of the source contact region 31s may extend in the horizontal direction in the surface layer portion of the body region 10.

The upper end portion of the source contact region 31s is electrically connected to the upper end portion of the gate contact region 31g in the body region 10. In this embodiment, the upper end portion of the source contact region 31s is integrally formed with the upper end portion of the gate contact region 31g.

The plurality of dummy contact regions 31d are respectively formed in regions along the plurality of dummy structures 25 at intervals from the plurality of gate structures 15 and the plurality of source structures 20. The plurality of dummy contact regions 31d are formed in a one-to-one correspondence with the plurality of dummy structures 25.

The plurality of dummy contact regions 31d are respectively interposed in regions between the bottom walls of the corresponding dummy structures 25 and the bottom portions of the corresponding dummy well regions 30d, and extend in a band shape along the corresponding dummy structures 25. In this embodiment, each of the plurality of dummy contact regions 31d extends in a polygonal annular shape (in this embodiment, a quadrilateral annular shape) along the corresponding dummy structures 25 in plan view.

The plurality of dummy contact regions 31d are respectively connected to the bottom walls of the corresponding dummy structures 25 and the corresponding dummy well regions 30d. Each of the plurality of dummy contact regions 31d has an extension portion protruding from a region directly below the dummy structure 25 to both sides of the dummy structure 25 and extending along the side walls of the dummy structure 25.

The thickness in the horizontal direction (the first direction X) of the portions (the extension portion) of the plurality of dummy contact regions 31d along the side walls of the dummy structures 25 is preferably less than the thickness in the vertical direction Z of the portions of the plurality of dummy contact regions 31d along the bottom walls of the dummy structures 25.

The extension portions of the plurality of dummy contact regions 31d are electrically connected to the body region 10 in the surface layer portion of the first main surface 3 and electrically connect the corresponding dummy well regions 30d to the body region 10. The plurality of dummy well regions 30d are thereby suppressed from being in an electrically floating state, and electrical response characteristics of the plurality of dummy well regions 30d are improved.

Each of the plurality of dummy contact regions 31d has an upper end portion exposed from the first main surface 3. In this embodiment, the upper end portions of the plurality of dummy contact regions 31d are exposed from the side wall of the third trench 26 at an opening end of the third trench 26.

The upper end portions of the plurality of dummy contact regions 31d may extend in the horizontal direction in the surface layer portion of the body region 10. The upper end portions of the plurality of dummy contact regions 31d are electrically connected to each other in the body region 10. In this embodiment, the upper end portions of the plurality of dummy contact regions 31d are integrally formed in the body region 10.

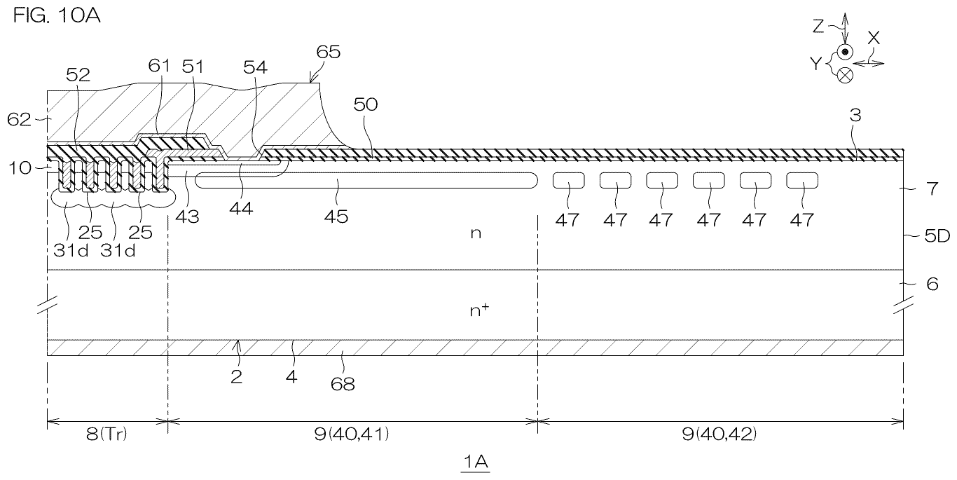

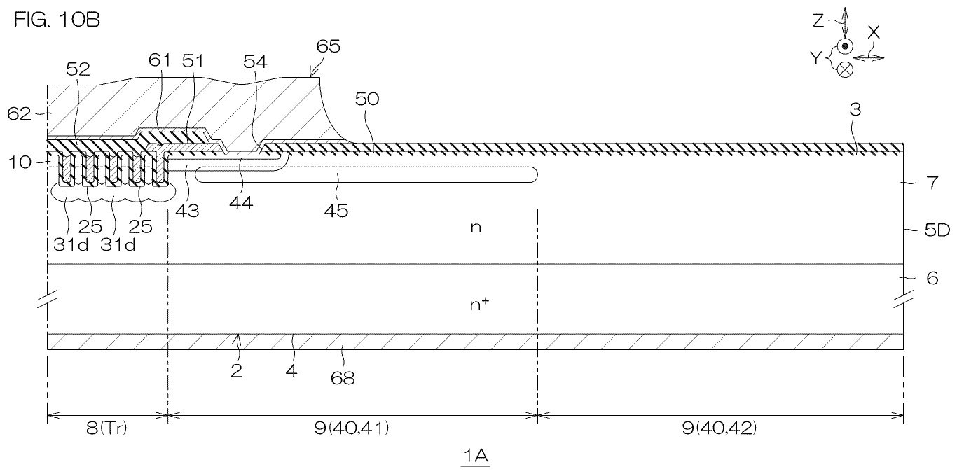

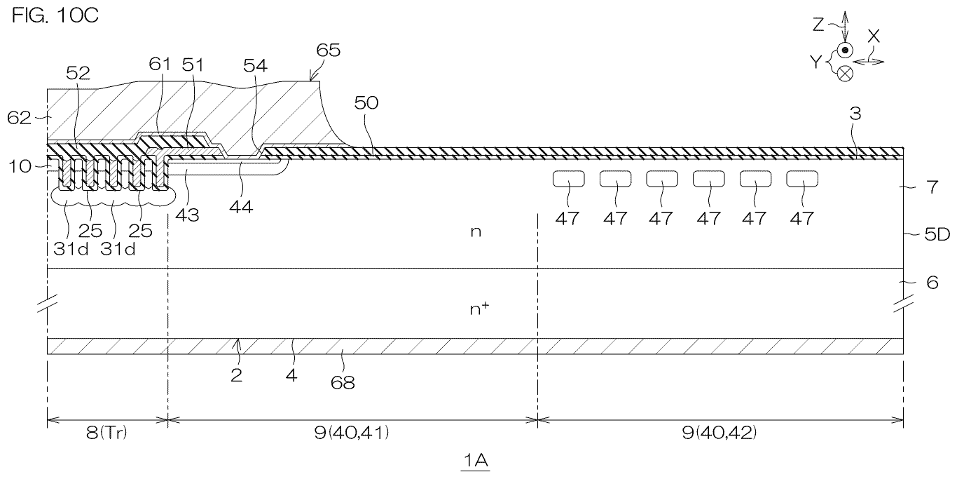

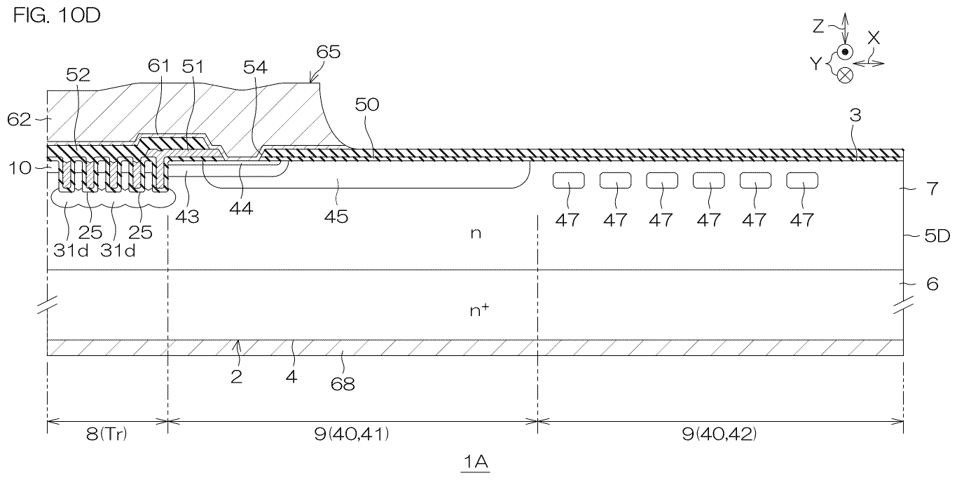

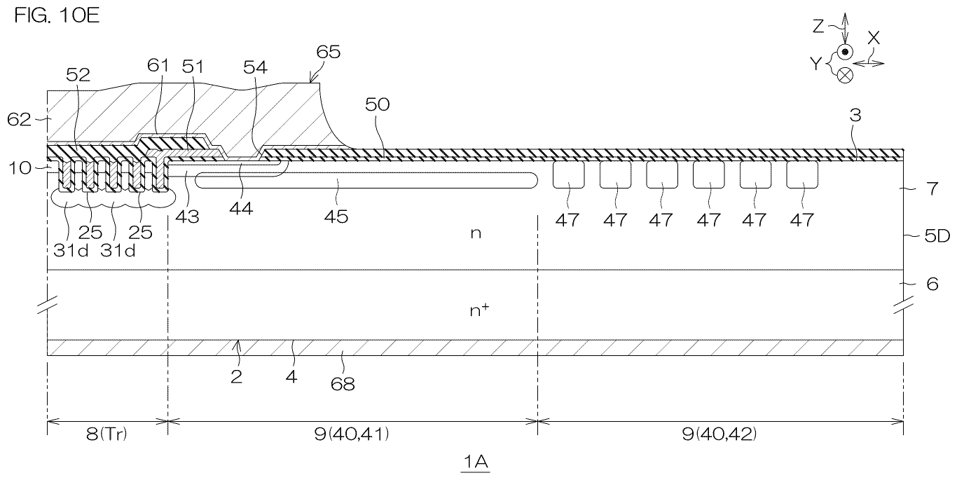

Hereinafter, an arrangement of the outer peripheral region 9 will be described with reference to FIGS. 10A to 10E. FIGS. 10A to 10E are cross-sectional views illustrating a cross-sectional structure of the outer peripheral region 9 along line X-X illustrated in FIG. 1 together with an outer peripheral structure 40 according to the first to fifth configuration examples.

Referring to FIG. 10A, the semiconductor device 1A may include the outer peripheral structure 40 according to the first configuration example formed in the outer peripheral region 9. The outer peripheral structure 40 includes a first outer peripheral structure 41 on the inner side of the first main surface 3 (the active region 8 side) and a second outer peripheral structure 42 on the peripheral edge side of the first main surface 3.

The first outer peripheral structure 41 includes an outer well region 43 of the p-type formed in the surface layer portion of the first main surface 3 in the outer peripheral region 9 (the peripheral edge portion of the first main surface 3). The outer well region 43 may be referred to as a “well region,” etc. The source potential is to be applied to the outer well region 43. The outer well region 43 has a p-type impurity concentration higher than the n-type impurity concentration of the second semiconductor region 7.

The outer well region 43 has a p-type impurity concentration less than the p-type impurity concentration of the contact region 31. The p-type impurity concentration of the outer well region 43 may be substantially equal to the p-type impurity concentration of the body region 10. The p-type impurity concentration of the outer well region 43 may be higher than the p-type impurity concentration of the body region 10, or may be less than the p-type impurity concentration of the body region 10.

The p-type impurity concentration of the outer well region 43 may be substantially equal to the p-type impurity concentration of the well region 30. The p-type impurity concentration of the outer well region 43 may be higher than the p-type impurity concentration of the well region 30, or may be less than the p-type impurity concentration of the well region 30.

The outer well region 43 is formed in the surface layer portion of the second semiconductor region 7 and is electrically connected to the second semiconductor region 7. The outer well region 43 extends in a layer shape along the first main surface 3. The outer well region 43 is formed on the inner side of the first main surface 3 (the active region 8 side) at an interval from the peripheral edge (the first to fourth side surfaces 5A to 5D) of the first main surface 3. The outer well region 43 extends in a band shape along the peripheral edge of the first main surface 3 (the peripheral edge of the active region 8) in plan view.

In this embodiment, the outer well region 43 is formed in a polygonal annular shape (in this embodiment, a quadrilateral annular shape) having four sides parallel to the peripheral edge of the chip 2 in plan view, and surrounds the inner portion (the active region 8) of the first main surface 3. The outer well region 43 may have an edge portion that connects a portion extending in the first direction X and a portion extending in the second direction Y in an arc shape (preferably, a quarter arc shape).

The outer well region 43 has an inner edge portion on the inner side of the first main surface 3 (the active region 8 side) and an outer edge portion on the peripheral edge side of the first main surface 3. In this embodiment, the inner edge portion of the outer well region 43 is connected to the outermost dummy structure 25. The inner edge portion of the outer well region 43 demarcates a boundary portion between the active region 8 and the outer peripheral region 9.

The outer well region 43 has a width greater than a width of the outermost dummy structure 25. The width of the outer well region 43 may be greater than a total width of the plurality of dummy structures 25.

The outer well region 43 may have a width of more than 0 μm and not more than 300 μm. The width of the outer well region 43 may have a value belonging to at least one range among more than 0 μm and not more than 25 μm, not less than 25 μm and not more than 50 μm, not less than 50 μm and not more than 75 μm, not less than 75 μm and not more than 100 μm, not less than 100 μm and not more than 125 μm, not less than 125 μm and not more than 150 μm, not less than 150 μm and not more than 175 μm, not less than 175 μm and not more than 200 μm, not less than 200 μm and not more than 225 μm, not less than 225 μm and not more than 250 μm, not less than 250 μm and not more than 275 μm, and not less than 275 μm and not more than 300 μm. The width of the outer well region 43 is preferably not less than 10 μm and not more than 200 μm.

The outer well region 43 is formed at an interval toward the first main surface 3 side from the bottom portion of the second semiconductor region 7, and faces the first semiconductor region 6 with a portion of the second semiconductor region 7 interposed therebetween. The outer well region 43 is preferably formed at an interval toward the first main surface 3 side from the depth position of the intermediate portion of the second semiconductor region 7.

The outer well region 43 has an upper end portion exposed from the first main surface 3 and a bottom portion positioned in the second semiconductor region 7. The bottom portion of the outer well region 43 is positioned at the bottom portion side of the second semiconductor region 7 with respect to a depth position of the bottom portion of the body region 10. As a matter of course, the bottom portion of the outer well region 43 may be positioned at the first main surface 3 side with respect to the depth position of the bottom portion of the body region 10.

The bottom portion of the outer well region 43 may be positioned at the first main surface 3 side with respect to a depth position of the bottom portion of at least one type of the well region 30 (at least one of the gate well region 30g, the source well region 30s, and the dummy well region 30d).

The bottom portion of the outer well region 43 may be positioned at the bottom portion side of the second semiconductor region 7 with respect to the depth position of the bottom portion of at least one type of the well region 30. The bottom portion of the outer well region 43 may be positioned at the depth position substantially equal to the bottom portion of at least one type of the well region 30.

The bottom portion of the outer well region 43 is positioned at the first main surface 3 side with respect to a depth position of the bottom wall of the gate structure 15. The bottom portion of the outer well region 43 is positioned at the first main surface 3 side with respect to a depth position of the bottom wall of the source structure 20. The bottom portion of the outer well region 43 is positioned at the first main surface 3 side with respect to a depth position of the bottom wall of the dummy structure 25.

The bottom portion of the outer well region 43 may be positioned at the bottom portion side of the second semiconductor region 7 with respect to the depth position of the bottom wall of the gate structure 15. The bottom portion of the outer well region 43 may be positioned at the bottom portion side of the second semiconductor region 7 with respect to the depth position of the bottom wall of the source structure 20. The bottom portion of the outer well region 43 may be positioned at the bottom portion side of the second semiconductor region 7 with respect to the depth position of the bottom wall of the dummy structure 25.

In this embodiment, the outer well region 43 is formed at an interval toward the first main surface 3 side from a depth position of the upper end portion of the dummy well region 30d, and does not have a direct connection portion with respect to the dummy well region 30d.

For example, in a case where the bottom portion of the outer well region 43 is positioned at the bottom portion side of the second semiconductor region 7 with respect to the depth position of the bottom wall of the dummy structure 25, the outer well region 43 may have a portion connected to the well region 30 (the dummy well region 30d). The bottom portion of the outer well region 43 may be connected to the upper end portion of the dummy well region 30d.

A depth (thickness) of the outer well region 43 may be more than 0 μm and not more than 5 μm. The depth of the outer well region 43 may have a value belonging to at least one range among more than 0 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The depth of the outer well region 43 is preferably not less than 0.2 μm and not more than 3 μm.

The outer well region 43 forms a pn junction portion with the second semiconductor region 7. The outer well region 43 spreads a depletion layer in the second semiconductor region 7 when a reverse bias voltage is applied. The depletion layer of the outer well region 43 spreads in the horizontal direction and the thickness direction, and is integrated with the depletion layer spreading from the active region 8 side. The outer well region 43 expands the depletion layer spreading from the active region 8 toward the peripheral edge side of the first main surface 3, and relaxes an electric field strength (a concentration of electric field) in the peripheral edge portion (the outer peripheral region 9) of the first main surface 3.

The first outer peripheral structure 41 includes an outer contact region 44 of the p-type formed in the surface layer portion of the first main surface 3 in the outer peripheral region 9 (the peripheral edge portion of the first main surface 3). The outer contact region 44 may be referred to as a “contact region,” a “fourth contact region,” etc.

The outer contact region 44 has a p-type impurity concentration higher than the p-type impurity concentration of the body region 10. The p-type impurity concentration of the outer contact region 44 is higher than the p-type impurity concentration of the well region 30. The p-type impurity concentration of the outer contact region 44 is higher than the p-type impurity concentration of the outer well region 43.

The p-type impurity concentration of the outer contact region 44 may be substantially equal to the p-type impurity concentration of the contact region 31. The p-type impurity concentration of the outer contact region 44 may be higher than the p-type impurity concentration of the contact region 31, or may be less than the p-type impurity concentration of the contact region 31.

The outer contact region 44 is formed in a surface layer portion of the outer well region 43. That is, the outer contact region 44 is formed in a thickness range between the first main surface 3 and the bottom portion of the outer well region 43. The outer contact region 44 increases the p-type impurity concentration of the outer well region 43 and improves an electrical response speed of the outer well region 43.

The outer contact region 44 extends in a band shape along the outer well region 43 (the active region 8) in plan view. In this embodiment, the outer contact region 44 is formed in a polygonal annular shape (in this embodiment, a quadrilateral annular shape) having four sides parallel to the peripheral edge of the chip 2 in plan view, and surrounds the inner portion (the active region 8) of the first main surface 3.

The outer contact region 44 may have an edge portion that connects a portion extending in the first direction X and a portion extending in the second direction Y in an arc shape (preferably, a quarter arc shape). As a matter of course, the outer contact region 44 may each have a plurality of portions that are aligned at intervals along the active region 8 so as to surround the active region 8. In this case, each of the plurality of portions may extend in a band shape along the active region 8.

The outer contact region 44 has a width less than the width of the outer well region 43, and is formed in the outer well region 43. The outer contact region 44 has an inner edge portion on the inner side of the first main surface 3 (the active region 8 side) and an outer edge portion on the peripheral edge side of the first main surface 3.

In this embodiment, the inner edge portion of the outer well region 43 is connected to the outermost dummy structure 25. In this embodiment, the inner edge portion of the outer well region 43 is connected to the dummy contact region 31d along the outermost dummy structure 25. The outer well region 43 is thereby electrically connected to the body region 10 via the dummy contact region 31d. As a matter of course, the outer well region 43 may be formed at an interval from the dummy contact region 31d.

The outer edge portion of the outer contact region 44 is formed at an interval from the outer edge portion of the outer well region 43. As a matter of course, the outer contact region 44 may cross the outer edge portion of the outer well region 43.

The outer contact region 44 has a width greater than the width of the outermost dummy structure 25. The width of the outer contact region 44 may be greater than the total width of the plurality of dummy structures 25.

The width of the outer contact region 44 may be more than 0 μm and not more than 300 μm. The width of the outer contact region 44 may have a value belonging to at least one range among more than 0 μm and not more than 25 μm, not less than 25 μm and not more than 50 μm, not less than 50 μm and not more than 75 μm, 75 μm and not more than 100 μm, not less than 100 μm and not more than 125 μm, not less than 125 μm and not more than 150 μm, not less than 150 μm and not more than 175 μm, not less than 175 μm and not more than 200 μm, not less than 200 μm and not more than 225 μm, not less than 225 μm and not more than 250 μm, not less than 250 μm and not more than 275 μm, and not less than 275 μm and not more than 300 μm. The width of the outer contact region 44 is preferably not less than 10 μm and not more than 50 μm.

The outer contact region 44 has an upper end portion positioned at the first main surface 3 side and a bottom portion positioned at the bottom portion side of the outer well region 43. The upper end portion of the outer contact region 44 is exposed from the first main surface 3.

The bottom portion of the outer contact region 44 is positioned at the first main surface 3 side with respect to the depth position of the bottom portion of at least one type of the well region 30 (at least one of the gate well region 30g, the source well region 30s, and the dummy well region 30d).

The bottom portion of the outer contact region 44 is positioned at the first main surface 3 side with respect to the depth position of the bottom wall of the gate structure 15. The bottom portion of the outer contact region 44 is positioned at the first main surface 3 side with respect to the depth position of the bottom wall of the source structure 20. The bottom portion of the outer contact region 44 is positioned at the first main surface 3 side with respect to the depth position of the bottom wall of the dummy structure 25.

The bottom portion of the outer contact region 44 is formed at an interval toward the first main surface 3 side from the bottom portion of the outer well region 43, and faces the second semiconductor region 7 with a portion of the outer well region 43 interposed therebetween. The bottom portion of the outer contact region 44 may be formed at an interval toward the first main surface 3 side from a depth position of an intermediate portion of the outer well region 43.

The bottom portion of the outer contact region 44 may be positioned at the bottom portion side of the outer well region 43 with respect to the depth position of the intermediate portion of the outer well region 43. The bottom portion of the outer contact region 44 may cross the bottom portion of the outer well region 43 and be positioned in the second semiconductor region 7.

The bottom portion of the outer contact region 44 is positioned at the first main surface 3 side with respect to the depth position of the bottom portion of the body region 10. The bottom portion of the outer contact region 44 may be positioned at the bottom portion side of the second semiconductor region 7 with respect to the depth position of the bottom portion of the body region 10.

A depth (thickness) of the outer contact region 44 may be more than 0 μm and not more than 1 μm. The depth of the outer contact region 44 may have a value belonging to at least one range among more than 0 μm and not more than 0.1 μm, not less than 0.1 μm and not more than 0.2 μm, not less than 0.2 μm and not more than 0.3 μm, not less than 0.3 μm and not more than 0.4 μm, not less than 0.4 μm and not more than 0.5 μm, not less than 0.5 μm and not more than 0.6 μm, not less than 0.6 μm and not more than 0.7 μm, not less than 0.7 μm and not more than 0.8 μm, not less than 0.8 μm and not more than 0.9 μm, and not less than 0.9 μm and not more than 1 μm. The depth of the outer contact region 44 is preferably not less than 0.05 μm and not more than 0.5 μm.

The first outer peripheral structure 41 includes a terminal region 45 of the p-type formed in the surface layer portion of the first main surface 3 in the outer peripheral region 9 (the peripheral edge portion of the first main surface 3). The terminal region 45 may be referred to as a “terminal well region,” a “JTE region (junction termination extension region),” etc. The source potential is to be applied to the terminal region 45.

The terminal region 45 has a p-type impurity concentration higher than the n-type impurity concentration of the second semiconductor region 7. The p-type impurity concentration of the terminal region 45 is less than the p-type impurity concentration of the contact region 31. The p-type impurity concentration of the terminal region 45 is less than the p-type impurity concentration of the outer contact region 44.

The p-type impurity concentration of the terminal region 45 may be higher than the p-type impurity concentration of the body region 10, or may be less than the p-type impurity concentration of the body region 10. The p-type impurity concentration of the terminal region 45 may be higher than the p-type impurity concentration of the well region 30, or may be less than the p-type impurity concentration of the well region 30. The p-type impurity concentration of the terminal region 45 may be higher than the p-type impurity concentration of the outer well region 43, or may be less than the p-type impurity concentration of the outer well region 43.

The terminal region 45 is formed in a region between the peripheral edge of the first main surface 3 and the active region 8. Specifically, the terminal region 45 is formed in a region between the peripheral edge of the first main surface 3 and the outer well region 43. The terminal region 45 extends in a band shape along the peripheral edge (the outer well region 43, the active region 8) of the first main surface 3 in plan view.

In this embodiment, the terminal region 45 is formed in a polygonal annular shape (in this embodiment, a quadrilateral annular shape) having four sides parallel to the peripheral edge of the chip 2 in plan view, and surrounds the inner portion (the outer well region 43, the active region 8) of the first main surface 3. The terminal region 45 may have an edge portion that connects a portion extending in the first direction X and a portion extending in the second direction Y in an arc shape (preferably, a quarter arc shape).

As a matter of course, the terminal region 45 may each have a plurality of portions that are aligned at intervals along the inner portion (the outer well region 43, the active region 8) of the first main surface 3 so as to surround the inner portion (the outer well region 43, the active region 8) of the first main surface 3. In this case, the plurality of portions may each extend in a band shape along the inner portion (the outer well region 43, the active region 8) of the first main surface 3.

The terminal region 45 preferably has a width greater than the width of the outer well region 43. As a matter of course, the width of the terminal region 45 may be less than the width of the outer well region 43.

The width of the terminal region 45 may be more than 0 μm and not more than 300 μm. The width of the terminal region 45 may have a value belonging to at least one range among more than 0 μm and not more than 25 μm, not less than 25 μm and not more than 50 μm, not less than 50 μm and not more than 75 μm, not less than 75 μm and not more than 100 μm, not less than 100 μm and not more than 125 μm, not less than 125 μm and not more than 150 μm, not less than 150 μm and not more than 175 μm, not less than 175 μm and not more than 200 μm, not less than 200 μm and not more than 225 μm, not less than 225 μm and not more than 250 μm, not less than 250 μm and not more than 275 μm, and not less than 275 μm and not more than 300 μm. The width of the terminal region 45 is preferably not less than 10 μm and not more than 200 μm.

A width ratio of the width of the terminal region 45 to the width of the outer well region 43 may be not less than 0.5 and not more than 5. The width ratio may have a value belonging to any one range among not less than 0.5 and not more than 0.75, not less than 0.75 and not more than 1, not less than 1 and not more than 1.25, not less than 1.25 and not more than 1.5, not less than 1.5 and not more than 1.75, not less than 1.75 and not more than 2, not less than 2 and not more than 2.25, not less than 2.25 and not more than 2.5, not less than 2.5 and not more than 2.75, not less than 2.75 and not more than 3, not less than 4 and not more than 4.25, not less than 4.25 and not more than 4.5, not less than 4.5 and not more than 4.75, and not less than 4.75 and not more than 5. The width ratio is preferably not less than 1 and not more than 2.5.

The terminal region 45 is formed in the surface layer portion of the second semiconductor region 7 and is electrically connected to the second semiconductor region 7. The terminal region 45 is formed at an interval toward the first main surface 3 side from the bottom portion of the second semiconductor region 7, and faces the first semiconductor region 6 with a portion of the second semiconductor region 7 interposed therebetween. The terminal region 45 is preferably formed at an interval toward the first main surface 3 side from the depth position of the intermediate portion of the second semiconductor region 7.

The terminal region 45 is formed at an interval from the first main surface 3 in the thickness direction of the chip 2. That is, the terminal region 45 has a portion that is formed at an interval toward the bottom portion side of the second semiconductor region 7 from the first main surface 3 and faces the first main surface 3 with a portion of the second semiconductor region 7 interposed therebetween.

A distance between the first main surface 3 and the terminal region 45 may be more than 0 μm and not more than 3 μm. The distance may have a value belonging to at least one range among more than 0 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.25 μm, not less than 2.25 μm and not more than 2.5 μm, not less than 2.5 μm and not more than 2.75 μm, and not less than 2.75 μm and not more than 3 μm. The distance is preferably not less than 0.1 μm and not more than 2 μm.

The terminal region 45 has an upper end portion positioned at the first main surface 3 side and a bottom portion positioned at the bottom portion side of the second semiconductor region 7. The upper end portion of the terminal region 45 extends in the horizontal direction along the first main surface 3 and forms a pn junction portion with the second semiconductor region 7. The upper end portion of the terminal region 45 is positioned at the first main surface 3 side with respect to the depth position of the bottom portion of at least one type of the well region 30 (at least one of the gate well region 30g, the source well region 30s, and the dummy well region 30d).

The upper end portion of the terminal region 45 is positioned at the first main surface 3 side with respect to the depth position of the bottom wall of the gate structure 15. The upper end portion of the terminal region 45 is positioned at the first main surface 3 side with respect to the depth position of the bottom wall of the source structure 20. The upper end portion of the terminal region 45 is positioned at the first main surface 3 side with respect to the depth position of the bottom wall of the dummy structure 25. The upper end portion of the terminal region 45 is positioned at the first main surface 3 side with respect to a depth position of the bottom portion of the outer well region 43.

The bottom portion of the terminal region 45 extends in the horizontal direction along the first main surface 3 and forms a pn junction portion with the second semiconductor region 7. In this embodiment, the bottom portion of the terminal region 45 is positioned at the bottom portion side of the second semiconductor region 7 with respect to the depth position of the bottom portion of the body region 10. The bottom portion of the terminal region 45 may be positioned at the first main surface 3 side with respect to the depth position of the bottom portion of the body region 10.

The bottom portion of the terminal region 45 may be positioned at the bottom portion side of the second semiconductor region 7 with respect to the depth position of the bottom portion of the outer well region 43. The bottom portion of the terminal region 45 may be positioned at the first main surface 3 side with respect to the depth position of the bottom portion of the outer well region 43. The bottom portion of the terminal region 45 may be positioned at a depth position substantially equal to the bottom portion of the outer well region 43.

The bottom portion of the terminal region 45 may be positioned at the first main surface 3 side with respect to the depth position of the bottom wall of the gate structure 15. The bottom portion of the terminal region 45 may be positioned at the bottom portion side of the second semiconductor region 7 with respect to the depth position of the bottom wall of the gate structure 15. The bottom portion of the terminal region 45 may be positioned at the first main surface 3 side with respect to the depth position of the bottom wall of the source structure 20. The bottom portion of the terminal region 45 may be positioned at the bottom portion side of the second semiconductor region 7 with respect to the depth position of the bottom wall of the source structure 20.

The bottom portion of the terminal region 45 may be positioned at the first main surface 3 side with respect to the depth position of the bottom wall of the dummy structure 25. The bottom portion of the terminal region 45 may be positioned at the bottom portion side of the second semiconductor region 7 with respect to the depth position of the bottom wall of the dummy structure 25.

The bottom portion of the terminal region 45 may be positioned at the first main surface 3 side with respect to the depth position of the bottom portion of at least one type of the well region 30 (at least one of the gate well region 30g, the source well region 30s, and the dummy well region 30d). The bottom portion of the terminal region 45 may be positioned at the bottom portion side of the second semiconductor region 7 with respect to the depth position of the bottom portion of at least one type of the well region 30. The bottom portion of the terminal region 45 may be positioned at the depth position substantially equal to the bottom portion of at least one type of the well region 30.

The terminal region 45 may have a depth (thickness) greater than a distance between the first main surface 3 and the terminal region 45. The depth of the terminal region 45 is the distance between the upper end portion and the bottom portion of the terminal region 45. The depth of the terminal region 45 may be smaller than the distance between the first main surface 3 and the terminal region 45.

The depth of the terminal region 45 may be smaller than the distance between the bottom portion of the second semiconductor region 7 and the terminal region 45. The depth of the terminal region 45 may be greater than the distance between the bottom portion of the second semiconductor region 7 and the terminal region 45. The depth of the terminal region 45 is preferably less than the depth of the outer well region 43. The depth of the terminal region 45 may be greater than the depth of the outer well region 43.

The depth (thickness) of the terminal region 45 may be more than 0 μm and not more than 4 μm. The depth of the terminal region 45 may have a value belonging to at least one range among more than 0 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.25 μm, not less than 2.25 μm and not more than 2.5 μm, not less than 2.5 μm and not more than 2.75 μm, not less than 2.75 μm and not more than 3 μm, not less than 3 μm and not more than 3.25 μm, not less than 3.25 μm and not more than 3.5 μm, not less than 3.5 μm and not more than 3.75 μm, and not less than 3.75 μm and not more than 4 μm. The depth of the terminal region 45 is preferably not less than 0.5 μm and not more than 3 μm.

The terminal region 45 has an inner edge portion on the inner side of the first main surface 3 (the outer well region 43 side) and an outer edge portion on the peripheral edge side of the first main surface 3. The inner edge portion of the terminal region 45 is connected to the outer edge portion of the outer well region 43.

Specifically, the inner edge portion of the terminal region 45 is connected to the outer edge portion of the outer well region 43 in a region on the bottom portion side of the outer well region 43 with respect to the depth position of the intermediate portion of the outer well region 43. The terminal region 45 is thereby electrically connected to the body region 10 and the outer contact region 44 via the outer well region 43.

The inner edge portion of the terminal region 45 may be positioned at the inner edge portion side of the outer well region 43 with respect to the outer edge portion of the outer contact region 44. The inner edge portion of the terminal region 45 may be formed at an interval toward the outer edge portion side of the outer well region 43 from the outer edge portion of the outer contact region 44.

The inner edge portion of the terminal region 45 may be formed at an interval toward the bottom portion side of the outer well region 43 from the bottom portion of the outer contact region 44, and may face the outer contact region 44 with a portion of the outer well region 43 interposed therebetween. The inner edge portion of the terminal region 45 may be connected to the outer contact region 44.

The inner edge portion of the terminal region 45 may be formed at an interval toward the outer edge portion side of the outer well region 43 from the inner edge portion (the outermost dummy structure 25) of the outer well region 43. The inner edge portion of the terminal region 45 may be connected to the outermost dummy structure 25.

In this case, the inner edge portion of the terminal region 45 may have a portion connected to the outermost dummy well region 30d. As a matter of course, this Description does not exclude an arrangement in which the inner edge portion of the terminal region 45 is formed at an interval toward the peripheral edge portion side of the first main surface 3 from the inner edge portion of the outer well region 43 from the technical idea.

A connection portion (an overlap portion) between the outer edge portion of the outer well region 43 and the inner edge portion of the terminal region 45 contains a p-type impurity of the outer well region 43 and a p-type impurity of the terminal region 45. Therefore, the connection portion (the overlap portion) has a p-type impurity concentration higher than both the p-type impurity concentration of the outer well region 43 and the p-type impurity concentration of the terminal region 45.

The terminal region 45 spreads a depletion layer in the second semiconductor region 7 when a reverse bias voltage is applied. The depletion layer of the terminal region 45 spreads in the horizontal direction and the thickness direction, and is integrated with the depletion layer spreading from the active region 8 (the outer well region 43) side. The terminal region 45 expands the depletion layer spreading from the active region 8 toward the peripheral edge side of the first main surface 3, and relaxes the electric field strength (concentration of electric field) at the peripheral edge portion (the outer peripheral region 9) of the first main surface 3.

The second outer peripheral structure 42 includes at least one field region 47 of the p-type formed in the surface layer portion of the first main surface 3 in the outer peripheral region 9 (the peripheral edge portion of the first main surface 3). The field region 47 may be referred to as a “guard region,” a “field limit region,” etc.

The plurality of field regions 47 are formed in an electrically floating state. As a matter of course, the plurality of field regions 47 may be fixed to the source potential. The plurality of field regions 47 relax an electric field in the chip 2 in the outer peripheral region 9.

The number of the field regions 47 is arbitrary. The number of the field regions 47 may be not less than 1 and not more than 15. The number of the field regions 47 may be 1, 2, 3, 4, 5, 6, 7, 8, 9, 10, 11, 12, 13, 14, or 15. The number of the field regions 47 is typically not less than 1 and not more than 10. In this embodiment, the second outer peripheral structure 42 includes the six field regions 47 as an example.

The plurality of field regions 47 have a p-type impurity concentration higher than the n-type impurity concentration of the second semiconductor region 7. The p-type impurity concentration of the plurality of field regions 47 less than the p-type impurity concentration of the contact region 31. The p-type impurity concentration of the plurality of field regions 47 may be higher than the p-type impurity concentration of the contact region 31.

The p-type impurity concentration of the plurality of field regions 47 is less than the p-type impurity concentration of the outer contact region 44. The p-type impurity concentration of the plurality of field regions 47 may be higher than the p-type impurity concentration of the outer contact region 44.

The p-type impurity concentration of the plurality of field regions 47 may be higher than the p-type impurity concentration of the body region 10, or may be less than the p-type impurity concentration of the body region 10. The p-type impurity concentration of the plurality of field regions 47 may be substantially equal to the p-type impurity concentration of the body region 10.

The p-type impurity concentration of the plurality of field regions 47 may be higher than the p-type impurity concentration of the well region 30, or may be less than the p-type impurity concentration of the well region 30. The p-type impurity concentration of the plurality of field regions 47 may be substantially equal to the p-type impurity concentration of the well region 30.

The p-type impurity concentration of the plurality of field regions 47 may be higher than the p-type impurity concentration of the outer well region 43, or may be less than the p-type impurity concentration of the outer well region 43. The p-type impurity concentration of the plurality of field regions 47 may be substantially equal to the p-type impurity concentration of the outer well region 43.

The p-type impurity concentration of the plurality of field regions 47 is preferably substantially equal to the p-type impurity concentration of the terminal region 45. As a matter of course, the p-type impurity concentration of the plurality of field regions 47 may be higher than the p-type impurity concentration of the terminal region 45, or may be less than the p-type impurity concentration of the terminal region 45.

In this embodiment, the p-type impurity concentrations of the plurality of field regions 47 are substantially equal to each other. The p-type impurity concentrations of the plurality of field regions 47 are arbitrary, and can take various values in accordance with the electric field to be relaxed. The p-type impurity concentrations of the plurality of field regions 47 may be different from each other.

The p-type impurity concentration of the plurality of field regions 47 may sequentially increase toward the peripheral edge side of the first main surface 3. As a matter of course, the p-type impurity concentration of the plurality of field regions 47 may increase toward the peripheral edge side of the first main surface 3 in units of two or more groups, in which each group includes the two or more field regions 47.

The p-type impurity concentration of the plurality of field regions 47 may sequentially decrease toward the peripheral edge side of the first main surface 3. As a matter of course, the p-type impurity concentration of the plurality of field regions 47 may decrease toward the peripheral edge side of the first main surface 3 in units of two or more groups, in which each group includes the two or more field regions 47.

The plurality of field regions 47 are formed in a region between the peripheral edge of the first main surface 3 and the active region 8 at an interval from the peripheral edge of the first main surface 3 (the first to fourth side surfaces 5A to 5D) and the active region 8.

The plurality of field regions 47 are formed in a region between the peripheral edge of the first main surface 3 and the outer well region 43 at an interval from the peripheral edge of the first main surface 3 and the outer well region 43. The plurality of field regions 47 are formed in a region between the peripheral edge of the first main surface 3 and the terminal region 45 at an interval from the peripheral edge of the first main surface 3 and the terminal region 45.

The plurality of field regions 47 are formed in the surface layer portion of the second semiconductor region 7 at intervals from each other, and are electrically connected to the second semiconductor region 7. The plurality of field regions 47 extend in a band shape along the peripheral edge (the outer well region 43, the active region 8) of the first main surface 3 in plan view.

In this embodiment, the plurality of field regions 47 are formed in a polygonal annular shape (in this embodiment, a quadrilateral annular shape) having four sides parallel to the peripheral edge of the chip 2 in plan view, and surround the inner portion (the outer well region 43, the active region 8) of the first main surface 3. The plurality of field regions 47 may have an edge portion that connects a portion extending in the first direction X and a portion extending in the second direction Y in an arc shape (preferably, a quarter arc shape).

As a matter of course, each of the plurality of field regions 47 may have a plurality of portions that are aligned at intervals along the peripheral edge (the outer well region 43, the active region 8) of the first main surface 3 so as to surround the inner portion (the outer well region 43, the active region 8) of the first main surface 3. In this case, the plurality of portions may each extend in a band shape along the peripheral edge (the outer well region 43, the active region 8) of the first main surface 3. Each of the plurality of field regions 47 has a width less than the width of the terminal region 45.

The width of the field region 47 may be more than 0 μm and not more than 5 μm. The width of the field region 47 may have a value belonging to at least one range among more than 0 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.25 μm, not less than 2.25 μm and not more than 2.5 μm, not less than 2.5 μm and not more than 2.75 μm, not less than 2.75 μm and not more than 3 μm, not less than 3 μm and not more than 3.25 μm, not less than 3.25 μm and not more than 3.5 μm, not less than 3.5 μm and not more than 3.75 μm, not less than 3.75 μm and not more than 4 μm, not less than 4 μm and not more than 4.25 μm, not less than 4.25 μm and not more than 4.5 μm, not less than 4.5 μm and not more than 4.75 μm, and not less than 4.75 μm and not more than 5 μm. The width of the field region 47 is preferably not less than 0.5 μm and not more than 3 μm.

In this embodiment, the widths of the plurality of field regions 47 are substantially equal to each other. The widths of the plurality of field regions 47 are arbitrary, and can take various values in accordance with the electric field to be relaxed. The widths of the plurality of field regions 47 may be different from each other.

Intervals between the plurality of field regions 47 may be not more than the width of the field region 47. The intervals between the plurality of field regions 47 are preferably less than the width of the field region 47. As a matter of course, the intervals between the plurality of field regions 47 may be greater than the width of the field region 47.

A ratio (interval ratio) of the interval between the field regions 47 to the width of the field region 47 may be not less than 0.1 and not more than 5. The interval ratio may have a value belonging to at least one range among not less than 0.1 and not more than 0.5, not less than 0.5 and not more than 1, not less than 1 and not more than 1.5, not less than 1.5 and not more than 2, not less than 2 and not more than 2.5, not less than 2.5 and not more than 3, not less than 3 and not more than 3.5, not less than 3.5 and not more than 4, not less than 4 and not more than 4.5, and not less than 4.5 and not more than 5. The interval ratio is preferably not less than 0.1 and not more than 2.

In this embodiment, the intervals between the plurality of field regions 47 are substantially equal to each other. The intervals between the plurality of field regions 47 are arbitrary, and can take various values in accordance with the electric field to be relaxed. The intervals between the plurality of field regions 47 may be different from each other.

The interval between the field regions 47 may be more than 0 μm and not more than 5 μm. The interval may have a value belonging to at least one range among more than 0 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The interval is preferably not less than 0.5 μm and not more than 3 μm.

The plurality of field regions 47 are formed at intervals toward the first main surface 3 side from the bottom portion of the second semiconductor region 7, and face the first semiconductor region 6 with a portion of the second semiconductor region 7 interposed therebetween. The plurality of field regions 47 are preferably formed at intervals toward the first main surface 3 side from the depth position of the intermediate portion of the second semiconductor region 7.

The plurality of field regions 47 are formed at intervals in the thickness direction of the chip 2 from the first main surface 3. That is, the plurality of field regions 47 have a portion that is formed at intervals toward the bottom portion side of the second semiconductor region 7 from the first main surface 3 and faces the first main surface 3 with a portion of the second semiconductor region 7 interposed therebetween. The plurality of field regions 47 are each formed in the depth range between the upper end portion and the bottom portion of the terminal region 45, and face the terminal region 45 in the horizontal direction.

A distance between the first main surface 3 and the field region 47 is preferably substantially equal to the distance between the first main surface 3 and the terminal region 45. As a matter of course, the distance between the first main surface 3 and the field region 47 may be greater than the distance between the first main surface 3 and the terminal region 45, or may be smaller than the distance between the first main surface 3 and the terminal region 45.

The distance between the first main surface 3 and the field region 47 may be more than 0 μm and not more than 3 μm. The distance may have a value belonging to at least one range among more than 0 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.25 μm, not less than 2.25 μm and not more than 2.5 μm, not less than 2.5 μm and not more than 2.75 μm, and not less than 2.75 μm and not more than 3 μm. The distance is preferably not less than 0.1 μm and not more than 2 μm.

Each of the plurality of field regions 47 has an upper end portion positioned at the first main surface 3 side and a bottom portion positioned at the bottom portion side of the second semiconductor region 7. The upper end portion of the field region 47 extends in the horizontal direction along the first main surface 3 and forms a pn junction portion with the second semiconductor region 7. The upper end portion of the field region 47 is positioned at the first main surface 3 side with respect to the depth position of the bottom portion of at least one type of the well region 30 (at least one of the gate well region 30g, the source well region 30s, and the dummy well region 30d).

The upper end portion of the field region 47 is positioned at the first main surface 3 side with respect to the depth position of the bottom wall of the gate structure 15. The upper end portion of the field region 47 is positioned at the first main surface 3 side with respect to the depth position of the bottom wall of the source structure 20. The upper end portion of the field region 47 is positioned at the first main surface 3 side with respect to the depth position of the bottom wall of the dummy structure 25.

The upper end portion of the field region 47 is positioned at the first main surface 3 side with respect to the depth position of the bottom portion of the outer well region 43. The upper end portion of the field region 47 may be positioned at the bottom portion side of the second semiconductor region 7 with respect to the depth position of the bottom portion of the outer well region 43.

The bottom portion of the field region 47 extends in the horizontal direction along the first main surface 3 and forms a pn junction portion with the second semiconductor region 7. In this embodiment, the bottom portion of the field region 47 is positioned at the bottom portion side of the second semiconductor region 7 with respect to the depth position of the bottom portion of the body region 10. The bottom portion of the field region 47 may be positioned at the first main surface 3 side with respect to the depth position of the bottom portion of the body region 10.

The bottom portion of the field region 47 may be positioned at the bottom portion side of the second semiconductor region 7 with respect to the depth position of the bottom portion of the outer well region 43. The bottom portion of the field region 47 may be positioned at the first main surface 3 side with respect to the depth position of the bottom portion of the outer well region 43. The bottom portion of the field region 47 may be positioned at the depth position substantially equal to the bottom portion of the outer well region 43.

The bottom portion of the field region 47 may be positioned at the first main surface 3 side with respect to the depth position of the bottom wall of the gate structure 15. The bottom portion of the field region 47 may be positioned at the bottom portion side of the second semiconductor region 7 with respect to the depth position of the bottom wall of the gate structure 15. The bottom portion of the field region 47 may be positioned at the first main surface 3 side with respect to the depth position of the bottom wall of the source structure 20. The bottom portion of the field region 47 may be positioned at the bottom portion side of the second semiconductor region 7 with respect to the depth position of the bottom wall of the source structure 20.

The bottom portion of the field region 47 may be positioned at the first main surface 3 side with respect to the depth position of the bottom wall of the dummy structure 25. The bottom portion of the field region 47 may be positioned at the bottom portion side of the second semiconductor region 7 with respect to the depth position of the bottom wall of the dummy structure 25.

The bottom portion of the field region 47 may be positioned at the first main surface 3 side with respect to the depth position of the bottom portion of at least one type of the well region 30 (at least one of the gate well region 30g, the source well region 30s, and the dummy well region 30d).

The bottom portion of the field region 47 may be positioned at the bottom portion side of the second semiconductor region 7 with respect to the depth position of the bottom portion of at least one type of the well region 30. The bottom portion of the field region 47 may be positioned at the depth position substantially equal to the bottom portion of at least one type of the well region 30.

The field region 47 may have a depth (thickness) that is substantially equal to the depth (thickness) of the terminal region 45. The depth of the field region 47 is the distance between the upper end portion and bottom portion of the field region 47. As a matter of course, the depth of the field region 47 may be greater than the depth of the terminal region 45 or smaller than the depth of the terminal region 45.

The depth of the field region 47 may be greater than the distance between the first main surface 3 and the field region 47. The depth of the field region 47 may be smaller than the distance between the first main surface 3 and the field region 47. The depth of the field region 47 may be smaller than the distance between the bottom portion of the second semiconductor region 7 and the field region 47. The depth of the field region 47 may be greater than the distance between the bottom portion of the second semiconductor region 7 and the field region 47.

The depth (thickness) of the field region 47 may be more than 0 μm and not more than 4 μm. The depth of the field region 47 may have a value belonging to at least one range among more than 0 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, not less than 1.75 μm and not more than 2 μm, not less than 2 μm and not more than 2.25 μm, not less than 2.25 μm and not more than 2.5 μm, not less than 2.5 μm and not more than 2.75 μm, not less than 2.75 μm and not more than 3 μm, not less than 3 μm and not more than 3.25 μm, not less than 3.25 μm and not more than 3.5 μm, not less than 3.5 μm and not more than 3.75 μm, and not less than 3.75 μm and not more than 4 μm. The depth of the field region 47 is preferably not less than 0.5 μm and not more than 3 μm.

In this embodiment, the depths of the plurality of field regions 47 are substantially equal to each other. The depths of the plurality of field regions 47 are arbitrary, and can take various values in accordance with the electric field to be relaxed. The depths of the plurality of field regions 47 may be different from each other.

The plurality of field regions 47 spreads depletion layers in the second semiconductor region 7 when a reverse bias voltage is applied. The depletion layers of the plurality of field regions 47 spreads in the horizontal direction and the thickness direction, and are integrated with the depletion layer spreading from the active region 8 side (the terminal region 45 side). The plurality of field regions 47 expand the depletion layer spreading from the active region 8 side (the terminal region 45 side) toward the peripheral edge side of the first main surface 3, and relax the electric field strength (concentration of electric field) at the peripheral edge portion (the outer peripheral region 9) of the first main surface 3.

Referring to FIG. 10B, the semiconductor device 1A may include the outer peripheral structure 40 according to a second configuration example, formed in the outer peripheral region 9. The outer peripheral structure 40 according to the second configuration example has an arrangement in which the field region 47 is removed from the outer peripheral structure 40 (second outer peripheral structure 42) according to the first configuration example. That is, the outer peripheral structure 40 according to the second configuration example includes the outer well region 43, the outer contact region 44, and the terminal region 45, and does not include the field region 47.

Referring to FIG. 10C, the semiconductor device 1A may include the outer peripheral structure 40 according to a third configuration example, formed in the outer peripheral region 9. The outer peripheral structure 40 according to the third configuration example has an arrangement in which the terminal region 45 is removed from the outer peripheral structure 40 (first outer peripheral structure 41) according to the first configuration example. That is, the outer peripheral structure 40 according to the third configuration example includes the outer well region 43, the outer contact region 44, and the field region 47, and does not include the terminal region 45.

Referring to FIG. 10D, the semiconductor device 1A may include the outer peripheral structure 40 according to a fourth configuration example, formed in the outer peripheral region 9. The outer peripheral structure 40 according to the fourth configuration example includes the terminal region 45 having an upper end portion exposed from the first main surface 3 in the outer peripheral structure 40 (first outer peripheral structure 41) according to the first configuration example. Other arrangements of the outer peripheral structure 40 according to the fourth configuration example are similar to those of the outer peripheral structure 40 according to the first configuration example.

Referring to FIG. 10E, the semiconductor device 1A may include the outer peripheral structure 40 according to a fifth configuration example, formed in the outer peripheral region 9. The outer peripheral structure 40 according to the fifth configuration example includes one or a plurality of (in this embodiment, a plurality of) the field regions 47 having an upper end portion exposed from the first main surface 3 in the outer peripheral structure 40 (second outer peripheral structure 42) according to the first configuration example. Other arrangements of the outer peripheral structure 40 according to the fifth configuration example are similar to those of the outer peripheral structure 40 according to the first configuration example.

In the outer peripheral structure 40 according to the first to fifth configuration examples, the electric field distribution in the chip 2 (the first main surface 3) and the extension range of the depletion layer are adjusted by the layout (in particular, the terminal region 45 and the field region 47) of the first outer peripheral structure 41 and the second outer peripheral structure 42. That is, the outer peripheral structure 40 according to the first to fifth configuration examples has an advantage that a value of the breakdown voltage is adjusted by the layout of the first outer peripheral structure 41 and the second outer peripheral structure 42.

One or both of the terminal region 45 and the field region 47 can be formed in the surface layer portion of the second semiconductor region 7 at intervals from the first main surface 3, and can have an upper end portion that forms a pn junction portion with the second semiconductor region 7.

The expansion range of the depletion layer thereby increases compared with the case where one or both of the terminal region 45 and the field region 47 have the upper end portion exposed from the first main surface 3, and the breakdown voltage can be improved. Also, such an arrangement is also effective in adjusting the breakdown voltage in accordance with device specifications.

Referring to FIGS. 1 to 10E, the semiconductor device 1A includes a main surface insulating film 50 selectively covering the first main surface 3. The main surface insulating film 50 may include at least one among a silicon oxide film, a silicon nitride film, and a silicon oxynitride film.

The main surface insulating film 50 preferably includes the same type of insulating material as the insulating material of the first insulating film 17. In this embodiment, the main surface insulating film 50 has a single layer structure constituted of a silicon oxide film. The main surface insulating film 50 particularly preferably includes a silicon oxide film made of the oxide of the chip 2.

The main surface insulating film 50 is selectively connected to the first insulating films 17 of the plurality of gate structures 15, the second insulating films 22 of the plurality of source structures 20, and the third insulating films 27 of the plurality of dummy structures 25 in the active region 8, and exposes the first embedded electrodes 18 of the plurality of gate structures 15, the second embedded electrodes 23 of the plurality of source structures 20, and the third embedded electrodes 28 of the plurality of dummy structures 25.

The main surface insulating film 50 covers the second semiconductor region 7, the outer well region 43, and the outer contact region 44 in the outer peripheral region 9. In this embodiment, the main surface insulating film 50 is continuous to the first to fourth side surfaces 5A to 5D at the peripheral edge portion of the first main surface 3. As a matter of course, the main surface insulating film 50 may be formed at an interval inward from the peripheral edge of the first main surface 3 and expose the peripheral edge portion (the second semiconductor region 7) of the first main surface 3.

The semiconductor device 1A includes an outer wiring 51 arranged on the main surface insulating film 50 in the outer peripheral region 9. The outer wiring 51 may be referred to as a “wiring,” a “main surface wiring,” an “outer peripheral wiring,” a “side wiring,” etc.

The outer wiring 51 may contain either or both of a conductive polysilicon of the p-type and a conductive polysilicon of the n-type. The outer wiring 51 preferably has the same type of conductive material (conductivity type) as that of at least one of the first embedded electrode 18, the second embedded electrode 23, and the third embedded electrode 28.

The outer wiring 51 is arranged at an interval toward the active region 8 side from the peripheral edge of the first main surface 3 in the outer peripheral region 9. The outer wiring 51 is arranged on the outer well region 43 and faces the outer well region 43 with the main surface insulating film 50 interposed therebetween.

The outer wiring 51 extends in a band shape along the peripheral edge of the first main surface 3 (the peripheral edge of the active region 8) in conformance to the outer well region 43 in plan view. In this embodiment, the outer wiring 51 is formed in a polygonal annular shape (in this embodiment, a quadrilateral annular shape) having four sides parallel to the peripheral edge of the chip 2 in plan view, and surrounds the inner portion (the active region 8) of the first main surface 3.

The outer wiring 51 may have an edge portion may have an edge portion that connects a portion extending in the first direction X and a portion extending in the second direction Y in an arc shape (preferably, a quarter arc shape). The outer wiring 51 may be a shape with ends or an endless shape.

The outer wiring 51 has an inner edge portion on the inner portion side of the first main surface 3 (the active region 8 side) and an outer edge portion on the peripheral edge portion side of the first main surface 3. The inner edge portion of the outer wiring 51 is led out into the active region 8 across the boundary portion (that is, the inner edge portion of the outer well region 43) between the active region 8 and the outer peripheral region 9. The inner edge portion of the outer wiring 51 covers the one or plurality of dummy structures 25.

In this embodiment, the inner edge portion of the outer wiring 51 covers the outermost dummy structure 25 and is connected to the third embedded electrode 28 of the outermost dummy structure 25. The outer wiring 51 is integrally formed with the third embedded electrode 28 of the dummy structure 25. That is, the outer wiring 51 is formed as a lead-out portion of the third embedded electrode 28, and is routed on the main surface insulating film 50.

The outer edge portion of the outer wiring 51 is formed at an interval inward (the active region 8 side) from the innermost field region 47 among the plurality of field regions 47. That is, the outer edge portion of the outer wiring 51 does not face the plurality of field regions 47 with the main surface insulating film 50 interposed therebetween. According to this arrangement, a dispersion path of an electric field in the region above the plurality of field regions 47 is suppressed from being shielded by the outer wiring 51, and an electric field (a line of electric force) is appropriately dispersed by the plurality of field regions 47.

The outer edge portion of the outer wiring 51 is formed at an interval inward from the outer edge portion of the terminal region 45. In this embodiment, the outer edge portion of the outer wiring 51 has a portion that is arranged inward at an interval from the outer edge portion of the outer contact region 44 and that faces the outer contact region 44 with the main surface insulating film 50 interposed therebetween. The outer edge portion of the outer wiring 51 may have a portion that faces the terminal region 45 in a lamination direction.

The semiconductor device 1A includes an interlayer film 52 with an insulating property that selectively covers the first main surface 3 with the main surface insulating film 50 interposed therebetween. The interlayer film 52 may be referred to as an “insulating film,” an “interlayer insulating film,” an “intermediate insulating film,” etc. The interlayer film 52 may include at least one among a silicon oxide film, a silicon nitride film, and a silicon oxynitride film. The interlayer film 52 preferably includes a silicon oxide film.

The interlayer film 52 covers the plurality of gate structures 15 (the first embedded electrodes 18) and the plurality of dummy structures 25 (the third embedded electrodes 28) on the active region 8 side. The interlayer film 52 may cover both end portions of the source structure 20 on the active region 8 side.

The interlayer film 52 covers the second semiconductor region 7, the outer well region 43, and the outer contact region 44 with the main surface insulating film 50 interposed therebetween on the outer peripheral region 9 side.

In this embodiment, the interlayer film 52 is continuous to the first to fourth side surfaces 5A to 5D at the peripheral edge portion of the first main surface 3. As a matter of course, the interlayer film 52 may be formed at an interval inward from the peripheral edge of the first main surface 3 and expose the peripheral edge portion (the second semiconductor region 7) of the first main surface 3.

The interlayer film 52 may have a thickness of not less than 0.5 μm and not more than 3 μm. The thickness of the interlayer film 52 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm.

The semiconductor device 1A includes a plurality of source openings 53 formed in the interlayer film 52. The plurality of source openings 53 are each formed in a one-to-one correspondence with the plurality of source structures 20 in regions between the plurality of gate structures 15. Each of the plurality of source openings 53 extends in a band shape in the second direction Y along the corresponding source structure 20.

The plurality of source openings 53 penetrate the main surface insulating film 50 and the interlayer film 52, and respectively expose the one corresponding source structure 20, the source region 11, a plurality of corresponding gate contact regions 31g, and a plurality of corresponding source contact regions 31s. Each of the plurality of source openings 53 may have an opening end curved in an arc shape.

The plurality of source openings 53 may be formed in a multiple-to-one correspondence with the one corresponding source structure 20. In this case, the plurality of source openings 53 may be formed at intervals along the one corresponding source structure 20. Also, in this case, the plurality of source openings 53 may be formed in a quadrilateral shape, a rectangular shape (a band shape), a circular shape, etc., in plan view.

The semiconductor device 1A includes at least one (in this embodiment, one) outer opening 54 formed in the interlayer film 52. The outer opening 54 penetrates the main surface insulating film 50 and the interlayer film 52, and exposes the outer edge portion of the outer wiring 51 and the outer contact region 44. The outer opening 54 extends in a band shape along the outer edge portion of the outer wiring 51 and the outer contact region 44 in plan view.

In this embodiment, the outer opening 54 is formed in a polygonal annular shape (specifically, a quadrilateral annular shape) surrounding the inner portion (the active region 8) of the first main surface 3 along the outer contact region 44 and the outer wiring 51 in plan view. The outer opening 54 may have an opening end curved in an arc shape.

As a matter of course, the semiconductor device 1A may have a plurality of outer openings 54. In this case, the plurality of outer openings 54 may be formed at intervals along the outer contact region 44 and the outer wiring 51 so as to surround the inner portion (the active region 8) of the first main surface 3. In this case, the plurality of outer openings 54 may be formed in a quadrilateral shape (a square shape), a rectangular shape, a hexagonal shape, a circular shape, etc., in plan view.

The semiconductor device 1A includes a plurality of gate openings 55 formed in the interlayer film 52 (see FIG. 3). The plurality of gate openings 55 are formed in a multiple-to-one correspondence with the one corresponding gate structure 15. In this embodiment, the plurality of gate openings 55 penetrate the interlayer film 52 and respectively expose one end portion or the other end portion of each of the plurality of gate structures 15 (the first embedded electrodes 18).

Each of the plurality of gate openings 55 may have an opening end curved in an arc shape. The plurality of gate openings 55 may be formed in a quadrilateral shape, a rectangular shape (a band shape) extending in the first direction X, a rectangular shape (a band shape) extending in the second direction Y, a circular shape, etc., in plan view.

The semiconductor device 1A includes a source electrode 60 arranged on the first main surface 3. The source electrode 60 is a terminal electrode to which the source potential is to be applied from an exterior. The source electrode 60 may be referred to as a “source pad electrode,” a “first pad electrode,” a “first main surface electrode,” a “first terminal electrode,” etc.

The source electrode 60 is arranged on a portion of the interlayer film 52 that covers the active region 8. The source electrode 60 enters the plurality of source openings 53 from above the interlayer film 52, and is electrically connected to the source region 11 and the plurality of contact regions 31 in the plurality of source openings 53.

In this embodiment, the source electrode 60 includes a first pad portion 60a, a second pad portion 60b, and a third pad portion 60c. The first pad portion 60a has a relatively large planar area, and forms a main body of the source electrode 60. In this embodiment, the first pad portion 60a is formed in a polygonal shape (in this embodiment, a quadrilateral shape) having four sides parallel to the peripheral edge of the chip 2 in plan view, and is unevenly positioned at the fourth side surface 5D side with respect to the central portion of the first main surface 3.

The second pad portion 60b has a planar area less than the planar area of the first pad portion 60a, and is led out in a band shape (a quadrilateral shape) from one end portion (an end portion on the first side surface 5A side) of the first pad portion 60a in the second direction Y toward the third side surface 5C. The third pad portion 60c has a planar area less than the planar area of the first pad portion 60a, is led out in a band shape (a quadrilateral shape) from the other end portion (an end portion on the second side surface 5B side) of the first pad portion 60a in the second direction Y toward the third side surface 5C, and faces the second pad portion 60b in the second direction Y.

The planar area of the third pad portion 60c may be substantially equal to the planar area of the second pad portion 60b. As a matter of course, the planar area of the third pad portion 60c may be greater than the planar area of the second pad portion 60b, or may be less than the planar area of the second pad portion 60b. One or both of the second pad portion 60b and the third pad portion 60c may be used as a terminal portion for current monitoring.

The source electrode 60 does not necessarily have to have both the second pad portion 60b and the third pad portion 60c at the same time. The source electrode 60 may include only one of the second pad portion 60b and the third pad portion 60c. As a matter of course, the source electrode 60 may include only the first pad portion 60a, and may have neither of the second pad portion 60b and the third pad portion 60c.

In this embodiment, the source electrode 60 has a laminated structure including a lower electrode film 61 and a main electrode film 62 laminated in that order from the chip 2 side. In this embodiment, the lower electrode film 61 has a laminated structure including a first electrode film 63 and a second electrode film 64. In this embodiment, the first electrode film 63 includes a Ti film, and the second electrode film 64 includes a TiN film. The lower electrode film 61 does not necessarily have to have a laminated structure, and may have a single layer structure including one of the first electrode film 63 (a Ti film) and the second electrode film 64 (a TiN film).

The first electrode film 63 has a thickness less than the thickness of the interlayer film 52. The thickness of the first electrode film 63 may be not less than 10 nm and not more than 100 nm. The thickness of the first electrode film 63 may have a value belonging to at least one range among not less than 10 nm and not more than 25 nm, not less than 25 nm and not more than 50 nm, not less than 50 nm and not more than 75 nm, and not less than 75 nm and not more than 100 nm.

The second electrode film 64 has a thickness less than the thickness of the interlayer film 52. The thickness of the second electrode film 64 is preferably greater than the thickness of the first electrode film 63. The thickness of the second electrode film 64 may be not less than 50 nm and not more than 200 nm. The thickness of the second electrode film 64 may have a value belonging to at least one range among not less than 50 nm and not more than 75 nm, not less than 75 nm and not more than 100 nm, not less than 100 nm and not more than 125 nm, not less than 125 nm and not more than 150 nm, not less than 150 nm and not more than 175 nm, and not less than 175 nm and not more than 200 nm.

The first electrode film 63 entirely covers, in a film shape, a region of the interlayer film 52 in which the plurality of source openings 53 are formed, and enters the plurality of source openings 53 from above the interlayer film 52. The first electrode film 63 has a portion that covers the insulating main surface of the interlayer film 52 in a film shape, a portion that covers the wall surfaces of the plurality of source openings 53 in a film shape, and a portion that covers the first main surface 3 in a film shape in the plurality of source openings 53. The first electrode film 63 is mechanically and electrically connected to the source region 11 and the plurality of contact regions 31 in the source opening 53.

The second electrode film 64 directly covers the first electrode film 63. The second electrode film 64 entirely covers, in a film shape, a region of the interlayer film 52 in which the plurality of source openings 53 are formed with the first electrode film 63 interposed therebetween, and enters the plurality of source openings 53 from above the interlayer film 52.

The second electrode film 64 has a portion that covers the insulating main surface of the interlayer film 52 in a film shape with the first electrode film 63 interposed therebetween, a portion that covers the wall surfaces of the plurality of source openings 53 in a film shape with the first electrode film 63 interposed therebetween, and a portion that covers the first main surface 3 in a film shape with the first electrode film 63 interposed therebetween in the plurality of source openings 53. The second electrode film 64 is electrically connected to the source region 11 and the plurality of contact regions 31 via the first electrode film 63 in the source opening 53.

The main electrode film 62 includes a conductive material different from that of the lower electrode film 61 (the first electrode film 63 and the second electrode film 64). The main electrode film 62 may include at least one of an Al film, an Al alloy film, a Cu film, and a Cu alloy film. The Al alloy film may include at least one of an AlSi alloy film, an AlCu alloy film, and an AlSiCu alloy film. The main electrode film 62 has a thickness greater than the thickness (the total thickness) of the lower electrode film 61. The thickness of the main electrode film 62 is preferably greater than the thickness of the interlayer film 52.

The thickness of the main electrode film 62 may be not less than 0.5 μm and not more than 5 μm. The thickness of the main electrode film 62 may have a value belonging to at least one range among not less than 0.5 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The main electrode film 62 directly covers the lower electrode film 61 (the second electrode film 64). The main electrode film 62 entirely covers, in a film shape, a region of the interlayer film 52 in which the plurality of source openings 53 are formed, and refills the plurality of source openings 53.

The main electrode film 62 has a portion that covers the insulating main surface of the interlayer film 52 with the lower electrode film 61 interposed therebetween, a portion that covers the wall surfaces of the plurality of source openings 53 with the lower electrode film 61 interposed therebetween, and a portion that covers the first main surface 3 with the lower electrode film 61 interposed therebetween. The main electrode film 62 is electrically connected to the source region 11 and the plurality of contact regions 31 via the lower electrode film 61 in the plurality of source openings 53.

The semiconductor device 1A includes a terminal wiring 65 arranged around the source electrode 60 on the interlayer film 52. The same potential (the source potential) as the potential (the source potential) applied to the source electrode 60 is applied to the terminal wiring 65. The terminal wiring 65 may be referred to as a “terminal electrode,” a “wiring,” a “source wiring,” a “first wiring,” a “finger electrode,” a “source finger,” etc.

The terminal wiring 65 has a wiring width less than an electrode width of the source electrode 60, and is selectively routed on the interlayer film 52. In this embodiment, the terminal wiring 65 is led out from the source electrode 60 (the first pad portion 60a) toward the fourth side surface 5D. The terminal wiring 65 has a portion that is led out from the active region 8 side to the outer peripheral region 9 side and that faces the outer wiring 51 with the interlayer film 52 interposed therebetween. In this embodiment, the terminal wiring 65 covers the outer wiring 51 across an entire periphery.

The terminal wiring 65 enters the outer opening 54 from above the interlayer film 52, and is electrically connected to the outer contact region 44 and the outer wiring 51 in the outer opening 54. That is, the terminal wiring 65 is electrically connected to the terminal region 45 via the outer contact region 44.

The terminal wiring 65 is electrically connected to one or a plurality (in this embodiment, one) of the dummy structures 25 (the third embedded electrodes 28) via the outer wiring 51. The source potential applied to the source electrode 60 is applied to the dummy structure 25 via the terminal wiring 65, and simultaneously applied to the terminal region 45 via the terminal wiring 65.

The terminal wiring 65 extends in a band shape along the peripheral edge of the first main surface 3 (the peripheral edge of the active region 8) in conformance to the outer contact region 44 in plan view. In this embodiment, the terminal wiring 65 is formed in a polygonal annular shape (in this embodiment, a quadrilateral annular shape) having four sides parallel to the peripheral edge of the chip 2 in plan view, and surrounds the inner portion (the active region 8) of the first main surface 3.

The terminal wiring 65 may have an edge portion that connects a portion extending in the first direction X and a portion extending in the second direction Y in an arc shape (preferably, a quarter arc shape). The terminal wiring 65 may be a shape with ends or an endless shape.

The terminal wiring 65 has an inner edge portion on the inner portion side of the first main surface 3 (the active region 8 side) and an outer edge portion on the peripheral edge portion side of the first main surface 3. The inner edge portion of the terminal wiring 65 is positioned in the active region 8 and faces one or a plurality (in this embodiment, a plurality) of the dummy structures 25 with the interlayer film 52 interposed therebetween.

The outer edge portion of the terminal wiring 65 is formed at an interval inward (toward the active region 8) from the peripheral edge of the first main surface 3. The outer edge portion of the terminal wiring 65 is formed at an interval inward from the innermost field region 47 among the plurality of field regions 47. That is, the terminal wiring 65 does not face the plurality of field regions 47 via the interlayer film 52 interposed therebetween.

According to this arrangement, the dispersion path of the electric field in the region above the plurality of field regions 47 is suppressed from being shielded by the terminal wiring 65, and the electric field (the line of electric force) is appropriately dispersed by the plurality of field regions 47.

The outer edge portion of the terminal wiring 65 is formed at an interval inward from the outer edge portion of the terminal region 45, and faces the terminal region 45 with the interlayer film 52 interposed therebetween. In this embodiment, the outer edge portion of the outer wiring 51 is arranged at an interval toward the outer edge portion side of the terminal region 45 from the outer edge portion of the outer contact region 44, and faces the entire region of the outer contact region 44 with the main surface insulating film 50 interposed therebetween.

As with the source electrode 60, the terminal wiring 65 has a laminated structure including the lower electrode film 61 and the main electrode film 62 laminated in that order from the chip 2 side. In this embodiment, the lower electrode film 61 has a laminated structure including the first electrode film 63 and the second electrode film 64.

The first electrode film 63 entirely covers, in a film shape, a region of the interlayer film 52 in which the outer opening 54 is formed, and enters the outer opening 54 from above the interlayer film 52. The first electrode film 63 has a portion that covers the insulating main surface of the interlayer film 52 in a film shape, a portion that covers the wall surface of the outer opening 54 in a film shape, and a portion that covers the outer wiring 51 and the first main surface 3 in a film shape in the outer opening 54. The first electrode film 63 is mechanically and electrically connected to the outer contact region 44 and the outer wiring 51 in the outer opening 54.

The second electrode film 64 directly covers the first electrode film 63. The second electrode film 64 entirely covers, in a film shape, a region of the interlayer film 52 in which the outer opening 54 is formed with the first electrode film 63 interposed therebetween, and enters the outer opening 54 from above the interlayer film 52.

The second electrode film 64 has a portion that covers the insulating main surface of the interlayer film 52 in a film shape with the first electrode film 63 interposed therebetween, a portion that covers the wall surface of the outer opening 54 in a film shape with the first electrode film 63 interposed therebetween, and a portion that covers the first main surface 3 in a film shape with the first electrode film 63 interposed therebetween in the outer opening 54. The second electrode film 64 is electrically connected to the outer contact region 44 and the outer wiring 51 via the first electrode film 63 in the outer opening 54.

The main electrode film 62 directly covers the lower electrode film 61 (the second electrode film 64). The main electrode film 62 entirely covers, in a film shape, the region of the interlayer film 52 in which the outer opening 54 is formed, and refills the outer opening 54.

The main electrode film 62 has a portion that covers the insulating main surface of the interlayer film 52 with the lower electrode film 61 interposed therebetween, a portion that covers the wall surface of the outer opening 54 with the lower electrode film 61 interposed therebetween, and a portion that covers the first main surface 3 with the lower electrode film 61 interposed therebetween. The main electrode film 62 is electrically connected to the outer contact region 44 and the outer wiring 51 via the lower electrode film 61 in the outer opening 54.

The semiconductor device 1A includes a gate electrode 66 arranged on the first main surface 3. The gate electrode 66 is a terminal electrode to which the gate potential is to be applied from an exterior. The gate electrode 66 may be referred to as a “second pad electrode,” a “second main surface electrode,” a “second terminal electrode,” etc. Although not illustrated, as with the source electrode 60, the gate electrode 66 includes the lower electrode film 61 and the main electrode film 62 laminated in that order from the chip 2 side.

The gate electrode 66 is arranged on a portion of the interlayer film 52 that covers the active region 8 at an interval from the source electrode 60. In this embodiment, the gate electrode 66 is arranged in a region on the third side surface 5C side with respect to the first pad portion 60a, and faces the first pad portion 60a in the first direction X. The gate electrode 66 is interposed in a region between the second pad portion 60b and the third pad portion 60c, and faces both the second pad portion 60b and the third pad portion 60c in the second direction Y.

The gate electrode 66 is formed in a polygonal shape (in this embodiment, a quadrilateral shape) having four sides parallel to the peripheral edge of the chip 2 in plan view. The gate electrode 66 has a planar area less than the planar area of the source electrode 60. The gate electrode 66 has a planar area less than the planar area of the first pad portion 60a. The gate electrode 66 may have a planar area less than the planar area of the second pad portion 60b (the third pad portion 60c).

The gate electrode 66 partially faces the plurality of gate structures 15 and the plurality of source structures 20 with the interlayer film 52 interposed therebetween. Specifically, the gate electrode 66 is arranged inward at an interval from the both end portions of the plurality of gate structures 15, and faces inner portions of the plurality of gate structures 15 with the interlayer film 52 interposed therebetween. In this embodiment, the gate electrode 66 does not have a direct electrical connection location to the plurality of gate structures 15.

As a matter of course, the gate electrode 66 may be electrically connected to the plurality of gate structures 15 via the plurality of gate openings 55. Portions of the plurality of gate structures 15 positioned at the gate electrode 66 may be removed.

In this case, the gate electrode 66 may face the body region 10 with the main surface insulating film 50 and the interlayer film 52 interposed therebetween. The gate electrode 66 may partially face the one or plurality of dummy structures 25 with the interlayer film 52 interposed therebetween.

The semiconductor device 1A includes a gate wiring 67 led out from the gate electrode 66 onto the first main surface 3. The gate wiring 67 may be referred to as a “wiring,” a “second wiring,” a “finger electrode,” a “gate finger,” etc.

The gate wiring 67 transmits the gate potential applied to the gate electrode 66 to other regions. Although not illustrated, as with the source electrode 60 (the gate electrode 66), the gate wiring 67 includes the lower electrode film 61 and the main electrode film 62 laminated in that order from the chip 2 side.

The gate wiring 67 is led from the gate electrode 66 onto a portion of the interlayer film 52 that covers the active region 8, and is routed to a region between the source electrode 60 and the terminal wiring 65 at an interval from the source electrode 60 and the terminal wiring 65.

The gate wiring 67 has a portion extending in a band shape in the first direction X and a portion extending in a band shape in the second direction Y in plan view, and intersects (specifically, is orthogonal to) end portions (in this embodiment, the both end portions) of the plurality of gate structures 15. In this embodiment, the gate wiring 67 is formed in a band shape with ends having four sides parallel to the peripheral edge of the first main surface 3, and surrounds the source electrode 60.

The gate wiring 67 enters the plurality of gate openings 55 from above the interlayer film 52, and is mechanically and electrically connected to the end portions (the both end portions) of the plurality of gate structures 15 (the first embedded electrodes 18) in the plurality of gate openings 55. The gate potential applied to the gate electrode 66 is thereby applied to the plurality of gate structures 15 via the gate wiring 67.

The semiconductor device 1A includes a drain electrode 68 that covers the second main surface 4. The drain electrode 68 is a terminal electrode to which the drain potential is to be applied from an exterior. The drain electrode 68 may be referred to as a “third pad electrode,” a “third main surface electrode,” a “third terminal electrode,” etc.

The drain electrode 68 is electrically connected to the first semiconductor region 6. The drain electrode 68 may cover the entire region of the second main surface 4 so as to be continuous to the peripheral edge (the first to fourth side surfaces 5A to 5D) of the second main surface 4. The drain electrode 68 may partially cover the second main surface 4 so as to expose the peripheral edge portion of the second main surface 4.

The breakdown voltage that can be applied between the source electrode 60 and the drain electrode 68 (between the first main surface 3 and the second main surface 4) may be not less than 500 V and not more than 3000 V. The breakdown voltage may have a value belonging to at least one range among not less than 500 V and not more than 750 V, 750 V and not more than 1000 V, not less than 1000 V and not more than 1250 V, not less than 1250 V and not more than 1500 V, not less than 1500 V and not more than 1750 V, and 1750 V and not more than 2000 V, not less than 2000 V and not more than 2250 V, not less than 2250 V and not more than 2500 V, not less than 2500 V and not more than 2750 V, and not less than 2750 V and not more than 3000 V.

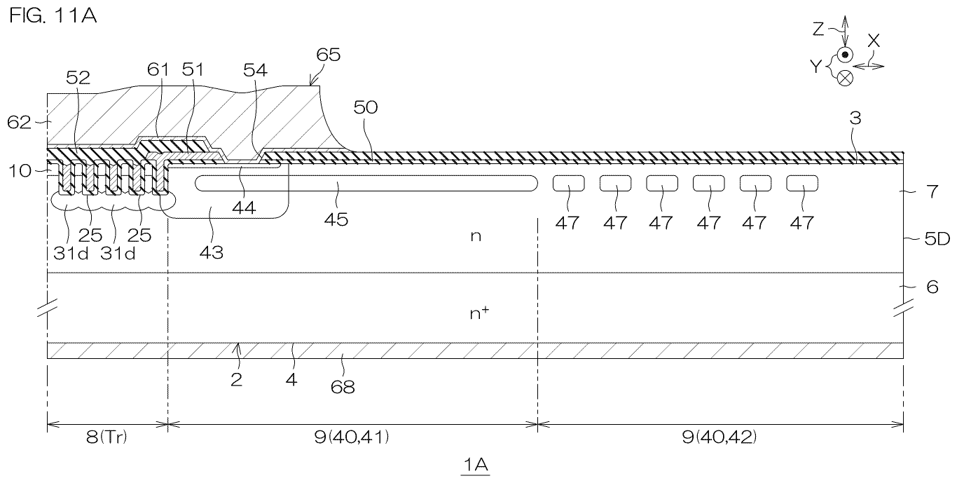

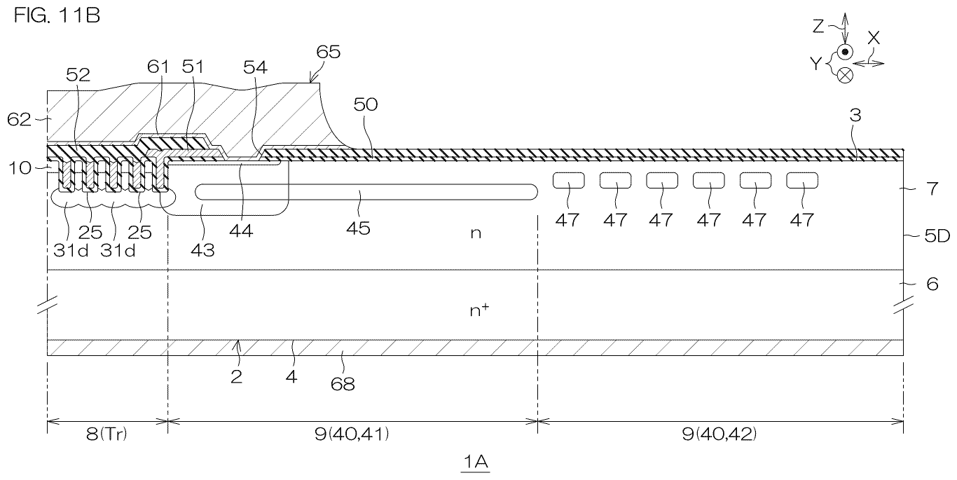

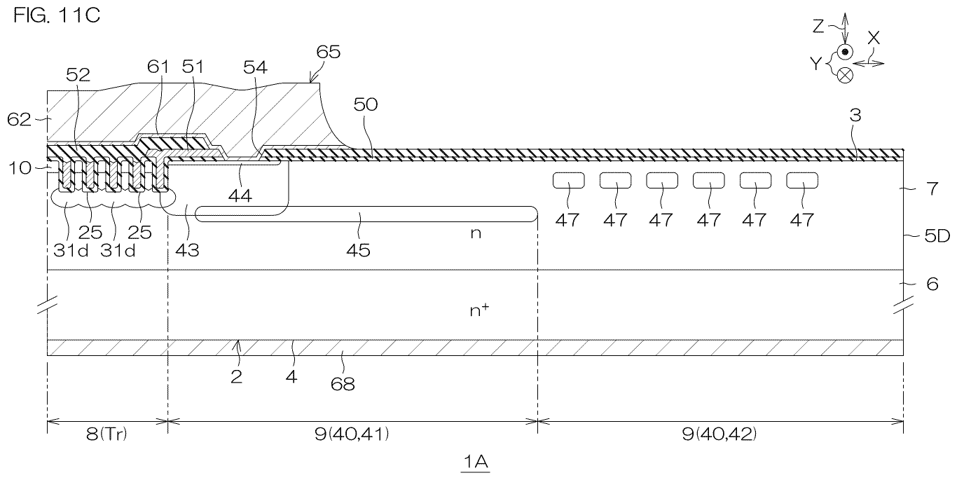

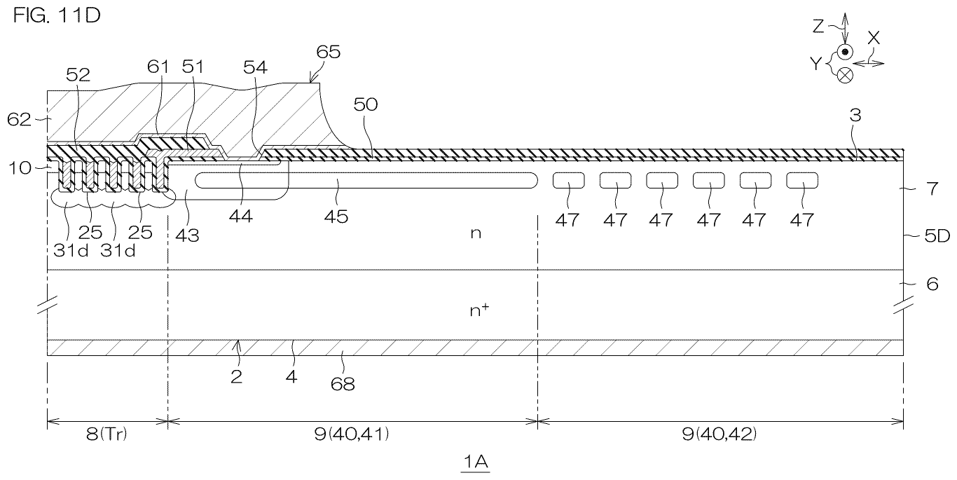

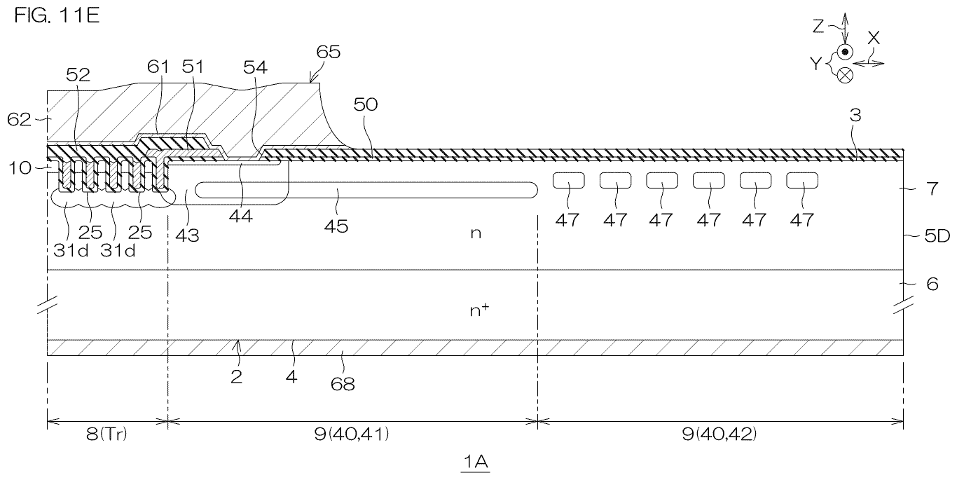

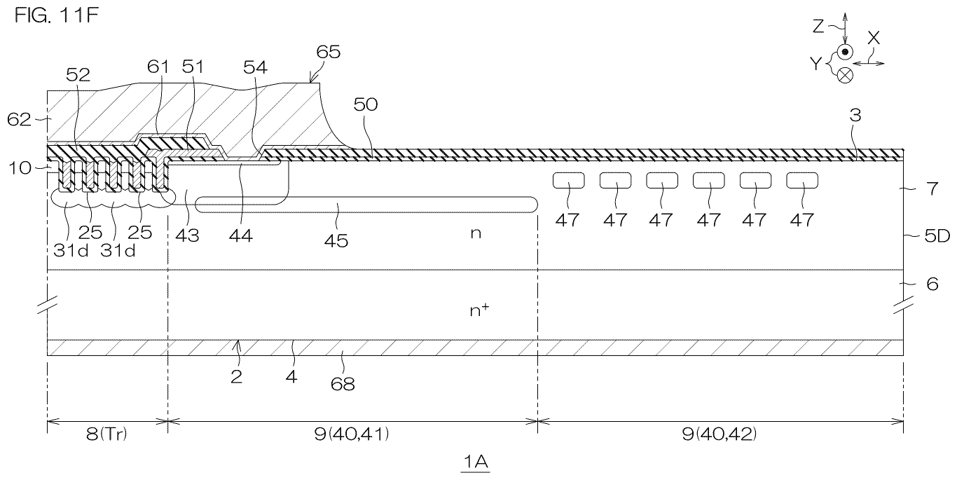

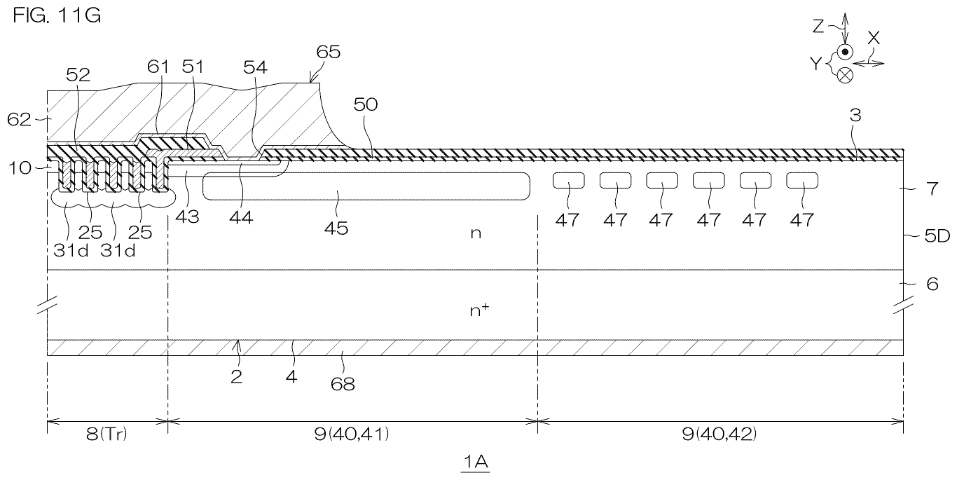

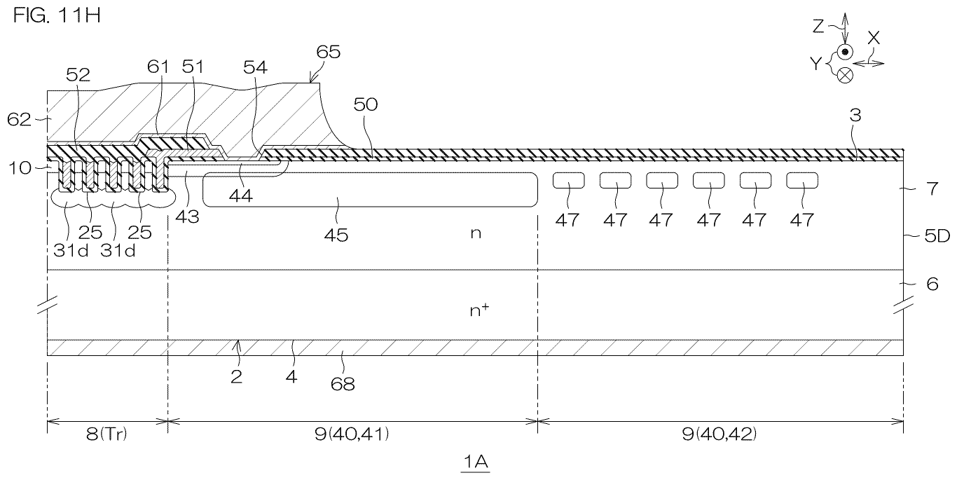

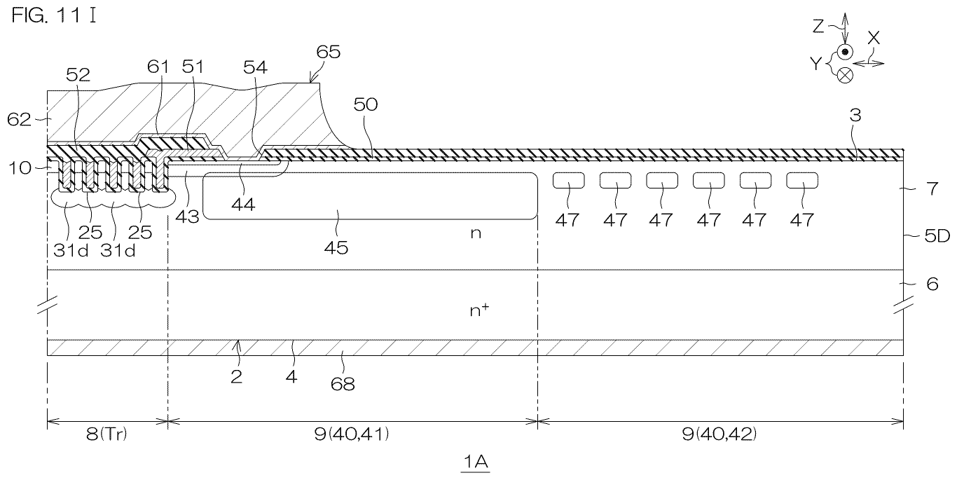

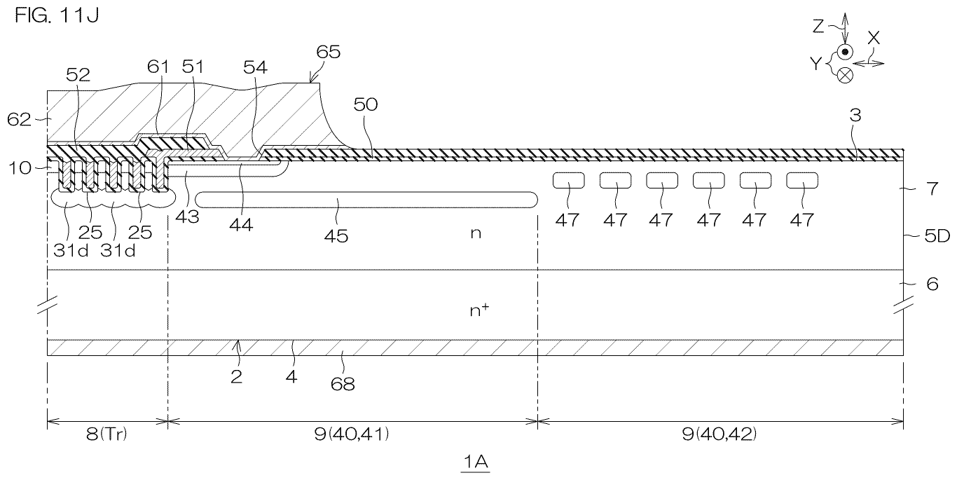

Hereinafter, with reference to FIGS. 11A to 11J, first to tenth modification examples of the first outer peripheral structures 41 according to the first to fifth configuration examples will be described. FIGS. 11A to 11J are cross-sectional views illustrating the first outer peripheral structure 41 according to first to tenth modification examples.

The semiconductor device 1A may include any one of the features of the first outer peripheral structures 41 according to the first to tenth modification examples with respect to the first outer peripheral structures 41 according to the first to fifth configuration examples. As a matter of course, the features of the first outer peripheral structures 41 according to the first to tenth modification examples can be combined as appropriate with each other.

Therefore, with respect to the first outer peripheral structures 41 according to the first to fifth configuration examples, the semiconductor device 1A may simultaneously include at least two of the features of the first outer peripheral structures 41 according to the first to tenth modification examples in the same or different regions.

At least one feature of the outer well region 43, the outer contact region 44, and the terminal region 45 according to the first to tenth modification examples is selected as appropriate according to the arrangements of the first to fifth configuration examples, and applied to the arrangements of the first to fifth configuration examples.

Referring to FIG. 11A (the first modification example), the first outer peripheral structure 41 may include the outer well region 43 having a bottom portion positioned at the bottom portion side of the second semiconductor region 7 with respect to the depth position of the bottom portion of at least one type of the well region 30 (at least one of the gate well region 30g, the source well region 30s, and the dummy well region 30d).

The bottom portion of the outer well region 43 may be connected to the well region 30 (dummy well region 30d), or may be formed at an interval from the well region 30.

The bottom portion of the terminal region 45 may be positioned at the first main surface 3 side with respect to a depth position of at least one of the bottom wall of the gate structure 15, the bottom wall of the source structure 20, and the bottom wall of the dummy structure 25.

Referring to FIG. 11B (the second modification example), the first outer peripheral structure 41 may include the outer well region 43 having the bottom portion positioned at the bottom portion side of the second semiconductor region 7 with respect to the depth position of the bottom portion of at least one type of the well region 30 (at least one of the gate well region 30g, the source well region 30s, and the dummy well region 30d).

The bottom portion of the outer well region 43 may be connected to the well region 30 (dummy well region 30d), or may be formed at an interval from the well region 30.

The bottom portion of the terminal region 45 may be positioned at the bottom portion side of the second semiconductor region 7 with respect to the depth position of at least one of the bottom wall of the gate structure 15, the bottom wall of the source structure 20, and the bottom wall of the dummy structure 25. The bottom portion of the terminal region 45 may be positioned at the first main surface 3 side with respect to the depth position of the bottom portion of at least one type of the well region 30 (at least one of the gate well region 30g, the source well region 30s, and the dummy well region 30d).

Referring to FIG. 11C (the third modification example), the first outer peripheral structure 41 may include the outer well region 43 having the bottom portion positioned at the bottom portion side of the second semiconductor region 7 with respect to the depth position of the bottom portion of at least one type of the well region 30 (at least one of the gate well region 30g, the source well region 30s, and the dummy well region 30d).

The bottom portion of the outer well region 43 may be connected to the well region 30 (dummy well region 30d), or may be formed at an interval from the well region 30.

The bottom portion of the terminal region 45 may be positioned at the bottom portion side of the second semiconductor region 7 with respect to a depth position of at least one of the bottom wall of the gate structure 15, the bottom wall of the source structure 20, and the bottom wall of the dummy structure 25. In this embodiment, the bottom portion of the terminal region 45 may be positioned at the bottom portion side of the second semiconductor region 7 with respect to the depth position of the bottom portion of at least one type of the well region 30.

The bottom portion of the terminal region 45 may be positioned at the first main surface 3 side with respect to a depth position of the bottom portion of the intermediate portion of the second semiconductor region 7. The bottom portion of the terminal region 45 may be positioned at the bottom portion side of the second semiconductor region 7 with respect to the depth position of the bottom portion of the intermediate portion of the second semiconductor region 7.

Referring to FIG. 11D (the fourth modification example), the first outer peripheral structure 41 may include the outer well region 43 having a bottom portion positioned at the first main surface 3 side with respect to the depth position of the bottom portion of at least one type of the well region 30 (at least one of the gate well region 30g, the source well region 30s, and the dummy well region 30d).

The bottom portion of the outer well region 43 may be connected to the well region 30 (dummy well region 30d), or may be formed at an interval from the well region 30. The bottom portion of the outer well region 43 may be positioned at the bottom portion side of the second semiconductor region 7 with respect to the depth position of at least one of the bottom wall of the gate structure 15, the bottom wall of the source structure 20, and the bottom wall of the dummy structure 25.

The bottom portion of the terminal region 45 may be positioned at the first main surface 3 side with respect to a depth position of at least one of the bottom wall of the gate structure 15, the bottom wall of the source structure 20, and the bottom wall of the dummy structure 25.

Referring to FIG. 11E (the fifth modification example), the first outer peripheral structure 41 may include the outer well region 43 having the bottom portion positioned at the first main surface 3 side with respect to the depth position of the bottom portion of at least one type of the well region 30 (at least one of the gate well region 30g, the source well region 30s, and the dummy well region 30d).

The bottom portion of the outer well region 43 may be connected to the well region 30 (dummy well region 30d), or may be formed at an interval from the well region 30. The bottom portion of the outer well region 43 may be positioned at the bottom portion side of the second semiconductor region 7 with respect to the depth position of at least one of the bottom wall of the gate structure 15, the bottom wall of the source structure 20, and the bottom wall of the dummy structure 25.

The bottom portion of the terminal region 45 may be positioned at the first main surface 3 side with respect to the depth position of the bottom portion of at least one type of the well region 30 (at least one of the gate well region 30g, the source well region 30s, and the dummy well region 30d).

The bottom portion of the terminal region 45 may be positioned at the bottom portion side of the second semiconductor region 7 with respect to a depth position of at least one of the bottom wall of the gate structure 15, the bottom wall of the source structure 20, and the bottom wall of the dummy structure 25.

Referring to FIG. 11F (the sixth modification example), the first outer peripheral structure 41 may include the outer well region 43 having the bottom portion positioned at the first main surface 3 side with respect to the depth position of the bottom portion of at least one type of the well region 30 (at least one of the gate well region 30g, the source well region 30s, and the dummy well region 30d).

The bottom portion of the outer well region 43 may be connected to the well region 30 (dummy well region 30d), or may be formed at an interval from the well region 30. The bottom portion of the outer well region 43 may be positioned at the bottom portion side of the second semiconductor region 7 with respect to the depth position of at least one of the bottom wall of the gate structure 15, the bottom wall of the source structure 20, and the bottom wall of the dummy structure 25.

The bottom portion of the terminal region 45 may be positioned at the bottom portion side of the second semiconductor region 7 with respect to the depth position of the bottom portion of at least one type of the well region 30 (at least one of the gate well region 30g, the source well region 30s, and the dummy well region 30d).

The bottom portion of the terminal region 45 may be positioned at the first main surface 3 side with respect to the depth position of the bottom portion of the intermediate portion of the second semiconductor region 7. The bottom portion of the terminal region 45 may be positioned at the bottom portion side of the second semiconductor region 7 with respect to the depth position of the bottom portion of the intermediate portion of the second semiconductor region 7.

Referring to FIG. 11G (the seventh modification example), the first outer peripheral structure 41 may include the outer well region 43 having the bottom portion positioned at the first main surface 3 side with respect to the depth position of the bottom wall of the dummy structure 25. The bottom portion of the outer well region 43 may be connected to the well region 30 (dummy well region 30d), or may be formed at an interval from the well region 30.

The upper end portion of the terminal region 45 may be connected to the outer well region 43. The bottom portion of the terminal region 45 may be positioned at the bottom portion side of the second semiconductor region 7 with respect to a depth position of at least one of the bottom wall of the gate structure 15, the bottom wall of the source structure 20, and the bottom wall of the dummy structure 25.

The bottom portion of the terminal region 45 may be positioned at the first main surface 3 side with respect to the depth position of the bottom portion of at least one type of the well region 30 (at least one of the gate well region 30g, the source well region 30s, and the dummy well region 30d).

Referring to FIG. 11H (the eighth modification example), the first outer peripheral structure 41 may include the outer well region 43 having the bottom portion positioned at the first main surface 3 side with respect to the depth position of the bottom wall of the dummy structure 25. The bottom portion of the outer well region 43 may be connected to the well region 30 (dummy well region 30d), or may be formed at an interval from the well region 30.

The upper end portion of the terminal region 45 may be connected to the outer well region 43. The bottom portion of the terminal region 45 may be positioned at a depth substantially equal to the bottom portion of at least one type of the well region 30 (at least one of the gate well region 30g, the source well region 30s, and the dummy well region 30d).

Referring to FIG. 11I (the ninth modification example), the first outer peripheral structure 41 may include the outer well region 43 having the bottom portion positioned at the first main surface 3 side with respect to the depth position of the bottom wall of the dummy structure 25. The bottom portion of the outer well region 43 may be connected to the well region 30 (dummy well region 30d), or may be formed at an interval from the well region 30.

The bottom portion of the terminal region 45 may be positioned at the bottom portion side of the second semiconductor region 7 with respect to the depth position of the bottom portion of the at least one type of well region 30 (at least one of the gate well region 30g, the source well region 30s, and the dummy well region 30d).

The bottom portion of the terminal region 45 may be positioned at the first main surface 3 side with respect to the depth position of the bottom portion of the intermediate portion of the second semiconductor region 7. The bottom portion of the terminal region 45 may be positioned at the bottom portion side of the second semiconductor region 7 with respect to the depth position of the bottom portion of the intermediate portion of the second semiconductor region 7.

Referring to FIG. 11J (the tenth modification example), the first outer peripheral structure 41 may include the terminal region 45 formed at an interval from the bottom portion of the outer well region 43 toward the bottom portion side of the second semiconductor region 7.

The bottom portion of the terminal region 45 may be positioned at the first main surface 3 side with respect to a depth position of at least one of the bottom wall of the gate structure 15, the bottom wall of the source structure 20, and the bottom wall of the dummy structure 25. The bottom portion of the terminal region 45 may be positioned at the bottom portion side of the second semiconductor region 7 with respect to a depth position of at least one of the bottom wall of the gate structure 15, the bottom wall of the source structure 20, and the bottom wall of the dummy structure 25.

The bottom portion of the terminal region 45 may be positioned at the first main surface 3 side with respect to the depth position of the bottom portion of at least one type of the well region 30 (at least one of the gate well region 30g, the source well region 30s, and the dummy well region 30d). The bottom portion of the terminal region 45 may be positioned at the bottom portion side of the second semiconductor region 7 with respect to the depth position of the bottom portion of at least one type of the well region 30.

The bottom portion of the terminal region 45 may be positioned at a depth substantially equal to the bottom portion of at least one type of the well region 30. The bottom portion of the terminal region 45 may be positioned at the first main surface 3 side with respect to the depth position of the intermediate portion of the second semiconductor region 7. The bottom portion of the terminal region 45 may be positioned at the bottom portion side of the second semiconductor region 7 with respect to the depth position of the intermediate portion of the second semiconductor region 7.

The upper end portion of the terminal region 45 may be positioned at the first main surface 3 side with respect to the depth position of at least one of the bottom wall of the gate structure 15, the bottom wall of the source structure 20, and the bottom wall of the dummy structure 25. The upper end portion of the terminal region 45 may be positioned at the bottom portion side of the second semiconductor region 7 with respect to the depth position of at least one of the bottom wall of the gate structure 15, the bottom wall of the source structure 20, and the bottom wall of the dummy structure 25.

The upper end portion of the terminal region 45 may be positioned at the first main surface 3 side with respect to the depth position of the bottom portion of at least one type of the well region 30 (at least one of the gate well region 30g, the source well region 30s, and the dummy well region 30d). The upper end portion of the terminal region 45 may be positioned at the bottom portion side of the second semiconductor region 7 with respect to the depth position of the bottom portion of at least one type of the well region 30.

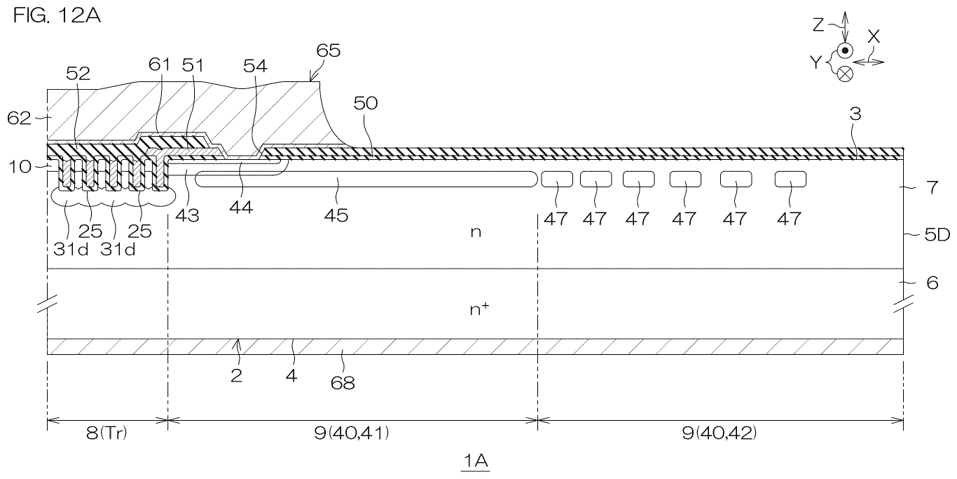

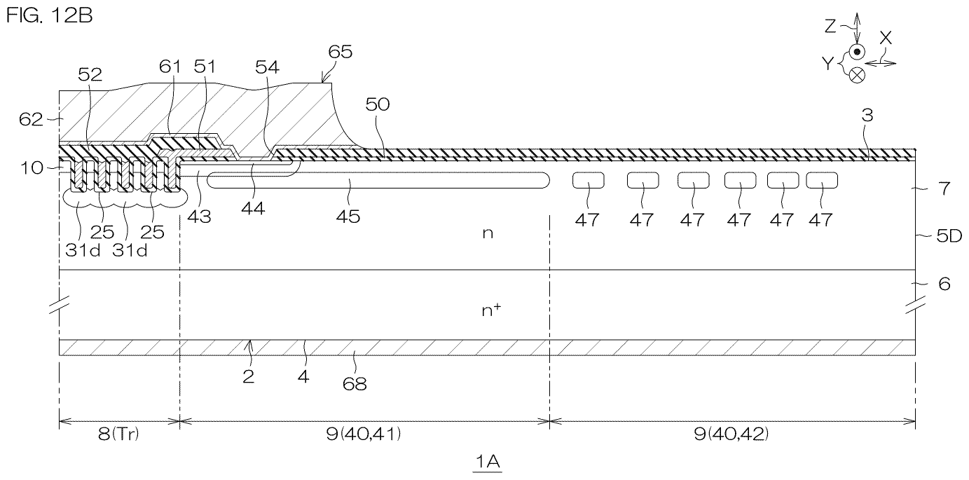

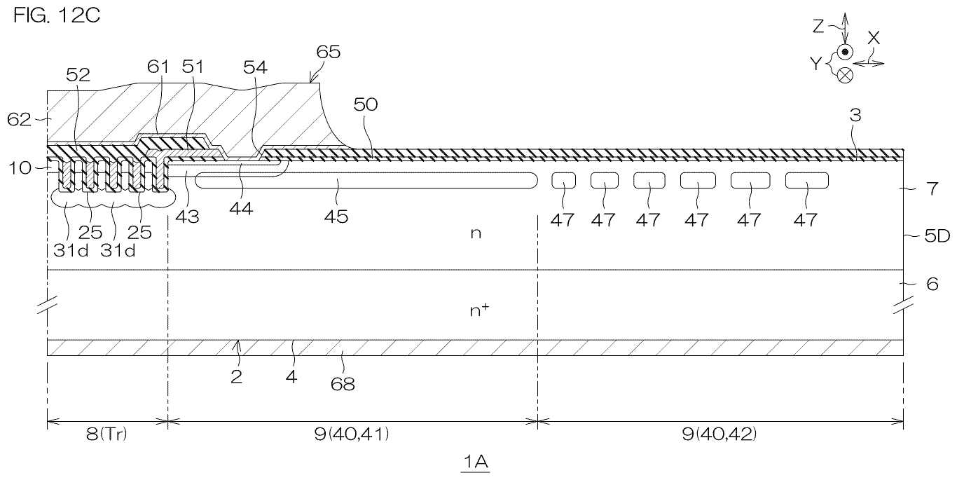

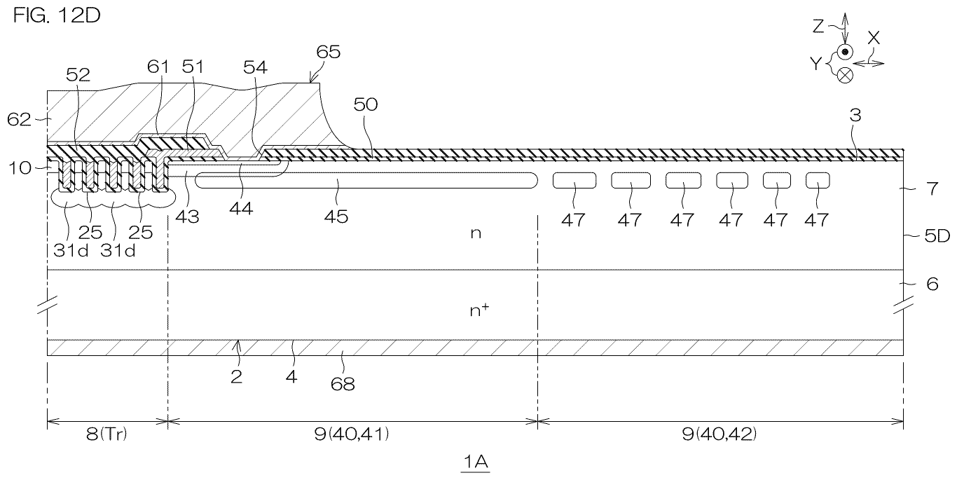

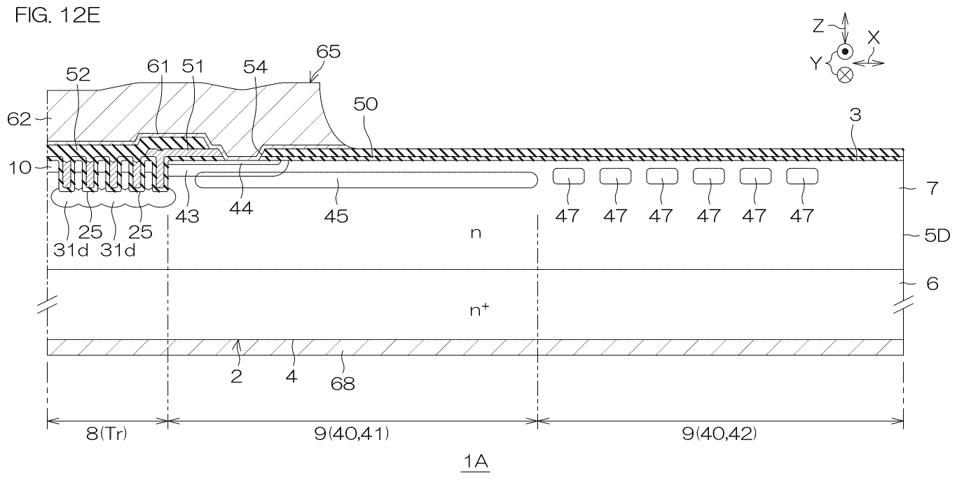

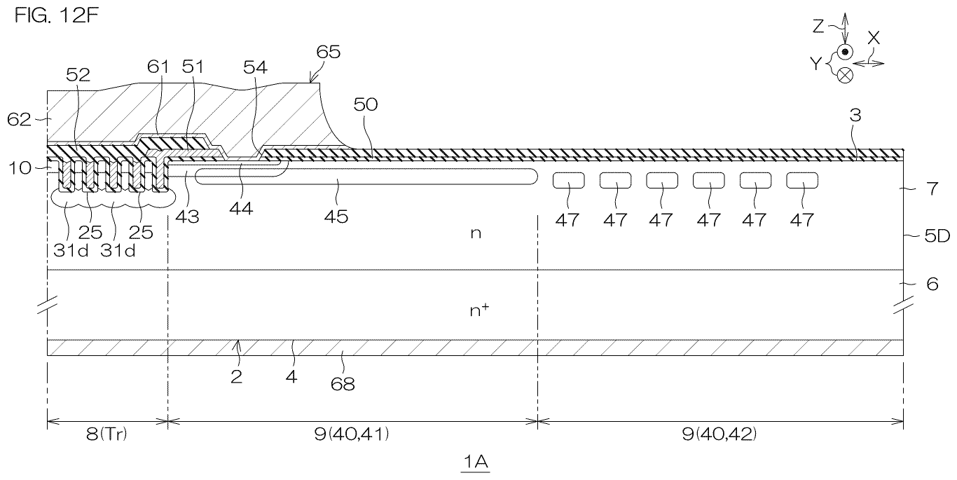

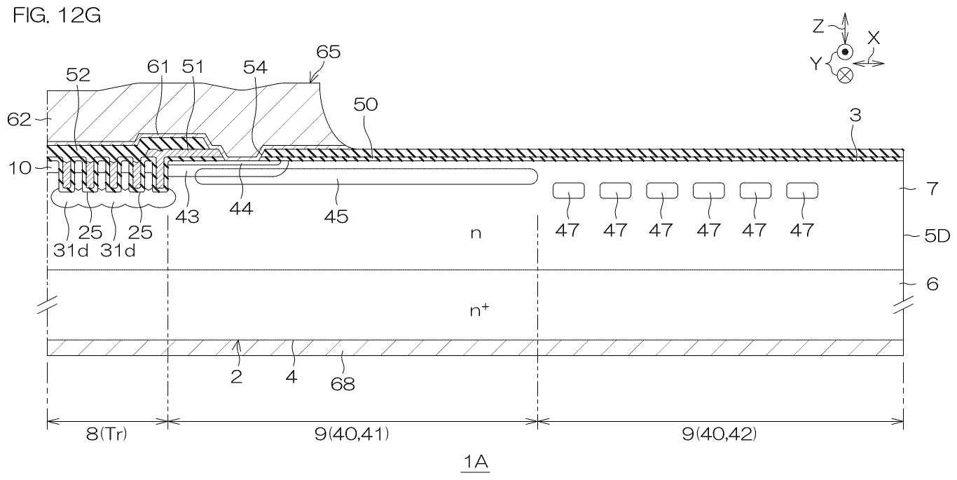

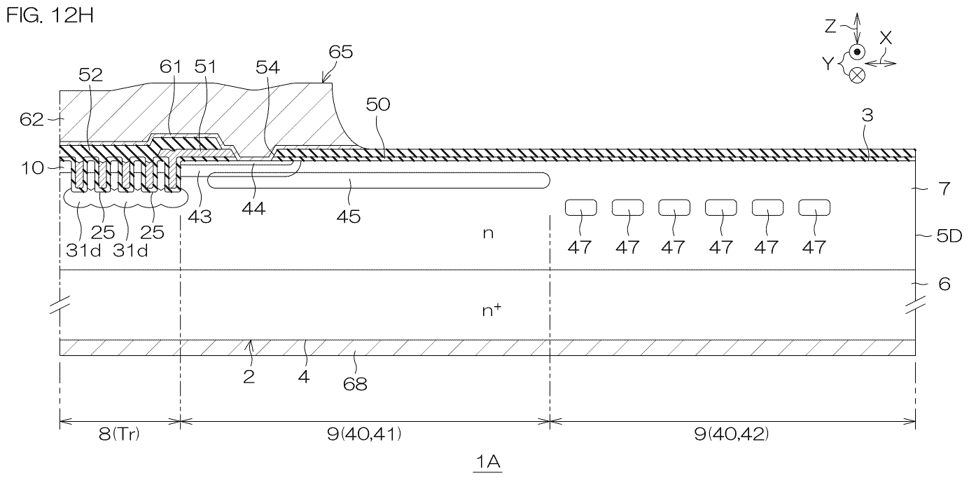

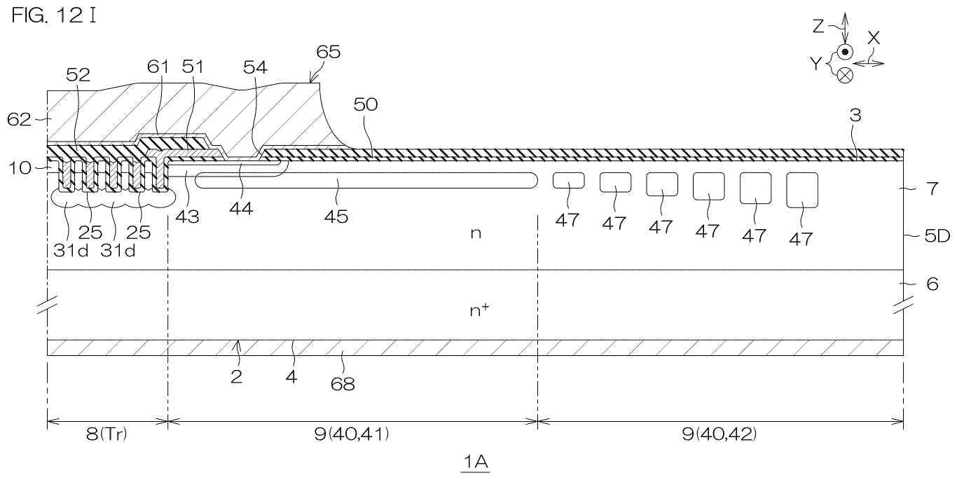

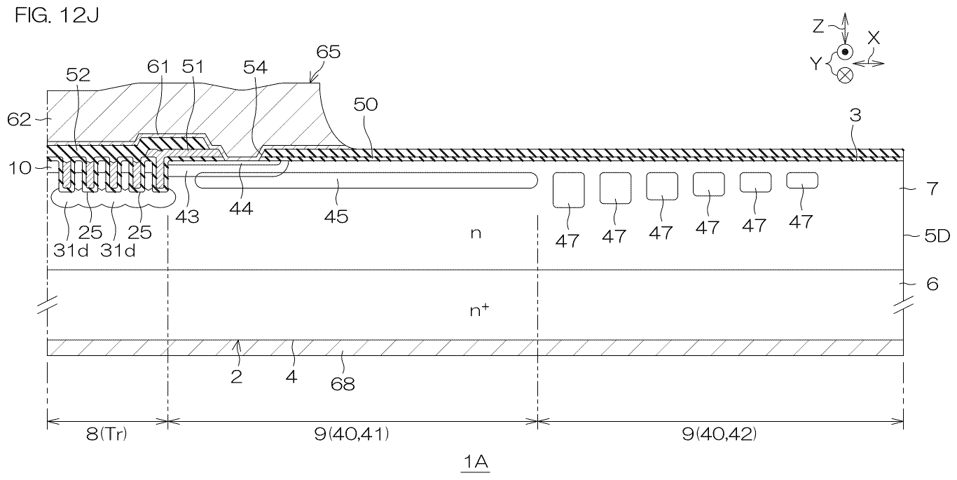

Hereinafter, with reference to FIGS. 12A to 12J, first to tenth modification examples of the second outer peripheral structures 42 according to the first to fifth configuration examples will be described. FIGS. 12A to 12J are cross-sectional views illustrating the second outer peripheral structure 42 according to the first to tenth modification examples.

The semiconductor device 1A may include any one of the features of the second outer peripheral structures 42 according to the first to tenth modification examples with respect to the second outer peripheral structures 42 according to the first to fifth configuration examples. As a matter of course, the features of the second outer peripheral structures 42 according to the first to tenth modification examples can be combined as appropriate with each other.

Therefore, with respect to the second outer peripheral structures 42 according to the first to fifth configuration examples, the semiconductor device 1A may simultaneously include at least two of the features of the second outer peripheral structures 42 according to the first to tenth modification examples in the same or different regions. At least one feature of the field regions 47 according to the first to tenth modification examples is selected as appropriate according to the arrangements of the first to fifth configuration examples, and applied to the arrangements of the first to fifth configuration examples.

One or a plurality of the features of the second outer peripheral structures 42 according to the first to tenth modification examples are applied as appropriate to the arrangement of any one of the first to fifth configuration examples together with one or a plurality of the features of the first outer peripheral structures 41 according to the first to tenth modification examples.

Referring to FIG. 12A (the first modification example), the second outer peripheral structure 42 may include the plurality of field regions 47 aligned at mutually different intervals. The intervals between the plurality of field regions 47 may sequentially increase toward the peripheral edge side of the first main surface 3.

That is, intervals between the plurality of field regions 47 positioned at the peripheral edge side of the first main surface 3 may be greater than the intervals between the plurality of field regions 47 positioned at the inner edge portion side of the first main surface 3. As a matter of course, the intervals between the plurality of field regions 47 may increase toward the peripheral edge side of the first main surface 3 in units of two or more groups, in which each group includes the two or more field regions 47.

Referring to FIG. 12B (the second modification example), the second outer peripheral structure 42 may include the plurality of field regions 47 aligned at mutually different intervals. The intervals between the plurality of field regions 47 may sequentially decrease toward the peripheral edge side of the first main surface 3.

That is, the intervals between the plurality of field regions 47 positioned at the peripheral edge side of the first main surface 3 may be smaller than the intervals between the plurality of field regions 47 positioned at the inner edge portion side of the first main surface 3. As a matter of course, the intervals between the plurality of field regions 47 may decrease toward the peripheral edge side of the first main surface 3 in units of two or more groups, in which each group includes the two or more field regions 47.

Referring to FIG. 12C (the third modification example), the second outer peripheral structure 42 may include the plurality of field regions 47 aligned at mutually different widths. The widths of the plurality of field regions 47 may sequentially increase toward the peripheral edge side of the first main surface 3.

That is, the widths of the plurality of field regions 47 positioned at the peripheral edge side of the first main surface 3 may be greater than the widths of the plurality of field regions 47 positioned at the inner edge portion side of the first main surface 3. As a matter of course, the widths of the plurality of field regions 47 may increase toward the peripheral edge side of the first main surface 3 in units of two or more groups, in which each group includes the two or more field regions 47.

Referring to FIG. 12D (the fourth modification example), the second outer peripheral structure 42 may include the plurality of field regions 47 aligned at mutually different widths. The widths of the plurality of field regions 47 may sequentially decrease toward the peripheral edge side of the first main surface 3.

That is, the widths of the plurality of field regions 47 positioned at the peripheral edge side of the first main surface 3 may be smaller than the widths of the plurality of field regions 47 positioned at the inner edge portion side of the first main surface 3. As a matter of course, the widths of the plurality of field regions 47 may decrease toward the peripheral edge side of the first main surface 3 in units of two or more groups, in which each group includes the two or more field regions 47.

Referring to FIG. 12E (the fifth modification example), the second outer peripheral structure 42 may include one or a plurality of (in this embodiment, a plurality of) the field regions 47 formed shallower than the terminal region 45. The bottom portions of the plurality of field regions 47 may be positioned at the first main surface 3 side with respect to a depth position of the bottom portion of the terminal region 45.

The bottom portions of the plurality of field regions 47 may be positioned at the first main surface 3 side with respect to the depth position of at least one of the bottom wall of the gate structure 15, the bottom wall of the source structure 20, and the bottom wall of the dummy structure 25.

The upper end portions of the plurality of field regions 47 may be positioned at the first main surface 3 side with respect to a depth position of the upper end portion of the terminal region 45. The upper end portions of the plurality of field regions 47 may be positioned at the bottom portion side of the second semiconductor region 7 with respect to the depth position of the upper end portion of the terminal region 45.

Referring to FIG. 12F (the sixth modification example), the second outer peripheral structure 42 may include one or a plurality of (in this embodiment, a plurality of) the field regions 47 formed deeper than the terminal region 45. The bottom portions of the plurality of field regions 47 may be positioned at the bottom portion side of the second semiconductor region 7 with respect to the depth position of the bottom portion of the terminal region 45.

The bottom portions of the plurality of field regions 47 may be positioned at the bottom portion side of the second semiconductor region 7 with respect to the depth position of at least one of the bottom wall of the gate structure 15, the bottom wall of the source structure 20, and the bottom wall of the dummy structure 25.

The upper end portions of the plurality of field regions 47 may be positioned at the first main surface 3 side with respect to the depth position of the upper end portion of the terminal region 45. The upper end portions of the plurality of field regions 47 may be positioned at the bottom portion side of the second semiconductor region 7 with respect to the depth position of the upper end portion of the terminal region 45. The upper end portions of the plurality of field regions 47 may be positioned at the bottom portion side of the second semiconductor region 7 with respect to the depth position of the bottom portion of the terminal region 45.

Referring to FIG. 12G (the seventh modification example), the second outer peripheral structure 42 may include one or a plurality of (in this embodiment, a plurality of) the field regions 47 formed deeper than the terminal region 45. The bottom portions of the plurality of field regions 47 may be positioned at the bottom portion side of the second semiconductor region 7 with respect to a depth position of at least one of the bottom wall of the gate structure 15, the bottom wall of the source structure 20, and the bottom wall of the dummy structure 25.

The bottom portions of the plurality of field regions 47 may be positioned at the first main surface 3 side with respect to the depth position of the bottom portion of at least one type of the well region 30 (at least one of the gate well region 30g, the source well region 30s, and the dummy well region 30d).

The bottom portions of the plurality of field regions 47 may be positioned at the bottom portion side of the second semiconductor region 7 with respect to the depth position of the bottom portion of at least one type of the well region 30. The bottom portions of the plurality of field regions 47 may be positioned at the depth substantially equal to the bottom portion of at least one type of the well region 30.

The upper end portions of the plurality of field regions 47 may be positioned at the first main surface 3 side with respect to the depth position of the upper end portion of the terminal region 45. The upper end portions of the plurality of field regions 47 may be positioned at the bottom portion side of the second semiconductor region 7 with respect to the depth position of the upper end portion of the terminal region 45. The upper end portions of the plurality of field regions 47 may be positioned at the bottom portion side of the second semiconductor region 7 with respect to the depth position of the bottom portion of the terminal region 45.

The upper end portions of the plurality of field regions 47 may be positioned at the bottom portion side of the second semiconductor region 7 with respect to the depth position of at least one of the bottom wall of the gate structure 15, the bottom wall of the source structure 20, and the bottom wall of the dummy structure 25. The upper end portions of the plurality of field regions 47 may be positioned at the first main surface 3 side with respect to the depth position of at least one of the bottom wall of the gate structure 15, the bottom wall of the source structure 20, and the bottom wall of the dummy structure 25.

Referring to FIG. 12H (the eighth modification example), the second outer peripheral structure 42 may include one or a plurality of (in this embodiment, a plurality of) the field regions 47 formed deeper than the terminal region 45. The bottom portions of the plurality of field regions 47 may be positioned at the bottom portion side of the second semiconductor region 7 with respect to the depth position of the bottom portion of at least one type of the well region 30 (at least one of the gate well region 30g, the source well region 30s, and the dummy well region 30d).

The bottom portions of the plurality of field regions 47 may be positioned at the first main surface 3 side with respect to the depth position of the intermediate portion of the second semiconductor region 7. The bottom portions of the plurality of field regions 47 may be positioned at the bottom portion side of the second semiconductor region 7 with respect to the depth position of the intermediate portion of the second semiconductor region 7.

The upper end portions of the plurality of field regions 47 may be positioned at the first main surface 3 side with respect to the depth position of the upper end portion of the terminal region 45. The upper end portions of the plurality of field regions 47 may be positioned at the bottom portion side of the second semiconductor region 7 with respect to the depth position of the upper end portion of the terminal region 45. The upper end portions of the plurality of field regions 47 may be positioned at the bottom portion side of the second semiconductor region 7 with respect to the depth position of the bottom portion of the terminal region 45.

The upper end portions of the plurality of field regions 47 may be positioned at the first main surface 3 side with respect to a depth position of at least one of the bottom wall of the gate structure 15, the bottom wall of the source structure 20, and the bottom wall of the dummy structure 25. The upper end portions of the plurality of field regions 47 may be positioned at the bottom portion side of the second semiconductor region 7 with respect to a depth position of at least one of the bottom wall of the gate structure 15, the bottom wall of the source structure 20, and the bottom wall of the dummy structure 25.

The upper end portions of the plurality of field regions 47 may be positioned at the first main surface 3 side with respect to the depth position of the bottom portion of at least one type of the well region 30. The upper end portions of the plurality of field regions 47 may be positioned at the bottom portion side of the second semiconductor region 7 with respect to the depth position of the bottom portion of at least one type of the well region 30.

Referring to FIG. 12I (the ninth modification example), the second outer peripheral structure 42 may include the plurality of field regions 47 each having bottom portions positioned at mutually different depths. Depth positions of the bottom portions of the plurality of field regions 47 may sequentially increase toward the peripheral edge side of the first main surface 3.

That is, the depth position of the bottom portion of the one or plurality of field regions 47 positioned at the peripheral edge side of the first main surface 3 may be greater than the depth position of the bottom portion of the one or plurality of field regions 47 positioned at the inner side of the first main surface 3. As a matter of course, the depth positions of the bottom portions of the plurality of field regions 47 may increase toward the peripheral edge side of the first main surface 3 in units of two or more groups, in which each group includes the two or more field regions 47.

The plurality of field regions 47 may each have mutually different depths (thicknesses). The depths of the plurality of field regions 47 may sequentially increase toward the peripheral edge side of the first main surface 3.

That is, the depth(s) of the one or plurality of field regions 47 positioned at the peripheral edge side of the first main surface 3 may be greater than the depth(s) of the one or plurality of field regions 47 positioned at the inner side of the first main surface 3. The depths of the plurality of field regions 47 may increase toward the peripheral edge side of the first main surface 3 in units of two or more groups, in which each group includes the two or more field regions 47.

The plurality of field regions 47 may have substantially equal depths (thicknesses). That is, the interval between the first main surface 3 and the upper end portions of the plurality of field regions 47 may increase toward the peripheral edge side of the first main surface 3. As in other modification examples, the one or plurality of field regions 47 may be formed at intervals from the first main surface 3 or may be exposed from the first main surface 3.

Referring to FIG. 12J (the tenth modification example), the second outer peripheral structure 42 may include the plurality of field regions 47 each having bottom portions positioned at mutually different depths. The depth positions of the bottom portions of the plurality of field regions 47 may sequentially decrease toward the peripheral edge side of the first main surface 3.

That is, the depth position of the bottom portion of the one or plurality of field regions 47 positioned at the peripheral edge side of the first main surface 3 may be smaller than the depth position of the bottom portion of the one or plurality of field regions 47 positioned at the inner side of the first main surface 3. As a matter of course, the depth positions of the bottom portions of the plurality of field regions 47 may decrease toward the peripheral edge side of the first main surface 3 in units of two or more groups, in which each group includes the two or more field regions 47.

The plurality of field regions 47 may each have mutually different depths (thicknesses). The depths of the plurality of field regions 47 may sequentially decrease toward the peripheral edge side of the first main surface 3.

That is, the depth(s) of the one or plurality of field regions 47 positioned at the peripheral edge side of the first main surface 3 may be smaller than the depth(s) of the one or plurality of field regions 47 positioned at the inner side of the first main surface 3. The depths of the plurality of field regions 47 may decrease toward the peripheral edge side of the first main surface 3 in units of two or more groups, in which each group includes the two or more field regions 47.

The plurality of field regions 47 may have substantially equal depths. That is, the interval between the first main surface 3 and the upper end portions of the plurality of field regions 47 may decrease toward the peripheral edge side of the first main surface 3. As in other modification examples, the one or plurality of field regions 47 may be formed at intervals from the first main surface 3 or may be exposed from the first main surface 3.

As described above, the semiconductor device 1A may include the chip 2, the second semiconductor region 7 (semiconductor region) of the n-type (the first conductivity type), and the terminal region 45 of the p-type (the second conductivity type). The chip 2 may have the first main surface 3. The second semiconductor region 7 may be formed in the surface layer portion of the first main surface 3. The terminal region 45 may be formed in the surface layer portion of the second semiconductor region 7 at an interval in the thickness direction of the chip 2 from the first main surface 3 in the peripheral edge portion of the first main surface 3.

According to this arrangement, the semiconductor device 1A having a novel layout can be provided. For example, according to this semiconductor device 1A, the expansion range of the depletion layer can be adjusted by the terminal region 45 separated from the first main surface 3. This layout is effective in improving the withstand voltage of the semiconductor device 1A.

The chip 2 may contain SiC. According to this arrangement, the semiconductor device 1A as an SiC semiconductor device having a novel layout can be provided. According to the SiC semiconductor device, the withstand voltage is further improved by the physical properties of SiC. In particular, in the case of the SiC semiconductor device, since the SiC semiconductor device is used under a relatively high voltage environment, the withstand voltage improvement effect by the terminal region 45 is effective.

The terminal region 45 may form a pn junction portion with the second semiconductor region 7. According to this arrangement, the depletion layer with the terminal region 45 as a starting point can be appropriately expanded. The terminal region 45 may face the first main surface 3 with a portion of the second semiconductor region 7 interposed therebetween.

According to this arrangement, the terminal region 45 may have an upper end portion that forms the pn junction portion with the second semiconductor region 7. Therefore, the depletion layer with the terminal region 45 as a starting point can be expanded also to a portion of the second semiconductor region 7 positioned between the first main surface 3 and the terminal region 45.

The terminal region 45 may have a thickness (depth) greater than a distance between the first main surface 3 and the terminal region 45. According to this arrangement, the expansion range of the depletion layer can be adjusted by the terminal region 45 having a thickness greater than the distance between the first main surface 3 and the terminal region 45.

The terminal region 45 may be formed at an interval toward the first main surface 3 side from the bottom portion of the second semiconductor region 7. According to this arrangement, the expansion range of the depletion layer can be adjusted by the terminal region 45 separated from the bottom portion of the second semiconductor region 7.

The terminal region 45 may have a thickness (depth) less than the distance between the bottom portion of the second semiconductor region 7 and the terminal region 45. According to this arrangement, the expansion range of the depletion layer can be adjusted by the terminal region 45 having the thickness less than the distance between the bottom portion of the second semiconductor region 7 and the terminal region 45.

The semiconductor device 1A may include the p-type outer well region 43. The outer well region 43 may be formed in the surface layer portion of the first main surface 3 in the peripheral edge portion of the first main surface 3. In this case, the terminal region 45 may be formed in a region between the peripheral edge of the first main surface 3 and the outer well region 43.

According to this arrangement, the depletion layer expands with the outer well region 43 as a starting point on the inner portion side of the first main surface 3, and at the same time, the depletion layer expands, on the peripheral edge portion side of the first main surface 3, with the terminal region 45 as a starting point. The withstand voltage of the semiconductor device 1A can thereby be improved.

The terminal region 45 may be connected to the outer well region 43. According to this arrangement, the depletion layer expanded with the terminal region 45 as the starting point can be integrated with a depletion layer expanded with the outer well region 43 as a starting point. The discontinuity of the depletion layer in the chip 2 is thereby reduced, and the withstand voltage of the semiconductor device 1A can be improved.

The terminal region 45 may have a bottom portion positioned below with respect to the depth position of the bottom portion of the outer well region 43. According to this arrangement, the expansion range of the depletion layer can be adjusted by the terminal region 45 having the bottom portion positioned below the bottom portion of the outer well region 43. This layout is effective in improving the withstand voltage of the semiconductor device 1A.

The semiconductor device 1A may include the p-type outer contact region 44. The outer contact region 44 is formed in the surface layer portion of the outer well region 43, and may have a p-type impurity concentration higher than the p-type impurity concentration of the outer well region 43. According to this arrangement, the electrical response speed of the outer well region 43 is improved by the outer contact region 44.

The terminal region 45 may have a p-type impurity concentration less than the p-type impurity concentration of the outer contact region 44. According to this arrangement, the expansion range of the depletion layer can be adjusted by the terminal region 45 having a p-type impurity concentration less than the p-type impurity concentration of the outer contact region 44. This layout is effective in improving the withstand voltage of the semiconductor device 1A.

The semiconductor device 1A may include the terminal wiring 65 (the terminal electrode) arranged on the first main surface 3 and electrically connected to the terminal region 45. According to this arrangement, a predetermined terminal potential is to be applied to the terminal region 45 via the terminal wiring 65. Electrical response characteristics of the terminal region 45 can thereby be improved by the terminal wiring 65. The terminal potential may be the reference potential serving as a reference of circuit operation. The reference potential may be the ground potential. The terminal potential may be the source potential.

In this case, the semiconductor device 1A may include the p-type outer well region 43. The outer well region 43 may be formed in the surface layer portion of the first main surface 3 in the peripheral edge portion of the first main surface 3. In this case, the terminal region 45 may be formed in a region between the peripheral edge of the first main surface 3 and the outer well region 43 so as to be electrically connected to the outer well region 43. The terminal wiring 65 may be electrically connected to the outer well region 43.

According to this arrangement, the depletion layer expands with the outer well region 43 as a starting point on the inner portion side of the first main surface 3, and at the same time, the depletion layer expands, on the peripheral edge portion side of the first main surface 3, with the terminal region 45 as a starting point. Also, the electrical response speed of the outer well region 43 and the electrical response speed of the terminal region 45 can be improved by the terminal wiring 65.

The semiconductor device 1A may include the p-type outer contact region 44. The outer contact region 44 is formed in the surface layer portion of the outer well region 43, and may have a p-type impurity concentration higher than the p-type impurity concentration of the outer well region 43. In this case, the terminal wiring 65 may be electrically connected to the outer well region 43 via the outer contact region 44.

According to this arrangement, the electrical response speed of the outer well region 43 can be improved by the outer contact region 44 and the terminal wiring 65. Also, an ohmic property of the terminal wiring 65 with respect to the outer well region 43 can be improved by the outer contact region 44.

The semiconductor device 1A may include the interlayer film 52 (the insulating film) that covers the first main surface 3. The semiconductor device 1A may include the outer opening 54 (the contact opening) formed in the interlayer film 52 so as to expose the outer contact region 44.

In this case, the terminal wiring 65 may be arranged on the interlayer film 52 and electrically connected to the outer contact region 44 via the outer opening 54. According to this arrangement, the terminal wiring 65 can be appropriately electrically connected to the outer contact region 44.

The semiconductor device 1A may include the active region 8 provided in an inner portion of the first main surface 3 and the outer peripheral region 9 provided in the peripheral edge portion of the first main surface 3. In this case, the terminal region 45 may be formed in the outer peripheral region 9. According to this arrangement, the withstand voltage of the semiconductor device 1A can be improved by using the terminal region 45 formed in the outer peripheral region 9 outside the active region 8.

The terminal region 45 may extend in a band shape along the active region 8 in plan view. According to this arrangement, the withstand voltage of the semiconductor device 1A can be improved by the terminal region 45 extending in a band shape along the active region 8. The terminal region 45 may surround the active region 8 in plan view. According to this arrangement, the withstand voltage of the semiconductor device 1A can be improved by the terminal region 45 surrounding the active region 8.

The semiconductor device 1A may include the transistor structure Tr formed in the active region 8. According to this arrangement, the withstand voltage of the semiconductor device 1A including the transistor structure Tr can be improved by the terminal region 45 formed in the outer peripheral region 9.

The semiconductor device 1A may include the p-type field region 47. The field region 47 may be formed in the surface layer portion of the second semiconductor region 7 in the region between the peripheral edge of the first main surface 3 and the terminal region 45.

According to this arrangement, the depletion layer expands with the terminal region 45 as a starting point on the inner portion side of the first main surface 3, and at the same time, the depletion layer expands with the field region 47 as a starting point on the peripheral edge portion side of the first main surface 3. The withstand voltage of the semiconductor device 1A can thereby be improved.

From another point of view, the semiconductor device 1A may include the chip 2, the second semiconductor region 7 (the semiconductor region) of the n-type (the first conductivity type), and the field region 47 of the p-type (the second conductivity type). The chip 2 may have the first main surface 3. The second semiconductor region 7 may be formed in the surface layer portion of the first main surface 3. The field region 47 may be formed in the surface layer portion of the second semiconductor region 7 at an interval in the thickness direction of the chip 2 from the first main surface 3 in the peripheral edge portion of the first main surface 3.

According to this arrangement, the semiconductor device 1A having a novel layout can be provided. For example, according to this semiconductor device 1A, the expansion range of the depletion layer can be adjusted by the field region 47 separated from the first main surface 3. This layout is effective in improving the withstand voltage of the semiconductor device 1A.

The chip 2 may contain SiC. According to this arrangement, the semiconductor device 1A as an SiC semiconductor device having a novel layout can be provided. According to the SiC semiconductor device, the withstand voltage is further improved by the physical properties of SiC. In particular, in the case of the SiC semiconductor device, since the SiC semiconductor device is used under a relatively high voltage environment, the withstand voltage improvement effect using the field region 47 is effective.

The field region 47 may form a pn junction portion with the second semiconductor region 7. According to this arrangement, the depletion layer with the field region 47 as a starting point can be appropriately expanded. The field region 47 may face the first main surface 3 with a portion of the second semiconductor region 7 interposed therebetween. According to this arrangement, the depletion layer with the field region 47 as a starting point is expanded also to a portion of the second semiconductor region 7 positioned between the first main surface 3 and the field region 47.

The field region 47 may have a thickness (depth) greater than the distance between the first main surface 3 and the field region 47. According to this arrangement, the expansion range of the depletion layer can be adjusted by the field region 47 having a thickness greater than the distance between the first main surface 3 and the field region 47.

The field region 47 may be formed at an interval toward the first main surface 3 side from the bottom portion of the second semiconductor region 7. According to this arrangement, the expansion range of the depletion layer can be adjusted by the field region 47 separated from the bottom portion of the second semiconductor region 7.

The field region 47 may have a thickness (depth) less than the distance between the bottom portion of the second semiconductor region 7 and the field region 47. According to this arrangement, the expansion range of the depletion layer can be adjusted by the field region 47 having the thickness less than the distance between the bottom portion of the second semiconductor region 7 and the field region 47.

The field region 47 may extend in a band shape along the peripheral edge of the first main surface 3. According to this arrangement, the withstand voltage of the semiconductor device 1A can be improved by the field region 47 extending in a band shape along the peripheral edge of the first main surface 3. The field region 47 may surround the inner portion of the first main surface 3 in plan view. According to this arrangement, the withstand voltage of the semiconductor device 1A can be improved by the field region 47 surrounding the inner portion of the first main surface 3.

The plurality of field regions 47 may be formed at intervals in the surface layer portion of the second semiconductor region 7. According to this arrangement, the withstand voltage of the semiconductor device 1A can be improved by the plurality of field regions 47. The plurality of field regions 47 may have mutually equal depths. According to this arrangement, the withstand voltage of the semiconductor device 1A can be improved by the plurality of field regions 47 having the mutually equal depths.

The semiconductor device 1A may include the active region 8 provided in an inner portion of the first main surface 3 and the outer peripheral region 9 provided in the peripheral edge portion of the first main surface 3. In this case, the field region 47 may be formed in the outer peripheral region 9. According to this arrangement, the withstand voltage of the semiconductor device 1A can be improved by using the field region 47 formed in the outer peripheral region 9 outside the active region 8.

The field region 47 may extend in a band shape along the active region 8 in plan view. According to this arrangement, the withstand voltage of the semiconductor device 1A can be improved by the field region 47 extending in a band shape along the active region 8. The field region 47 may surround the active region 8 in plan view. According to this arrangement, the withstand voltage of the semiconductor device 1A can be improved by the field region 47 surrounding the active region 8.

The semiconductor device 1A may include the transistor structure Tr formed in the active region 8. According to this arrangement, the withstand voltage of the semiconductor device 1A including the transistor structure Tr can be improved by the field region 47 formed in the outer peripheral region 9.

The semiconductor device 1A may include the p-type terminal region 45. The terminal region 45 may be formed in the surface layer portion of the second semiconductor region 7 in the peripheral edge portion of the first main surface 3. In this case, the field region 47 may be formed in the surface layer portion of the second semiconductor region 7 in the region between the peripheral edge of the first main surface 3 and the terminal region 45.

According to this arrangement, the depletion layer expands with the terminal region 45 as a starting point on the inner portion side of the first main surface 3, and at the same time, the depletion layer expands with the field region 47 as a starting point on the peripheral edge portion side of the first main surface 3. The withstand voltage of the semiconductor device 1A can thereby be improved.

The field region 47 may be formed to be narrower in width than the terminal region 45. According to this arrangement, the withstand voltage of the semiconductor device 1A can be improved by the field region 47 narrower in width than the terminal region 45.

The semiconductor device 1A may include the p-type outer well region 43. The outer well region 43 may be formed in the surface layer portion of the first main surface 3 in the peripheral edge portion of the first main surface 3. In this case, the terminal region 45 may be formed in a region between the peripheral edge of the first main surface 3 and the outer well region 43.

According to this arrangement, the depletion layer expands with the outer well region 43 as a starting point on the inner portion side of the first main surface 3, and at the same time, the depletion layer expands, on the peripheral edge portion side of the first main surface 3, with the terminal region 45 as a starting point. The withstand voltage of the semiconductor device 1A can thereby be improved.

The semiconductor device 1A may include the p-type outer contact region 44. The outer contact region 44 is formed in the surface layer portion of the outer well region 43, and may have a p-type impurity concentration higher than the p-type impurity concentration of the outer well region 43. According to this arrangement, the electrical response speed of the outer well region 43 is improved by the outer contact region 44.

The semiconductor device 1A may include the terminal wiring 65 (the terminal electrode) arranged on the first main surface 3 and electrically connected to the terminal region 45. According to this arrangement, a predetermined terminal potential is to be applied to the terminal region 45 via the terminal wiring 65. Electrical response characteristics of the terminal region 45 can thereby be improved by the terminal wiring 65. The terminal potential may be the reference potential serving as a reference of circuit operation. The reference potential may be the ground potential. The terminal potential may be the source potential.

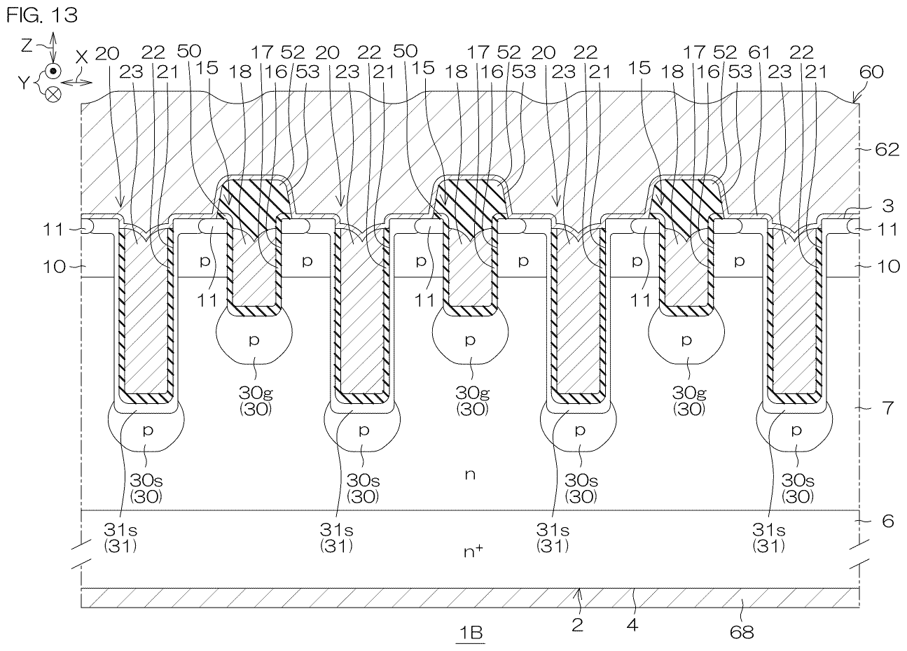

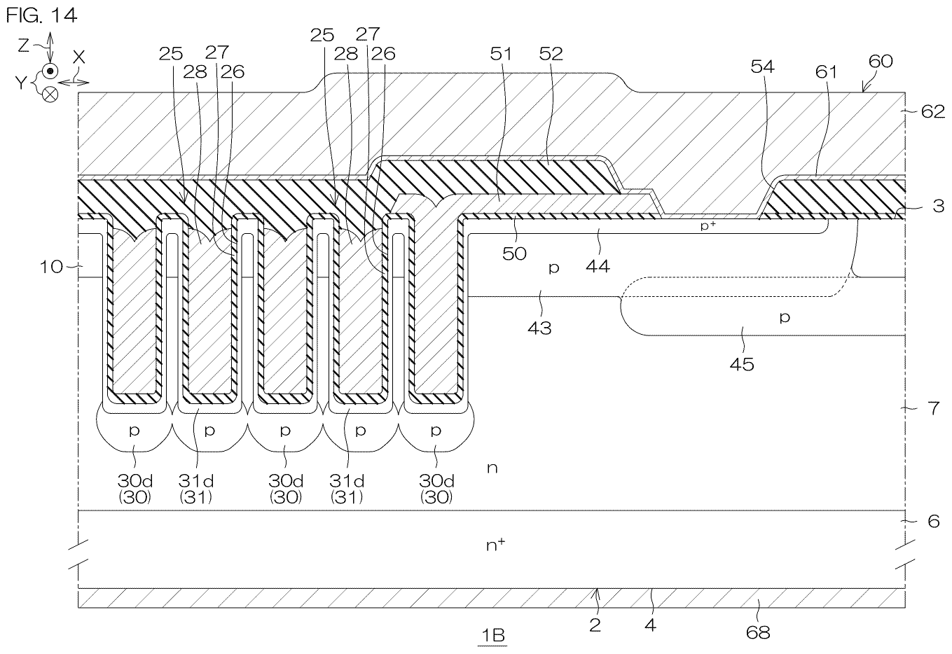

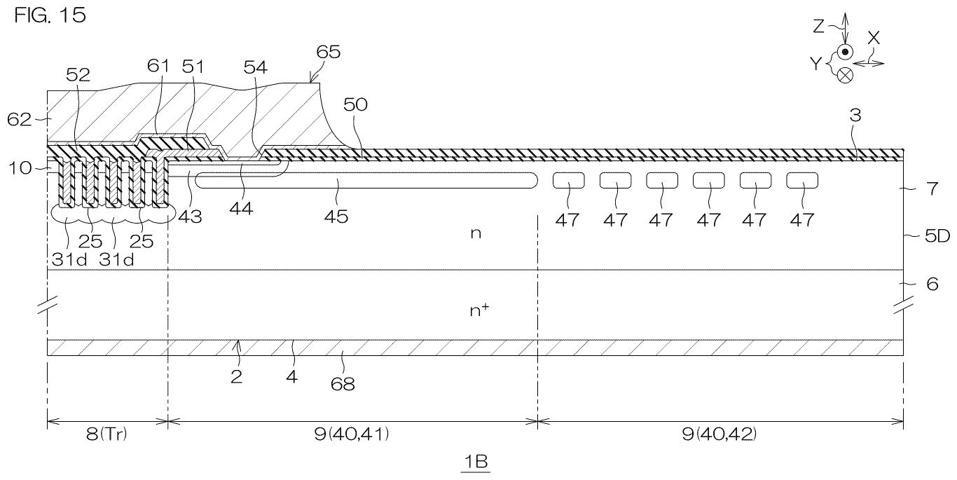

FIG. 13 is a cross-sectional view illustrating one main portion of the active region 8 of a semiconductor device 1B according to a second embodiment. FIG. 14 is a cross-sectional view illustrating one main portion of the active region 8 of the semiconductor device 1B illustrated in FIG. 13. FIG. 15 is a cross-sectional view illustrating the outer peripheral region 9 of the semiconductor device 1B illustrated in FIG. 13 together with the outer peripheral structure 40 according to the first configuration example.

Referring to FIGS. 13 to 15, the semiconductor device 1B has a form in which the arrangements of the plurality of gate structures 15, the plurality of source structures 20, and the plurality of dummy structures 25 according to the semiconductor device 1A are changed. Specifically, the semiconductor device 1B includes the plurality of source structures 20 having a depth greater than the depths of the plurality of gate structures 15.

A ratio (depth ratio) of the depth of the source structure 20 to the depth of the gate structure 15 may be not less than 1.5 and not more than 2.5. The depth ratio may have a value belonging to at least one range among not less than 1.5 and not more than 1.75, not less than 1.75 and not more than 2, not less than 2 and not more than 2.25, and not less than 2.25 and not more than 2.5.

The semiconductor device 1B has the plurality of dummy structures 25 having a depth greater than the depths of the plurality of gate structures 15. The depths of the plurality of dummy structures 25 is preferably substantially equal to the depths of the plurality of source structures 20. As a matter of course, the depths of the plurality of dummy structures 25 may be greater than the depths of the plurality of source structures 20 or may be smaller than the depths of the plurality of source structures 20.

A ratio (depth ratio) of the depth of the dummy structure 25 to the depth of the gate structure 15 may be not less than 1.5 and not more than 2.5. The depth ratio may have a value belonging to at least one range among not less than 1.5 and not more than 1.75, not less than 1.75 and not more than 2, not less than 2 and not more than 2.25, and not less than 2.25 and not more than 2.5.

The bottom portion of the outer well region 43 may be formed at intervals toward the first main surface 3 side from the depth positions of the bottom walls of the plurality of source structures 20. The bottom portion of the outer well region 43 may be formed at intervals toward the first main surface 3 side from the depth positions of the bottom walls of the plurality of dummy structures 25.

The bottom portion of the outer contact region 44 may be formed at intervals toward the first main surface 3 side from the depth positions of the bottom walls of the plurality of source structures 20. The bottom portion of the outer contact region 44 may be formed at intervals toward the first main surface 3 side from the depth positions of the bottom walls of the plurality of dummy structures 25.

The bottom portion of the terminal region 45 may be formed at an interval toward the first main surface 3 side from the depth positions of the bottom walls of the plurality of source structures 20. The bottom portion of the terminal region 45 may be formed at an interval toward the first main surface 3 side from the depth positions of the bottom walls of the plurality of dummy structures 25.

The bottom portions of the plurality of field regions 47 may be formed at intervals toward the first main surface 3 side from the depth positions of the bottom walls of the plurality of source structures 20. The bottom portions of the plurality of field regions 47 may be formed at intervals toward the first main surface 3 side from the depth positions of the bottom walls of the plurality of dummy structures 25.

Other arrangements and descriptions of the semiconductor device 1B are the same as in the case of the semiconductor device 1A. As a matter of course, as in the case of the case of the semiconductor device 1A, the semiconductor device 1B may include any one of the outer peripheral structures 40 according to the first to fifth configuration examples (see also FIG. 10A to FIG. 10E).

Also, the semiconductor device 1B may include any one of the features of the first outer peripheral structures 41 according to the first to tenth modification examples with respect to the first outer peripheral structures 41 according to the first to fifth configuration examples (see also FIGS. 11A to 11J). Of course, the features of the first outer peripheral structures 41 according to the first to tenth modification examples can be combined therebetween as appropriate.

Therefore, with respect to the first outer peripheral structures 41 according to the first to fifth configuration examples, the semiconductor device 1B may simultaneously include at least two of the features of the first outer peripheral structures 41 according to the first to tenth modification examples in the same or different regions.

At least one feature of the outer well region 43, the outer contact region 44, and the terminal region 45 according to the first to tenth modification examples is selected as appropriate according to the configurations of the first to fifth configuration examples, and is applied to the configurations of the first to fifth configuration examples.

The semiconductor device 1B may include any one of the features of the second outer peripheral structures 42 according to the first to tenth modification examples with respect to the second outer peripheral structures 42 according to the first to fifth configuration examples (see also FIGS. 12A to 12J). Of course, the features of the second outer peripheral structures 42 according to the first to tenth modification examples can be combined therebetween as appropriate.

Therefore, with respect to the second outer peripheral structures 42 according to the first to fifth configuration examples, the semiconductor device 1B may simultaneously include at least two of the features of the second outer peripheral structures 42 according to the first to tenth modification examples in the same or different regions. At least one feature of the field regions 47 according to the first to tenth modification examples is selected as appropriate according to the configurations of the first to fifth configuration examples, and is applied to the configurations of the first to fifth configuration examples.

The semiconductor device 1B may include one or a plurality of the features of the first outer peripheral structures 41 according to the first to tenth modification examples and one or a plurality of the features of the second outer peripheral structures 42 according to the first to tenth modification examples, together with the arrangement of any one of the first to fifth configuration examples.

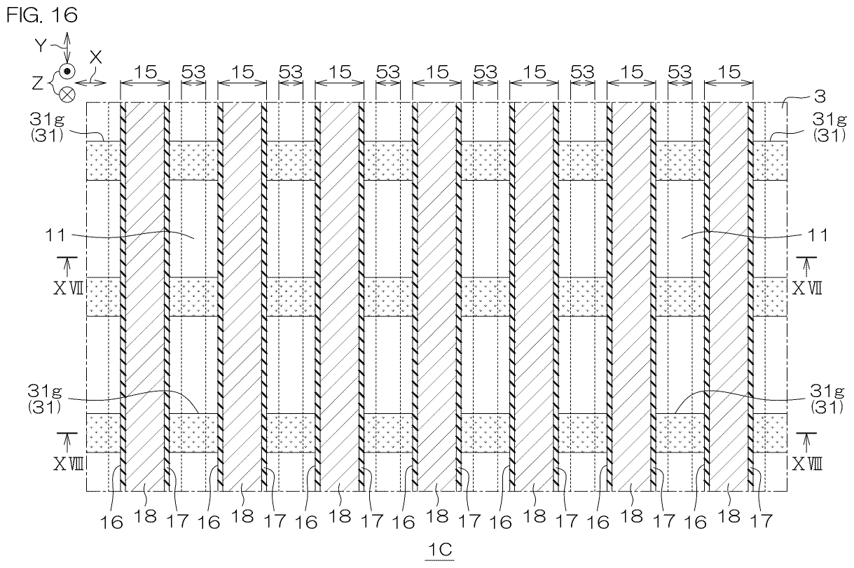

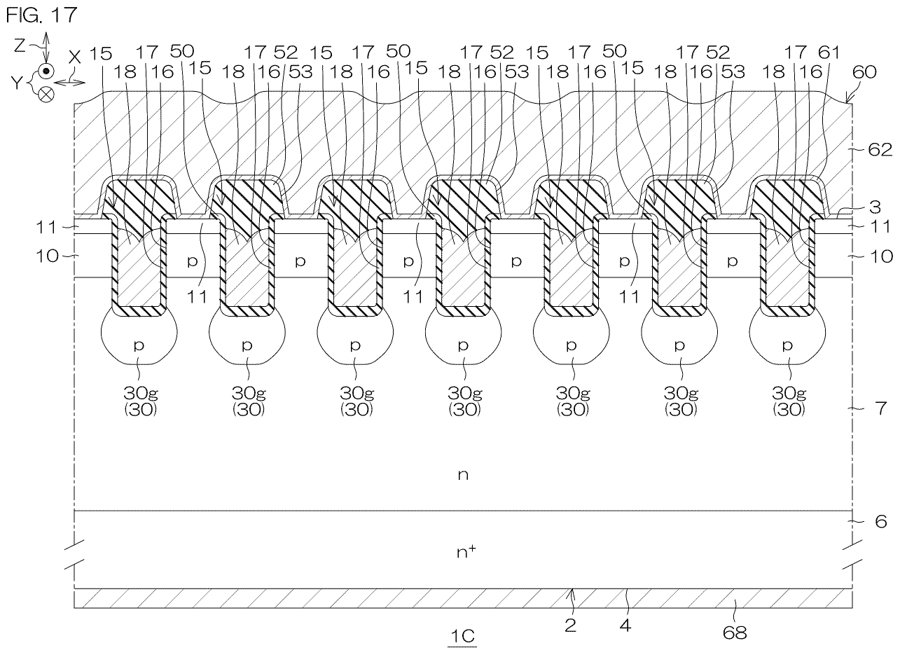

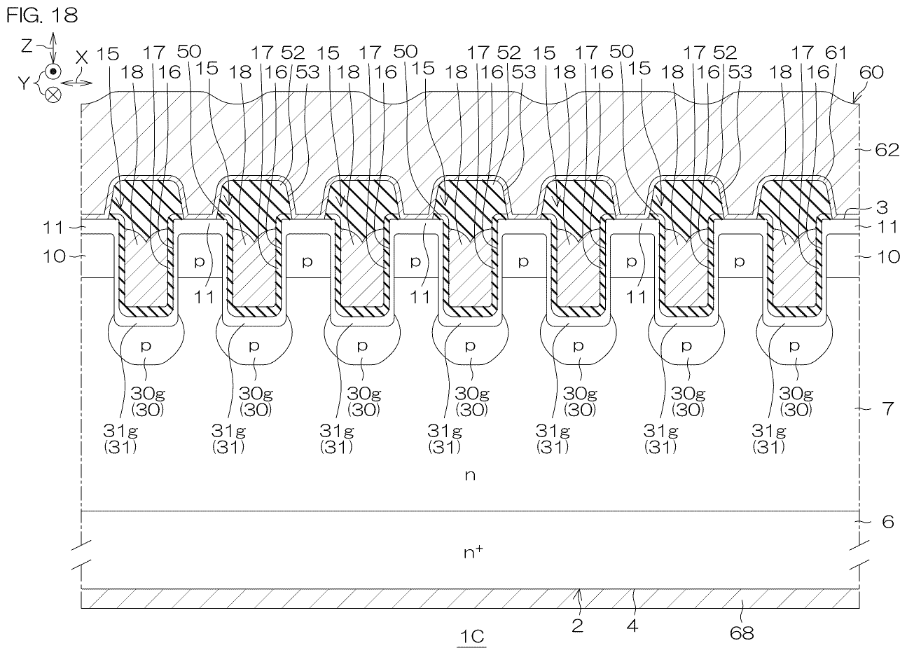

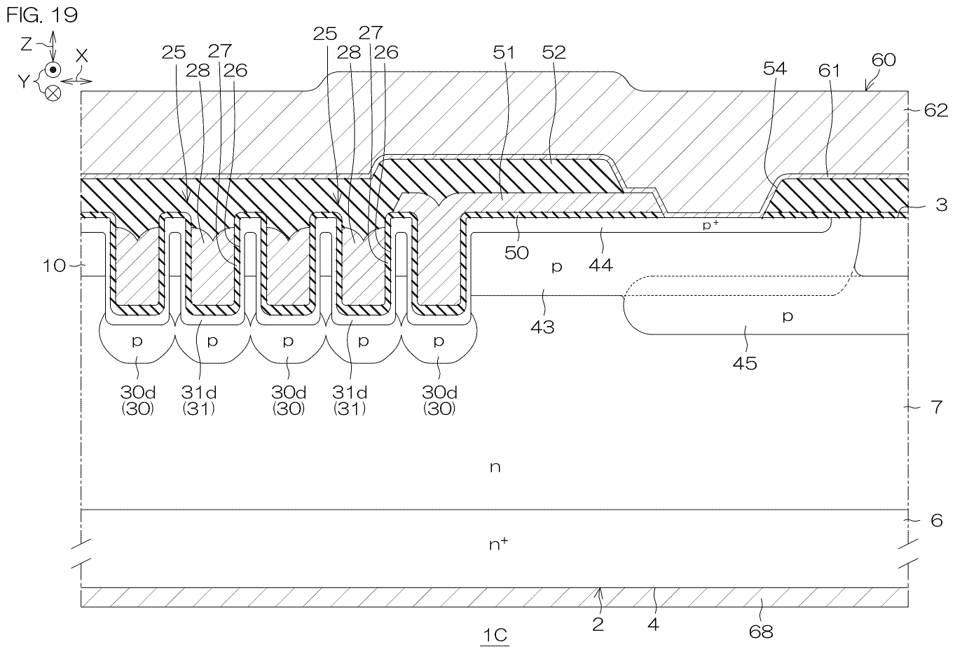

FIG. 16 is an enlarged plan view illustrating one main portion of the active region 8 of a semiconductor device 1C according to a third embodiment. FIG. 17 is a cross-sectional view taken along line XVII-XVII illustrated in FIG. 16. FIG. 18 is a cross-sectional view taken along line XVIII-XVIII illustrated in FIG. 16. FIG. 19 is a cross-sectional view illustrating one main portion of the active region 8 of the semiconductor device 1C illustrated in FIG. 16.

Referring to FIGS. 16 to 19, the semiconductor device 1C has a form in which the arrangements of the plurality of gate structures 15 and the plurality of source structures 20, and the arrangements of the plurality of dummy structures 25 according to the semiconductor device 1A are changed.

Specifically, unlike the semiconductor device 1A, the semiconductor device 1C includes the plurality of gate structures 15 and the plurality of dummy structures 25, and does not include the plurality of source structures 20. In this embodiment, the plurality of gate structures 15 are aligned so as to be adjacent to each other at intervals in the first direction X (=the m-axis direction), and each extend in a band shape in the second direction Y (=the a-axis direction).

The plurality of dummy structures 25 are arranged on the peripheral edge of the active region 8 at intervals from a structure group including the plurality of gate structures 15. The plurality of dummy structures 25 may each be formed in a polygonal annular shape (a quadrilateral annular shape) entirely surrounding a structure group including the plurality of gate structures 15 in plan view.

The depths of the plurality of dummy structures 25 are preferably substantially equal to the depths of the plurality of gate structures 15. As a matter of course, the depths of the plurality of dummy structures 25 may be greater than the depths of the plurality of gate structures 15, or may be smaller than the depths of the plurality of gate structures 15.

Unlike the semiconductor device 1A, the semiconductor device 1C includes the plurality of gate well regions 30g and the plurality of dummy well regions 30d, and does not include the plurality of source well regions 30s. The plurality of gate well regions 30g and the plurality of dummy well regions 30d have the same forms as in the case of the semiconductor device 1A.

The semiconductor device 1C includes the plurality of gate contact regions 31g and the plurality of dummy contact regions 31d, and does not include the plurality of source contact regions 31s. The plurality of gate contact regions 31g and the plurality of dummy contact regions 31d have the same forms as in the case of the semiconductor device 1A.

With respect to the one gate structure 15 and the other gate structure 15, the plurality of gate contact regions 31g along the one gate structure 15 face the plurality of gate contact regions 31g along the other gate structure 15 in the first direction X in plan view.

That is, the plurality of gate contact regions 31g are aligned in a matrix at intervals in the first direction X and the second direction Y as a whole in plan view. In this case, the plurality of gate contact regions 31g along the one gate structure 15 may be connected to the plurality of gate contact regions 31g along the other gate structure 15 in the surface layer portion of the body region 10.

As a matter of course, the plurality of gate contact regions 31g along the one gate structure 15 may face a region between the plurality of gate contact regions 31g along the other gate structure 15 in the first direction X in plan view. That is, the plurality of gate contact regions 31g may be aligned in a staggered manner at intervals in the first direction X and the second direction Y as a whole in plan view.

As in the case of the semiconductor device 1A, the semiconductor device 1C includes the plurality of source openings 53 formed in the interlayer film 52. In this embodiment, the plurality of source openings 53 are respectively formed in regions between the plurality of adjacent gate structures 15 and respectively expose the source region 11 and the plurality of gate contact regions 31g.

As in the case of the semiconductor device 1A, the semiconductor device 1C includes the source electrode 60 arranged on the first main surface 3. The source electrode 60 has a laminated structure including the lower electrode film 61 and the main electrode film 62 laminated in that order from the chip 2 side. As in the case of the semiconductor device 1A, the lower electrode film 61 has a laminated structure including the first electrode film 63 and the second electrode film 64.

The first electrode film 63 entirely covers, in a film shape, a region of the interlayer film 52 in which the plurality of source openings 53 are formed, and enters the plurality of source openings 53 from above the interlayer film 52. The first electrode film 63 is mechanically and electrically connected to the source region 11 and the plurality of gate contact regions 31g in the plurality of source openings 53.

The second electrode film 64 entirely covers, in a film shape, a region of the interlayer film 52 in which the plurality of source openings 53 are formed with the first electrode film 63 interposed therebetween, and enters the plurality of source openings 53 from above the interlayer film 52. The second electrode film 64 is electrically connected to the source region 11 and the plurality of gate contact regions 31g via the first electrode film 63 in the plurality of source openings 53.

The main electrode film 62 entirely covers, in a film shape, a region of the interlayer film 52 in which the plurality of source openings 53 are formed, and refills the plurality of source openings 53. The main electrode film 62 is electrically connected to the source region 11 and the plurality of gate contact regions 31g via the lower electrode film 61 in the plurality of source openings 53.

Other arrangements and descriptions of the semiconductor device 1C are the same as in the case of the semiconductor device 1A. As in the case of the semiconductor device 1A, the semiconductor device 1C may include any one of the outer peripheral structures 40 according to the first to fifth configuration examples (see also FIGS. 10A to 10E).

Also, the semiconductor device 1C may include any one of the features of the first outer peripheral structures 41 according to the first to tenth modification examples with respect to the first outer peripheral structures 41 according to the first to fifth configuration examples (see also FIGS. 11A to 11J). Of course, the features of the first outer peripheral structures 41 according to the first to tenth modification examples can be combined therebetween as appropriate.

Therefore, with respect to the first outer peripheral structures 41 according to the first to fifth configuration examples, the semiconductor device 1C may simultaneously include at least two of the features of the first outer peripheral structures 41 according to the first to tenth modification examples in the same or different regions.

At least one feature of the outer well region 43, the outer contact region 44, and the terminal region 45 according to the first to tenth modification examples is selected as appropriate according to the configurations of the first to fifth configuration examples, and is applied to the configurations of the first to fifth configuration examples.

The semiconductor device 1C may include any one of the features of the second outer peripheral structures 42 according to the first to tenth modification examples with respect to the second outer peripheral structures 42 according to the first to fifth configuration examples (see also FIGS. 12A to 12J). Of course, the features of the second outer peripheral structures 42 according to the first to tenth modification examples can be combined therebetween as appropriate.

Therefore, with respect to the second outer peripheral structures 42 according to the first to fifth configuration examples, the semiconductor device 1C may simultaneously include at least two of the features of the second outer peripheral structures 42 according to the first to tenth modification examples in the same or different regions. At least one feature of the field regions 47 according to the first to tenth modification examples is selected as appropriate according to the configurations of the first to fifth configuration examples, and is applied to the configurations of the first to fifth configuration examples.

The semiconductor device 1C may include one or a plurality of the features of the first outer peripheral structures 41 according to the first to tenth modification examples and one or a plurality of the features of the second outer peripheral structures 42 according to the first to tenth modification examples, together with the arrangement of any one of the first to fifth configuration examples.

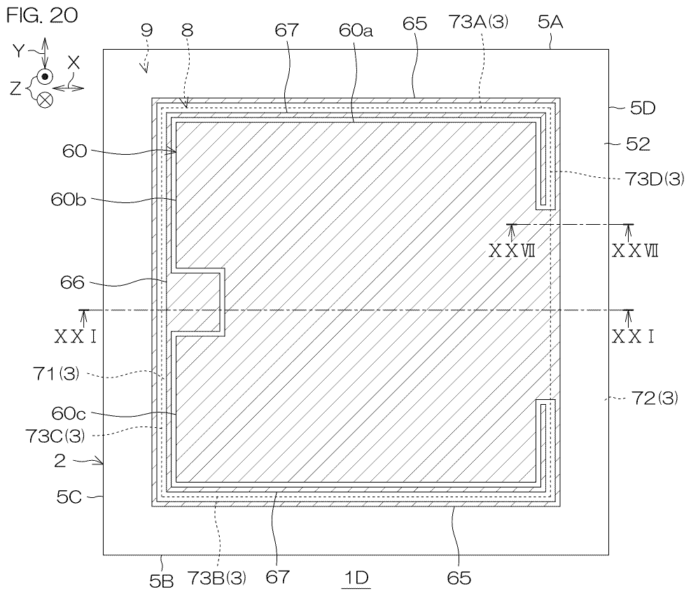

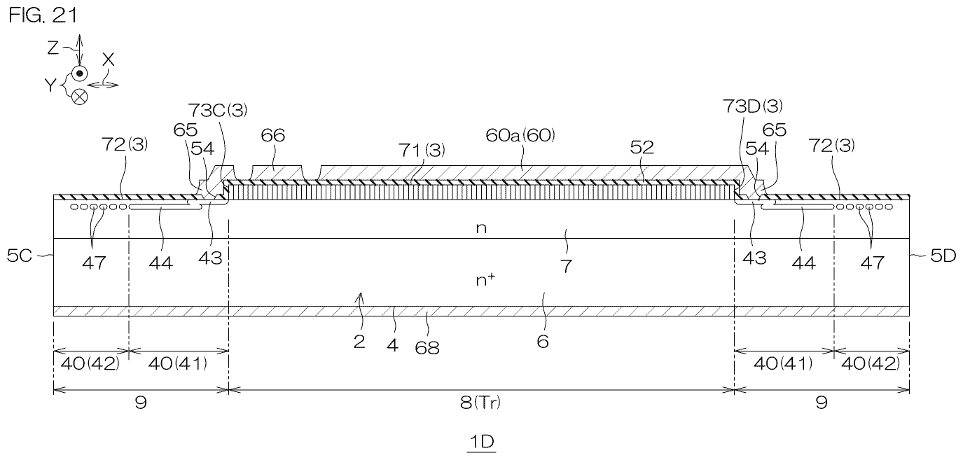

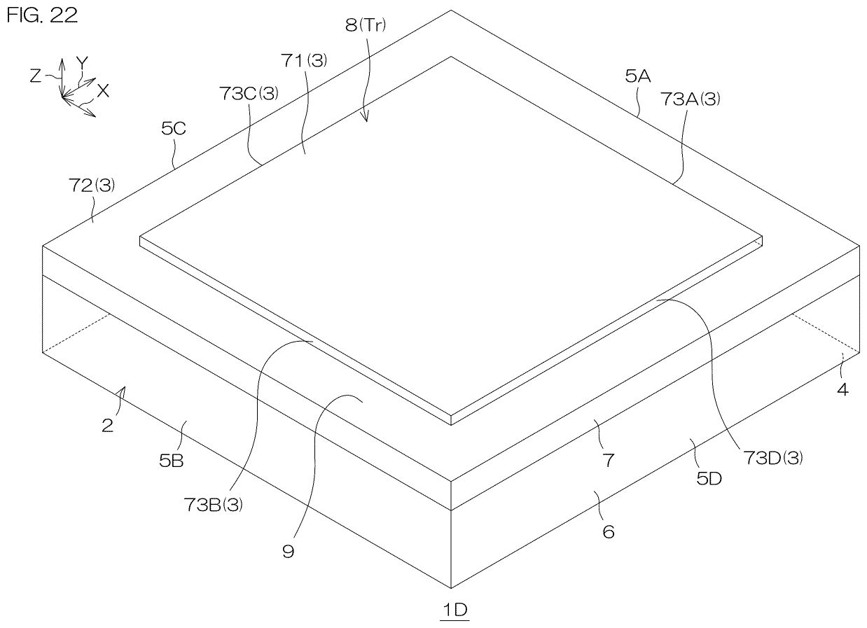

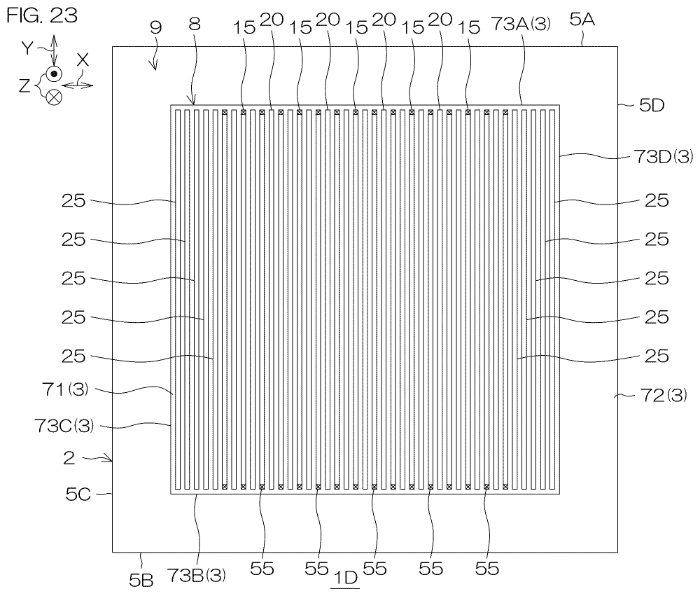

FIG. 20 is a plan view illustrating a semiconductor device 1D according to a fourth embodiment. FIG. 21 is a cross-sectional view taken along line XXI-XXI illustrated in FIG. 20. FIG. 22 is a perspective view illustrating a shape of the chip 2. FIG. 23 is a plan view illustrating a layout example of the first main surface 3.

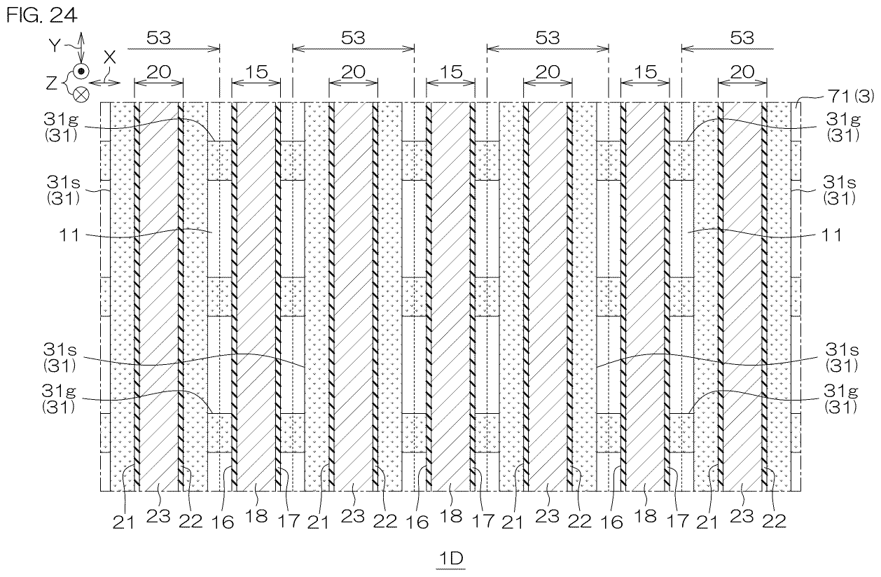

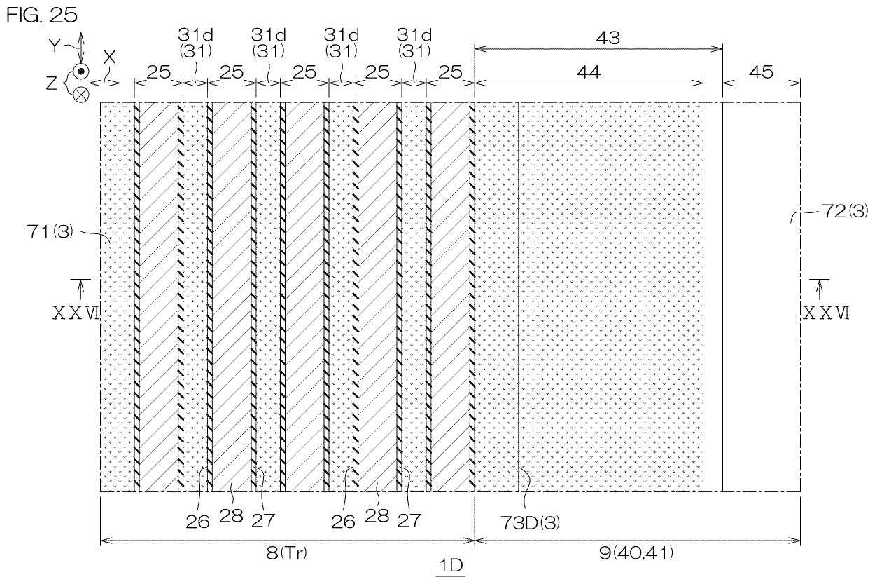

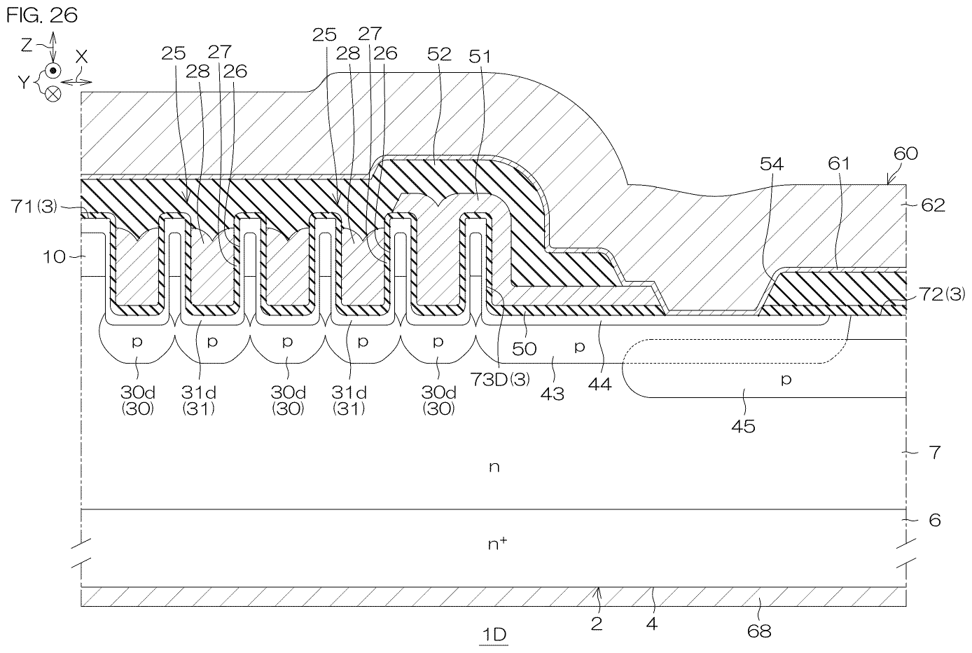

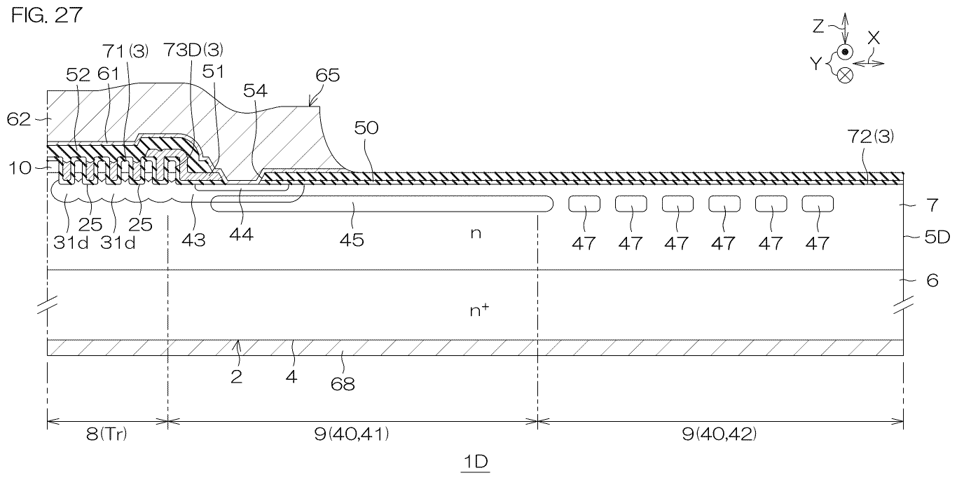

FIG. 24 is an enlarged plan view illustrating one main portion of the first main surface 3 illustrated in FIG. 23. FIG. 25 is an enlarged plan view illustrating one main portion of the first main surface 3 illustrated in FIG. 23. FIG. 26 is a cross-sectional view taken along line XXVI-XXVI illustrated in FIG. 25. FIG. 27 is a cross-sectional view illustrating a cross-sectional structure of the outer peripheral region 9 taken along line XXVII-XXVII illustrated in FIG. 20 together with the outer peripheral structure 40 according to the first configuration example.

As in the case of the semiconductor device 1A, the semiconductor device 1D includes the chip 2, the first semiconductor region 6, and the second semiconductor region 7. The semiconductor device 1D includes a first surface portion 71, a second surface portion 72, and first to fourth connecting surface portions 73A to 73D formed on the first main surface 3.

The first surface portion 71, the second surface portion 72, and the first to fourth connecting surface portions 73A to 73D demarcate a mesa on the first main surface 3. The first surface portion 71, the second surface portion 72, and the first to fourth connecting surface portions 73A to 73D (that is, mesa) may be regarded as constituent elements of the chip 2 (the first main surface 3).

The first surface portion 71 may be referred to as an “active surface,” the second surface portion 72 may be referred to as an “outer surface,” the first to fourth connecting surface portions 73A to 73D may be referred to as “connecting surfaces,” and the mesa may be referred to as an “active mesa.”

The first surface portion 71 is demarcated in the inner portion of the first main surface 3 at an interval from the peripheral edge (the first to fourth side surfaces 5A to 5D) of the first main surface 3. The first surface portion 71 has a flat surface extending in the horizontal directions and is formed of the c-plane (the Si plane). In this embodiment, the first surface portion 71 is formed in a polygonal shape (specifically, a quadrilateral shape) having four sides parallel to the first to fourth side surfaces 5A to 5D in plan view.

The ratio (area ratio) of the planar area of the first surface portion 71 to the planar area of the first main surface 3 may be not less than 0.5 and not more than 0.95. The area ratio may be not less than 0.5 and not more than 0.6, not less than 0.6 and not more than 0.7, not less than 0.7 and not more than 0.8, not less than 0.8 and not more than 0.9, or not less than 0.9 and not more than 0.95.

The second surface portion 72 is positioned at the peripheral edge portion side of the first main surface 3 with respect to the first surface portion 71, and is recessed in the thickness direction (the second main surface 4 side) of the chip 2 from a height position of the first surface portion 71. The second surface portion 72 extends in a band shape along the first surface portion 71 in plan view, and is formed in a polygonal annular shape (specifically, a quadrilateral annular shape) surrounding the first surface portion 71. The second surface portion 72 is continuous to the first to fourth side surfaces 5A to 5D.

The second surface portion 72 is formed substantially parallel to the first surface portion 71 and has a flat surface extending in the horizontal directions. In this embodiment, the second surface portion 72 is formed of the c-plane (the Si plane). The second surface portion 72 is formed in the second semiconductor region 7 at an interval from the first semiconductor region 6. That is, the second surface portion 72 is recessed at a depth less than the thickness of the second semiconductor region 7 and exposes the second semiconductor region 7.

The second surface portion 72 may have a depth of not less than 0.1 μm and not more than 3 μm. The depth of the second surface portion 72 may have a value belonging to at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm.

The first to fourth connecting surface portions 73A to 73D extend in the vertical direction Z and are connected to the first surface portion 71 and the second surface portion 72. The first connecting surface portion 73A is positioned at the first side surface 5A side, the second connecting surface portion 73B is positioned at the second side surface 5B side, the third connecting surface portion 73C is positioned at the third side surface 5C side, and the fourth connecting surface portion 73D is positioned at the fourth side surface 5D side.

The first connecting surface portion 73A and the second connecting surface portion 73B extend in the first direction X and oppose each other in the second direction Y. The third connecting surface portion 73C and the fourth connecting surface portion 73D extend in the second direction Y and oppose each other in the first direction X.

The mesa is thus demarcated in a projecting shape (a convex shape) in the first main surface 3. The mesa is formed only in the second semiconductor region 7 and is not formed in the first semiconductor region 6. The first to fourth connecting surface portions 73A to 73D may extend substantially perpendicularly between the first surface portion 71 and the second surface portion 72 and demarcate a mesa of a quadratic prism shape.

The first to fourth connecting surface portions 73A to 73D may be inclined obliquely downward toward the first surface portion 71 and the second surface portion 72 and demarcate a mesa of a truncated quadrilateral prism shape. The first to fourth connecting surface portions 73A to 73D may be inclined at an angle exceeding 90° and not more than 135° with respect to the first surface portion 71.

As in the case of the semiconductor device 1A, the semiconductor device 1D includes the active region 8 and the outer peripheral region 9. In this embodiment, the active region 8 is set in the first surface portion 71. The outer peripheral region 9 is set in the second surface portion 72.

That is, the active region 8 is set in a polygonal shape (in this embodiment, quadrilateral shape) having four sides parallel to the peripheral edge of the chip 2 in conformance to the first surface portion 71 in plan view. The outer peripheral region 9 extends in a band shape along the active region 8 in conformance to the second surface portion 72 and is set in a polygonal annular shape (in this embodiment, a quadrilateral annular shape) surrounding the active region 8.

As in the case of the semiconductor device 1A, the semiconductor device 1D includes the p-type body region 10 formed in the surface layer portion of the first main surface 3 in the inner portion of the first main surface 3. In this embodiment, the body region 10 is formed in the surface layer portion of the first surface portion 71. The body region 10 is formed at an interval toward the first surface portion 71 side from the bottom portion of the second semiconductor region 7, and faces the first semiconductor region 6 with a portion of the second semiconductor region 7 interposed therebetween.

The body region 10 is formed at an interval toward the first surface portion 71 side from a depth position of the second surface portion 72, and extends in a layer shape along the first surface portion 71. In this embodiment, the body region 10 is formed over the entire first surface portion 71 and is exposed from the first to fourth connecting surface portions 73A to 73D. As a matter of course, the body region 10 may be formed at an interval inward from a peripheral edge of the first surface portion 71.

As in the case of the semiconductor device 1A, the semiconductor device 1D includes the n-type source region 11 formed in the surface layer portion of the first main surface 3 in the inner portion of the first main surface 3. In this embodiment, the source region 11 is formed in the surface layer portion of the body region 10 in the first surface portion 71 at an interval toward the first surface portion 71 side from the depth position of the bottom portion of the body region 10.

The source region 11 extends in a layer shape along the first surface portion 71. In this embodiment, the source region 11 is formed over the entire first surface portion 71 and is exposed from the first to fourth connecting surface portions 73A to 73D. As a matter of course, the source region 11 may be formed at an interval inward from the peripheral edge of the first surface portion 71.

As in the case of the semiconductor device 1A, the semiconductor device 1D includes the plurality of gate structures 15 formed on the first main surface 3 in the inner portion of the first main surface 3. In this embodiment, the plurality of gate structures 15 are formed in the inner portion of the first surface portion 71 at an interval from the peripheral edge of the first surface portion 71.

In this embodiment, the plurality of gate structures 15 are formed at intervals toward the first surface portion 71 side from the depth position of the bottom portion of the second semiconductor region 7, and face the first semiconductor region 6 with a portion of the second semiconductor region 7 interposed therebetween.

In this embodiment, the plurality of gate structures 15 have a depth substantially equal to the depth of the second surface portion 72. As a matter of course, the depths of the plurality of gate structures 15 may be greater than the depth of the second surface portion 72 or may be less than the depth of the second surface portion 72. The description of the gate structure 15 related to the semiconductor device 1D can be obtained by replacing the “first main surface 3” with the “first surface portion 71” in the description of the gate structure 15 related to the semiconductor device 1A.

As in the case of the semiconductor device 1A, the semiconductor device 1D includes the plurality of source structures 20 formed in the first main surface 3 in the inner portion of the first main surface 3. In this embodiment, the plurality of source structures 20 are formed in the inner portion of the first surface portion 71 at an interval from the peripheral edge of the first surface portion 71.

In this embodiment, the plurality of source structures 20 are formed at intervals toward the first surface portion 71 side from the depth position of the bottom portion of the second semiconductor region 7, and face the first semiconductor region 6 with a portion of the second semiconductor region 7 interposed therebetween.

In this embodiment, the plurality of source structures 20 have a depth substantially equal to the depth of the second surface portion 72. As a matter of course, the depths of the plurality of source structures 20 may be greater than the depth of the second surface portion 72 or may be less than the depth of the second surface portion 72. The description of the source structure 20 related to the semiconductor device 1D can be obtained by replacing the “first main surface 3” with the “first surface portion 71” in the description of the source structure 20 related to the semiconductor device 1A.

As in the case of the semiconductor device 1A, the semiconductor device 1D includes one or a plurality (in this embodiment, a plurality) of the dummy structures 25 formed in the first main surface 3 at the peripheral edge portion of the active region 8. In this embodiment, the plurality of dummy structures 25 are formed in the peripheral edge portion of the first surface portion 71 at an interval from the peripheral edge of the first surface portion 71.

In this embodiment, the plurality of dummy structures 25 are each formed in a region on the third connecting surface portion 73C side and a region on the fourth connecting surface portion 73D side in the peripheral edge portion of the first surface portion 71. In this embodiment, the plurality of dummy structures 25 are aligned at intervals from each other in the first direction X, and each formed in a band shape extending in the second direction Y. As a matter of course, as in the case of the semiconductor device 1A, the plurality of dummy structures 25 may be formed in an annular shape surrounding the plurality of gate structures 15 and the plurality of source structures 20 in the first surface portion 71.

In this embodiment, the plurality of dummy structures 25 have a depth substantially equal to the depth of the second surface portion 72. As a matter of course, the depths of the plurality of dummy structures 25 may be greater than the depth of the second surface portion 72 or may be less than the depth of the second surface portion 72. The description of the dummy structure 25 related to the semiconductor device 1D can be obtained by replacing the “first main surface 3” with the “first surface portion 71” in the description of the dummy structure 25 related to the semiconductor device 1A.

As in the case of the semiconductor device 1A, the semiconductor device 1D includes the plurality of well regions 30 formed in the chip 2 (the second semiconductor region 7) in the active region 8. The plurality of well regions 30 include the plurality of gate well regions 30g, the plurality of source well regions 30s, and the plurality of dummy well regions 30d.

As in the case of the semiconductor device 1A, the plurality of gate well regions 30g are respectively formed at intervals from each other in the horizontal direction (the first direction X) in regions directly below the plurality of gate structures 15. In this embodiment, the bottom portions of the plurality of gate well regions 30g are positioned at the bottom portion side of the second semiconductor region 7 with respect to the depth position of the second surface portion 72.

As in the case of the case of the semiconductor device 1A, the plurality of source well regions 30s are respectively formed in regions directly below the plurality of source structures 20 at intervals from the plurality of gate well regions 30g in the horizontal direction (the first direction X). In this embodiment, the bottom portions of the plurality of source well regions 30s are positioned at the bottom portion side of the second semiconductor region 7 with respect to the depth position of the second surface portion 72.

Similar to the case of the semiconductor device 1A, the plurality of dummy well regions 30d are respectively formed in regions directly below the plurality of dummy structures 25 at intervals in the horizontal direction from the plurality of gate well regions 30g and the plurality of source well regions 30s. In this embodiment, the bottom portions of the plurality of dummy well regions 30d are positioned at the bottom portion side of the second semiconductor region 7 with respect to the depth position of the second surface portion 72.

As in the case of the semiconductor device 1A, the semiconductor device 1D includes the plurality of contact regions 31 formed in the chip 2 (the second semiconductor region 7). The plurality of contact regions 31 include the plurality of gate contact regions 31g, the plurality of source contact regions 31s, and the plurality of dummy contact regions 31d.

The description of the plurality of gate contact regions 31g, the plurality of source contact regions 31s, and the plurality of dummy contact regions 31d related to the semiconductor device 1D can be obtained by replacing the “first main surface 3” with the “first surface portion 71” in the description of the plurality of gate contact regions 31g, the plurality of source contact regions 31s, and the plurality of dummy contact regions 31d related to the semiconductor device 1A.

Similarly to the semiconductor device 1A, the semiconductor device 1D includes any one of the outer peripheral structures 40 according to the first to fifth configuration examples formed in the outer peripheral region 9 (see also FIGS. 10A to 10E). FIG. 27 illustrates an example in which the semiconductor device 1D has the outer peripheral structure 40 according to the first configuration example. The outer peripheral structure 40 includes the first outer peripheral structure 41 on the inner side of the first main surface 3 (the active region 8 side) and the second outer peripheral structure 42 on the peripheral edge side of the first main surface 3.

As in the case of the semiconductor device 1A, the first outer peripheral structure 41 includes the p-type outer well region 43 formed in the surface layer portion of the first main surface 3 in the outer peripheral region 9. In this embodiment, the outer well region 43 is formed in a surface layer portion of the second surface portion 72. Specifically, the outer well region 43 is formed in the surface layer portion of the second semiconductor region 7 on the second surface portion 72, and is electrically connected to the second semiconductor region 7.

In this embodiment, the outer well region 43 is formed at an interval toward the first surface portion 71 side from a peripheral edge (the first to fourth side surfaces 5A to 5D) of the second surface portion 72. The outer well region 43 extends in a band shape along the peripheral edge (the first to fourth connecting surface portions 73A to 73D) of the first surface portion 71 in plan view.

In this embodiment, the outer well region 43 is formed in a polygonal annular shape (in this embodiment, a quadrilateral annular shape) having four sides parallel to the peripheral edge of the first surface portion 71 in plan view, and surrounds the first surface portion 71. The outer well region 43 may have an edge portion that connects a portion extending in the first direction X and a portion extending in the second direction Y in an arc shape (preferably, a quarter arc shape).

The outer well region 43 has an inner edge portion on the first surface portion 71 side and an outer edge portion on the peripheral edge side of the second surface portion 72. In this embodiment, the inner edge portion of the outer well region 43 is led out from the outer peripheral region 9 to the active region 8 side and connected to the dummy well region 30d.

The inner edge portion of the outer well region 43 may have a portion extending in the vertical direction Z in surface layer portions of the first to fourth connecting surface portions 73A to 73D along the first to fourth connecting surface portions 73A to 73D. In this case, the inner edge portion of the outer well region 43 may be connected to the body region 10 in the surface layer portion of the first surface portion 71. As a matter of course, the inner edge portion of the outer well region 43 may be formed at an interval toward the peripheral edge side of the second surface portion 72 from the dummy well region 30d.

The outer well region 43 is formed at an interval toward the second surface portion 72 side from the bottom portion of the second semiconductor region 7, and faces the first semiconductor region 6 with a portion of the second semiconductor region 7 interposed therebetween. The outer well region 43 may be formed at an interval toward the second surface portion 72 side from the depth position of the intermediate portion of the second semiconductor region 7. The outer well region 43 may cross the depth position of the intermediate portion of the second semiconductor region 7.

In this embodiment, the outer well region 43 is formed in a region on the second surface portion 72 side with respect to the depth position of the bottom portion of at least one type of the well region 30 (at least one of the gate well region 30g, the source well region 30s, and the dummy well region 30d), and faces the at least one type of the well region 30 in the horizontal direction.

The outer well region 43 has an upper end portion exposed from the second surface portion 72 and a bottom portion positioned in the second semiconductor region 7. The bottom portion of the outer well region 43 is formed at an interval toward the second surface portion 72 side from the depth position of the intermediate portion of the second semiconductor region 7. In this embodiment, the bottom portion of the outer well region 43 is positioned at the bottom portion side of the second semiconductor region 7 with respect to the depth position of the bottom portion of the body region 10.

The bottom portion of the outer well region 43 is positioned at the bottom portion side of the second semiconductor region 7 with respect to the depth position of the bottom wall of the gate structure 15. The bottom portion of the outer well region 43 is positioned at the bottom portion side of the second semiconductor region 7 with respect to the depth position of the bottom wall of the source structure 20. The bottom portion of the outer well region 43 is positioned at the bottom portion side of the second semiconductor region 7 with respect to the depth position of the bottom wall of the dummy structure 25.

The bottom portion of the outer well region 43 may be formed at an interval toward the second surface portion 72 side from the depth position of the bottom portion of at least one type of the well region 30. The bottom portion of the outer well region 43 may be positioned at the bottom portion side of the second semiconductor region 7 with respect to the depth position of the bottom portion of at least one type of the well region 30.

The bottom portion of the outer well region 43 may be positioned at the depth position substantially equal to the bottom portion of at least one type of the well region 30. Other descriptions of the outer well region 43 related to the semiconductor device 1D are the same as in the case of the outer well region 43 related to the semiconductor device 1A.

As in the case of the semiconductor device 1A, the first outer peripheral structure 41 includes the p-type outer contact region 44 formed in the surface layer portion of the first main surface 3 in the outer peripheral region 9. In this embodiment, the outer contact region 44 is formed in the surface layer portion of the second surface portion 72.

Specifically, the outer contact region 44 is formed in the surface layer portion of the outer well region 43 in the second surface portion 72. The outer contact region 44 is formed at an interval toward the second surface portion 72 side from the bottom portion of the outer well region 43, and faces the second semiconductor region 7 with a portion of the outer well region 43 interposed therebetween.

The outer contact region 44 extends in a band shape along the peripheral edge (the first to fourth connecting surface portions 73A to 73D) of the first surface portion 71 in plan view. In this embodiment, the outer contact region 44 is formed in a polygonal annular shape (in this embodiment, a quadrilateral annular shape) having four sides parallel to the peripheral edge of the first surface portion 71 in plan view, and surrounds the first surface portion 71.

The outer contact region 44 may have an edge portion that connects a portion extending in the first direction X and a portion extending in the second direction Y in an arc shape (preferably, a quarter arc shape). As a matter of course, the outer contact region 44 may each have a plurality of portions that are aligned at intervals along the first surface portion 71 so as to surround the first surface portion 71. In this case, the plurality of portions may each extend in a band shape along the first surface portion 71.

The outer contact region 44 has a width less than the width of the outer well region 43, and is formed in the outer well region 43. The outer contact region 44 has an inner edge portion on the first surface portion 71 side and an outer edge portion on the peripheral edge side of the second surface portion 72.

In this embodiment, the inner edge portion of the outer contact region 44 is formed at an interval toward the peripheral edge side of the second surface portion 72 from the peripheral edge of the first surface portion 71 (the first to fourth connecting surface portions 73A to 73D). As a matter of course, as with the outer well region 43, the inner edge portion of the outer contact region 44 may be led out from the outer peripheral region 9 to the active region 8 side and connected to the dummy well region 30d.

In this case, the inner edge portion of the outer contact region 44 may have a portion extending in the vertical direction Z in the surface layer portions of the first to fourth connecting surface portions 73A to 73D along the first to fourth connecting surface portions 73A to 73D. In this case, the inner edge portion of the outer contact region 44 may be connected to the body region 10 in the surface layer portion of the first surface portion 71. As a matter of course, the inner edge portion of the outer contact region 44 may be connected to the dummy contact region 31d in the surface layer portion of the first surface portion 71.

The outer edge portion of the outer contact region 44 is formed at an interval toward the first surface portion 71 side from the outer edge portion of the outer well region 43. As a matter of course, the outer contact region 44 may cross the outer edge portion of the outer well region 43.

The outer contact region 44 has an upper end portion positioned at the second surface portion 72 side and a bottom portion positioned at the bottom portion side of the outer well region 43. The upper end portion of the outer contact region 44 is exposed from the second surface portion 72.

The bottom portion of the outer contact region 44 may be formed at an interval toward the second surface portion 72 side from the depth position of the intermediate portion of the outer well region 43. The bottom portion of the outer contact region 44 may be positioned at the bottom portion side of the outer well region 43 with respect to the depth position of the intermediate portion of the outer well region 43.

The bottom portion of the outer contact region 44 is positioned at the bottom portion side of the second semiconductor region 7 with respect to the depth position of the bottom wall of the gate structure 15. The bottom portion of the outer contact region 44 is positioned at the bottom portion side of the second semiconductor region 7 with respect to the depth position of the bottom wall of the source structure 20. The bottom portion of the outer contact region 44 is positioned at the bottom portion side of the second semiconductor region 7 with respect to the depth position of the bottom wall of the dummy structure 25.

The bottom portion of the outer contact region 44 is formed at an interval toward the second surface portion 72 side from the depth position of the bottom portion of at least one type of the well region 30 (at least one of the gate well region 30g, the source well region 30s, and the dummy well region 30d).

The bottom portion of the outer contact region 44 may be positioned at the bottom portion side of the second semiconductor region 7 with respect to the depth position of the bottom portion of at least one type of the well region 30. The bottom portion of the outer contact region 44 may be positioned at the depth position substantially equal to the bottom portion of at least one type of the well region 30.

The bottom portion of the outer contact region 44 may be positioned at the bottom portion side of the second semiconductor region 7 from a depth position of the bottom portion of at least one type of the contact region 31 (at least one of the gate contact region 31g, the source contact region 31s, and the dummy contact region 31d).

The bottom portion of the outer contact region 44 may be formed at an interval toward the second surface portion 72 side from a depth position of the bottom portion of the at least one type of contact region 31. Other descriptions of the outer contact region 44 related to the semiconductor device 1D are the same as in the case of the outer contact region 44 related to the semiconductor device 1A.

As in the case of the semiconductor device 1A, the first outer peripheral structure 41 includes the p-type terminal region 45 formed in the surface layer portion of the first main surface 3 in the outer peripheral region 9. In this embodiment, the terminal region 45 is formed in the surface layer portion of the second surface portion 72.

Specifically, the terminal region 45 is formed in a region between the peripheral edge (the first to fourth connecting surface portions 73A to 73D) of the first surface portion 71 and the peripheral edge (the first to fourth side surfaces 5A to 5D) of the second surface portion 72 in the surface layer portion of the second surface portion 72. More specifically, the terminal region 45 is formed in a region between the peripheral edge of the first surface portion 71 and the outer well region 43.

The terminal region 45 extends in a band shape along the peripheral edge of the first surface portion 71 in plan view. In this embodiment, the terminal region 45 is formed in a polygonal annular shape (in this embodiment, a quadrilateral annular shape) having four sides parallel to the peripheral edge of the first surface portion 71 in plan view, and surrounds the first surface portion 71. The terminal region 45 may have an edge portion that connects a portion extending in the first direction X and a portion extending in the second direction Y in an arc shape (preferably, a quarter arc shape).

As a matter of course, the terminal region 45 may each have a plurality of portions that are aligned at intervals along the first surface portion 71 so as to surround the first surface portion 71. In this case, the plurality of portions may each extend in a band shape along the first surface portion 71. The terminal region 45 preferably has a width greater than the width of the outer well region 43. As a matter of course, the width of the terminal region 45 may be less than the width of the outer well region 43.

The terminal region 45 is formed in the surface layer portion of the second semiconductor region 7 on the second surface portion 72, and is electrically connected to the second semiconductor region 7. The terminal region 45 is formed at an interval toward the second surface portion 72 side from the bottom portion of the second semiconductor region 7, and faces the first semiconductor region 6 with a portion of the second semiconductor region 7 interposed therebetween.

The terminal region 45 is formed at an interval from the second surface portion 72 in the thickness direction of the chip 2. That is, the terminal region 45 has a portion that is formed at an interval toward the bottom portion side of the second semiconductor region 7 from the second surface portion 72 and faces the second surface portion 72 with a portion of the second semiconductor region 7 interposed therebetween.

The terminal region 45 has an upper end portion positioned at the second surface portion 72 side and a bottom portion positioned at the bottom portion side of the second semiconductor region 7. The upper end portion of the terminal region 45 extends in the horizontal direction along the second surface portion 72 and forms a pn junction portion with the second semiconductor region 7.

The upper end portion of the terminal region 45 may be positioned at the second surface portion 72 side with respect to the depth position of the bottom portion of the outer well region 43. The upper end portion of the terminal region 45 may be positioned at the bottom portion side of the second semiconductor region 7 with respect to the depth position of the bottom portion of the outer well region 43.

The upper end portion of the terminal region 45 is positioned at the bottom portion side of the second semiconductor region 7 with respect to the depth position of the bottom wall of the gate structure 15. The upper end portion of the terminal region 45 is positioned at the bottom portion side of the second semiconductor region 7 with respect to the depth position of the bottom wall of the source structure 20. The upper end portion of the terminal region 45 is positioned at the bottom portion side of the second semiconductor region 7 with respect to the depth position of the bottom wall of the dummy structure 25.

The upper end portion of the terminal region 45 may be positioned at the second surface portion 72 side with respect to the depth position of the bottom portion of at least one type of the well region 30 (at least one of the gate well region 30g, the source well region 30s, and the dummy well region 30d). The upper end portion of the terminal region 45 may be positioned at the bottom portion side of the second semiconductor region 7 with respect to the depth position of the bottom portion of at least one type of the well region 30.

The bottom portion of the terminal region 45 extends in the horizontal direction along the second surface portion 72 and forms a pn junction portion with the second semiconductor region 7. The bottom portion of the terminal region 45 may be positioned at the bottom portion side of the second semiconductor region 7 with respect to the depth position of the bottom portion of the outer well region 43, or may be positioned at the second surface portion 72 side. As a matter of course, the bottom portion of the terminal region 45 may be positioned at the depth position substantially equal to the bottom portion of the outer well region 43.

The bottom portion of the terminal region 45 is positioned at the bottom portion side of the second semiconductor region 7 with respect to the depth position of the bottom wall of the gate structure 15. The bottom portion of the terminal region 45 is positioned at the bottom portion side of the second semiconductor region 7 with respect to the depth position of the bottom wall of the source structure 20. The bottom portion of the terminal region 45 is positioned at the bottom portion side of the second semiconductor region 7 with respect to the depth position of the bottom wall of the dummy structure 25.

The bottom portion of the terminal region 45 may be positioned at the second surface portion 72 side with respect to the depth position of the bottom portion of at least one type of the well region 30. The bottom portion of the terminal region 45 may be positioned at the bottom portion side of the second semiconductor region 7 with respect to the depth position of the bottom portion of at least one type of the well region 30.

The terminal region 45 may have a depth (thickness) greater than a distance between the second surface portion 72 and the terminal region 45. The depth of the terminal region 45 is the distance between the upper end portion and the bottom portion of the terminal region 45. The depth of the terminal region 45 may be smaller than the distance between the second surface portion 72 and the terminal region 45.

The depth of the terminal region 45 may be smaller than the distance between the bottom portion of the second semiconductor region 7 and the terminal region 45. The depth of the terminal region 45 may be greater than the distance between the bottom portion of the second semiconductor region 7 and the terminal region 45. The depth of the terminal region 45 is preferably less than the depth of the outer well region 43. The depth of the terminal region 45 may be greater than the depth of the outer well region 43.

The terminal region 45 has an inner edge portion on the first surface portion 71 side and an outer edge portion on the peripheral edge side of the second surface portion 72. The inner edge portion of the terminal region 45 is connected to the outer edge portion of the outer well region 43. Specifically, the inner edge portion of the terminal region 45 is connected to the outer edge portion of the outer well region 43 in a region on the bottom portion side of the outer well region 43. In this embodiment, the terminal region 45 is electrically connected to the body region 10 and the outer contact region 44 via the outer well region 43 and the dummy well region 30d.

The inner edge portion of the terminal region 45 may be formed at an interval toward the outer edge portion side of the outer well region 43 from the outer edge portion of the outer contact region 44. The inner edge portion of the terminal region 45 may be positioned at the inner edge portion side of the outer well region 43 with respect to the outer edge portion of the outer contact region 44.

The inner edge portion of the terminal region 45 may be formed at an interval toward the bottom portion side of the outer well region 43 from the bottom portion of the outer contact region 44, and may face the outer contact region 44 with a portion of the outer well region 43 interposed therebetween. The inner edge portion of the terminal region 45 may be connected to the outer contact region 44.

The inner edge portion of the terminal region 45 may be formed at an interval toward the outer edge portion side of the outer well region 43 from the inner edge portion of the outer well region 43. The inner edge portion of the terminal region 45 may be formed at an interval toward the outer edge portion side of the outer well region 43 from the peripheral edge (the first to fourth connecting surface portions 73A to 73D) of the first surface portion 71.

As a matter of course, as with the outer well region 43, the inner edge portion of the terminal region 45 may be connected to the dummy well region 30d. Other descriptions of the terminal region 45 related to the semiconductor device 1D are the same as in the case of the terminal region 45 related to the semiconductor device 1A.

As in the case of the semiconductor device 1A, the second outer peripheral structure 42 includes at least one (in this embodiment, a plurality) of the p-type field regions 47 formed in the surface layer portion of the first main surface 3 in the outer peripheral region 9.

In this embodiment, the plurality of field regions 47 are formed in the surface layer portion of the second surface portion 72. The plurality of field regions 47 are formed in regions between the peripheral edge (the first to fourth connecting surface portions 73A to 73D) of the first surface portion 71 and the peripheral edge (the first to fourth side surfaces 5A to 5D) of the second surface portion 72 in the surface layer portion of the second surface portion 72.

Specifically, the plurality of field regions 47 are formed in regions between the peripheral edge of the second surface portion 72 and the outer well region 43 at an interval from the peripheral edge of the second surface portion 72 and the outer well region 43. More specifically, the plurality of field regions 47 are formed in regions between the peripheral edge of the second surface portion 72 and the terminal region 45 at an interval from the peripheral edge of the second surface portion 72 and the terminal region 45.

The plurality of field regions 47 are formed in the surface layer portion of the second semiconductor region 7 at intervals from each other, and are electrically connected to the second semiconductor region 7. The plurality of field regions 47 are formed at intervals toward the second surface portion 72 side from the bottom portion of the second semiconductor region 7, and face the first semiconductor region 6 with a portion of the second semiconductor region 7 interposed therebetween.

The plurality of field regions 47 are formed at intervals in the thickness direction of the chip 2 from the second surface portion 72. That is, each of the plurality of field regions 47 has a portion that is formed at intervals toward the bottom portion side of the second semiconductor region 7 from the second surface portion 72 and faces the second surface portion 72 with a portion of the second semiconductor region 7 interposed therebetween. The plurality of field regions 47 are each formed in the depth range between the upper end portion and the bottom portion of the terminal region 45, and face the terminal region 45 in the horizontal direction.

A distance between the second surface portion 72 and the field region 47 is preferably substantially equal to the distance between the second surface portion 72 and the terminal region 45. As a matter of course, the distance between the second surface portion 72 and the field region 47 may be greater than the distance between the second surface portion 72 and the terminal region 45, or may be smaller than the distance between the second surface portion 72 and the terminal region 45.

The plurality of field regions 47 extend in a band shape along the peripheral edge of the first surface portion 71 in plan view. In this embodiment, the plurality of field regions 47 are formed in a polygonal annular shape (in this embodiment, a quadrilateral annular shape) having four sides parallel to the peripheral edge of the first surface portion 71 in plan view, and surround the first surface portion 71.

The plurality of field regions 47 may have an edge portion that connects a portion extending in the first direction X and a portion extending in the second direction Y in an arc shape (preferably, a quarter arc shape). As a matter of course, the plurality of field regions 47 may each have a plurality of portions that are aligned at intervals along the peripheral edge of the first surface portion 71 so as to surround the first surface portion 71. In this case, the plurality of portions may each extend in a band shape along the peripheral edge of the first surface portion 71. Each of the plurality of field regions 47 has a width less than the width of the terminal region 45.

Each of the plurality of field regions 47 has an upper end portion positioned at the second surface portion 72 side and a bottom portion positioned at the bottom portion side of the second semiconductor region 7. The upper end portions of the plurality of field regions 47 extend in the horizontal direction along the second surface portion 72 and form a pn junction portion with the second semiconductor region 7.

The upper end portions of the plurality of field regions 47 may be positioned at the second surface portion 72 side with respect to the depth position of the bottom portion of the outer well region 43. The upper end portions of the plurality of field regions 47 may be positioned at the bottom portion side of the second semiconductor region 7 with respect to the depth position of the bottom portion of the outer well region 43.

The upper end portions of the plurality of field regions 47 are positioned at the bottom portion side of the second semiconductor region 7 with respect to the depth position of the bottom wall of the gate structure 15. The upper end portions of the plurality of field regions 47 are positioned at the bottom portion side of the second semiconductor region 7 with respect to the depth position of the bottom wall of the source structure 20. The upper end portions of the plurality of field regions 47 are positioned at the bottom portion side of the second semiconductor region 7 with respect to the depth position of the bottom wall of the dummy structure 25.

The upper end portions of the plurality of field regions 47 may be positioned at the second surface portion 72 side with respect to the depth position of the bottom portion of at least one type of the well region 30 (at least one of the gate well region 30g, the source well region 30s, and the dummy well region 30d). The upper end portions of the plurality of field regions 47 may be positioned at the bottom portion side of the second semiconductor region 7 with respect to the depth position of the bottom portion of at least one type of the well region 30.

The bottom portions of the plurality of field regions 47 extend in the horizontal direction along the second surface portion 72 and form a pn junction portion with the second semiconductor region 7. The bottom portions of the plurality of field regions 47 may be positioned at the bottom portion side of the second semiconductor region 7 with respect to the depth position of the bottom portion of the outer well region 43, or may be positioned at the second surface portion 72 side. As a matter of course, the bottom portions of the plurality of field regions 47 may be positioned at the depth position substantially equal to the bottom portion of the outer well region 43.

The bottom portions of the plurality of field regions 47 are positioned at the bottom portion side of the second semiconductor region 7 with respect to the depth position of the bottom wall of the gate structure 15. The bottom portions of the plurality of field regions 47 are positioned at the bottom portion side of the second semiconductor region 7 with respect to the depth position of the bottom wall of the source structure 20. The bottom portions of the plurality of field regions 47 are positioned at the bottom portion side of the second semiconductor region 7 with respect to the depth position of the bottom wall of the dummy structure 25.

The bottom portions of the plurality of field regions 47 may be positioned at the second surface portion 72 side with respect to the depth position of the bottom portion of at least one type of the well region 30. The bottom portions of the plurality of field regions 47 may be positioned at the bottom portion side of the second semiconductor region 7 with respect to the depth position of the bottom portion of at least one type of the well region 30.

The field region 47 may have a depth (thickness) that is substantially equal to the depth (thickness) of the terminal region 45. The depth of the field region 47 is the distance between the upper end portion and bottom portion of the field region 47. As a matter of course, the depth of the field region 47 may be greater than the depth of the terminal region 45 or smaller than the depth of the terminal region 45.

The depth of the field region 47 may be greater than the distance between the second surface portion 72 and the field region 47. The depth of the field region 47 may be smaller than the distance between the second surface portion 72 and the field region 47.

The depth of the field region 47 may be smaller than the distance between the bottom portion of the second semiconductor region 7 and the field region 47. The depth of the field region 47 may be greater than the distance between the bottom portion of the second semiconductor region 7 and the field region 47. Other descriptions of the field region 47 related to the semiconductor device 1D are the same as in the case of the field region 47 related to the semiconductor device 1A.

As in the case of the semiconductor device 1A, the semiconductor device 1D includes the main surface insulating film 50 that selectively covers the first main surface 3. In this embodiment, the main surface insulating film 50 selectively covers the first surface portion 71, the second surface portion 72, and the first to fourth connecting surface portions 73A to 73D.

The main surface insulating film 50 is selectively connected to the first insulating films 17 of the plurality of gate structures 15, the second insulating films 22 of the plurality of source structures 20, and the third insulating films 27 of the plurality of dummy structures 25 in the first surface portion 71, and exposes the first embedded electrodes 18 of the plurality of gate structures 15, the second embedded electrodes 23 of the plurality of source structures 20, and the third embedded electrodes 28 of the plurality of dummy structures 25.

The main surface insulating film 50 covers the second semiconductor region 7, the outer well region 43, and the outer contact region 44 on the second surface portion 72. In this embodiment, the main surface insulating film 50 is continuous to the first to fourth side surfaces 5A to 5D in the peripheral edge portion of the second surface portion 72.

As a matter of course, the main surface insulating film 50 may be formed at an interval inward from the peripheral edge of the second surface portion 72 and expose the peripheral edge portion (the second semiconductor region 7) of the second surface portion 72. The main surface insulating film 50 covers the inner edge portions of the body region 10, the source region 11, and the outer well region 43 in the first to fourth connecting surface portions 73A to 73D.

As in the case of the semiconductor device 1A, the semiconductor device 1D includes the outer wiring 51 arranged on the main surface insulating film 50 in the outer peripheral region 9. In this embodiment, the outer wiring 51 is formed as a side wall wiring that covers at least one (in this embodiment, all) of the first to fourth connecting surface portions 73A to 73D on the second surface portion 72.

The outer wiring 51 is arranged at an interval toward the first surface portion 71 side from the peripheral edge of the second surface portion 72. Specifically, the outer wiring 51 is arranged at an interval toward the first surface portion 71 side from the outer edge portion of the terminal region 45.

More specifically, the outer wiring 51 is arranged at an interval toward the first surface portion 71 side from the outer edge portion of the outer well region 43, and faces the outer well region 43 with the main surface insulating film 50 interposed therebetween. In this embodiment, the outer wiring 51 faces the outer contact region 44 with the main surface insulating film 50 interposed therebetween. The outer wiring 51 may have a portion that faces the terminal region 45 in the lamination direction.

In this embodiment, the outer wiring 51 is formed in a polygonal annular shape (specifically, a quadrilateral annular shape) extending along the peripheral edge (the first to fourth connecting surface portions 73A to 73D) of the first surface portion 71 in conformance to the outer contact region 44 in plan view, and surrounds the first surface portion 71.

The outer wiring 51 may have an edge portion may have an edge portion that connects a portion extending in the first direction X and a portion extending in the second direction Y in an arc shape (preferably, a quarter arc shape). The outer wiring 51 may be a shape with ends or an endless shape.

The outer wiring 51 includes an outer edge portion extending in a film shape along the second surface portion 72, an intermediate portion extending in a film shape along the first to fourth connecting surface portions 73A to 73D, and an inner edge portion extending in a film shape along the first surface portion 71. The outer edge portion of the outer wiring 51 may have a thickness less than the depth of the second surface portion 72, and cover the second surface portion 72 in a film shape in a region on the second surface portion 72 side with respect to the height position of the first surface portion 71.

The outer edge portion of the outer wiring 51 is formed at an interval toward the first surface portion 71 side from the innermost field region 47 among the plurality of field regions 47. That is, the outer edge portion of the outer wiring 51 does not face the plurality of field regions 47 with the main surface insulating film 50 interposed therebetween. The outer edge portion of the outer wiring 51 is formed at an interval toward the first surface portion 71 side from the outer edge portion of the terminal region 45.

In this embodiment, the outer wiring 51 has a portion that is arranged at an interval toward the first surface portion 71 side from the outer edge portion of the outer contact region 44 and that faces the outer contact region 44 with the main surface insulating film 50 interposed therebetween. The outer wiring 51 may have a portion that faces the terminal region 45 in the lamination direction.

The intermediate portion of the outer wiring 51 covers the first to fourth connecting surface portions 73A to 73D. The outer wiring 51 thereby functions as a “side wall structure (side wall wiring)” that moderates the level difference between the first surface portion 71 and the second surface portion 72.

The intermediate portion of the outer wiring 51 may cover the first to fourth connecting surface portions 73A to 73D in a film shape in conformance to the inclination angles of the first to fourth connecting surface portions 73A to 73D. The intermediate portion of the outer wiring 51 covers the inner edge portions of the body region 10, the source region 11, and the outer well region 43 with the main surface insulating film 50 interposed therebetween.

The inner edge portion of the outer wiring 51 overlaps onto the first surface portion 71 from at least one (in this embodiment, all) of the first to fourth connecting surface portions 73A to 73D, and extends in a band shape along the edge portion of the first surface portion 71. In this embodiment, the inner edge portion of the outer wiring 51 is formed in a polygonal annular shape (specifically, a quadrilateral annular shape) surrounding the inner portion of the first surface portion 71.

The inner edge portion of the outer wiring 51 covers one or a plurality (in this embodiment, one) of the dummy structures 25 among the plurality of dummy structures 25. The inner edge portion of the outer wiring 51 is connected to the third embedded electrode 28 of the dummy structure 25. Specifically, the outer wiring 51 is integrally formed with the third embedded electrode 28 of the dummy structure 25. That is, the outer wiring 51 is formed as a lead-out portion in which a part of the third embedded electrode 28 is led out onto the main surface insulating film 50.

As in the case of the semiconductor device 1A, the semiconductor device 1D includes the interlayer film 52 that selectively covers the first main surface 3 with the main surface insulating film 50 interposed therebetween. The interlayer film 52 covers the plurality of gate structures 15 (the first embedded electrodes 18) and the plurality of dummy structures 25 (the third embedded electrodes 28) on the first surface portion 71 side. The interlayer film 52 covers the second semiconductor region 7, the outer well region 43, and the outer contact region 44 with the main surface insulating film 50 interposed therebetween on the second surface portion 72 side.

In this embodiment, the interlayer film 52 is continuous to the first to fourth side surfaces 5A to 5D in the peripheral edge portion of the second surface portion 72. As a matter of course, the interlayer film 52 may be formed at an interval inward from the peripheral edge of the second surface portion 72 and expose the peripheral edge portion (the second semiconductor region 7) of the second surface portion 72. The interlayer film 52 covers the first to fourth connecting surface portions 73A to 73D with the outer wiring 51 interposed therebetween.

As in the case of the semiconductor device 1A, the semiconductor device 1D includes the plurality of source openings 53, at least one (in this embodiment, one) of the outer openings 54, and at least one (in this embodiment, a plurality) of the gate openings 55 formed in the interlayer film 52.

The plurality of source openings 53 are formed on the first surface portion 71 side in the same manner as in the semiconductor device 1A, and expose the source region 11 and the plurality of contact regions 31. The outer opening 54 is formed on the second surface portion 72 side in the same manner as in the semiconductor device 1A, and exposes the outer edge portion of the outer wiring 51 and the outer contact region 44.

The plurality of gate openings 55 are formed on the first surface portion 71 side in the same manner as in the semiconductor device 1A, and expose one end portion or the other end portion of the plurality of gate structures 15 (the first embedded electrodes 18).

As in the case of the semiconductor device 1A, the semiconductor device 1D includes the source electrode 60 arranged on the first main surface 3. The source electrode 60 is arranged on a portion of the interlayer film 52 that covers the first surface portion 71. The source electrode 60 enters the plurality of source openings 53 from above the interlayer film 52, and is electrically connected to the source region 11 and the plurality of contact regions 31 in the plurality of source openings 53.

As in the case of the semiconductor device 1A, the source electrode 60 has a laminated structure including the lower electrode film 61 and the main electrode film 62 laminated in that order from the chip 2 side. The lower electrode film 61 has a laminated structure including the first electrode film 63 and the second electrode film 64. Other descriptions of the source electrode 60 related to the semiconductor device 1D are the same as in the case of the source electrode 60 related to the semiconductor device 1A.

As in the case of the semiconductor device 1A, the semiconductor device 1D includes the terminal wiring 65 arranged around the source electrode 60 on the interlayer film 52. As in the case of the semiconductor device 1A, the terminal wiring 65 has a laminated structure including the lower electrode film 61 and the main electrode film 62 laminated in that order from the chip 2 side. The lower electrode film 61 has a laminated structure including the first electrode film 63 and the second electrode film 64.

In this embodiment, the terminal wiring 65 is led out from the source electrode 60 (the first pad portion 60a) to the fourth connecting surface portion 73D side, and is selectively routed on the interlayer film 52. The terminal wiring 65 has a wiring width less than the electrode width of source electrode 60. In this embodiment, the terminal wiring 65 covers the peripheral edge portion of the first surface portion 71 at an interval from the source electrode 60, and extends in a band shape along at least one (in this embodiment, all) of the first to fourth connecting surface portions 73A to 73D.

In this embodiment, the terminal wiring 65 is formed in a polygonal annular shape (specifically, a quadrilateral annular shape) extending along the first to fourth connecting surface portions 73A to 73D in plan view, and surrounds the source electrode 60. The terminal wiring 65 may have an edge portion that connects a portion extending in the first direction X and a portion extending in the second direction Y in an arc shape (preferably, a quarter arc shape). The outer wiring 51 may be a shape with ends or an endless shape.

The terminal wiring 65 has a portion that is led out from the first surface portion 71 (the active region 8) side to the second surface portion 72 (the outer peripheral region 9) side across at least one (in this embodiment, all) of the first to fourth connecting surface portions 73A to 73D and that faces the outer wiring 51 with the interlayer film 52 interposed therebetween. In this embodiment, the terminal wiring 65 covers the outer wiring 51 across an entire periphery.

The terminal wiring 65 enters the outer opening 54 from above the interlayer film 52, and is electrically connected to the outer contact region 44 and the outer wiring 51 in the outer opening 54.

That is, the terminal wiring 65 is electrically connected to the terminal region 45 via the outer contact region 44, and is electrically connected to one or a plurality (in this embodiment, one) of the dummy structures 25 (the third embedded electrodes 28) via the outer wiring 51. The source potential applied to the source electrode 60 is applied to the terminal region 45 via the terminal wiring 65, and simultaneously applied to the dummy structure 25 via the terminal wiring 65.

The terminal wiring 65 has an inner edge portion on the first surface portion 71 side and an outer edge portion on the second surface portion 72 side. The inner edge portion of the terminal wiring 65 is positioned on the first surface portion 71 and faces the plurality of dummy structures 25 with the interlayer film 52 interposed therebetween.

The outer edge portion of the terminal wiring 65 is formed at an interval inward from the peripheral edge of the second surface portion 72. The outer edge portion of the terminal wiring 65 is formed at an interval inward from the innermost field region 47 among the plurality of field regions 47. That is, the terminal wiring 65 does not face the plurality of field regions 47 via the interlayer film 52 interposed therebetween. The outer edge portion of the terminal wiring 65 is formed at an interval inward from the outer edge portion of the terminal region 45, and faces the terminal region 45 with the interlayer film 52 interposed therebetween.

The outer edge portion of the terminal wiring 65 is formed at an interval toward the peripheral edge side of the second surface portion 72 from the outer edge portion of the outer well region 43. That is, the terminal wiring 65 covers the entire outer well region 43. Other descriptions of the terminal wiring 65 related to the semiconductor device 1D are the same as in the case of the terminal wiring 65 related to the semiconductor device 1A.

As in the case of the semiconductor device 1A, the semiconductor device 1D includes the gate electrode 66 arranged on the first main surface 3. The source electrode 60 is arranged on a portion of the interlayer film 52 that covers the first surface portion 71.

As in the case of the semiconductor device 1A, the gate electrode 66 has a laminated structure including the lower electrode film 61 and the main electrode film 62 laminated in that order from the chip 2 side. The lower electrode film 61 has a laminated structure including the first electrode film 63 and the second electrode film 64. Other descriptions of the gate electrode 66 related to the semiconductor device 1D are the same as in the case of the gate electrode 66 related to the semiconductor device 1A.

As in the case of the semiconductor device 1A, the semiconductor device 1D includes the gate wiring 67 led out from the gate electrode 66 onto the first main surface 3. In this embodiment, the gate wiring 67 is arranged on the first surface portion 71 inward at an interval from the peripheral edge of the first surface portion 71. Therefore, the gate wiring 67 is not positioned on the second surface portion 72.

As in the case of the semiconductor device 1A, the gate wiring 67 enters the plurality of gate openings 55 from above the interlayer film 52, and is mechanically and electrically connected to the end portions (the both end portions) of the plurality of gate structures 15 (the first embedded electrodes 18) in the plurality of gate openings 55. Other descriptions of the gate wiring 67 related to the semiconductor device 1D are the same as in the case of the gate wiring 67 related to the semiconductor device 1A.

As in the case of the semiconductor device 1A, the semiconductor device 1D includes the drain electrode 68 that covers the second main surface 4. The drain electrode 68 is electrically connected to the first semiconductor region 6. Other descriptions of the drain electrode 68 related to the semiconductor device 1D are the same as in the case of the drain electrode 68 related to the semiconductor device 1A.

The breakdown voltage that can be applied between the source electrode 60 and the drain electrode 68 (between the first main surface 3 and the second main surface 4) may be not less than 500 V and not more than 3000 V. The breakdown voltage may have a value belonging to at least one range among not less than 500 V and not more than 750 V, 750 V and not more than 1000 V, not less than 1000 V and not more than 1250 V, not less than 1250 V and not more than 1500 V, not less than 1500 V and not more than 1750 V, and 1750 V and not more than 2000 V, not less than 2000 V and not more than 2250 V, not less than 2250 V and not more than 2500 V, not less than 2500 V and not more than 2750 V, and not less than 2750 V and not more than 3000 V.

As in the case of the semiconductor device 1A, the semiconductor device 1D may include any one of the features of the first outer peripheral structures 41 according to the first to tenth modification examples with respect to the first outer peripheral structures 41 according to the first to fifth configuration examples (see also FIGS. 11A to 11J).

A specific arrangement in this case can be obtained by replacing “the inner portion (the active region 8) of the first main surface 3” with “the first surface portion 71 (the active region 8)” and replacing “the peripheral edge portion (the outer peripheral region 9) of the first main surface 3” with “the second surface portion 72 (the outer peripheral region 9)” in the description of the first outer peripheral structures 41 according to the first to tenth modification examples. Of course, the features of the first outer peripheral structures 41 according to the first to tenth modification examples can be combined therebetween as appropriate.

Therefore, with respect to the first outer peripheral structures 41 according to the first to fifth configuration examples, the semiconductor device 1D may simultaneously include at least two of the features of the first outer peripheral structures 41 according to the first to tenth modification examples in the same or different regions.

At least one feature of the outer well region 43, the outer contact region 44, and the terminal region 45 according to the first to tenth modification examples is selected as appropriate according to the configurations of the first to fifth configuration examples, and is applied to the configurations of the first to fifth configuration examples.

The semiconductor device 1D may include any one of the features of the second outer peripheral structures 42 according to the first to tenth modification examples with respect to the second outer peripheral structures 42 according to the first to fifth configuration examples (see also FIGS. 12A to 12J).

A specific arrangement in this case can be obtained by replacing “the inner portion (the active region 8) of the first main surface 3” with “the first surface portion 71 (the active region 8)” and replacing “the peripheral edge portion (the outer peripheral region 9) of the first main surface 3” with “the second surface portion 72 (the outer peripheral region 9)” in the description of the second outer peripheral structures 42 according to the first to tenth modification examples. Of course, the features of the second outer peripheral structures 42 according to the first to tenth modification examples can be combined therebetween as appropriate.

Therefore, with respect to the second outer peripheral structures 42 according to the first to fifth configuration examples, the semiconductor device 1D may simultaneously include at least two of the features of the second outer peripheral structures 42 according to the first to tenth modification examples in the same or different regions.

At least one feature of the field regions 47 according to the first to tenth modification examples is selected as appropriate according to the configurations of the first to fifth configuration examples, and is applied to the configurations of the first to fifth configuration examples.

The semiconductor device 1D may include one or a plurality of the features of the first outer peripheral structures 41 according to the first to tenth modification examples and one or a plurality of the features of the second outer peripheral structures 42 according to the first to tenth modification examples, together with the arrangement of any one of the first to fifth configuration examples.

As described above, the semiconductor device 1D may include the chip 2, the second semiconductor region 7 (the semiconductor region) of the n-type (the first conductivity type), and the terminal region 45 of the p-type (the second conductivity type). The chip 2 may have the first surface portion 71 and the second surface portion 72 recessed in the thickness direction with respect to the first surface portion 71. The second semiconductor region 7 may be formed in the surface layer portion of the second surface portion 72. The terminal region 45 may be formed in the surface layer portion of the second semiconductor region 7 at an interval from the second surface portion 72 in the thickness direction of the chip 2.

According to this arrangement, the semiconductor device 1D having a novel layout can be provided. For example, according to this semiconductor device 1D, the expansion range of the depletion layer can be adjusted by the terminal region 45 separated from the second surface portion 72. This layout is effective in improving the withstand voltage of the semiconductor device 1D.

The chip 2 may contain SiC. According to this arrangement, the semiconductor device 1D as an SiC semiconductor device having a novel layout can be provided. According to the SiC semiconductor device, the withstand voltage is further improved by the physical properties of SiC. In particular, in the case of the SiC semiconductor device, since the SiC semiconductor device is used under a relatively high voltage environment, the withstand voltage improvement effect by the terminal region 45 is effective.

The terminal region 45 may form a pn junction portion with the second semiconductor region 7. According to this arrangement, the depletion layer with the terminal region 45 as a starting point can be appropriately expanded. The terminal region 45 may face the second surface portion 72 with a portion of the second semiconductor region 7 interposed therebetween.

According to this arrangement, the terminal region 45 may have an upper end portion that forms the pn junction portion with the second semiconductor region 7. Therefore, the depletion layer with the terminal region 45 as a starting point can be expanded also to a portion of the second semiconductor region 7 positioned between the second surface portion 72 and the terminal region 45.

The terminal region 45 may have a thickness (depth) greater than the distance between the second surface portion 72 and the terminal region 45. According to this arrangement, the expansion range of the depletion layer can be adjusted by the terminal region 45 having a thickness greater than the distance between the second surface portion 72 and the terminal region 45.

The terminal region 45 may be formed at an interval toward the second surface portion 72 side from the bottom portion of the second semiconductor region 7. According to this arrangement, the expansion range of the depletion layer can be adjusted by the terminal region 45 separated from the bottom portion of the second semiconductor region 7.

The terminal region 45 may have a thickness (depth) less than the distance between the bottom portion of the second semiconductor region 7 and the terminal region 45. According to this arrangement, the expansion range of the depletion layer can be adjusted by the terminal region 45 having the thickness less than the distance between the bottom portion of the second semiconductor region 7 and the terminal region 45.

The terminal region 45 may extend in a band shape along the first surface portion 71 in plan view. According to this arrangement, the withstand voltage of the semiconductor device 1D can be improved by the terminal region 45 extending in a band shape along the first surface portion 71. The terminal region 45 may surround the first surface portion 71 in plan view. According to this arrangement, the withstand voltage of the semiconductor device 1D can be improved by the terminal region 45 surrounding the first surface portion 71.

The semiconductor device 1D may include the p-type outer well region 43. The outer well region 43 may be formed in the surface layer portion of the second surface portion 72. In this case, the terminal region 45 may be formed in a region between the peripheral edge of the second surface portion 72 and the outer well region 43.

According to this arrangement, the depletion layer expands with the outer well region 43 as a starting point on the first surface portion 71 side, and at the same time, the depletion layer expands with the terminal region 45 as a starting point on the peripheral edge portion side of the second surface portion 72. The withstand voltage of the semiconductor device 1D can thereby be improved.

The terminal region 45 may be connected to the outer well region 43. According to this arrangement, the depletion layer expanded with the terminal region 45 as the starting point can be integrated with a depletion layer expanded with the outer well region 43 as a starting point. The discontinuity of the depletion layer in the chip 2 is thereby reduced, and the withstand voltage of the semiconductor device 1D can be improved.

The terminal region 45 may have a bottom portion positioned below with respect to the depth position of the bottom portion of the outer well region 43. According to this arrangement, the expansion range of the depletion layer can be adjusted by the terminal region 45 having the bottom portion positioned below the bottom portion of the outer well region 43. This layout is effective in improving the withstand voltage of the semiconductor device 1D.

The semiconductor device 1D may include the p-type outer contact region 44. The outer contact region 44 is formed in the surface layer portion of the outer well region 43 on the second surface portion 72 side, and may have a p-type impurity concentration higher than the p-type impurity concentration of the outer well region 43. According to this arrangement, the electrical response speed of the outer well region 43 is improved by the outer contact region 44.

The semiconductor device 1D may include the interlayer film 52 (the insulating film) that covers the second surface portion 72. The semiconductor device 1D may include the outer opening 54 (the contact opening) formed in the interlayer film 52 so as to expose the outer contact region 44.

In this case, the terminal wiring 65 may be arranged on the interlayer film 52 and electrically connected to the outer contact region 44 via the outer opening 54. According to this arrangement, the terminal wiring 65 can be appropriately electrically connected to the outer contact region 44.

The semiconductor device 1D may include the first trench 16 formed in the first surface portion 71. In this case, the bottom portion of the terminal region 45 may be positioned below a depth position of the bottom wall of the first trench 16.

According to this arrangement, the withstand voltage of the semiconductor device 1D can be improved by the terminal region 45 having the bottom portion positioned below the depth position of the bottom wall of the first trench 16. The first trench 16 may have a depth not more than the depth of the second surface portion 72.

The semiconductor device 1D may include the second trench 21 formed in the first surface portion 71. In this case, the bottom portion of the terminal region 45 may be positioned below a depth position of the bottom wall of the second trench 21.

According to this arrangement, the withstand voltage of the semiconductor device 1D can be improved by the terminal region 45 having the bottom portion positioned below the depth position of the bottom wall of the second trench 21. The second trench 21 may have a depth not more than the depth of the second surface portion 72.

The semiconductor device 1D may include the third trench 26 formed in the first surface portion 71. In this case, the bottom portion of the terminal region 45 may be positioned below a depth position of the bottom wall of the first trench 16.

According to this arrangement, the withstand voltage of the semiconductor device 1D can be improved by the terminal region 45 having a bottom portion positioned below a depth position of the bottom wall of the third trench 26. The third trench 26 may have a depth not more than the depth of the second surface portion 72.

The semiconductor device 1D may include the p-type field region 47. The field region 47 may be formed in the surface layer portion of the second semiconductor region 7 in a region between the peripheral edge of the second surface portion 72 and the terminal region 45.

According to this arrangement, the depletion layer expands with the terminal region 45 as a starting point on the first surface portion 71 side, and at the same time, the depletion layer expands with the field region 47 as a starting point on the peripheral edge side of the second surface portion 72. The withstand voltage of the semiconductor device 1D can thereby be improved.

From another viewpoint, the semiconductor device 1D may include the chip 2, the second semiconductor region 7 (the semiconductor region) of the n-type (the first conductivity type), and the field region 47 of the p-type (the second conductivity type). The chip 2 may have the first surface portion 71 and the second surface portion 72 recessed in the thickness direction with respect to the first surface portion 71. The second semiconductor region 7 may be formed in the surface layer portion of the second surface portion 72. The field region 47 may be formed in the surface layer portion of the second semiconductor region 7 at an interval from the second surface portion 72 in the thickness direction of the chip 2.

According to this arrangement, the semiconductor device 1D having a novel layout can be provided. For example, according to this semiconductor device 1D, the expansion range of the depletion layer can be adjusted by the field region 47 separated from the second surface portion 72. This layout is effective in improving the withstand voltage of the semiconductor device 1D.

The chip 2 may contain SiC. According to this arrangement, the semiconductor device 1D as an SiC semiconductor device having a novel layout can be provided. According to the SiC semiconductor device, the withstand voltage is further improved by the physical properties of SiC. In particular, in the case of the SiC semiconductor device, since the SiC semiconductor device is used under a relatively high voltage environment, the withstand voltage improvement effect using the field region 47 is effective.

The field region 47 may form a pn junction portion with the second semiconductor region 7. According to this arrangement, the depletion layer with the field region 47 as a starting point can be appropriately expanded. The field region 47 may face the second surface portion 72 with a portion of the second semiconductor region 7 interposed therebetween. According to this arrangement, the depletion layer with the field region 47 as a starting point is expanded also to a portion of the second semiconductor region 7 positioned between the second surface portion 72 and the field region 47.

The field region 47 may have a thickness (depth) greater than the distance between the second surface portion 72 and the field region 47. According to this arrangement, the expansion range of the depletion layer can be adjusted by the field region 47 having a thickness greater than the distance between the second surface portion 72 and the field region 47.

The field region 47 may be formed at an interval toward the second surface portion 72 side from the bottom portion of the second semiconductor region 7. According to this arrangement, the expansion range of the depletion layer can be adjusted by the field region 47 separated from the bottom portion of the second semiconductor region 7.

The field region 47 may have a thickness (depth) less than the distance between the bottom portion of the second semiconductor region 7 and the field region 47. According to this arrangement, the expansion range of the depletion layer can be adjusted by the field region 47 having the thickness less than the distance between the bottom portion of the second semiconductor region 7 and the field region 47.

The field region 47 may extend in a band shape along the first surface portion 71 in plan view. According to this arrangement, the withstand voltage of the semiconductor device 1D can be improved by the field region 47 extending in a band shape along the first surface portion 71. The field region 47 may surround the first surface portion 71 in plan view. According to this arrangement, the withstand voltage of the semiconductor device 1D can be improved by the field region 47 surrounding the first surface portion 71.

The plurality of field regions 47 may be formed at intervals in the surface layer portion of the second semiconductor region 7. According to this arrangement, the withstand voltage of the semiconductor device 1D can be improved by the plurality of field regions 47. The plurality of field regions 47 may have mutually equal depths. According to this arrangement, the withstand voltage of the semiconductor device 1D can be improved by the plurality of field regions 47 having the mutually equal depths.

The semiconductor device 1D may include the first trench 16 formed in the first surface portion 71. In this case, the bottom portion of the field region 47 may be positioned below the depth position of the bottom wall of the first trench 16.

According to this arrangement, the withstand voltage of the semiconductor device 1D can be improved by the field region 47 having the bottom portion positioned below the depth position of the bottom wall of the first trench 16. The first trench 16 may have a depth not more than the depth of the second surface portion 72.

The semiconductor device 1D may include the second trench 21 formed in the first surface portion 71. In this case, the bottom portion of the field region 47 may be positioned below the depth position of the bottom wall of the second trench 21.

According to this arrangement, the withstand voltage of the semiconductor device 1D can be improved by the field region 47 having the bottom portion positioned below the depth position of the bottom wall of the second trench 21. The second trench 21 may have a depth not more than the depth of the second surface portion 72.

The semiconductor device 1D may include the third trench 26 formed in the first surface portion 71. In this case, the bottom portion of the field region 47 may be positioned below the depth position of the bottom wall of the third trench 26.

According to this arrangement, the withstand voltage of the semiconductor device 1D can be improved by the field region 47 having the bottom portion positioned below the depth position of the bottom wall of the third trench 26. The third trench 26 may have a depth not more than the depth of the second surface portion 72.

The semiconductor device 1D may include the p-type terminal region 45 formed in the surface layer portion of the second semiconductor region 7 in the second surface portion 72. In this case, the field region 47 may be formed in a region between the peripheral edge of the second surface portion 72 and the terminal region 45.

According to this arrangement, the depletion layer expands with the terminal region 45 as a starting point on the first surface portion 71 side, and at the same time, the depletion layer expands with the field region 47 as a starting point on the peripheral edge side of the second surface portion 72. The withstand voltage of the semiconductor device 1D can thereby be improved.

The terminal region 45 may be formed at an interval from the second surface portion 72 in the thickness direction of the chip 2. According to the semiconductor device 1D, the expansion range of the depletion layer can be adjusted by the terminal region 45 separated from the second surface portion 72. The field region 47 may be formed to be narrower in width than the terminal region 45. According to this arrangement, the withstand voltage of the semiconductor device 1D can be improved by the field region 47 narrower in width than the terminal region 45.

The semiconductor device 1D may include terminal wiring 65 arranged on second surface portion 72 and electrically connected to terminal region 45. According to this arrangement, a predetermined terminal voltage (a source voltage) is applied to the terminal region 45 via the terminal wiring 65. The electrical response characteristics of the terminal region 45 can thereby be improved.

The semiconductor device 1D may include the p-type outer well region 43. The outer well region 43 may be formed in the surface layer portion of the second surface portion 72. In this case, the terminal region 45 may be formed in a region between the peripheral edge of the second surface portion 72 and the outer well region 43.

According to this arrangement, the depletion layer expands with the outer well region 43 as a starting point on the first surface portion 71 side, and at the same time, the depletion layer expands with the terminal region 45 and the field region 47 as starting points on the peripheral edge portion side of the second surface portion 72. The withstand voltage of the semiconductor device 1D can thereby be improved.

The semiconductor device 1D may include the p-type outer contact region 44. The outer contact region 44 is formed in the surface layer portion of the outer well region 43 on the second surface portion 72 side, and may have a p-type impurity concentration higher than the p-type impurity concentration of the outer well region 43. According to this arrangement, the electrical response speed of the outer well region 43 is improved by the outer contact region 44.

The semiconductor device 1D may include the terminal wiring 65 (the terminal electrode) arranged on the second surface portion 72 and electrically connected to the outer well region 43. According to this arrangement, a predetermined terminal potential is to be applied to the outer well region 43. Electrical response characteristics of the outer well region 43 can thereby be improved by the terminal wiring 65. The terminal potential may be the reference potential serving as a reference of circuit operation. The reference potential may be the ground potential. The terminal potential may be the source potential.

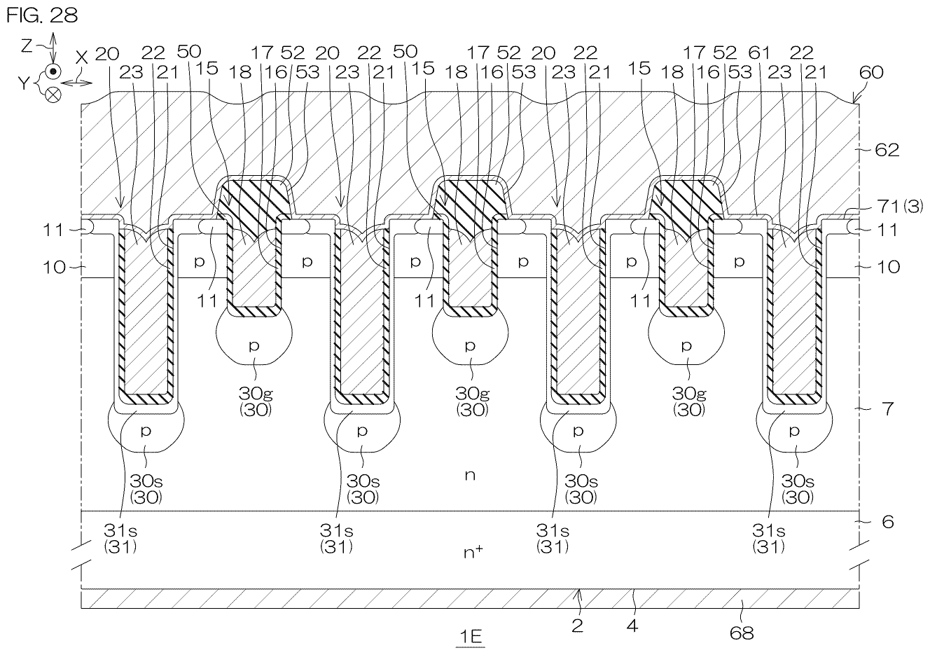

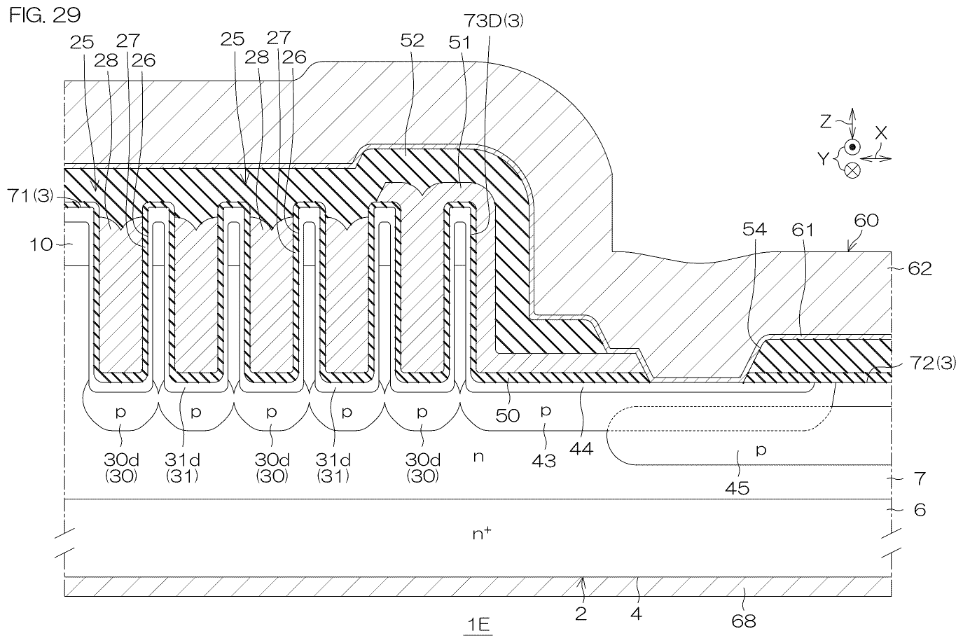

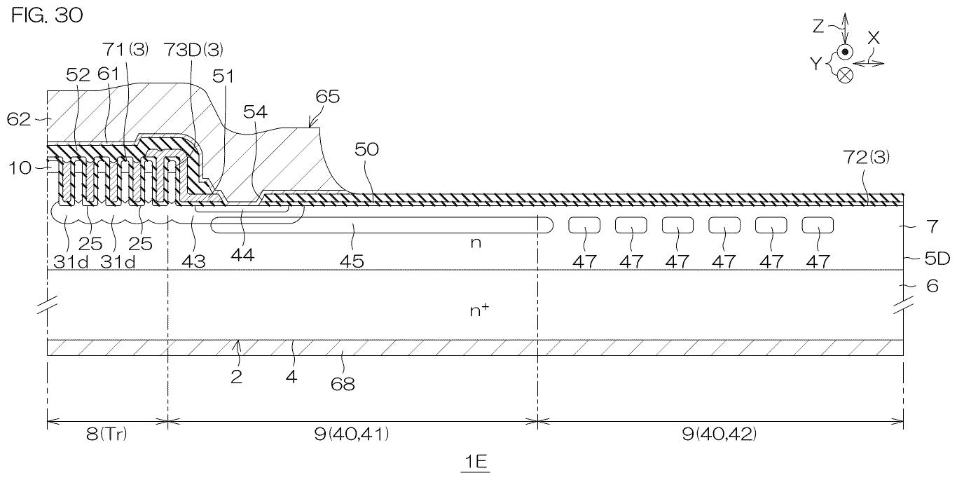

FIG. 28 is a cross-sectional view illustrating one main portion of the active region 8 of a semiconductor device 1E according to a fifth embodiment. FIG. 29 is a cross-sectional view illustrating one main portion of the active region 8 of the semiconductor device 1E illustrated in FIG. 28. FIG. 30 is a cross-sectional view illustrating the outer peripheral region 9 of the semiconductor device 1E illustrated in FIG. 28 together with the outer peripheral structure 40 according to the first configuration example.

Referring to FIGS. 28 to 30, the semiconductor device 1E has a form in which the arrangements of the plurality of gate structures 15 and the plurality of source structures 20, and the arrangements of the plurality of dummy structures 25 according to the semiconductor device 1D are changed.

Specifically, the semiconductor device 1E includes the plurality of gate structures 15 formed at intervals toward the first surface portion 71 side from the depth position of the second surface portion 72. That is, the plurality of gate structures 15 have a depth less than the depth of the second surface portion 72.

The bottom walls of the plurality of gate structures 15 may be formed at intervals toward the first surface portion 71 side from depth positions of intermediate portions of the first to fourth connecting surface portions 73A to 73D. The bottom walls of the plurality of gate structures 15 may be positioned at the second surface portion 72 side with respect to the depth positions of the intermediate portions of the first to fourth connecting surface portions 73A to 73D.

A ratio of the depth of the gate structure 15 to the depth of the second surface portion 72 (gate depth ratio) may be not less than 0.1 and less than 1. The gate depth ratio may have a value belonging to at least one range among not less than 0.1 and not more than 0.25, not less than 0.25 and not more than 0.5, not less than 0.5 and not more than 0.75, and not less than 0.75 and less than 1.

The semiconductor device 1E includes the plurality of source structures 20 having a depth greater than the depths of the plurality of gate structures 15. The plurality of source structures 20 have a depth not more than the depth of the second surface portion 72. The depths of the plurality of source structures 20 may be substantially equal to the depth of the second surface portion 72. As a matter of course, the depths of the plurality of source structures 20 may be greater than the depth of the second surface portion 72.

A ratio of the depth of the source structure 20 to the depth of the gate structure 15 (a first source depth ratio) may be not less than 1.5 and not more than 2.5. The first source depth ratio may have a value belonging to at least one range among not less than 1.5 and not more than 1.75, not less than 1.75 and not more than 2, not less than 2 and not more than 2.25, and not less than 2.25 and not more than 2.5.

A ratio of the depth of the source structure 20 to the depth of the second surface portion 72 (a second source depth ratio) may be not less than 0.8 and not more than 1.2. The second source depth ratio may have a value belonging to any one range among not less than 0.8 and not more than 0.85, not less than 0.85 and not more than 0.9, not less than 0.9 and not more than 0.95, not less than 0.95 and not more than 1, not less than 1 and not more than 1.05, not less than 1.05 and not more than 1.1, not less than 1.1 and not more than 1.15, and not less than 1.15 and not more than 1.2.

The semiconductor device 1E includes the plurality of dummy structures 25 having a depth greater than the depths of the plurality of gate structures 15. The plurality of dummy structures 25 have a depth not more than the depth of the second surface portion 72. The depths of the plurality of dummy structures 25 may be substantially equal to the depth of the second surface portion 72. As a matter of course, the depths of the plurality of dummy structures 25 may be greater than the depth of the second surface portion 72.

The plurality of dummy structures 25 have a depth not more than the depth of the source structure 20. The depths of the plurality of dummy structures 25 may be substantially equal to the depth of the source structure 20. As a matter of course, the depths of the plurality of dummy structures 25 may be greater than the depth of the source structures 20.

A ratio of the depth of the dummy structure 25 to the depth of the gate structure 15 (a first dummy depth ratio) may be not less than 1.5 and not more than 2.5. The first dummy depth ratio may have a value belonging to at least one range among not less than 1.5 and not more than 1.75, not less than 1.75 and not more than 2, not less than 2 and not more than 2.25, and not less than 2.25 and not more than 2.5.

A ratio of the depth of the dummy structure 25 to the depth of the second surface portion 72 (a second dummy depth ratio) may be not less than 0.8 and not more than 1.2. The second dummy depth ratio may have a value belonging to any one range among not less than 0.8 and not more than 0.85, not less than 0.85 and not more than 0.9, not less than 0.9 and not more than 0.95, not less than 0.95 and not more than 1, not less than 1 and not more than 1.05, not less than 1.05 and not more than 1.1, not less than 1.1 and not more than 1.15, and not less than 1.15 and not more than 1.2.

The bottom portions of the plurality of gate well regions 30g may be positioned at the first surface portion 71 side with respect to the depth position of the second surface portion 72, or may be positioned at the bottom portion side of the second semiconductor region 7. The bottom portions of the plurality of gate well regions 30g may be positioned at the first surface portion 71 side with respect to the depth positions of the bottom walls of the plurality of source structures 20, or may be positioned at the bottom portion side of the second semiconductor region 7.

The bottom portions of the plurality of gate well regions 30g may be positioned at the first surface portion 71 side with respect to the depth positions of the bottom walls of the plurality of dummy structures 25, or may be positioned at the bottom portion side of the second semiconductor region 7. The bottom portions of the plurality of source well regions 30s are positioned at the bottom portion side of the second semiconductor region 7. The bottom portions of the plurality of dummy well regions 30d are positioned at the bottom portion side of the second semiconductor region 7.

The bottom portions of the plurality of gate contact regions 31g may be positioned at the first surface portion 71 side with respect to the depth position of the second surface portion 72, or may be positioned at the bottom portion side of the second semiconductor region 7. The bottom portions of the plurality of gate contact regions 31g may be positioned at the first surface portion 71 side with respect to the depth positions of the bottom walls of the plurality of source structures 20, or may be positioned at the bottom portion side of the second semiconductor region 7.

The bottom portions of the plurality of gate contact regions 31g may be positioned at the first surface portion 71 side with respect to the depth positions of the bottom walls of the plurality of dummy structures 25, or may be positioned at the bottom portion side of the second semiconductor region 7. The bottom portions of the plurality of source contact regions 31s are positioned at the bottom portion side of the second semiconductor region 7. The bottom portions of the plurality of dummy contact regions 31d are positioned at the bottom portion side of the second semiconductor region 7.

The bottom portion of the outer well region 43 is positioned at the bottom portion side of the second semiconductor region 7 with respect to depth positions of the bottom walls of the plurality of gate structures 15. The bottom portion of the outer well region 43 is positioned at the bottom portion side of the second semiconductor region 7 with respect to the depth positions of the bottom walls of the plurality of source structures 20. The bottom portion of the outer well region 43 is positioned at the bottom portion side of the second semiconductor region 7 with respect to the depth positions of the bottom walls of the plurality of dummy structures 25.

The bottom portion of the outer contact region 44 is positioned at the bottom portion side of the second semiconductor region 7 with respect to the depth positions of the bottom walls of the plurality of gate structures 15. The bottom portion of the outer contact region 44 is positioned at the bottom portion side of the second semiconductor region 7 with respect to the depth positions of the bottom walls of the plurality of source structures 20. The bottom portion of the outer contact region 44 is positioned at the bottom portion side of the second semiconductor region 7 with respect to the depth positions of the bottom walls of the plurality of dummy structures 25.

The bottom portion of the terminal region 45 is positioned at the bottom portion side of the second semiconductor region 7 with respect to the depth positions of the bottom walls of the plurality of gate structures 15. The bottom portion of the terminal region 45 is positioned at the bottom portion side of the second semiconductor region 7 with respect to the depth positions of the bottom walls of the plurality of source structures 20. The bottom portion of the terminal region 45 is positioned at the bottom portion side of the second semiconductor region 7 with respect to the depth positions of the bottom walls of the plurality of dummy structures 25.

The bottom portions of the plurality of field regions 47 are positioned at the bottom portion side of the second semiconductor region 7 with respect to the depth positions of the bottom walls of the plurality of gate structures 15. The bottom portions of the plurality of field regions 47 are positioned at the bottom portion side of the second semiconductor region 7 with respect to the depth positions of the bottom walls of the plurality of source structures 20. The bottom portions of the plurality of field regions 47 are positioned at the bottom portion side of the second semiconductor region 7 with respect to the depth positions of the bottom walls of the plurality of dummy structures 25.

Other arrangements and descriptions of the semiconductor device 1E are the same as in the case of the semiconductor device 1D. As a matter of course, as in the case of the semiconductor device 1D, the semiconductor device 1E may include any one of the outer peripheral structures 40 according to the first to fifth configuration examples (see also FIGS. 10A to 10E).

The semiconductor device 1E may include any one of the features of the first outer peripheral structures 41 according to the first to tenth modification examples with respect to the first outer peripheral structures 41 according to the first to fifth configuration examples (see also FIGS. 11A to 11J). Of course, the features of the first outer peripheral structures 41 according to the first to tenth modification examples can be combined therebetween as appropriate.

Therefore, with respect to the first outer peripheral structures 41 according to the first to fifth configuration examples, the semiconductor device 1E may simultaneously include at least two of the features of the first outer peripheral structures 41 according to the first to tenth modification examples in the same or different regions.

At least one feature of the outer well region 43, the outer contact region 44, and the terminal region 45 according to the first to tenth modification examples is selected as appropriate according to the configurations of the first to fifth configuration examples, and is applied to the configurations of the first to fifth configuration examples.

The semiconductor device 1E may include any one of the features of the second outer peripheral structures 42 according to the first to tenth modification examples with respect to the second outer peripheral structures 42 according to the first to fifth configuration examples (see also FIGS. 12A to 12J). Of course, the features of the second outer peripheral structures 42 according to the first to tenth modification examples can be combined therebetween as appropriate.

Therefore, with respect to the second outer peripheral structures 42 according to the first to fifth configuration examples, the semiconductor device 1E may simultaneously include at least two of the features of the second outer peripheral structures 42 according to the first to tenth modification examples in the same or different regions. At least one feature of the field regions 47 according to the first to tenth modification examples is selected as appropriate according to the configurations of the first to fifth configuration examples, and is applied to the configurations of the first to fifth configuration examples.

The semiconductor device 1E may include one or a plurality of the features of the first outer peripheral structures 41 according to the first to tenth modification examples and one or a plurality of the features of the second outer peripheral structures 42 according to the first to tenth modification examples, together with the arrangement of any one of the first to fifth configuration examples.

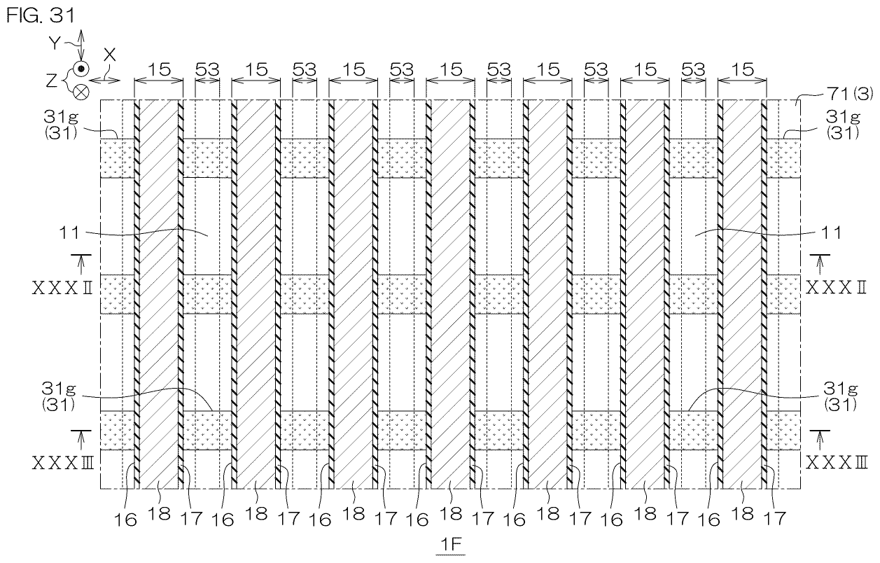

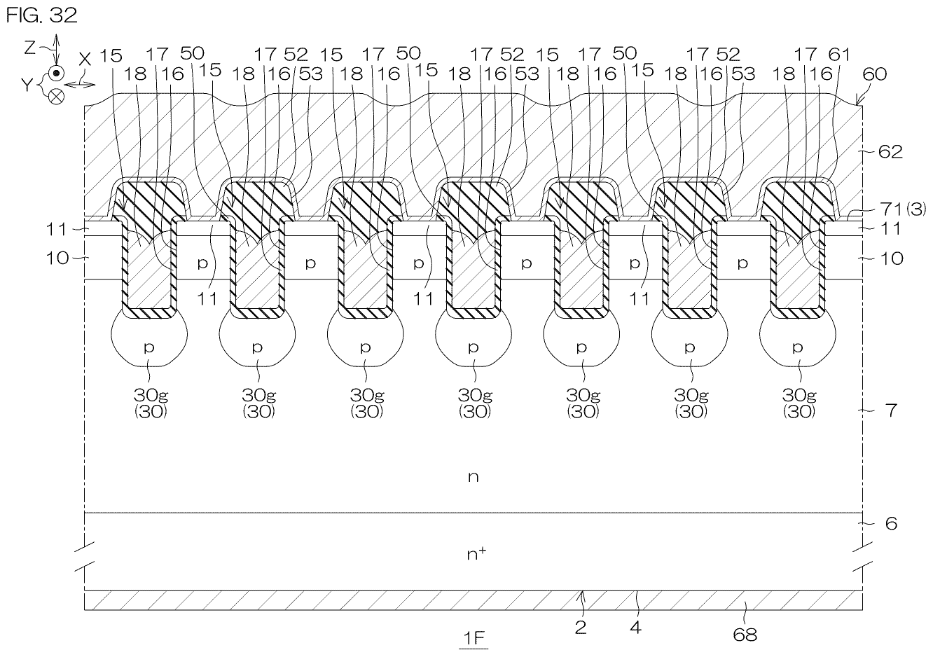

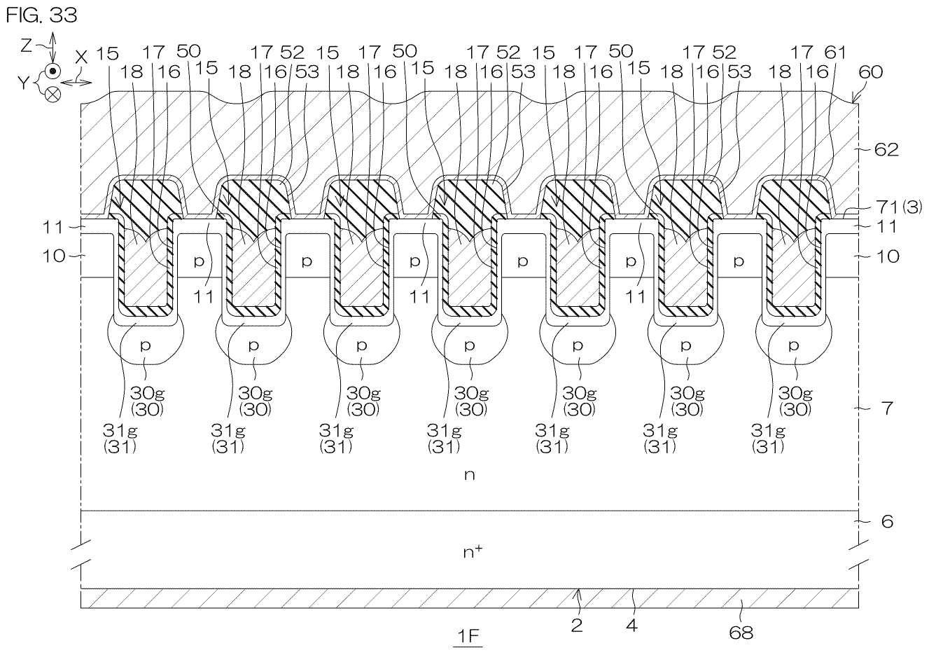

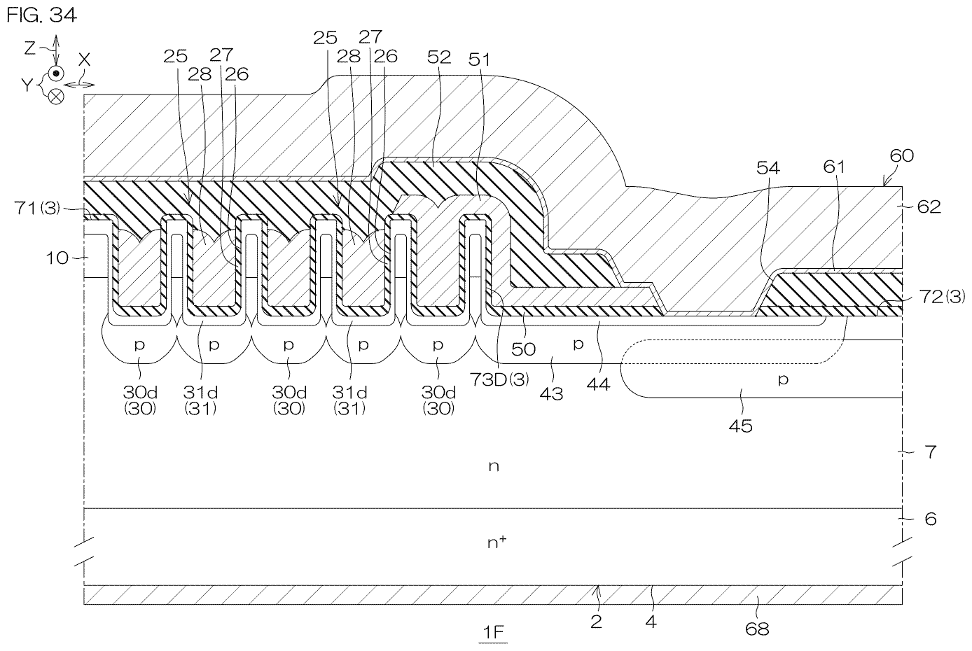

FIG. 31 is an enlarged plan view illustrating the active region 8 of a semiconductor device 1F according to a sixth embodiment. FIG. 32 is a cross-sectional view taken along line XXXII-XXXII illustrated in FIG. 31. FIG. 33 is a cross-sectional view taken along line XXXIII-XXXIII illustrated in FIG. 31. FIG. 34 is a cross-sectional view illustrating one main portion of the active region 8 of the semiconductor device 1F illustrated in FIG. 31.

Referring to FIGS. 31 to 34, the semiconductor device 1F has a form in which the arrangements of the plurality of gate structures 15 and the plurality of source structures 20, and the arrangements of the plurality of dummy structures 25 according to the semiconductor device 1D are changed.

Specifically, unlike the case of the semiconductor device 1D, the semiconductor device 1F includes the plurality of gate structures 15 and the plurality of dummy structures 25, and does not include the plurality of source structures 20. In this embodiment, the plurality of gate structures 15 are aligned so as to be adjacent to each other at intervals in the first direction X (=the m-axis direction), and each extend in a band shape in the second direction Y (=the a-axis direction).

The plurality of dummy structures 25 are arranged on the peripheral edge of the active region 8 at intervals from a structure group including the plurality of gate structures 15. The plurality of dummy structures 25 may each be formed in a polygonal annular shape (a quadrilateral annular shape) entirely surrounding a structure group including the plurality of gate structures 15 in plan view.

The depths of the plurality of dummy structures 25 are preferably substantially equal to the depths of the plurality of gate structures 15. As a matter of course, the depths of the plurality of dummy structures 25 may be greater than the depths of the plurality of gate structures 15, or may be smaller than the depths of the plurality of gate structures 15.

Unlike the case of the semiconductor device 1D, the semiconductor device 1F includes the plurality of gate well regions 30g and the plurality of dummy well regions 30d, and does not include the plurality of source well regions 30s. The plurality of gate well regions 30g and the plurality of dummy well regions 30d have the same forms as in the case of the semiconductor device 1D.

The semiconductor device 1F includes the plurality of gate contact regions 31g and the plurality of dummy contact regions 31d, and does not include the plurality of source contact regions 31s. The plurality of gate contact regions 31g and the plurality of dummy contact regions 31d have the same forms as in the case of the semiconductor device 1D.

With respect to the one gate structure 15 and the other gate structure 15, the plurality of gate contact regions 31g along the one gate structure 15 face the plurality of gate contact regions 31g along the other gate structure 15 in the first direction X in plan view.

That is, the plurality of gate contact regions 31g are aligned in a matrix at intervals in the first direction X and the second direction Y as a whole in plan view. In this case, the plurality of gate contact regions 31g along the one gate structure 15 may be connected to the plurality of gate contact regions 31g along the other gate structure 15 in the surface layer portion of the body region 10.

As a matter of course, the plurality of gate contact regions 31g along the one gate structure 15 may face a region between the plurality of gate contact regions 31g along the other gate structure 15 in the first direction X in plan view. That is, the plurality of gate contact regions 31g may be aligned in a staggered manner at intervals in the first direction X and the second direction Y as a whole in plan view.

As in the case of the semiconductor device 1D, the semiconductor device 1F includes the plurality of source openings 53 formed in the interlayer film 52. In this embodiment, the plurality of source openings 53 are respectively formed in regions between the plurality of adjacent gate structures 15 and respectively expose the source region 11 and the plurality of gate contact regions 31g.

As in the case of the semiconductor device 1D, the semiconductor device 1F includes the source electrode 60 arranged on the first main surface 3. The source electrode 60 has a laminated structure including the lower electrode film 61 and the main electrode film 62 laminated in that order from the chip 2 side. As in the case of the semiconductor device 1D, the lower electrode film 61 has a laminated structure including the first electrode film 63 and the second electrode film 64.

The first electrode film 63 entirely covers, in a film shape, a region of the interlayer film 52 in which the plurality of source openings 53 are formed, and enters the plurality of source openings 53 from above the interlayer film 52. The first electrode film 63 is mechanically and electrically connected to the source region 11 and the plurality of gate contact regions 31g in the plurality of source openings 53.

The second electrode film 64 entirely covers, in a film shape, a region of the interlayer film 52 in which the plurality of source openings 53 are formed with the first electrode film 63 interposed therebetween, and enters the plurality of source openings 53 from above the interlayer film 52. The second electrode film 64 is electrically connected to the source region 11 and the plurality of gate contact regions 31g via the first electrode film 63 in the plurality of source openings 53.

The main electrode film 62 entirely covers, in a film shape, a region of the interlayer film 52 in which the plurality of source openings 53 are formed, and refills the plurality of source openings 53. The main electrode film 62 is electrically connected to the source region 11 and the plurality of gate contact regions 31g via the lower electrode film 61 in the plurality of source openings 53.

Other arrangements and descriptions of the semiconductor device 1F are the same as in the case of the semiconductor device 1D. As a matter of course, as in the case of the semiconductor device 1D, the semiconductor device 1F may include any one of the outer peripheral structures 40 according to the first to fifth configuration examples (see also FIGS. 10A to 10E).

The semiconductor device 1F may include any one of the features of the first outer peripheral structures 41 according to the first to tenth modification examples with respect to the first outer peripheral structures 41 according to the first to fifth configuration examples (see also FIGS. 11A to 11J). Of course, the features of the first outer peripheral structures 41 according to the first to tenth modification examples can be combined therebetween as appropriate.

Therefore, with respect to the first outer peripheral structures 41 according to the first to fifth configuration examples, the semiconductor device 1F may simultaneously include at least two of the features of the first outer peripheral structures 41 according to the first to tenth modification examples in the same or different regions.

At least one feature of the outer well region 43, the outer contact region 44, and the terminal region 45 according to the first to tenth modification examples is selected as appropriate according to the configurations of the first to fifth configuration examples, and is applied to the configurations of the first to fifth configuration examples.

The semiconductor device 1F may include any one of the features of the second outer peripheral structures 42 according to the first to tenth modification examples with respect to the second outer peripheral structures 42 according to the first to fifth configuration examples (see also FIGS. 12A to 12J). Of course, the features of the second outer peripheral structures 42 according to the first to tenth modification examples can be combined therebetween as appropriate.

Therefore, with respect to the second outer peripheral structures 42 according to the first to fifth configuration examples, the semiconductor device 1F may simultaneously include at least two of the features of the second outer peripheral structures 42 according to the first to tenth modification examples in the same or different regions. At least one feature of the field regions 47 according to the first to tenth modification examples is selected as appropriate according to the configurations of the first to fifth configuration examples, and is applied to the configurations of the first to fifth configuration examples.

The semiconductor device 1F may include one or a plurality of the features of the first outer peripheral structures 41 according to the first to tenth modification examples and one or a plurality of the features of the second outer peripheral structures 42 according to the first to tenth modification examples, together with the arrangement of any one of the first to fifth configuration examples.

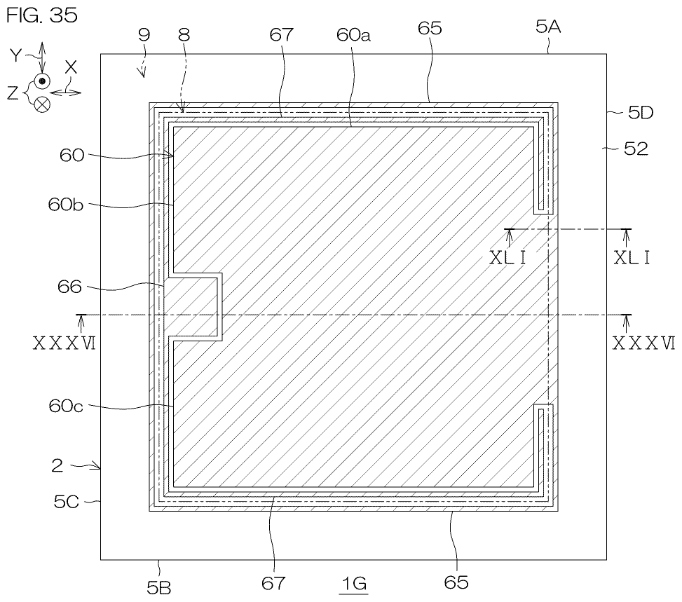

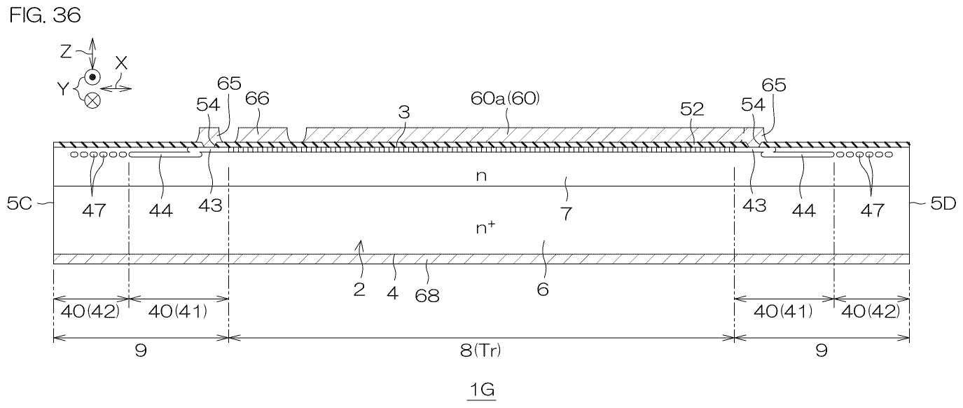

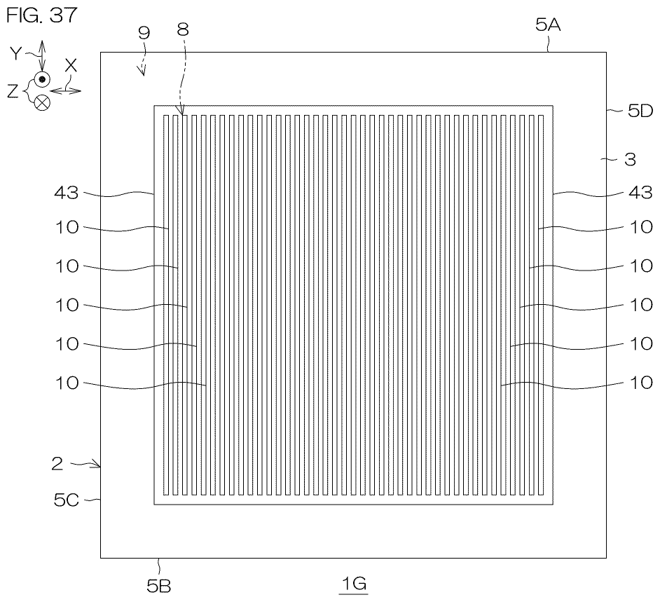

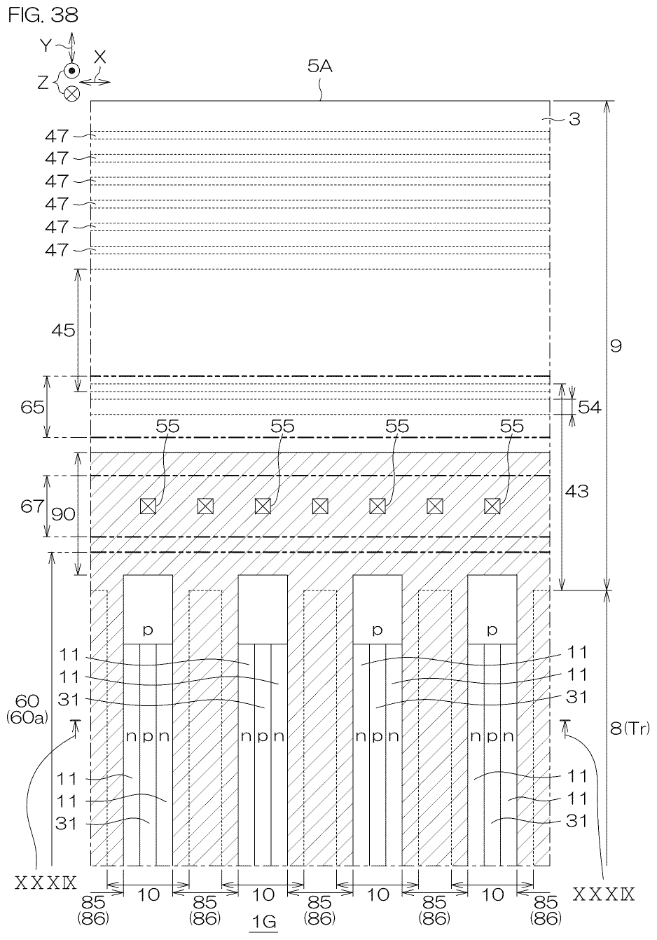

FIG. 35 is a plan view illustrating a semiconductor device 1G according to a seventh embodiment. FIG. 36 is a cross-sectional view taken along line XXXVI-XXXVI illustrated in FIG. 35. FIG. 37 is a plan view illustrating a layout example of the first main surface 3. FIG. 38 is an enlarged plan view illustrating one main portion of the first main surface 3 illustrated in FIG. 37.

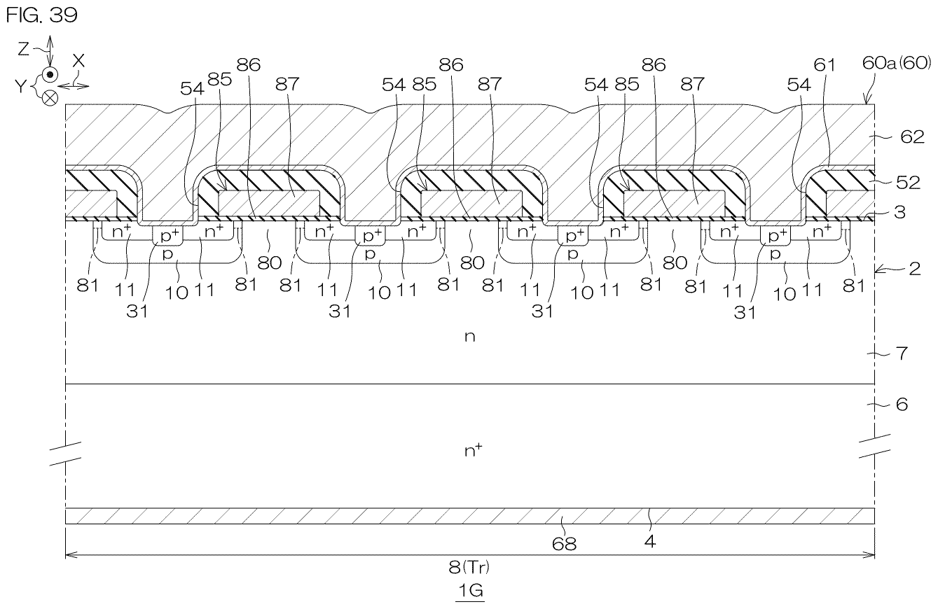

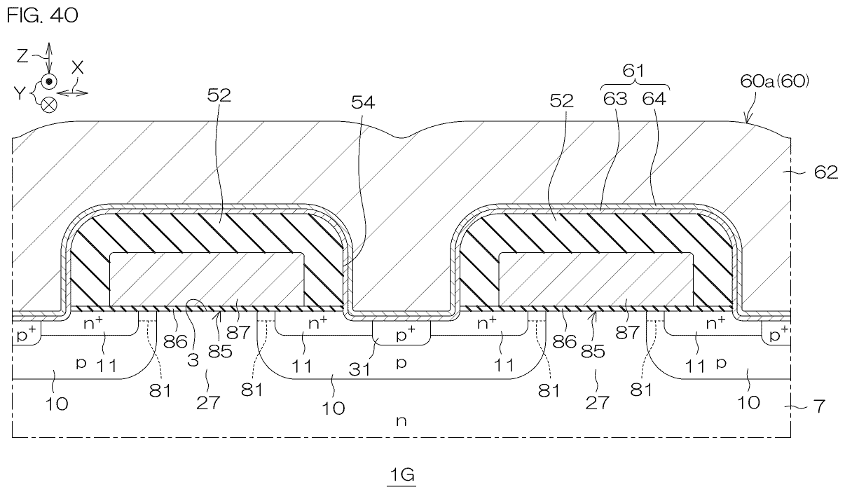

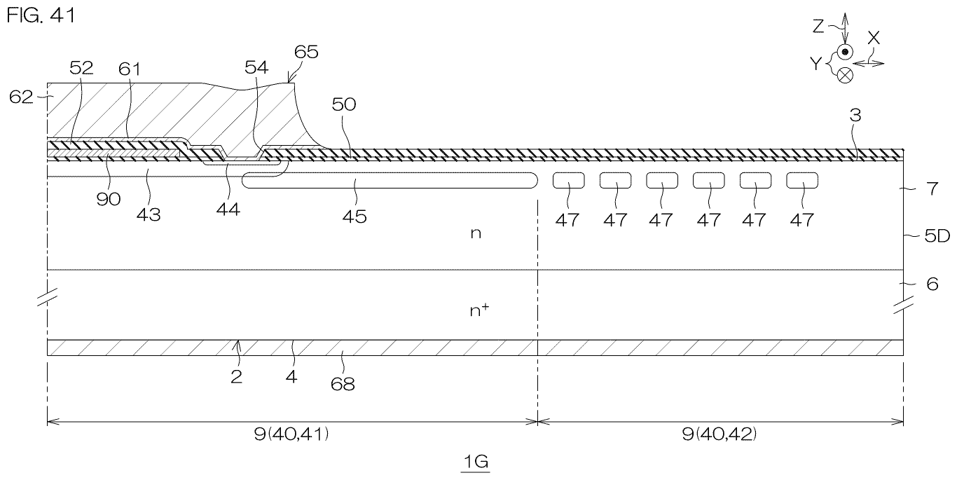

FIG. 39 is a cross-sectional view taken along line XXXIX-XXXIX illustrated in FIG. 38. FIG. 40 is an enlarged cross-sectional view of one region illustrated in FIG. 39. FIG. 41 is a cross-sectional view illustrating a cross-sectional structure taken along line XLI-XLI illustrated in FIG. 35 together with the outer peripheral structure 40 according to the first configuration example.

Referring to FIGS. 35 to 41, the semiconductor device 1G is a semiconductor switching device having the transistor structure Tr of an insulated gate type as an example of a device structure. The transistor structure Tr has a vertical structure of a planar gate type.

As in the case of the semiconductor device 1A, the semiconductor device 1G includes the chip 2, the first semiconductor region 6, the second semiconductor region 7, the active region 8, and the outer peripheral region 9. In this embodiment, the first main surface 3 is constituted of a flat surface extending in the horizontal directions, and is formed by the second semiconductor region 7.

The semiconductor device 1G includes a plurality of the p-type body regions 10 formed in the surface layer portion of the first main surface 3 in the active region 8. The plurality of body regions 10 are aligned at intervals in the first direction X, and each formed in a band shape extending in the second direction Y. That is, the plurality of body regions 10 are aligned in a stripe shape extending in the second direction Y. The extension direction of the plurality of body regions 10 coincides with the off direction of the SiC monocrystal.

The plurality of body regions 10 are formed at intervals toward the first main surface 3 side from the bottom portion of the second semiconductor region 7, and face the first semiconductor region 6 with a portion of the second semiconductor region 7 interposed therebetween. It is preferable that the plurality of body regions 10 are formed at intervals toward the first main surface 3 side from the intermediate portion of the second semiconductor region 7. The plurality of body regions 10 are exposed from the first main surface 3.

The semiconductor device 1G includes a plurality of the n-type source regions 11 respectively formed in the surface layer portions of the plurality of body regions 10. The plurality of source regions 11 are formed at intervals in the first direction X in the surface layer portions of the corresponding body regions 10.

Each of the plurality of source regions 11 is formed at intervals from both edge portions of the corresponding body region 10 to the inner portion of the corresponding body region 10 in the first direction X, and extends in a band shape along the extension direction of the corresponding body region 10. As a matter of course, each of the plurality of source regions 11 may be formed at intervals along the extension direction of the corresponding body region 10.

Each of the plurality of source regions 11 is formed at intervals inward from both end portions of the corresponding body region 10 in the second direction Y, and exposes the both end portions of the corresponding body region 10 in the second direction Y from the first main surface 3.

Each of the plurality of source regions 11 is formed at intervals toward the first main surface 3 side from the bottom portion of the corresponding body region 10, and faces the second semiconductor region 7 with a portion of the corresponding body region 10 interposed therebetween. Each of the plurality of source regions 11 may have a peripheral edge portion protruding in an arc shape toward the peripheral edge portion side of the corresponding body region 10.

The semiconductor device 1G includes the plurality of p-type contact regions 31 formed in regions different from those of the plurality of source regions 11 in the surface layer portions of the corresponding body regions 10. The plurality of contact regions 31 are interposed in regions between the plurality of source regions 11 in the surface layer portions of the corresponding body regions 10, and are electrically connected to the body regions 10.

The plurality of contact regions 31 extend in a band shape along the extension direction of the corresponding body regions 10 (the source regions 11). Each of the plurality of contact regions 31 is formed at intervals inward from both end portions of the corresponding body region 10 in the second direction Y. That is, each of the plurality of contact regions 31 exposes the both end portions of the corresponding body region 10 from the first main surface 3.

Each of the plurality of contact regions 31 is formed at intervals toward the first main surface 3 side from the bottom portion of the corresponding body region 10, and faces the second semiconductor region 7 with a portion of the corresponding body region 10 interposed therebetween. In this embodiment, the contact region 31 has a width less than the widths of the plurality of source regions 11. The width of the contact region 31 may be greater than the widths of the plurality of source regions 11.

In this embodiment, the plurality of contact regions 31 have a thickness greater than the thicknesses of the plurality of source regions 11, and have bottom portions positioned further to the bottom portions side of the corresponding body regions 10 than the bottom portions of the plurality of source regions 11.

The semiconductor device 1G includes a plurality of surface layer drift regions 80 of the n-type formed in the surface layer portion of the first main surface 3. In this embodiment, each of the plurality of surface layer drift regions 80 is constituted of a part of the second semiconductor region 7. As a matter of course, the plurality of surface layer drift regions 80 may have an n-type impurity concentration higher than the n-type impurity concentration of the second semiconductor region 7, or may have an n-type impurity concentration less than the n-type impurity concentration of the second semiconductor region 7.

The plurality of surface layer drift regions 80 are demarcated in a region between the plurality of body regions 10 adjacent to each other in the first direction X in the surface layer portion of the second semiconductor region 7. That is, the plurality of surface layer drift regions 80 are aligned at intervals in the first direction X, and each formed in a band shape extending in the second direction Y. Also, the plurality of surface layer drift regions 80 are formed in a stripe shape extending in the second direction Y.

The semiconductor device 1G includes a plurality of channel regions 81 of the p-type formed in the surface layer portion of the first main surface 3. The plurality of channel regions 81 are demarcated in a region between the plurality of source regions 11 and the plurality of surface layer drift regions 80 (the second semiconductor region 7) in the surface layer portions of the plurality of body regions 10. The plurality of channel regions 81 form a current path extending in the horizontal direction along the first main surface 3.

The semiconductor device 1G includes a plurality of gate structures 85 of a planar type (a planar electrode type) arranged on the first main surface 3 in the active region 8. The plurality of gate structures 85 are aligned at intervals in the first direction X, and each formed in a band shape extending in the second direction Y. That is, the plurality of gate structures 85 are aligned in a stripe shape extending in the second direction Y. Also, the extension direction of the plurality of gate structures 85 coincides with the off direction of the SiC monocrystal.

Each of the plurality of gate structures 85 covers the at least one channel region 81 (the peripheral edge portion of the body region 10). Each of the plurality of gate structures 85 covers a peripheral edge portion of the at least one body region 10, the at least one source region 11, and the one surface layer drift region 80 so as to be positioned on the at least one channel region 81.

In this embodiment, the plurality of gate structures 85 cross the one surface layer drift region 80 and respectively cover the plurality of channel regions 81 across the peripheral edge portions of the two body regions 10 adjacent to each other. Specifically, the plurality of gate structures 85 extend over the source region 11 of the body region 10 on one side and the source region 11 of the body region 10 on the other side, and cover two source regions 11, the one surface layer drift region 80, and the two channel regions 81.

Each of the plurality of gate structures 85 has a laminated structure including a planar insulating film 86 and a planar electrode 87. The planar insulating film 86 may be referred to as a “gate insulating film,” and the planar electrode 87 may be referred to as a “gate electrode” or a “planar gate electrode.”

The planar insulating film 86 may include at least one among a silicon oxide film, a silicon nitride film, and a silicon oxynitride film. In this embodiment, the planar insulating film 86 has a single layer structure constituted of a silicon oxide film. The planar insulating film 86 particularly preferably includes a silicon oxide film made of the oxide of the chip 2.

The planar insulating film 86 covers the first main surface 3 in a film shape. The planar insulating film 86 covers the at least one channel region 81 (the peripheral edge portion of the body region 10). The planar insulating film 86 covers the peripheral edge portion of the at least one body region 10, the at least one source region 11, and the one surface layer drift region 80 so as to be positioned on the at least one channel region 81.

In this embodiment, the planar insulating film 86 crosses the one surface layer drift region 80, extends over the peripheral edge portions of the two body regions 10 adjacent to each other, and covers the plurality of channel regions 81. Specifically, the planar insulating film 86 extends over the source region 11 of the body region 10 on one side and the source region 11 of the body region 10 on the other side, and covers the two source regions 11, the one surface layer drift region 80, and the two channel regions 81.

The planar electrode 87 is arranged on the planar insulating film 86. The gate potential as the control potential is to be applied to the planar electrode 87. The planar electrode 87 may contain either or both of a conductive polysilicon of the p-type and a conductive polysilicon of the n-type.

The planar electrode 87 covers the at least one channel region 81 (the peripheral edge portion of the body region 10) with the planar insulating film 86 interposed therebetween. The planar electrode 87 covers the peripheral edge portion of the at least one body region 10, the at least one source region 11, and the one surface layer drift region 80 so as to be positioned on the at least one channel region 81 with the planar insulating film 86 interposed therebetween.

In this embodiment, the planar electrode 87 crosses the one surface layer drift region 80, extends over the peripheral edge portions of the two body regions 10 adjacent to each other, and covers the plurality of channel regions 81. Specifically, the planar electrode 87 extends over the source region 11 of the body region 10 on one side and the source region 11 of the body region 10 on the other side, and covers the two source regions 11, the one surface layer drift region 80, and the two channel regions 81.

The planar electrode 87 extends in a band shape in the second direction Y. In this embodiment, the planar electrode 87 is formed at an interval inward from both ends of the planar insulating film 86 in the first direction X and exposes both end portions of the planar insulating film 86.

As in the case of the semiconductor device 1A, the semiconductor device 1G includes any one of the outer peripheral structures 40 according to the first to fifth configuration examples (see also FIGS. 10A to 10E). FIG. 41 exemplifies an embodiment in which the semiconductor device 1G includes the outer peripheral structure 40 according to the first configuration example. The outer peripheral structure 40 includes the first outer peripheral structure 41 and the second outer peripheral structure 42.

As in the case of the semiconductor device 1A, the first outer peripheral structure 41 includes the p-type outer well region 43 formed in the surface layer portion of the first main surface 3 in the outer peripheral region 9 (the peripheral edge portion of the first main surface 3). The p-type impurity concentration of the outer well region 43 is preferably less than the p-type impurity concentration of the contact region 31.

The p-type impurity concentration of the outer well region 43 may be substantially equal to the p-type impurity concentration of the body region 10. As a matter of course, the p-type impurity concentration of the outer well region 43 may be less than the p-type impurity concentration of the body region 10, or may be higher than the p-type impurity concentration of the body region 10.

As in the case of the semiconductor device 1A, the outer well region 43 is formed in the surface layer portion of the second semiconductor region 7 and is electrically connected to the second semiconductor region 7. The outer well region 43 is formed at an interval toward the first main surface 3 side from the bottom portion of the second semiconductor region 7, and faces the first semiconductor region 6 with a portion of the second semiconductor region 7 interposed therebetween.

The outer well region 43 has an upper end portion exposed from the first main surface 3 and a bottom portion positioned in the second semiconductor region 7. The bottom portion of the outer well region 43 is formed at an interval toward the first main surface 3 side from the depth position of the intermediate portion of the second semiconductor region 7.

The bottom portion of the outer well region 43 may be formed at an interval toward the first main surface 3 side from the depth position of the bottom portion of the body region 10, or may be positioned at the bottom portion side of the second semiconductor region 7 with respect to the depth position of the bottom portion of the body region 10. In this embodiment, the bottom portion of the outer well region 43 may be formed at a depth position substantially equal to the bottom portion of the body region 10.

The outer well region 43 is formed at an interval toward the active region 8 side from the peripheral edge (the first to fourth side surfaces 5A to 5D) of the first main surface 3 in the surface layer portion of the second semiconductor region 7, and extends in a band shape along the active region 8. In this embodiment, the outer well region 43 entirely surrounds the plurality of body regions 10 (the active region 8) in plan view, and is demarcated into a polygonal annular shape (in this embodiment, a quadrilateral annular shape) having four sides parallel to the peripheral edge of the first main surface 3.

That is, the outer well region 43 forms the boundary portion between the active region 8 and the outer peripheral region 9. The outer well region 43 may have an edge portion that connects a portion extending in the first direction X and a portion extending in the second direction Y in plan view in an arc shape (preferably, a quarter arc shape) (see FIG. 4).

The outer well region 43 has an inner edge portion on the inner side of the first main surface 3 (the active region 8 side) and an outer edge portion on the peripheral edge side of the first main surface 3. The inner edge portion of the outer well region 43 is connected to the plurality of body regions 10 in a portion extending in the first direction X, and demarcates the plurality of body regions 10 and the plurality of surface layer drift regions 80. That is, the outer well region 43 is electrically connected to the plurality of body regions 10. The source potential is thereby applied to the outer well region 43 via the plurality of body regions 10.

The outer well region 43 is connected to the plurality of body regions 10 at intervals in the second direction Y from the source region 11. Therefore, the outer well region 43 does not have the source region 11 in the surface layer portion. Also, the outer well region 43 is connected to the plurality of body regions 10 at intervals in the second direction Y from the contact region 31. Therefore, the outer well region 43 does not have the contact region 31 in the surface layer portion.

The outer well region 43 preferably has a width greater than the width of the body region 10. The width of the outer well region 43 is a width in a direction orthogonal to the extension direction. As a matter of course, the width of the outer well region 43 may be substantially equal to the width of the body region 10, or may be less than the thickness of the body region 10.

A ratio of the width of the outer well region 43 to the width of the body region 10 may be not less than 1 and not more than 50. The ratio of the width may have a value belonging to at least one range among not less than 1 and not more than 10, not less than 10 and not more than 20, not less than 20 and not more than 30, not less than 30 and not more than 40, and not less than 40 and not more than 50. Preferably, the ratio of the width is not less than 10. Preferably, the ratio of the width is not less than 20 and not more than 40.

The outer well region 43 preferably has a thickness (depth) substantially equal to the thickness (depth) of the body region 10. As a matter of course, the thickness of the outer well region 43 may be less than the thickness of the body region 10 or may be greater than the thickness of the body region 10. Other descriptions of the outer well region 43 are the same as in the case of the semiconductor device 1A.

As in the case of the semiconductor device 1A, the first outer peripheral structure 41 includes the p-type terminal region 45 formed in the surface layer portion of the first main surface 3. The p-type impurity concentration of the terminal region 45 may be higher than the p-type impurity concentration of the body region 10, or may be less than the p-type impurity concentration of the body region 10. The p-type impurity concentration of the terminal region 45 is less than the p-type impurity concentration of the contact region 31. Other descriptions of the terminal region 45 are the same as in the case of the semiconductor device 1A.

As in the case of the semiconductor device 1A, the first outer peripheral structure 41 includes the p-type outer contact region 44 formed in the surface layer portion of the first main surface 3. The p-type impurity concentration of the outer contact region 44 is higher than the p-type impurity concentration of the body region 10. The p-type impurity concentration of the outer contact region 44 may be substantially equal to the p-type impurity concentration of the contact region 31.

As a matter of course, the p-type impurity concentration of the outer contact region 44 may be higher than the p-type impurity concentration of the contact region 31, or may be less than the p-type impurity concentration of the contact region 31. The p-type impurity concentration of the outer contact region 44 may be less than the p-type impurity concentration of the outer well region 43. Other descriptions of the outer contact region 44 are the same as in the case of the semiconductor device 1A.

As in the case of the semiconductor device 1A, the second outer peripheral structure 42 includes at least one (in this embodiment, a plurality) of the p-type field regions 47 formed in the surface layer portion of the first main surface 3 in the outer peripheral region 9 (the peripheral edge portion of the first main surface 3). The description of the plurality of field regions 47 is the same as in the case of the semiconductor device 1A.

As in the case of the semiconductor device 1A, the semiconductor device 1G includes the main surface insulating film 50 that selectively covers the first main surface 3. In this embodiment, the main surface insulating film 50 is connected to a plurality of the planar insulating films 86 on the active region 8 side. Specifically, the main surface insulating film 50 is integrally formed with the plurality of planar insulating films 86, and forms the one first insulating film 17 with the plurality of planar insulating films 86.

The main surface insulating film 50 covers the first main surface 3 in a film shape in the outer peripheral region 9. The main surface insulating film 50 covers the second semiconductor region 7, the outer well region 43, and the outer contact region 44.

In this embodiment, the main surface insulating film 50 is continuous to the first to fourth side surfaces 5A to 5D at the peripheral edge portion of the first main surface 3. As a matter of course, the main surface insulating film 50 may be formed at an interval inward from the peripheral edge of the first main surface 3 and expose the peripheral edge portion (the second semiconductor region 7) of the first main surface 3.

The semiconductor device 1G includes a planar wiring 90 arranged on the first main surface 3 in the outer peripheral region 9. The planar wiring 90 may be referred to as a “second planar electrode,” a “planar gate wiring,” etc. The planar wiring 90 applies the gate potential to the plurality of gate structures 85.

The planar wiring 90 may contain either or both of a conductive polysilicon of the p-type and a conductive polysilicon of the n-type. The planar wiring 90 preferably has the same conductivity type as the conductivity type of the planar electrode 87.

A thickness of the planar wiring 90 is preferably substantially equal to a thickness of the planar electrode 87. As a matter of course, the thickness of the planar wiring 90 may be greater than the thickness of the planar electrode 87 or may be less than the thickness of the planar electrode 87.

The planar wiring 90 is selectively routed on the main surface insulating film 50 at an interval toward the active region 8 side from the peripheral edge of the first main surface 3. In this embodiment, the planar wiring 90 is arranged at an interval toward the active region 8 side from the terminal region 45, and is arranged on a portion of the main surface insulating film 50 that covers the outer well region 43.

That is, the planar wiring 90 faces the outer well region 43 with the main surface insulating film 50 interposed therebetween. The planar wiring 90 may be arranged at a position that faces the terminal region 45 in the lamination direction.

The planar wiring 90 is arranged on the main surface insulating film 50 at an interval toward the active region 8 side from the peripheral edge (the first to fourth side surfaces 5A to 5D) of the first main surface 3, and extends in a band shape along the active region 8. In this embodiment, the planar wiring 90 is demarcated into a polygonal annular shape (in this embodiment, a quadrilateral annular shape) having four sides parallel to the peripheral edge of the first main surface 3 in plan view, and entirely surrounds the plurality of gate structures 85 (the active region 8).

The planar wiring 90 may be a shape with ends or an endless shape. The planar wiring 90 may have an edge portion that connects a portion extending in the first direction X and a portion extending in the second direction Y in plan view in an arc shape (preferably, a quarter arc shape).

The planar wiring 90 has an inner edge portion on the inner side of the first main surface 3 (the active region 8 side) and an outer edge portion on the peripheral edge side of the first main surface 3. The inner edge portion of the planar wiring 90 is connected to the planar electrodes 87 of the plurality of gate structures 85 in a portion extending in the first direction X.

That is, the planar wiring 90 is electrically connected to the plurality of gate structures 85 (the planar electrodes 87). The planar wiring 90 thereby applies the gate potential to the plurality of gate structures 85. In this embodiment, the planar wiring 90 is integrally formed with the planar electrode 87.

The inner edge portion of the planar wiring 90 is formed at an interval toward the outer edge portion side of the outer well region 43 from the inner edge portion of the outer well region 43 (the plurality of body regions 10). That is, the inner edge portion of the planar wiring 90 is connected to the plurality of gate structures 85 at intervals in the second direction Y from the plurality of source regions 11 and the plurality of contact regions 31.

The planar wiring 90 faces the outer well region 43 with the main surface insulating film 50 interposed therebetween, and does not face the plurality of source regions 11 and the plurality of contact regions 31 with the main surface insulating film 50 interposed therebetween.

The outer edge portion of the planar wiring 90 is formed at an interval inward (the active region 8 side) from the innermost field region 47 among the plurality of field regions 47. That is, the outer edge portion of the planar wiring 90 does not face the plurality of field regions 47 with the main surface insulating film 50 interposed therebetween.

According to this arrangement, the dispersion path of the electric field in the region above the plurality of field regions 47 is suppressed from being shielded by the planar wiring 90, and the electric field (the line of electric force) is appropriately dispersed by the plurality of field regions 47.

The outer edge portion of the planar wiring 90 is formed at an interval inward from the outer edge portion of the terminal region 45. In this embodiment, the outer edge portion of the planar wiring 90 is formed at an interval toward the peripheral edge side of the first main surface 3 from the outer edge portion of the outer well region 43.

In this case, the outer edge portion of the planar wiring 90 is preferably formed at an interval toward the inner edge portion side of the outer well region 43 from the outer edge portion of the outer contact region 44 and exposes a part or the whole of the outer contact region 44.

In this embodiment, the planar wiring 90 is formed to be narrower in width than the outer well region 43, and is arranged on the outer well region 43 at an interval from the inner edge portion and the outer edge portion of the outer well region 43. A width of the planar wiring 90 is preferably greater than a width of the planar electrode 87. The width of the planar wiring 90 is a width in a direction orthogonal to the extension direction.

A ratio of the width of the planar wiring 90 to the width of the planar electrode 87 may be not less than 1 and not more than 50. The ratio of the width may have a value belonging to at least one range among not less than 1 and not more than 10, not less than 10 and not more than 20, not less than 20 and not more than 30, not less than 30 and not more than 40, and not less than 40 and not more than 50. Preferably, the ratio of the width is not less than 10. Preferably, the ratio of the width is not less than 20 and not more than 40.

As in the case of the semiconductor device 1A, the semiconductor device 1G includes the interlayer film 52 that covers the first main surface 3. The interlayer film 52 covers the plurality of gate structures 85 in the active region 8. The interlayer film 52 covers the second semiconductor region 7, the outer well region 43, and the outer contact region 44 with the main surface insulating film 50 interposed therebetween in the outer peripheral region 9.

The interlayer film 52 covers the planar wiring 90 in the outer peripheral region 9. The interlayer film 52 is continuous to the first to fourth side surfaces 5A to 5D. The interlayer film 52 may be formed at an interval inward from the first to fourth side surfaces 5A to 5D and expose the peripheral edge portion (the second semiconductor region 7) of the first main surface 3.

The semiconductor device 1G includes the plurality of source openings 53 formed in the interlayer film 52 in the active region 8. The plurality of source openings 53 are respectively formed in regions between the plurality of planar electrodes 87 at intervals from the plurality of planar electrodes 87 and expose the first main surface 3 (the chip 2). Specifically, the plurality of source openings 53 penetrate the planar insulating film 86 and the interlayer film 52 in the regions between the plurality of planar electrodes 87, and respectively expose the corresponding plurality of source regions 11 and contact regions 31.

In this embodiment, the plurality of source openings 53 are formed at intervals in the first direction X, and are each formed in a band shape extending in the second direction Y. That is, the plurality of source openings 53 are formed in a stripe shape extending in the second direction Y.

The plurality of source openings 53 are formed at intervals in the second direction Y from the planar wiring 90. That is, the plurality of source openings 53 are formed in a region surrounded by the plurality of planar electrodes 87 and the planar wiring 90. The plurality of source openings 53 have opening ends demarcated by arc corner portions of the interlayer film 52.

The plurality of source openings 53 may be formed in a region between the two gate structures 85 adjacent in the first direction X. In this case, the plurality of source openings 53 may be formed at intervals in a single column in the second direction Y. In this case, each source opening 53 may be formed in a quadrilateral shape (a square shape), a rectangular shape extending in the first direction X, a rectangular shape extending in the second direction Y, a hexagonal shape, a circular shape, etc., in plan view.

The semiconductor device 1G includes at least one (in this embodiment, one) of the outer openings 54 formed in the interlayer film 52. The outer opening 54 penetrates the main surface insulating film 50 and the interlayer film 52 and exposes the outer contact region 44. The outer opening 54 extends in a band shape along the outer contact region 44 in plan view.

In this embodiment, the outer opening 54 is formed in a polygonal annular shape (specifically, a quadrilateral annular shape) surrounding the first main surface 3 along the outer contact region 44 in plan view. As a matter of course, the semiconductor device 1G may have the outer opening 54. In this case, the outer opening 54 may be formed at an interval along the outer contact region 44 so as to surround the first main surface 3. The outer opening 54 has an opening end demarcated by the arc corner portions of the interlayer film 52.

As a matter of course, the semiconductor device 1G may include the outer opening 54. In this case, the outer opening 54 may be formed at an interval along the outer contact region 44. In this case, the outer opening 54 may be formed in a quadrilateral shape (a square shape), a rectangular shape, a hexagonal shape, a circular shape, etc., in plan view.

The semiconductor device 1G includes at least one (in this embodiment, a plurality) of the gate openings 55 formed in the interlayer film 52 in the outer peripheral region 9. The plurality of gate openings 55 are formed in a portion that covers the planar wiring 90 in the interlayer film 52. The plurality of gate openings 55 penetrate the interlayer film 52 and expose the planar wiring 90. The plurality of gate openings 55 have opening ends demarcated by arc corner portions of the interlayer film 52.

The plurality of gate openings 55 are formed at intervals along the planar wiring 90 (see FIG. 4 and FIG. 5). The plurality of gate openings 55 may be formed in a quadrilateral shape (a square shape), a rectangular shape, a hexagonal shape, a circular shape, etc., in plan view. The plurality of gate openings 55 may extend in a band shape along the planar wiring 90 in plan view.

The semiconductor device 1G may have a single gate opening 55. The single gate opening 55 may extend in a band shape along the planar wiring 90. The single gate opening 55 may have a portion extending in a band shape in the first direction X and a portion extending in a band shape in the second direction Y in plan view.

As in the case of the semiconductor device 1A, the semiconductor device 1G includes the source electrode 60. As in the case of the semiconductor device 1A, the source electrode 60 is arranged in the active region 8, and includes the first pad portion 60a, the second pad portion 60b, and the third pad portion 60c. The source electrode 60 enters the plurality of source openings 53 from above the interlayer film 52, and is electrically connected to the plurality of source regions 11 and the plurality of contact regions 31 in the plurality of source openings 53.

As in the case of the semiconductor device 1A, the source electrode 60 has a laminated structure including the lower electrode film 61 and the main electrode film 62 laminated in that order from the chip 2 side. In this embodiment, the lower electrode film 61 has a laminated structure including the first electrode film 63 and the second electrode film 64.

The first electrode film 63 entirely covers, in a film shape, a region of the interlayer film 52 in which the plurality of source openings 53 are formed, and enters the plurality of source openings 53 from above the interlayer film 52. The first electrode film 63 has a portion that covers the insulating main surface of the interlayer film 52 in a film shape, a portion that covers the wall surfaces of the plurality of source openings 53 in a film shape, and a portion that covers the first main surface 3 in a film shape in the plurality of source openings 53. The first electrode film 63 covers the first main surface 3 in a film shape in the source opening 53, and is mechanically and electrically connected to the plurality of source regions 11 and the plurality of contact regions 31.

The second electrode film 64 directly covers the first electrode film 63. The second electrode film 64 entirely covers, in a film shape, a region of the interlayer film 52 in which the plurality of source openings 53 are formed with the first electrode film 63 interposed therebetween, and enters the plurality of source openings 53 from above the interlayer film 52.

The second electrode film 64 has a portion that covers the insulating main surface of the interlayer film 52 in a film shape with the first electrode film 63 interposed therebetween, a portion that covers the wall surfaces of the plurality of source openings 53 in a film shape with the first electrode film 63 interposed therebetween, and a portion that covers the first main surface 3 in a film shape with the first electrode film 63 interposed therebetween in the plurality of source openings 53. The second electrode film 64 covers the first main surface 3 in a film shape with the first electrode film 63 interposed therebetween in the source opening 53, and is electrically connected to the plurality of source regions 11 and the plurality of contact regions 31 via the first electrode film 63.

The main electrode film 62 directly covers the lower electrode film 61 (the second electrode film 64). The main electrode film 62 refills the plurality of source openings 53 and entirely covers, in a film shape, a region of the interlayer film 52 in which the plurality of source openings 53 are formed.

The main electrode film 62 has a portion that covers the insulating main surface of the interlayer film 52 with the lower electrode film 61 interposed therebetween, a portion that covers the wall surfaces of the plurality of source openings 53 with the lower electrode film 61 interposed therebetween, and a portion that covers the first main surface 3 with the lower electrode film 61 interposed therebetween. The main electrode film 62 is electrically connected to the plurality of source regions 11 and the plurality of contact regions 31 via the lower electrode film 61 in the plurality of source openings 53.

As in the case of the semiconductor device 1A, the semiconductor device 1G includes the terminal wiring 65. The terminal wiring 65 has a wiring width less than an electrode width of the source electrode 60, and is selectively routed on the interlayer film 52.

In this embodiment, the terminal wiring 65 is led out from the source electrode 60 (the first pad portion 60a) to the fourth side surface 5D side, and is positioned in the outer peripheral region 9. The terminal wiring 65 has a portion that covers the planar wiring 90 with the interlayer film 52 interposed therebetween. The terminal wiring 65 may cover a part or the entire region of the planar wiring 90 with the interlayer film 52 interposed therebetween.

The terminal wiring 65 extends in a band shape along the active region 8 in a region on the peripheral edge side of the first main surface 3 with respect to the planar wiring 90. In this embodiment, the terminal wiring 65 is formed in a polygonal annular shape (specifically, a quadrilateral annular shape) extending along the active region 8 and surrounds the active region 8 (the source electrode 60). The terminal wiring 65 may have an edge portion that connects a portion extending in the first direction X and a portion extending in the second direction Y in an arc shape (preferably, a quarter arc shape).

The terminal wiring 65 enters the outer opening 54 from above the interlayer film 52, and is electrically connected to the outer contact region 44 in the outer opening 54. That is, the terminal wiring 65 is electrically connected to the terminal region 45 via the outer contact region 44. The source potential applied to the source electrode 60 is applied to the terminal region 45 via the outer contact region 44 and the terminal wiring 65.

As with the source electrode 60, the terminal wiring 65 has a laminated structure including the lower electrode film 61 and the main electrode film 62 laminated in that order from the chip 2 side. In this embodiment, the lower electrode film 61 has a laminated structure including the first electrode film 63 and the second electrode film 64.

The first electrode film 63 entirely covers, in a film shape, a region of the interlayer film 52 in which the outer opening 54 is formed, and enters the outer opening 54 from above the interlayer film 52. The first electrode film 63 has a portion that covers the insulating main surface of the interlayer film 52 in a film shape, a portion that covers the wall surface of the outer opening 54 in a film shape, and a portion that covers the first main surface 3 in a film shape in the outer opening 54. The first electrode film 63 is mechanically and electrically connected to the outer contact region 44 in the outer opening 54.

The second electrode film 64 directly covers the first electrode film 63. The second electrode film 64 entirely covers, in a film shape, a region of the interlayer film 52 in which the outer opening 54 is formed with the first electrode film 63 interposed therebetween, and enters the outer opening 54 from above the interlayer film 52.

The second electrode film 64 has a portion that covers the insulating main surface of the interlayer film 52 in a film shape with the first electrode film 63 interposed therebetween, a portion that covers the wall surface of the outer opening 54 in a film shape with the first electrode film 63 interposed therebetween, and a portion that covers the first main surface 3 in a film shape with the first electrode film 63 interposed therebetween in the outer opening 54. The second electrode film 64 is electrically connected to the outer contact region 44 via the first electrode film 63 in the outer opening 54.

The main electrode film 62 directly covers the lower electrode film 61 (the second electrode film 64). The main electrode film 62 entirely covers, in a film shape, the region of the interlayer film 52 in which the outer opening 54 is formed, and refills the outer opening 54.

The main electrode film 62 has a portion that covers the insulating main surface of the interlayer film 52 with the lower electrode film 61 interposed therebetween, a portion that covers the wall surface of the outer opening 54 with the lower electrode film 61 interposed therebetween, and a portion that covers the first main surface 3 with the lower electrode film 61 interposed therebetween. The main electrode film 62 is electrically connected to the outer contact region 44 via the lower electrode film 61 in the outer opening 54.

As in the case of the semiconductor device 1A, the semiconductor device 1G includes the gate electrode 66 arranged on the first main surface 3. As with the source electrode 60, the gate electrode 66 includes the lower electrode film 61 and the main electrode film 62 laminated in that order from the chip 2 side.

The gate electrode 66 is arranged on a portion of the interlayer film 52 that covers the first main surface 3 at an interval from the source electrode 60 in the active region 8. In this embodiment, the gate electrode 66 is arranged in a region on the third side surface 5C side with respect to the first pad portion 60a, and faces the first pad portion 60a in the first direction X. The gate electrode 66 is interposed in a region between the second pad portion 60b and the third pad portion 60c, and faces both the second pad portion 60b and the third pad portion 60c in the second direction Y.

The gate electrode 66 is formed in a polygonal shape (in this embodiment, a quadrilateral shape) having four sides parallel to the peripheral edge of the chip 2 in plan view. The gate electrode 66 has a planar area less than the planar area of the source electrode 60. The gate electrode 66 has a planar area less than the planar area of the first pad portion 60a. The gate electrode 66 may have a planar area less than the planar area of the second pad portion 60b (the third pad portion 60c).

The gate electrode 66 partially faces the plurality of gate structures 15 with the interlayer film 52 interposed therebetween. Specifically, the gate electrode 66 is arranged inward at an interval from the both end portions of the plurality of gate structures 15, and faces inner portions of the plurality of gate structures 15 with the interlayer film 52 interposed therebetween. In this embodiment, the gate electrode 66 does not have a direct electrical connection location to the plurality of gate structures 15.

As a matter of course, the gate electrode 66 may be electrically connected to the plurality of gate structures 15 via the plurality of gate openings 55. Portions of the plurality of gate structures 15 positioned at the gate electrode 66 may be removed. In this case, the gate electrode 66 may face the body region 10 with the main surface insulating film 50 and the interlayer film 52 interposed therebetween.

As in the case of the semiconductor device 1A, the semiconductor device 1G includes the gate wiring 67 led out from the gate electrode 66 onto the first main surface 3. As with the source electrode 60, the gate wiring 67 includes the lower electrode film 61 and the main electrode film 62 laminated in that order from the chip 2 side.

The gate wiring 67 is led out from the gate electrode 66 onto a portion of the interlayer film 52 that covers the planar wiring 90. The gate wiring 67 is routed on the planar wiring 90 in a band shape.

The gate wiring 67 has a portion extending in a band shape in the first direction X and a portion extending in a band shape in the second direction Y in plan view. In this embodiment, the gate wiring 67 is formed in a band shape with ends having four sides parallel to the peripheral edge of the first main surface 3, and surrounds the source electrode 60.

The gate wiring 67 enters the plurality of gate openings 55 from above the interlayer film 52, and is mechanically and electrically connected to the planar wiring 90 in the plurality of gate openings 55. The gate potential applied to the gate electrode 66 is thereby applied to the plurality of gate structures 15 via the planar wiring 90.

As in the case of the semiconductor device 1A, the semiconductor device 1G includes the drain electrode 68 that covers the second main surface 4. The drain electrode 68 is electrically connected to the first semiconductor region 6. The drain electrode 68 may cover the entire region of the second main surface 4 so as to be continuous to the peripheral edge (the first to fourth side surfaces 5A to 5D) of the second main surface 4. The drain electrode 68 may partially cover the second main surface 4 so as to expose the peripheral edge portion of the second main surface 4.

The breakdown voltage that can be applied between the source electrode 60 and the drain electrode 68 (between the first main surface 3 and the second main surface 4) may be not less than 500 V and not more than 3000 V. The breakdown voltage may have a value belonging to at least one range among not less than 500 V and not more than 750 V, 750 V and not more than 1000 V, not less than 1000 V and not more than 1250 V, not less than 1250 V and not more than 1500 V, not less than 1500 V and not more than 1750 V, and 1750 V and not more than 2000 V, not less than 2000 V and not more than 2250 V, not less than 2250 V and not more than 2500 V, not less than 2500 V and not more than 2750 V, and not less than 2750 V and not more than 3000 V.

As in the case of the semiconductor device 1A, the semiconductor device 1G may include any one of the features of the first outer peripheral structures 41 according to the first to tenth modification examples with respect to the first outer peripheral structures 41 according to the first to fifth configuration examples (see also FIGS. 11A to 11J). Of course, the features of the first outer peripheral structures 41 according to the first to tenth modification examples can be combined therebetween as appropriate.

Therefore, with respect to the first outer peripheral structures 41 according to the first to fifth configuration examples, the semiconductor device 1G may simultaneously include at least two of the features of the first outer peripheral structures 41 according to the first to tenth modification examples in the same or different regions.

At least one feature of the outer well region 43, the outer contact region 44, and the terminal region 45 according to the first to tenth modification examples is selected as appropriate according to the configurations of the first to fifth configuration examples, and is applied to the configurations of the first to fifth configuration examples.

The semiconductor device 1G may include any one of the features of the second outer peripheral structures 42 according to the first to tenth modification examples with respect to the second outer peripheral structures 42 according to the first to fifth configuration examples (see also FIGS. 12A to 12J). Of course, the features of the second outer peripheral structures 42 according to the first to tenth modification examples can be combined therebetween as appropriate.

Therefore, with respect to the second outer peripheral structures 42 according to the first to fifth configuration examples, the semiconductor device 1G may simultaneously include at least two of the features of the second outer peripheral structures 42 according to the first to tenth modification examples in the same or different regions. At least one feature of the field regions 47 according to the first to tenth modification examples is selected as appropriate according to the configurations of the first to fifth configuration examples, and is applied to the configurations of the first to fifth configuration examples.

The semiconductor device 1G may include one or a plurality of the features of the first outer peripheral structures 41 according to the first to tenth modification examples and one or a plurality of the features of the second outer peripheral structures 42 according to the first to tenth modification examples, together with the arrangement of any one of the first to fifth configuration examples.

The embodiment (including the modification examples) described above can be implemented in yet other modes. For example, in the first to sixth embodiments described above, an example in which the gate well region 30g and the gate contact region 31g are formed has been described. However, the gate well region 30g and the gate contact region 31g are not necessarily required, and may be omitted.

In the first to seventh embodiments described above, an example in which the terminal wiring 65 is connected to the source electrode 60 has been described. However, the terminal wiring 65 may be electrically disconnected from the source electrode 60. In this case, the terminal wiring 65 may be formed in an electrically floating state as a floating wiring or a field wiring (a so-called field pre-plate).

In the first to seventh embodiments described above, the chip 2 including the SiC monocrystal is adopted. However, the chip 2 may include a silicon monocrystal instead. Similarly, the first semiconductor region 6 may include a silicon monocrystal. Similarly, the second semiconductor region 7 may include a silicon monocrystal.

In the first to seventh embodiments described above, a structure in which the conductivity type of a semiconductor region of the “n-type” is inverted to the “p-type” and the conductivity type of a semiconductor region of the “p-type” is inverted to the “n-type” may be adopted. The specific arrangement in this case is obtained by replacing “n-type” with “p-type” and replacing “p-type” with “n-type” at the same time in the above description and attached drawings.

In the first to seventh embodiments described above, a collector region of the p-type may be formed in a surface layer portion of the second main surface 4 of the chip 2. In this case, the transistor structure Tr includes an IGBT (insulated gate bipolar transistor) structure in place of the MISFET structure.

The specific arrangement in this case is obtained by replacing the “source” of the MISFET structure with an “emitter” of the IGBT structure and replacing the “drain” of the MISFET structure with a “collector” of the IGBT structure in the above description. In this case, the chip 2 may have a single layer structure constituted of a semiconductor substrate of the n-type.

In the first to seventh embodiments described above, the first semiconductor region 6 (the second semiconductor region 7) may be formed as a portion or a whole of a cathode region of a semiconductor rectifier (a diode) and the body region 10 may be formed as a portion or a whole of an anode region of the semiconductor rectifier (the diode).

In this case, the source electrode 60 is formed as an anode electrode and the drain electrode 68 is formed as a cathode electrode. As a matter of course, a Schottky electrode (an anode electrode) forming a Schottky junction with the second semiconductor region 7 may be adopted in place of the body region 10 and the source electrode 60.

Hereinafter, examples of features extracted from this Description and the attached drawings are indicated. Hereinafter, the alphanumeric characters, etc., in parentheses represent the corresponding constituent elements, etc., in the embodiment described above, but are not intended to limit the scope of each clause to the embodiment. The “semiconductor device” in the following clauses may be replaced with an “SiC semiconductor device,” a “wide bandgap semiconductor device,” “a semiconductor switching device,” a “MISFET device,” an “IGBT device,” a “semiconductor rectifier,” etc., as needed.
[A1] A semiconductor device (1A to 1G) comprising: a chip (2) having a main surface (3); a semiconductor region (7) of a first conductivity type (an n-type) formed in a surface layer portion of the main surface (3); and a terminal region (45) of a second conductivity type (a p-type) formed in a surface layer portion of the semiconductor region (7) at an interval in a thickness direction of the chip (2) from the main surface (3) in a peripheral edge portion of the main surface (3).
[A2] The semiconductor device (1A to 1G) according to A1, wherein the chip (2) contains SiC.
[A3] The semiconductor device (1A to 1G) according to A1 or A2, wherein the terminal region (45) forms a pn junction portion with the semiconductor region (7).
[A4] The semiconductor device (1A to 1G) according to any one of A1 to A3, wherein the terminal region (45) faces the main surface (3) with a portion of the semiconductor region (7) interposed therebetween.
[A5] The semiconductor device (1A to 1G) according to any one of A1 to A4, wherein the terminal region (45) has a thickness greater than a distance between the main surface (3) and the terminal region (45).
[A6] The semiconductor device (1A to 1G) according to any one of A1 to A5, wherein the terminal region (45) is formed at an interval toward the main surface (3) side from a bottom portion of the semiconductor region (7).
[A7] The semiconductor device (1A to 1G) according to any one of A1 to A6, wherein the terminal region (45) has a thickness less than a distance between the bottom portion of the semiconductor region (7) and the terminal region (45).
[A8] The semiconductor device (1A to 1G) according to any one of A1 to A7, further comprising: a well region (43) of the second conductivity type (the p-type) formed in the surface layer portion of the main surface (3) in the peripheral edge portion of the main surface (3); and wherein the terminal region (45) is formed in the surface layer portion of the semiconductor region (7) in a region between a peripheral edge of the main surface (3) and the well region (43).
[A9] The semiconductor device (1A to 1G) according to A8, wherein the terminal region (45) is connected to the well region (43).
[A10] The semiconductor device (1A to 1G) according to A8 or A9, wherein the terminal region (45) has a bottom portion positioned below a depth position of a bottom portion of the well region (43).
[A11] The semiconductor device (1A to 1G) according to any one of A8 to A10, further comprising: a contact region (44) of the second conductivity type (the p-type) formed in a surface layer portion of the well region (43) and having an impurity concentration higher than an impurity concentration of the well region (43).
[A12] The semiconductor device (1A to 1G) according to A11, wherein the terminal region (45) has an impurity concentration less than the impurity concentration of the contact region (44).
[A13] The semiconductor device (1A to 1G) according to any one of A1 to A7, further comprising: a terminal electrode (65) arranged on the main surface (3) and electrically connected to the terminal region (45).
[A14] The semiconductor device (1A to 1G) according to A13, further comprising: a well region (43) of the second conductivity type (the p-type) formed in the surface layer portion of the main surface (3) in the peripheral edge portion of the main surface (3); and wherein the terminal region (45) is formed in a region between a peripheral edge of the main surface (3) and the well region (43) so as to be electrically connected to the well region (43), and the terminal electrode (65) is electrically connected to the well region (43).
[A15] The semiconductor device (1A to 1G) according to A14, further comprising: a contact region (44) of the second conductivity type (the p-type) formed in the surface layer portion of the well region (43) and having an impurity concentration higher than an impurity concentration of the well region (43); and wherein the terminal electrode (65) is electrically connected to the contact region (44).
[A16] The semiconductor device (1A to 1G) according to A15, further comprising: an insulating film (52) that covers the main surface (3); and an opening (54) formed in the insulating film (52) so as to expose the contact region (44); and wherein the terminal electrode (65) is arranged on the insulating film (52) and is electrically connected to the contact region (44) via the opening (54).
[A17] The semiconductor device (1A to 1G) according to any one of A1 to A16, further comprising: an active region (8) provided in an inner portion of the main surface (3); and an outer peripheral region (9) provided in the peripheral edge portion of the main surface (3); and wherein the terminal region (45) is formed in the outer peripheral region (9).
[A18] The semiconductor device (1A to 1G) according to A17, wherein the terminal region (45) extends in a band shape along the active region (8) in plan view.
[A19] The semiconductor device (1A to 1G) according to A17 or A18, further comprising: a transistor structure (Tr) formed in the active region (8).
[A20] The semiconductor device (1A to 1G) according to any one of A1 to A19, further comprising: a field region (47) of the second conductivity type (the p-type) formed in the surface layer portion of the semiconductor region (7) in a region between a peripheral edge of the main surface (3) and the terminal region (45).
[B1] A semiconductor device (1A to 1G) comprising: a chip (2) having a main surface (3); a semiconductor region (7) of a first conductivity type (an n-type) formed in a surface layer portion of the main surface (3); and a field region (47) of a second conductivity type (a p-type) formed in a surface layer portion of the semiconductor region (7) at an interval in a thickness direction of the chip (2) from the main surface (3) in a peripheral edge portion of the main surface (3).
[B2] The semiconductor device (1A to 1G) according to B1, wherein the chip (2) contains SiC.
[B3] The semiconductor device (1A to 1G) according to B1 or B2, wherein the field region (47) forms a pn junction portion with the semiconductor region (7).
[B4] The semiconductor device (1A to 1G) according to any one of B1 to B3, wherein the field region (47) faces the main surface (3) with a portion of the semiconductor region (7) interposed therebetween.
[B5] The semiconductor device (1A to 1G) according to any one of B1 to B4, wherein the field region (47) has a thickness greater than a distance between the main surface (3) and the field region (47).
[B6] The semiconductor device (1A to 1G) according to any one of B1 to B5, wherein the field region (47) is formed at an interval toward the main surface (3) side from a bottom portion of the semiconductor region (7).
[B7] The semiconductor device (1A to 1G) according to any one of B1 to B6, wherein the field region (47) has a thickness less than a distance between the bottom portion of the semiconductor region (7) and the field region (47).
[B8] The semiconductor device (1A to 1G) according to any one of B1 to B7, wherein the field region (47) extends in a band shape along a peripheral edge of the main surface (3).
[B9] The semiconductor device (1A to 1G) according to B8, wherein the field region (47) surrounds an inner portion of the main surface (3).
[B10] The semiconductor device (1A to 1G) according to any one of B1 to B9, wherein the field regions (47) are formed at an interval in the surface layer portion of the semiconductor region (7).
[B11] The semiconductor device (1A to 1G) according to B10, wherein the field regions (47) have mutually equal depths.
[B12] The semiconductor device (1A to 1G) according to any one of B1 to B11, further comprising: an active region (8) provided in the inner portion of the main surface (3); and an outer peripheral region (9) provided in the peripheral edge portion of the main surface (3); and wherein the field region (47) is formed in the outer peripheral region (9).
[B13] The semiconductor device (1A to 1G) according to B12, wherein the field region (47) extends in a band shape along the active region (8) in plan view.
[B14] The semiconductor device (1A to 1G) according to B12 or B13, wherein the field region (47) surrounds the active region (8) in plan view.
[B15] The semiconductor device (1A to 1G) according to any one of B12 to B14, further comprising: a transistor structure (Tr) formed in the active region (8).
[B16] The semiconductor device (1A to 1G) according to any one of B1 to B15, further comprising: a terminal region (45) of the second conductivity type (the p-type) formed in the surface layer portion of the semiconductor region (7) in the peripheral edge portion of the main surface (3); and wherein the field region (47) is formed in the surface layer portion of the semiconductor region (7) in a region between a peripheral edge of the main surface (3) and the terminal region (45).
[B17] The semiconductor device (1A to 1G) according to B16, wherein the field region (47) is formed to be narrower in width than the terminal region (45).
[B18] The semiconductor device (1A to 1G) according to B16 or B17, further comprising: a well region (43) of the second conductivity type (the p-type) formed in the surface layer portion of the main surface (3) in the peripheral edge portion of the main surface (3); and wherein the terminal region (45) is formed in the surface layer portion of the semiconductor region (7) in a region between the peripheral edge of the main surface (3) and the well region (43).
[B19] The semiconductor device (1A to 1G) according to B18, further comprising: a contact region (44) of the second conductivity type (the p-type) formed in a surface layer portion of the well region (43) and having an impurity concentration higher than an impurity concentration of the well region (43).
[B20] The semiconductor device (1A to 1G) according to any one of B16 to B19, further comprising: a terminal electrode (65) arranged on the main surface (3) at an interval toward the inner portion side of the main surface (3) from the field region (47) and electrically connected to the terminal region (45).
[C1] A semiconductor device (1A to 1G) comprising: a chip (2) having a main surface (3); a semiconductor region (7) of a first conductivity type (an n-type) formed in a surface layer portion of the main surface (3); a trench (16, 21, 26) formed in an inner portion of the main surface (3) so as to be positioned in the semiconductor region (7); and a terminal region (45) of a second conductivity type (a p-type) formed in a surface layer portion of the semiconductor region (7) in a peripheral edge portion of the main surface (3) and having a bottom portion positioned further to the main surface (3) side than a depth position of a bottom wall of the trench (16, 21, 26).
[C2] The semiconductor device (1A to 1G) according to C1, wherein the chip (2) contains SiC.
[C3] The semiconductor device (1A to 1G) according to C1 or C2, wherein the semiconductor region (7) is formed as a drift region.
[C4] The semiconductor device (1A to 1G) according to any one of C1 to C3, wherein the bottom portion of the terminal region (45) forms a pn junction portion with the semiconductor region (7).
[C5] The semiconductor device (1A to 1G) according to any one of C1 to C4, wherein the trench (16, 21, 26) is a gate trench (16).
[C6] The semiconductor device (1A to 1G) according to any one of C1 to C4, wherein the trench (16, 21, 26) is a source trench (21).
[C7] The semiconductor device (1A to 1G) according to any one of C1 to C4, wherein the trenches (16, 21, 26) are formed at an interval in the main surface (3).
[C8] The semiconductor device (1A to 1G) according to C7, wherein the trenches (16, 21, 26) include a gate trench (16) and a source trench (21), and the bottom portion of the terminal region (45) is positioned further to the main surface (3) side than at least a depth position of a bottom wall of the source trench (21).
[C9] The semiconductor device (1A to 1G) according to C8, wherein the source trench (21) has a depth equal to a depth of the gate trench (16).
[C10] The semiconductor device (1A to 1G) according to C8, wherein the source trench (21) has a depth greater than a depth of the gate trench (16).
[C11] The semiconductor device (1A to 1G) according to C7, wherein the trenches (16, 21, 26) include gate trenches (16) formed to be adjacent to each other at an interval on the main surface (3).
[C12] The semiconductor device (1A to 1G) according to any one of C1 to C11, wherein the terminal region (45) is formed at an interval in a thickness direction of the chip (2) from the main surface (3).
[C13] The semiconductor device (1A to 1G) according to C12, wherein the terminal region (45) has an upper end portion that faces the main surface (3) with a portion of the semiconductor region (7) interposed therebetween.
[C14] The semiconductor device (1A to 1G) according to C13, wherein the upper end portion of the terminal region (45) forms a pn junction portion with the semiconductor region (7).
[C15] The semiconductor device (1A to 1G) according to any one of C1 to C14, further comprising: a well region (43) of the second conductivity type (the p-type) formed in the surface layer portion of the semiconductor region (7) in the peripheral edge portion of the main surface (3); and wherein the terminal region (45) is formed in the surface layer portion of the semiconductor region (7) in a region between a peripheral edge of the main surface (3) and the well region (43).
[C16] The semiconductor device (1A to 1G) according to C15, wherein the terminal region (45) is connected to the well region (43).
[C17] The semiconductor device (1A to 1G) according to C15 or C16, further comprising: a contact region (44) of the second conductivity type (the p-type) formed in a surface layer portion of the well region (43) and having an impurity concentration higher than an impurity concentration of the well region (43); and wherein the terminal region (45) has an impurity concentration less than the impurity concentration of the contact region (44).
[C18] The semiconductor device (1A to 1G) according to any one of C1 to C17, further comprising: a field region (47) of the second conductivity type (the p-type) formed in the surface layer portion of the semiconductor region (7) in a region between a peripheral edge of the main surface (3) and the terminal region (45).
[C19] The semiconductor device (1A to 1G) according to C18, wherein the field region (47) is formed in the surface layer portion of the main surface (3) at an interval in the thickness direction of the chip (2) from the main surface (3).
[C20] The semiconductor device (1A to 1G) according to C18 or C19, wherein the field regions (47) are formed at an interval in the surface layer portion of the main surface (3).
[D1] A semiconductor device (1A to 1G) comprising: a chip (2) having a main surface (3); a semiconductor region (7) of a first conductivity type (an n-type) formed in a surface layer portion of the main surface (3); a trench (16, 21, 26) formed in an inner portion of the main surface (3) so as to be positioned in the semiconductor region (7); and a field region (47) of a second conductivity type (a p-type) formed in a surface layer portion of the semiconductor region (7) in a peripheral edge portion of the main surface (3) and having a bottom portion positioned further to the main surface (3) side than a depth position of a bottom wall of the trench (16, 21, 26).
[D2] The semiconductor device (1A to 1G) according to D1, wherein the chip (2) contains SiC.
[D3] The semiconductor device (1A to 1G) according to D1 or D2, wherein the semiconductor region (7) is formed as a drift region.
[D4] The semiconductor device (1A to 1G) according to any one of D1 to D3, wherein the bottom portion of the field region (47) forms a pn junction portion with the semiconductor region (7).
[D5] The semiconductor device (1A to 1G) according to any one of D1 to D4, wherein the trench (16, 21, 26) is a gate trench (16).
[D6] The semiconductor device (1A to 1G) according to any one of D1 to D4, wherein the trench (16, 21, 26) is a source trench (21).
[D7] The semiconductor device (1A to 1G) according to any one of D1 to D4, wherein the trenches (16, 21, 26) are formed at an interval in the main surface (3).
[D8] The semiconductor device (1A to 1G) according to D7, wherein the trenches (16, 21, 26) include a gate trench (16) and a source trench (21), and the bottom portion of the field region (47) is positioned further to the main surface (3) side than at least a depth position of a bottom wall of the source trench (21).
[D9] The semiconductor device (1A to 1G) according to D8, wherein the source trench (21) has a depth equal to a depth of the gate trench (16).
[D10] The semiconductor device (1A to 1G) according to D8, wherein the source trench (21) has a depth greater than a depth of the gate trench (16).
[D11] The semiconductor device (1A to 1G) according to D7, wherein the trenches (16, 21, 26) include gate trenches (16) that are formed to be adjacent to each other at an interval in the main surface (3).
[D12] The semiconductor device (1A to 1G) according to any one of D1 to D11, wherein the field region (47) is formed at an interval in a thickness direction of the chip (2) from the main surface (3).
[D13] The semiconductor device (1A to 1G) according to D12, wherein the field region (47) has an upper end portion that faces the main surface (3) with a portion of the semiconductor region (7) interposed therebetween.
[D14] The semiconductor device (1A to 1G) according to D13, wherein the upper end portion of the field region (47) forms a pn junction portion with the semiconductor region (7).
[D15] The semiconductor device (1A to 1G) according to any one of D12 to D14, wherein the field region (47) has a thickness greater than a distance between the main surface (3) and the field region (47).
[D16] The semiconductor device (1A to 1G) according to any one of D1 to D15, wherein the field region (47) extends in a band shape along a peripheral edge of the main surface (3).
[D17] The semiconductor device (1A to 1G) according to any one of D1 to D16, wherein the field regions (47) are formed at an interval in the surface layer portion of the semiconductor region (7).
[D18] The semiconductor device (1A to 1G) according to any one of D1 to D17, further comprising: a terminal region (45) of the second conductivity type (the p-type) formed in the surface layer portion of the main surface (3) in the peripheral edge portion of the main surface (3); and wherein the field region (47) is formed in the surface layer portion of the semiconductor region (7) in a region between a peripheral edge of the main surface (3) and the terminal region (45).
[D19] The semiconductor device (1A to 1G) according to D18, further comprising: a well region (43) of the second conductivity type (the p-type) formed in the surface layer portion of the semiconductor region (7) in the peripheral edge portion of the main surface (3); and wherein the terminal region (45) is formed in the surface layer portion of the semiconductor region (7) in a region between the peripheral edge of the main surface (3) and the well region (43).
[D20] The semiconductor device (1A to 1G) according to D19, further comprising: a contact region (44) of the second conductivity type (the p-type) formed in a surface layer portion of the well region (43) and having an impurity concentration higher than an impurity concentration of the well region (43); and wherein the terminal region (45) has an impurity concentration less than an impurity concentration of the contact region (44).
[E1] A semiconductor device (1A to 1G) comprising: a chip (2) having a main surface (3); a semiconductor region (7) of a first conductivity type (an n-type) formed in a surface layer portion of the main surface (3); a trench structure (25) formed in an inner portion of the main surface (3) so as to be positioned in the semiconductor region (7); a well region (43) of a second conductivity type (a p-type) formed in a surface layer portion of the semiconductor region (7) so as to be positioned at a peripheral edge portion side of the main surface (3) with respect to the trench structure (25); and a terminal region (45) of the second conductivity type (the p-type) formed in the surface layer portion of the semiconductor region (7) so as to be positioned at the peripheral edge portion side of the main surface (3) with respect to the well region (43).
[E2] The semiconductor device (1A to 1G) according to E1, wherein the chip (2) contains SiC.
[E3] The semiconductor device (1A to 1G) according to E1 or E2, wherein the well region (43) is connected to the trench structure (25).
[E4] The semiconductor device (1A to 1G) according to any one of E1 to E3, wherein the well region (43) has a bottom portion positioned at the main surface (3) side with respect to a depth position of a bottom wall of the trench structure (25).
[E5] The semiconductor device (1A to 1G) according to any one of E1 to E3, wherein the well region (43) has a bottom portion positioned below a depth position of the bottom wall of the trench structure (25).
[E6] The semiconductor device (1A to 1G) according to any one of E1 to E5, wherein the terminal region (45) has a bottom portion positioned at the main surface (3) side with respect to a depth position of the bottom wall of the trench structure (25).
[E7] The semiconductor device (1A to 1G) according to any one of E1 to E5, wherein the terminal region (45) has a bottom portion positioned below a depth position of a bottom wall of the trench structure (25).
[E8] The semiconductor device (1A to 1G) according to any one of E1 to E7, wherein the terminal region (45) has a bottom portion positioned below a depth position of a bottom portion of the well region (43).
[E9] The semiconductor device (1A to 1G) according to any one of E1 to E7, wherein the terminal region (45) has a bottom portion positioned at the main surface (3) side with respect to a depth position of a bottom portion of the well region (43).
[E10] The semiconductor device (1A to 1G) according to any one of E1 to E9, wherein the terminal region (45) is formed to be wider than the well region (43).
[E11] The semiconductor device (1A to 1G) according to any one of E1 to E10, wherein the terminal region (45) is connected to the well region (43).
[E12] The semiconductor device (1A to 1G) according to any one of E1 to E11, wherein the well region (43) is exposed from the main surface (3), and the terminal region (45) is formed at an interval in a thickness direction of the chip (2) from the main surface (3).
[E13] The semiconductor device (1A to 1G) according to any one of E1 to E12, further comprising: a trench well region (30, 30d) formed in a region along a bottom wall of the trench structure (25) in the chip (2).
[E14] The semiconductor device (1A to 1G) according to any one of E1 to E13, further comprising: a contact region (44) of the second conductivity type (the p-type) formed in a surface layer portion of the well region (43) and having an impurity concentration higher than an impurity concentration of the well region (43); and wherein the terminal region (45) has an impurity concentration less than the impurity concentration of the contact region (44).
[E15] The semiconductor device (1A to 1G) according to any one of E1 to E14, further comprising: a wiring (65) electrically connected to the trench structure (25) on the main surface (3).
[E16] The semiconductor device (1A to 1G) according to any one of E1 to E15, further comprising: an electrode (60) electrically connected to the trench structure (25) via the wiring (65) on the main surface (3).
[E17] The semiconductor device (1A to 1G) according to E16, wherein the electrode (60) is electrically connected to the well region (43) on the main surface (3).
[E18] The semiconductor device (1A to 1G) according to any one of E1 to E17, further comprising: a field region (47) of the second conductivity type (the p-type) formed in the surface layer portion of the semiconductor region (7) so as to be positioned at the peripheral edge portion side of the main surface (3) with respect to the terminal region (45).
[E19] The semiconductor device (1A to 1G) according to any one of E18, wherein the field region (47) has a bottom portion positioned at the main surface (3) side with respect to a depth position of the bottom wall of the trench structure (25).
[E20] The semiconductor device (1A to 1G) according to E18 or E19, wherein the field region (47) is formed at an interval in the thickness direction of the chip (2) from the main surface (3).
[F1] A semiconductor device (1A to 1G) comprising: a chip (2) having a first surface portion (71) and a second surface portion (72) recessed in a thickness direction with respect to the first surface portion (71); a semiconductor region (7) of a first conductivity type (an n-type) formed in a surface layer portion of the second surface portion (72); and a terminal region (45) of a second conductivity type (a p-type) formed in a surface layer portion of the semiconductor region (7) at an interval in a thickness direction of the chip (2) from the second surface portion (72).
[F2] The semiconductor device (1A to 1G) according to F1, wherein the chip (2) contains SiC.
[F3] The semiconductor device (1A to 1G) according to F1 or F2, wherein the terminal region (45) forms a pn junction portion with the semiconductor region (7).
[F4] The semiconductor device (1A to 1G) according to any one of F1 to F3, wherein the terminal region (45) faces the second surface portion (72) with a portion of the semiconductor region (7) interposed therebetween.
[F5] The semiconductor device (1A to 1G) according to any one of F1 to F4, wherein the terminal region (45) has a thickness greater than a distance between the second surface portion (72) and the terminal region (45).
[F6] The semiconductor device (1A to 1G) according to any one of F1 to F5, wherein the terminal region (45) is formed at an interval toward the second surface portion (72) side from a bottom portion of the semiconductor region (7).
[F7] The semiconductor device (1A to 1G) according to any one of F1 to F6, wherein the terminal region (45) has a thickness less than a distance between the bottom portion of the semiconductor region (7) and the terminal region (45).
[F8] The semiconductor device (1A to 1G) according to any one of F1 to F7, wherein the terminal region (45) extends in a band shape along the first surface portion (71) in plan view.
[F9] The semiconductor device (1A to 1G) according to F8, wherein the terminal region (45) surrounds the first surface portion (71) in plan view.
[F10] The semiconductor device (1A to 1G) according to any one of F1 to F9, further comprising: a well region (43) of the second conductivity type (the p-type) formed in the surface layer portion of the second surface portion (72); and wherein the terminal region (45) is formed in the surface layer portion of the semiconductor region (7) in a region between a peripheral edge of the second surface portion (72) and the well region (43).
[F11] The semiconductor device (1A to 1G) according to F10, wherein the terminal region (45) is connected to the well region (43).
[F12] The semiconductor device (1A to 1G) according to F10 or F11, wherein the terminal region (45) has a bottom portion positioned below with respect to a depth position of a bottom portion of the well region (43).
[F13] The semiconductor device (1A to 1G) according to any one of F10 to F12, further comprising: a contact region (44) of the second conductivity type (the p-type) formed in a surface layer portion of the well region (43) on the second surface portion (72) side and having an impurity concentration higher than an impurity concentration of the well region (43).
[F14] The semiconductor device (1A to 1G) according to F13, wherein the terminal region (45) has an impurity concentration less than the impurity concentration of the contact region (44).
[F15] The semiconductor device (1A to 1G) according to any one of F1 to F9, further comprising: a terminal electrode (65) arranged on the second surface portion (72) and electrically connected to the terminal region (45).
[F16] The semiconductor device (1A to 1G) according to F15, further comprising: a well region (43) of the second conductivity type (the p-type) formed in the surface layer portion of the second surface portion (72); and wherein the terminal region (45) is formed in a region between a peripheral edge of the second surface portion (72) and the well region (43), and the terminal electrode (65) is electrically connected to the well region (43).
[F17] The semiconductor device (1A to 1G) according to F16, further comprising: a contact region (44) of the second conductivity type (the p-type) formed in the surface layer portion of the well region (43) on the second surface portion (72) side and having an impurity concentration higher than an impurity concentration of the well region (43); and wherein the terminal electrode (65) is electrically connected to the well region (43) via the contact region (44).
[F18] The semiconductor device (1A to 1G) according to any one of F1 to F17, further comprising: a trench (16, 21, 26) formed in the first surface portion (71), wherein a bottom portion of the terminal region (45) is positioned below a depth position of a bottom wall of the trench (16, 21, 26).
[F19] The semiconductor device (1A to 1G) according to F18, wherein the trench (16, 21, 26) has a depth not more than a depth of the second surface portion (72).
[F20] The semiconductor device (1A to 1G) according to any one of F1 to F19, further comprising: a field region (47) of the second conductivity type (the p-type) formed in the surface layer portion of the semiconductor region (7) in a region between a peripheral edge of the second surface portion (72) and the terminal region (45).
[G1] A semiconductor device (1A to 1G) comprising: a chip (2) having a first surface portion (71) and a second surface portion (72) recessed in a thickness direction with respect to the first surface portion (71); a semiconductor region (7) of a first conductivity type (an n-type) formed in a surface layer portion of the second surface portion (72); and a field region (47) of a second conductivity type (a p-type) formed in a surface layer portion of the semiconductor region (7) at an interval in a thickness direction of the chip (2) from the second surface portion (72) in the second surface portion (72).
[G2] The semiconductor device (1A to 1G) according to G1, wherein the chip (2) contains SiC.
[G3] The semiconductor device (1A to 1G) according to G1 or G2, wherein the field region (47) forms a pn junction portion with the semiconductor region (7).
[G4] The semiconductor device (1A to 1G) according to any one of G1 to G3, wherein the field region (47) faces the second surface portion (72) with a portion of the semiconductor region (7) interposed therebetween.
[G5] The semiconductor device (1A to 1G) according to any one of G1 to G4, wherein the field region (47) has a thickness greater than a distance between the second surface portion (72) and the field region (47).
[G6] The semiconductor device (1A to 1G) according to any one of G1 to G5, wherein the field region (47) is formed at an interval toward the second surface portion (72) side from a bottom portion of the semiconductor region (7).
[G7] The semiconductor device (1A to 1G) according to any one of G1 to G6, wherein the field region (47) has a thickness less than a distance between the bottom portion of the semiconductor region (7) and the field region (47).
[G8] The semiconductor device (1A to 1G) according to any one of G1 to G7, wherein the field region (47) extends in a band shape along the first surface portion (71) in plan view.
[G9] The semiconductor device (1A to 1G) according to G8, wherein the field region (47) surrounds the first surface portion (71) in plan view.
[G10] The semiconductor device (1A to 1G) according to any one of G1 to G9, wherein the field regions (47) are formed at an interval in the surface layer portion of the semiconductor region (7).
[G11] The semiconductor device (1A to 1G) according to G10, wherein the field regions (47) have mutually equal depths.
[G12] The semiconductor device (1A to 1G) according to any one of G1 to G11, further comprising: a trench (16, 21, 26) formed in the first surface portion (71); and wherein a bottom portion of the field region (47) is positioned below a depth position of a bottom wall of the trench (16, 21, 26).
[G13] The semiconductor device (1A to 1G) according to G12, wherein the trench (16, 21, 26) has a depth not more than a depth of the second surface portion (72).
[G14] The semiconductor device (1A to 1G) according to any one of G1 to G13, further comprising: a terminal region (45) of the second conductivity type (the p-type) formed in the surface layer portion of the semiconductor region (7) in the second surface portion (72); and wherein the field region (47) is formed in a region between a peripheral edge of the second surface portion (72) and the terminal region (45).
[G15] The semiconductor device (1A to 1G) according to G14, wherein the terminal region (45) is formed in the thickness direction of the chip (2) at an interval from the second surface portion (72).
[G16] The semiconductor device (1A to 1G) according to G14 or G15, wherein the field region (47) is formed to be narrower in width than the terminal region (45).
[G17] The semiconductor device (1A to 1G) according to any one of G14 to G16, further comprising: a terminal electrode (65) arranged on the second surface portion (72) and electrically connected to the terminal region (45).
[G18] The semiconductor device (1A to 1G) according to any one of G14 to G16, further comprising: a well region (43) of the second conductivity type (the p-type) formed in the surface layer portion of the second surface portion (72); and wherein the terminal region (45) is formed in a region between the peripheral edge of the second surface portion (72) and the well region (43).
[G19] The semiconductor device (1A to 1G) according to G18, further comprising: a contact region (44) of the second conductivity type (the p-type) formed in a surface layer portion of the well region (43) on the second surface portion (72) side and having an impurity concentration higher than an impurity concentration of the well region (43).
[G20] The semiconductor device (1A to 1G) according to G18 or G19, further comprising: a terminal electrode (65) arranged on the second surface portion (72) and electrically connected to the well region (43).

While the specific embodiments have been described in detail above, this is merely a specific example used to clarify the technical contents. The various technical ideas extracted from this Description can be combined as appropriate with each other without being limited by the order of description, the order of configuration examples, the order of modification examples, etc., in this Description.

What is claimed is:

1. A semiconductor device comprising:
a chip having a main surface;
a semiconductor region of a first conductivity type formed in a surface layer portion of the main surface; and
a terminal region of a second conductivity type formed in a surface layer portion of the semiconductor region at an interval in a thickness direction of the chip from the main surface in a peripheral edge portion of the main surface.

2. The semiconductor device according to claim 1,
wherein the chip contains SiC.

3. The semiconductor device according to claim 1,
wherein the terminal region faces the main surface with a portion of the semiconductor region interposed therebetween.

4. The semiconductor device according to claim 1,
wherein the terminal region has a thickness greater than a distance between the main surface and the terminal region.

5. The semiconductor device according to claim 1, further comprising:
a well region of the second conductivity type formed in the surface layer portion of the main surface in the peripheral edge portion of the main surface; and
wherein the terminal region is formed in the surface layer portion of the semiconductor region in a region between a peripheral edge of the main surface and the well region.

6. The semiconductor device according to claim 5,
wherein the terminal region is connected to the well region.

7. The semiconductor device according to claim 5,
wherein the terminal region has a bottom portion positioned below a depth position of a bottom portion of the well region.

8. The semiconductor device according to claim 5, further comprising:
a contact region of the second conductivity type formed in a surface layer portion of the well region and having an impurity concentration higher than an impurity concentration of the well region; and
wherein the terminal region has an impurity concentration less than the impurity concentration of the contact region.

9. The semiconductor device according to claim 1, further comprising:
a terminal electrode arranged on the main surface and electrically connected to the terminal region.

10. The semiconductor device according to claim 1, further comprising:
a field region of the second conductivity type formed in the surface layer portion of the semiconductor region in a region between a peripheral edge of the main surface and the terminal region.

11. A semiconductor device comprising:
a chip having a main surface;
a semiconductor region of a first conductivity type formed in a surface layer portion of the main surface; and
a field region of a second conductivity type formed in a surface layer portion of the semiconductor region at an interval in a thickness direction of the chip from the main surface in a peripheral edge portion of the main surface.

12. The semiconductor device according to claim 11,
wherein the chip contains SiC.

13. The semiconductor device according to claim 11,
wherein the field region faces the main surface with a portion of the semiconductor region interposed therebetween.

14. The semiconductor device according to claim 11,
wherein the field region has a thickness greater than a distance between the main surface and the field region.

15. The semiconductor device according to claim 11,
wherein the field regions are formed at an interval in the surface layer portion of the semiconductor region.

16. The semiconductor device according to claim 11, further comprising:
a terminal region of the second conductivity type formed in the surface layer portion of the semiconductor region in the peripheral edge portion of the main surface; and
wherein the field region is formed in the surface layer portion of the semiconductor region in a region between a peripheral edge of the main surface and the terminal region.

17. The semiconductor device according to claim 16, further comprising:
a well region of the second conductivity type formed in the surface layer portion of the main surface in the peripheral edge portion of the main surface; and
wherein the terminal region is formed in the surface layer portion of the semiconductor region in a region between a peripheral edge of the main surface and the well region.

18. The semiconductor device according to claim 17, further comprising:
a contact region of the second conductivity type formed in a surface layer portion of the well region and having an impurity concentration higher than an impurity concentration of the well region.

19. The semiconductor device according to claim 16, further comprising:
a terminal electrode arranged on the main surface at an interval toward an inner portion side of the main surface from the field region and electrically connected to the terminal region.

20. The semiconductor device according to claim 11, further comprising:
an active region provided in an inner portion of the main surface;
an outer peripheral region provided in the peripheral edge portion of the main surface; and
a device structure formed in the active region; and
wherein the field region is formed in the outer peripheral region.
